(19) United States
(12) Patent Application Publication
(10) Pub. No.: US 2025/0048929 A1
(43) Pub. Date: Feb. 6, 2025

(54) ORGANIC MOLECULES USABLE IN OPTOELECTRONIC DEVICES

(71) Applicant: Samsung Display Co., Ltd., Yongin-si, Gyeonggi-do (KR)

(72) Inventor: Sebastian DÜCK, Heidelberg (DE)

(21) Appl. No.: 18/834,985

(22) PCT Filed: Feb. 3, 2023
(86) PCT No.: PCT/KR2023/001620

§ 371 Date: Jul. 31, 2024

(30) Foreign Application Priority Data
Feb. 4, 2022 (EP) 22155196.3

(51) Int. Cl. H10K 85/60; C07F 5/02; C09K 11/02; C09K 11/06; H10K 50/11; H10K 101/20

(52) U.S. Cl. CPC H10K 85/658; C07F 5/027; C09K 11/02; C09K 11/06; C09K 2211/1007; C09K 2211/1018; H10K 50/11; H10K 2101/20

(57) ABSTRACT

The invention relates to an organic molecule, including or consisting of Formula A:

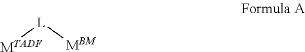

wherein
M^{TADF} represents a thermally activated delayed fluorescence (TADF) moiety,
L represents a direct bond or a divalent bridging unit that links M^{TADF} and M^{BN} and that is linked to M^{TADF} and to M^{BN} via a single bond each; and
M^{BN} represents an emitter moiety including a direct BN-bond.

Furthermore, the present invention relates to the use of such organic molecule as a luminescent emitter in an optoelectronic device.

### CROSS-REFERENCE TO RELATED APPLICATIONS

The present application is a U.S. National Phase patent application of International Patent Application Number PCT/KR2023/001620, filed on Feb. 3, 2023, which claims priority to and the benefit of European Patent Application Number 22155196.3, filed on Feb. 4, 2022, the entire content of each of which is incorporated herein by reference.

### TECHNICAL FIELD

The invention relates to light-emitting organic molecules and their use in organic light-emitting diodes (OLEDs) and in other optoelectronic devices.

### BACKGROUND ART

Organic electroluminescent devices containing one or more light-emitting layers based on organics such as, e.g., organic light emitting diodes (OLEDs), light emitting electrochemical cells (LECs), and light-emitting transistors gain increasing importance. In particular, OLEDs are promising devices for electronic products such as e.g., screens, displays, and illumination devices. In contrast to most electroluminescent devices essentially based on inorganics, organic electroluminescent devices based on organics are often rather flexible and producible in particularly thin layers. The OLED-based screens and displays already available today bear particularly beneficial brilliant colors, contrasts and are comparably efficient with respect to their energy consumption.

A central element of an organic electroluminescent device for generating light is a light-emitting layer placed between an anode and a cathode. When a voltage (and current) is applied to an organic electroluminescent device, holes and electrons are injected from an anode and a cathode, respectively, to the light-emitting layer. Typically, a hole transport layer is located between the light-emitting layer and the anode, and an electron transport layer is located between the light-emitting layer and the cathode. The different layers are sequentially disposed. Excitons of high energy are then generated by recombination of the holes and the electrons. The decay of such excited states (e.g., singlet states such as S1 and/or triplet states such as T1) to the ground state (S0) desirably leads to light emission.

In order to enable efficient energy transport and emission, an organic electroluminescent device includes one or more host compounds and one or more emitter compounds as dopants. Challenges when generating organic electroluminescent devices are thus the improvement of the illumination level of the devices (i.e., brightness per current), obtaining a desired light spectrum and achieving suitable (long) lifespans.

### DISCLOSURE

### Technical Problem

There is still a need for efficient and stable OLEDs, in particular efficient and stable OLEDs that emit in the blue region of the visible light spectrum, which would be expressed by a small CIEy value. Accordingly, there is still the unmet technical need for organic electroluminescent devices which have a long lifetime and high quantum yields, in particular in the blue range.

Exciton-polaron interaction (triplet-polaron and singlet-polaron interaction) as well as exciton-exciton interaction (singlet-singlet, triplet-singlet, and triplet-triplet interaction) are major pathways for device degradation. Degradation pathways such as triplet-triplet annihilation (TTA) and triplet-polaron quenching (TPQ) are of particular interest for blue emitting devices, as high energy states are generated. In particular, charged emitter molecules are prone to high energy excitons and/or polarons.

A suitable way to avoid the described degradation pathways and to enable an efficient energy transfer within the emission layer are the so-called “Hyper-” approaches, in which a thermally activated delayed fluorescence (TADF) material is employed to up-convert triplet excitons to singlet excitons, which are then transferred to the emitter, which emits light upon the decay of the singlet excited states to the ground state. As singlet emitters e.g., fluorescence emitters (Hyper-fluorescence), NRCT emitters (Hyper-NRCT), or TADF emitters (Hyper-TADF) can be employed.

The efficiencies and lifetimes of OLEDs employing “Hyper-” approaches available in the state of the art are limited due to several factors. To ensure efficient energy transfer, the radiation-free transfer of singlet excitons from the TADF material to the singlet emitter a sufficient, called Förster Resonance Energy Transfer (FRET), has to be realized. The FRET rate strongly depends on the distance between the TADF material and the singlet emitter and the so-called Förster radius. The Förster radius strongly depends on the emission wavelength of the singlet-exciton-donating molecule and decreases with shorter, i.e., blue-shifted, wavelength. A known way to ensure efficient Förster transfer in Hyper-systems is to increase the concentration of either the singlet emitter or the singlet-exciton-donating TADF material (FRET-donor) in the emission layer to increase the probability that a singlet emitter is located within the Förster radius of the singlet-exciton-donating TADF material. Increasing the singlet emitter, in particular the fluorescence or NRCT, concentration leads to π-stacking and/or exciplex formation of the singlet emitter resulting in emission shifting and/or broadening. In addition, with increasing concentration, the charges, in particular holes, are more likely to get trapped on the singlet emitter causing stress and potentially leading to degradation, e.g., hole trapping can lead to undesired direct charge recombination on the emitter acting as a trap. In addition, increasing the singlet emitter concentration leads to losses in efficiency due to quenching.

Analogously, increasing the TADF material concentration leads to losses in efficiency due to quenching. In addition, in case of higher concentrations triplet excitons can be transferred from the TADF material to the singlet emitter (Dexter transfer) before these are up-converted to singlet-excitons by the TADF material. Triplet excitons on the singlet emitter may decay without emission or be up-converted via a less efficient mechanism than TADF (e.g., triplet-triplet annihilation, TTA), in case the singlet emitter is a fluorescence emitter, which will result in reduced efficiency. On the other hand, near range charge transfer (NRCT) emitters are more prone to degradation by triplet excitons compared to TADF materials.

### Technical Solution

Surprisingly, it has been found that the organic molecules according to the invention, which combine a thermally activated delayed fluorescence (TADF) material moiety M^{TADF} and an emitter moiety including a direct BN-bond M^{BN} (or BN, boron-nitrogen bond) in one molecule, exhibit the advantageous effects without the described limitations of the Hyper-NRCT approach. The TADF moiety M^{TADF} and the emitter moiety including a direct BN-bond M^{BN} are bridged via a bridging unit L, which is chosen to enable a sufficient FRET from the TADF moiety to the emitter moiety including a direct BN-bond M^{BN} while inhibiting undesired Dexter transfer and, at the same time, leaving both the TADF properties of M^{TADF} and the emitter moiety including a direct BN-bond M^{BN} intact. Consequently, an emission layer including the organic molecules according to the invention provides an organic electroluminescent device having good lifetime and quantum yields and exhibiting blue emission.

One further advantageous effect of the organic molecules according to the invention is the reduced number of molecules to be processed during the production of an organic electroluminescent device, such as an OLED display, employing the Hyper-NRCT approach, as both the TADF and the NRCT function are combined in one molecule. In an evaporation process, the number of sources and complexity in the regulation of evaporation rates can thus advantageously be reduced.

According to the present invention, the organic molecules preferably exhibit emission maxima in the blue, sky-blue, or green spectral range. The organic molecules exhibit in particular emission maxima between 420 nm and 520 nm, preferably between 440 nm and 495 nm, more preferably between 450 nm and 470 nm. The photoluminescence quantum yields of the organic molecules according to the invention are, in particular, 60% or more.

An organic molecule according to the invention consist of a structure according to Formula A:

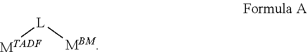

M^{TADF} represents a TADF moiety;
L represents a direct bond (single bond) or a divalent bridging unit that links M^{TADF} and M^{BN} and that is linked to M^{TADF} and to M^{BN} via a single bond each; and
M^{BN} represents an emitter moiety including a direct BN-bond.

The organic molecule may preferably be an organic light-emitting molecule. Such organic light-emitting molecule can also be designated as “emitter”, “emitter compound”, or “emitter molecule”. The organic molecule including such BN emitter moiety may also be considered as a BN emitter or BN material.

The terms “emitter moiety including a direct BN-bond”, “BN emitter moiety”, “BN moiety”, and its abbreviation M^{BN} may be understood interchangeably.

The term “small FWHM” refers to an emission spectrum with a full width at half maximum (FWHM) of less than or equal to 0.25 eV. If not stated otherwise, the emission spectrum of the TADF moiety is performed using a spin-coated film of the respective TADF moiety in poly(methyl methacrylate) (PMMA) with 1-10% by weight, in particular 10% by weight, of the respective TADF moiety, and the emission spectrum of the BN moiety is measured in a solution, typically with 0.001-0.2 mg/mL of the BN moiety in dichloromethane or toluene at room temperature (i.e., (approximately) 20° C.). The emission spectrum of a “small FWHM emitter” has a small FWHM.

A thermally activated delayed fluorescence (TADF) moiety is characterized by exhibiting a ΔE_{ST} value, which corresponds to the energy difference between the lowermost excited singlet state energy level E(S1^{E}) and the lowermost excited triplet state energy level E(T1^{E}), of less than 0.4 eV, preferably of less than 0.3 eV, more preferably of less than 0.2 eV, even more preferably of less than 0.1 eV, or even of less than 0.05 eV. Thus, ΔE_{ST} of a TADF moiety according to the invention may be sufficiently small to allow for thermal repopulation of the lowermost excited singlet state S1^{E} from the lowermost excited triplet state T1^{E} (also referred to as up intersystem crossing or reverse intersystem crossing, RISC) at room temperature (RT, i.e., (approximately) 20° C.).

Unless stated otherwise, the energy of the first (i.e., the lowermost) excited triplet state T1 is determined from the onset the phosphorescence spectrum at 77 K (for TADF moieties,
a spin-coated film of 10% by weight of TADF moiety in PMMA is typically used; for BN materials, a spin-coated film of 1-5%, preferably 2% by weight, of BN material in PMMA is typically used. As laid out for instance in EP2690681A1, it is acknowledged that for TADF materials with small ΔE_{ST} values, intersystem crossing and reverse intersystem crossing may both occur even at low temperatures. In consequence, the emission spectrum at 77 K may include emission from both, the S1 and the T1 state. However, as also described in EP2690681A1, the contribution/value of the triplet energy is typically considered dominant.

Unless stated otherwise, the energy of the first (i.e., the lowermost) excited singlet state S1 is determined from the onset the fluorescence spectrum at room temperature (i.e., approx. 20° C.) (steady-state spectrum; for TADF materials, a spin-coated film of 10% by weight of TADF material in PMMA is typically used; for BN materials, a solution, typically with 0.001-0.2 mg/mL, of the BN material in dichloromethane or toluene at room temperature (i.e., (approximately) 20° C.) is typically used.

NRCT emitters show a delayed component in the time-resolved photoluminescence spectrum and exhibit a near-range HOMO-LUMO separation. Typical NRCT emitters only show one emission band in the emission spectrum, wherein typical fluorescence emitters display several distinct emission bands due to vibrational progression. The skilled artisan knows how to design and synthesize NRCT emitters that may be suitable as small FWHM emitters in the context of the present invention. BN moieties might be NRCT emitters.

If not state otherwise, the FWHM and the emission maximum of the BN moiety and the TADF moiety is determined from the fluorescence spectrum at room temperature (i.e., approx. 20° C.) (steady-state spectrum; for TADF materials, a spin-coated film of 10% by weight of TADF material in PMMA is typically used; for BN materials, a solution, typically with 0.001-0.2 mg/mL, of the BN material in dichloromethane or toluene at room temperature (i.e., (approximately) 20° C.).

### Selection Criteria:

Preferably, the combination of TADF moiety M^{TADF} and emitter moiety including a direct BN-bond M^{BN} should be chosen to meet the following criteria:
Equation 1 is met (emission maxima relation):

$${λ}_{max} ( TADF ) < {λ}_{max} ( BN ) , \qquad Equation 1$$

λₘₐₓ(TADF) represents the emission maximum of the emission spectrum of a poly(methyl methacrylate) (PMMA) film with 10% by weight of the isolated; i.e., the substituent which represents the binding site of the single bond connecting the TADF moiety M^{TADF} and bridging unit L of M^{TADF} is replaced by a hydrogen (H) substituent; TADF material (M^{TADF}-H). All λₘₐₓ are given in nanometers.
λₘₐₓ(BN) represents the emission maximum of the emission spectrum of an organic solvent,
preferably DCM or toluene, with 0.001 mg/mL of the isolated emitter moiety including a direct BN-bond M^{BN}; i.e., the substituent which represents the binding site of the single bond connecting M^{BN} and bridging unit L of M^{BN} is replaced by a hydrogen (H) substituent; BN material (M^{BN}-H).

Spectral overlap of TADF emission and BN absorption:
M^{TADF} and M^{BN} are chosen to give a maximum resonance. The resonance between M^{TADF} and M^{BN} is represented by the spectral overlap integral:

$$J = {\int }_{0}^{∞} f ( λ ) ∈ ( λ ) {λ}_{max}^{4} ( T A D F ) d λ ,$$

wherein f(λ) is the normalized emission spectrum F(λ) of the isolated TADF material:

$$f ( λ ) = F ( λ ) / {\int }_{0}^{∞} F ( λ ) d λ ,$$

ϵ(λ) is the molar extinction coefficient of the isolated BN material.

### The Bridging Unit L:

The bridging unit L is chosen to enable sufficient FRET between M^{TADF} and M^{BN} while inhibiting undesired Dexter transfer. The FRET rate depends on the distance between the singlet exciton donor, i.e., M^{TADF}, and the singlet exciton acceptor, i.e., M^{BN}, to the inverse of the power of six. The Dexter transfer rate exponentially decays with the distance between the singlet exciton donor, i.e., the TADF moiety M^{TADF}, and the singlet exciton acceptor, i.e., the BN emitter moiety. The length of the bridging unit L thus should be chosen to provide a distance between the M^{TADF} and M^{BN} that minimizes the ratio of Dexter transfer rate to FRET rate.

In one embodiment of the invention, L includes or consists of one or more consecutively linked divalent moieties selected from the group consisting of:
a direct bond (single bond);
C₆-C₆₀-arylene, which is optionally substituted with one or more substituents R^{L};
C₃-C₅₇-heteroarylene, which is optionally substituted with one or more substituents R^{L};
R^{L}Si(R^{L}₂);
Si(R^{L}₂)R^{L};
Si(R^{L}₂); and
R^{L}Si(R^{L}₂)R^{L};
wherein R^{L} is at each occurrence independently from each other selected from the group consisting of:
   Ph, which is optionally substituted with one or more substituents independently from each other selected from the group consisting of C₁-C₄ alkyl, C₁-C₄ haloalkyl, CN, CF₃, and Ph;
   C₁-C₄ alkyl, C₁-C₄ haloalkyl, CN, CF₃, and Ph;
   pyridinyl and pyridinylene, each of which is optionally substituted with one or more substituents independently from each other selected from the group consisting of C₁-C₄ alkyl, C₁-C₄ haloalkyl, CN, CF₃, and Ph;
   pyrimidinyl and pyrimidinylene, each of which is optionally substituted with one or more substituents independently from each other selected from the group consisting of C₁-C₄ alkyl, C₁-C₄ haloalkyl, CN, CF₃, and Ph;
   carbazolyl and carbazolylene, each of which is optionally substituted with one or more substituents independently from each other selected from the group consisting of C₁-C₄ alkyl, C₁-C₄ haloalkyl, CN, CF₃, and Ph;
   triazinyl and triazinylene, each of which is optionally substituted with one or more substituents independently from each other selected from the group consisting of Me, C₁-C₄ alkyl, C₁-C₄ haloalkyl, CN, CF₃, and Ph;
and
   N(Ph)₂.

In one embodiment of the invention, L is selected from the group consisting of:
a direct bond;
C₆-C₆₀-arylene,
which is optionally substituted with one or more substituents R^{L};
C₃-C₅₇-heteroarylene, which is optionally substituted with one or more substituents R^{L};
C₆-C₆₀-arylene-C₃-C₅₇-heteroarylene, which is optionally substituted with one or more substituents R^{L};
C₃-C₅₇-heteroarylene-C₆-C₆₀-arylene, which is optionally substituted with one or more substituents R^{L};
C₆-C₆₀-arylene-C₆-C₆₀-arylene, which is optionally substituted with one or more substituents R^{L};
C₃-C₅₇-heteroarylene-C₃-C₅₇-heteroarylene, which is optionally substituted with one or more substituents R^{L};
C₆-C₆₀-arylene-C₃-C₅₇-heteroarylene-C₆-C₆₀-arylene, which is optionally substituted with one or more substituents R^{L};
C₃-C₅₇-heteroarylene-C₆-C₆₀-arylene-C₃-C₅₇-heteroarylene, which is optionally substituted with one or more substituents R^{L};
C₆-C₆₀-arylene-C₆-C₆₀-arylene-C₆-C₆₀-arylene, which is optionally substituted with one or more substituents R^{L};
C₃-C₅₇-heteroarylene-C₃-C₅₇-heteroarylene-C₃-C₅₇-heteroarylene, which is optionally substituted with one or more substituents R^{L};
R^{L}Si(R^{L}₂);
Si(R^{L}₂)R^{L};
Si(R^{L}₂); and
R^{L}Si(R^{L}₂)R^{L}—.

In this embodiment, R^{L} is at each occurrence independently from each other selected from the group consisting of:
Me, ⁱPr, ^{t}Bu, CN, CF₃;
Ph, which is optionally substituted with one or more substituents independently from each other selected from the group consisting of Me, ⁱPr, ^{t}Bu, CN, CF₃, and Ph;
pyridinyl and pyridinylene, each of which is optionally substituted with one or more substituents independently from each other selected from the group consisting of Me, ⁱPr, ^{t}Bu, CN, CF₃, and Ph;
pyrimidinyl and pyrimidinylene, each of which is optionally substituted with one or more substituents independently from each other selected from the group consisting of Me, ⁱPr, ^{t}Bu, CN, CF₃, and Ph;
carbazolyl and carbazolylene, each of which is optionally substituted with one or more substituents independently from each other selected from the group consisting of Me, ⁱPr, ^{t}Bu, CN, CF₃, and Ph;
triazinyl and triazinylene, each of which is optionally substituted with one or more substituents independently from each other selected from the group consisting of Me, ⁱPr, ^{t}Bu, CN, CF₃, and Ph;
and
N(Ph)₂.

In one embodiment, L is selected from the group consisting of structures of Formula L1 to L43:

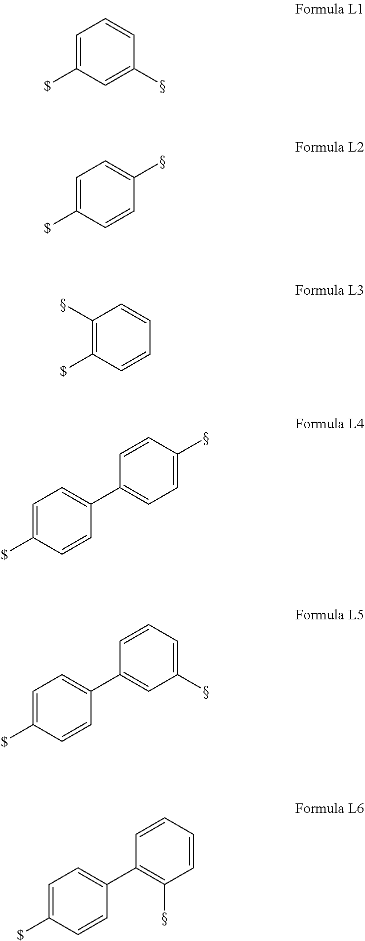

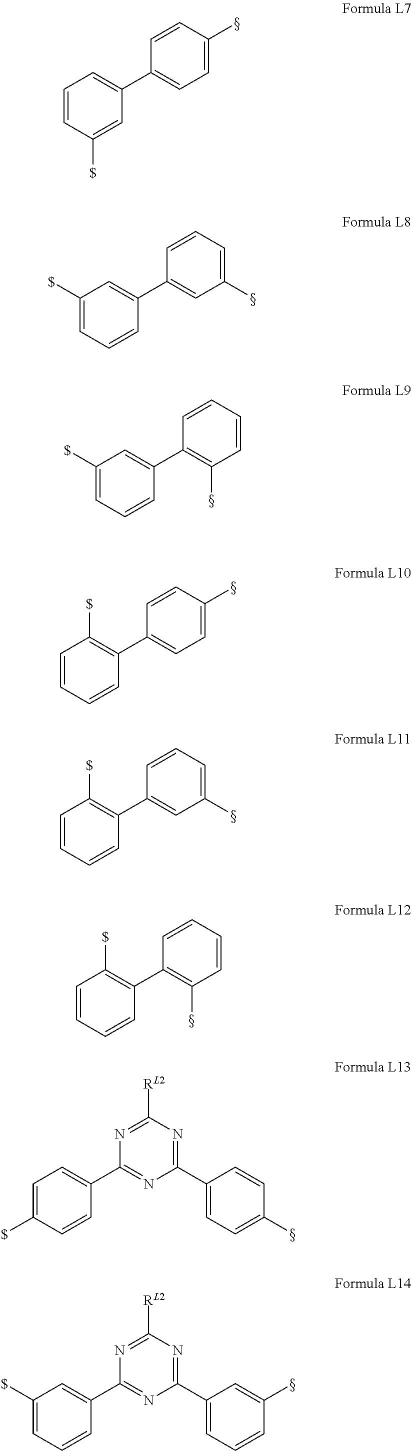

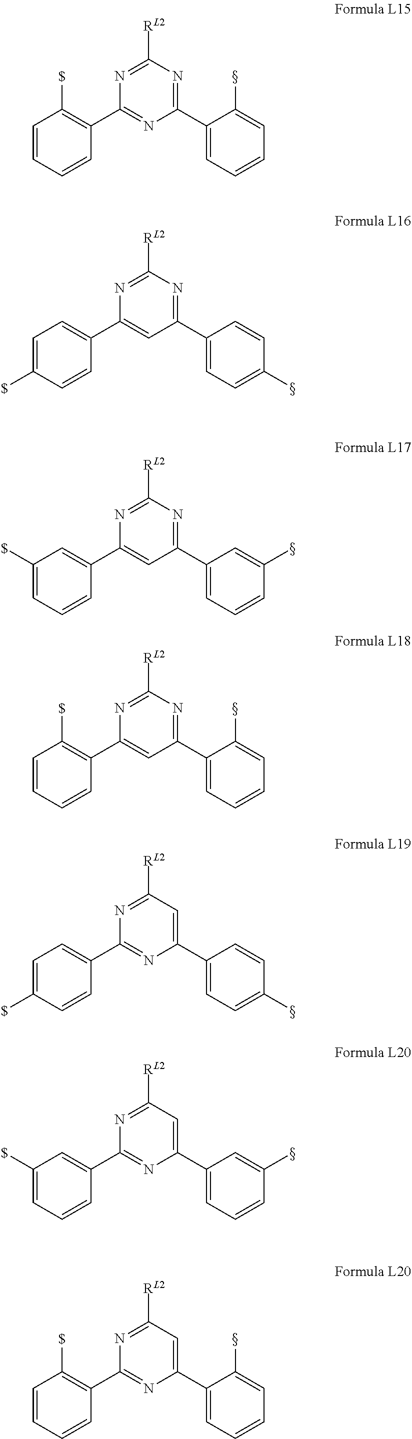

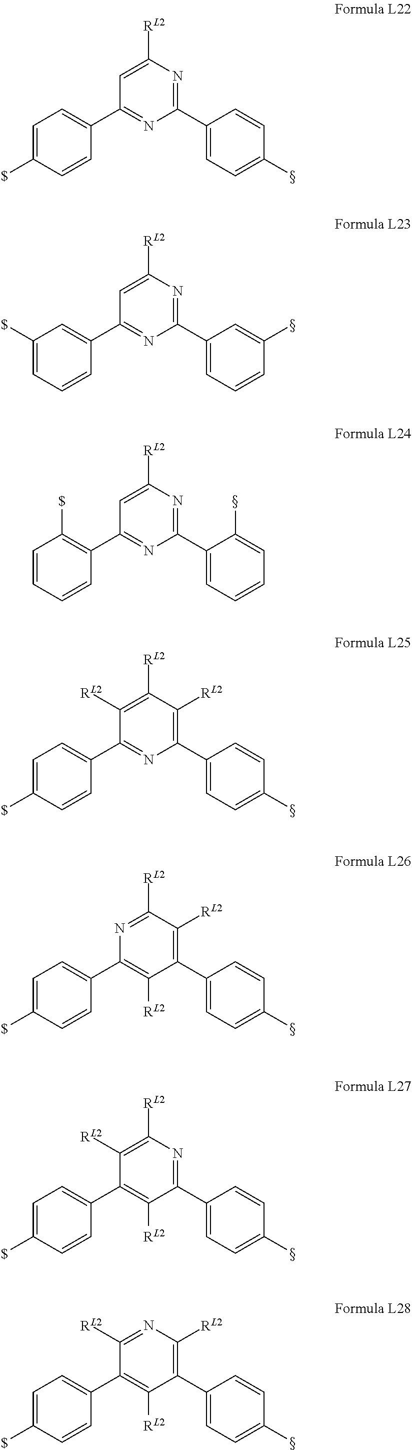

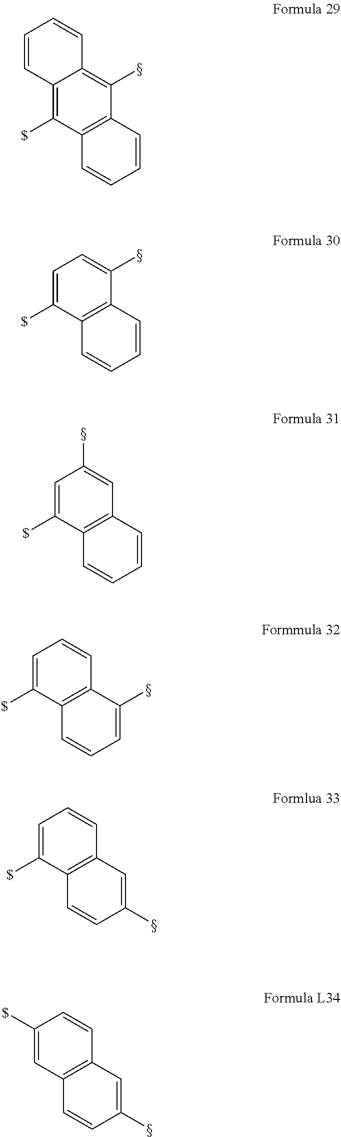

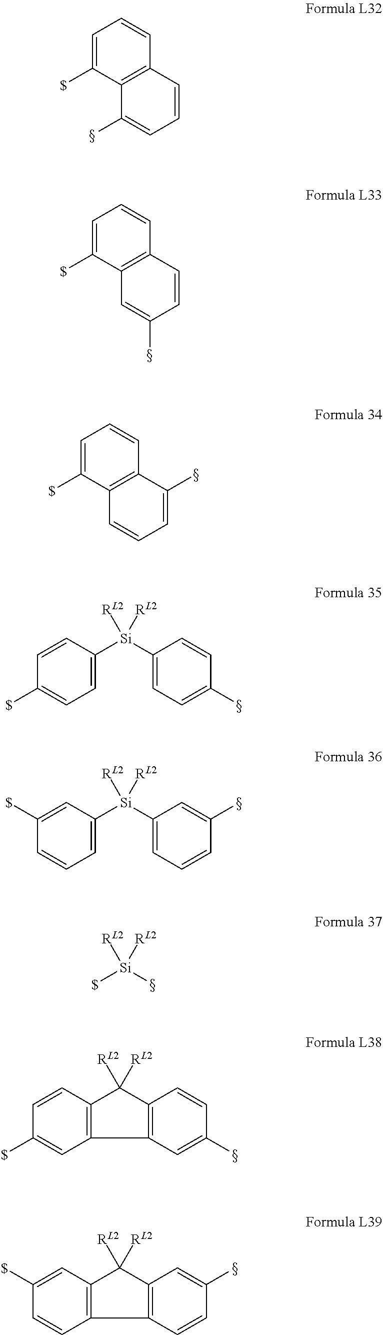

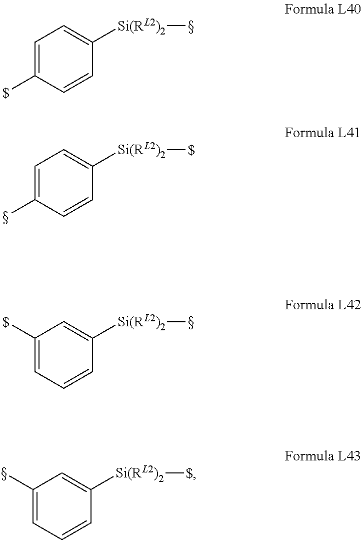

wherein $ represents the binding site of the single band linking L and M^{TADF}.

§ represents the binding site of the single band linking L and M^{B}N.

R^{L2} is at each occurrence independently selected from the group consisting of H, deuterium, Me, ^{t}Bu, ⁱPr, Ph, and pyridyl.

In a further embodiment, L is selected from the group consisting of structures of Formula L1, L2, L4, L8, L12, L35, L36, L37, L40, L41, L42, and L43:

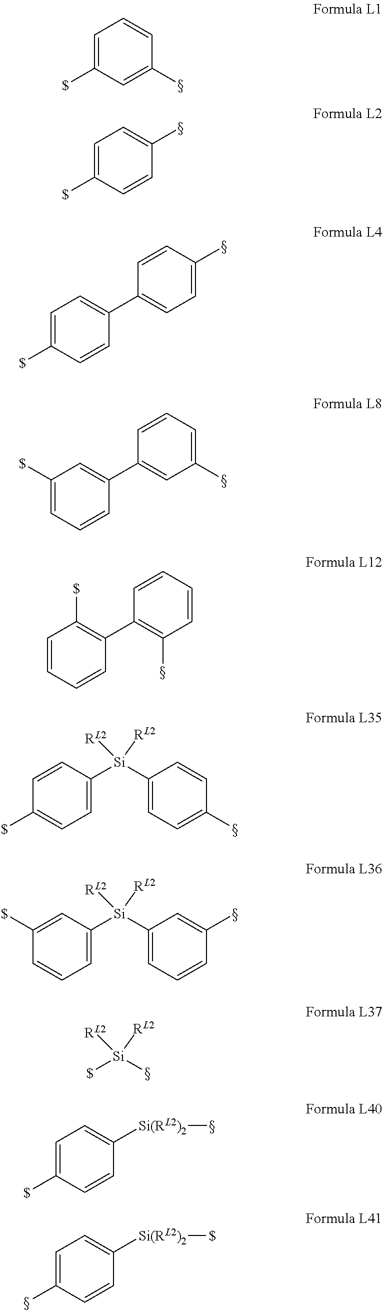

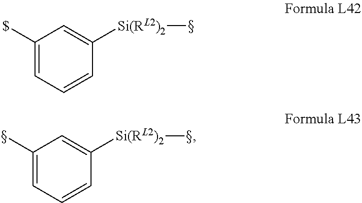

In a further embodiment, R^{L} is at each occurrence independently selected from the group consisting of H, Me, ^{t}Bu, and Ph.

### The BN Emitter Moiety M^{BN}:

Emitter materials including a direct B—N bond are known in the state of the art to perform beneficial emitter properties, such as an emission with a small full-width-at-half-maximum (FWHM) and high photoluminescence quantum yield (PLQY). Optionally and preferably, BN materials might also be near-range-charge-transfer (NRCT) emitters.

A class of molecules including a direct B—N bond are the well-known 4,4-difluoro-4-bora-3a,4a-diaza-s-indacene (BODIPY)-based materials, whose structural features and application in organic electroluminescent devices have been reviewed in detail and are common knowledge to those skilled in the art. The state of the art also reveals how such materials may be synthesized and how to arrive at an emitter with a certain emission color.

See for example: J. Liao, Y. Wang, Y. Xu, H. Zhao, X. Xiao, X. Yang, Tetrahedron 2015, 71(31), 5078, DOI: 10.1016/j.tet.2015.05.054; B. M Squeo, M. Pasini, Supramolecular Chemistry 2020, 32(1), 56-70, DOI: 10.1080/10610278.2019.1691727; M. Poddar, R. Misra, Coordination Chemistry Reviews 2020, 421, 213462-213483; DOI: 10.1016/j.ccr.2020.213462.

The skilled artisan is also familiar with the fact that the BODIPY base structure shown below

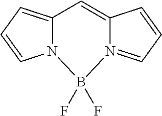

is not ideally suitable as emitter in an organic electroluminescent device, for example due to intermolecular π-π interactions and the associated self-quenching.

It is common knowledge to those skilled in the art that one may arrive at more suitable emitter molecules for organic electroluminescent devices by attaching bulky groups as substituents to the BODIPY core structure shown above. These bulky groups may for example (among many others) be aryl, heteroaryl, alkyl, or alkoxy substituents or condensed polycyclic aromatics, or heteroaromatics, all of which may optionally be substituted. The choice of suitable substituents at the BODIPY core is obvious for the skilled artisan and can easily be derived from the state of the art. The same holds true for the multitude of synthetic pathways which have been established for the synthesis and subsequent modification of such molecules.

See for example: B. M Squeo, M. Pasini, Supramolecular Chemistry 2020, 32(1), 56-70, DOI: 10.1080/10610278.2019.1691727; M. Poddar, R. Misra, Coordination Chemistry Reviews 2020, 421, 213462-213483; DOI: 10.1016fj.ccr.2020.213462.l

Examples of BODIPY-based emitters that may be suitable as BN emitters are shown below:

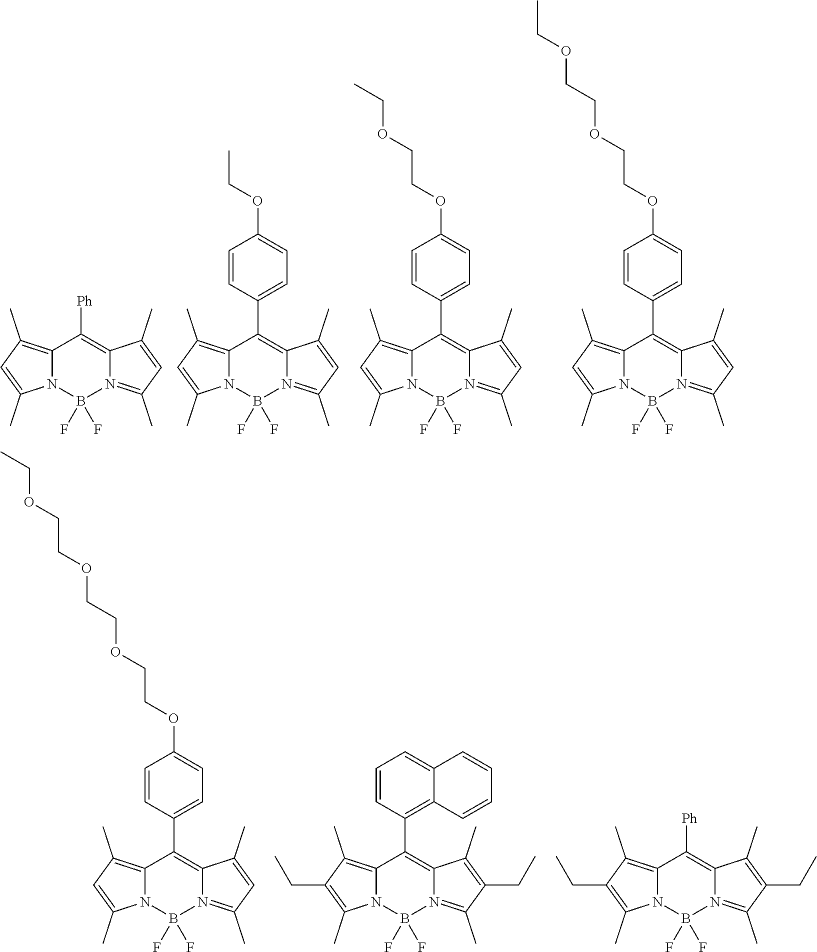

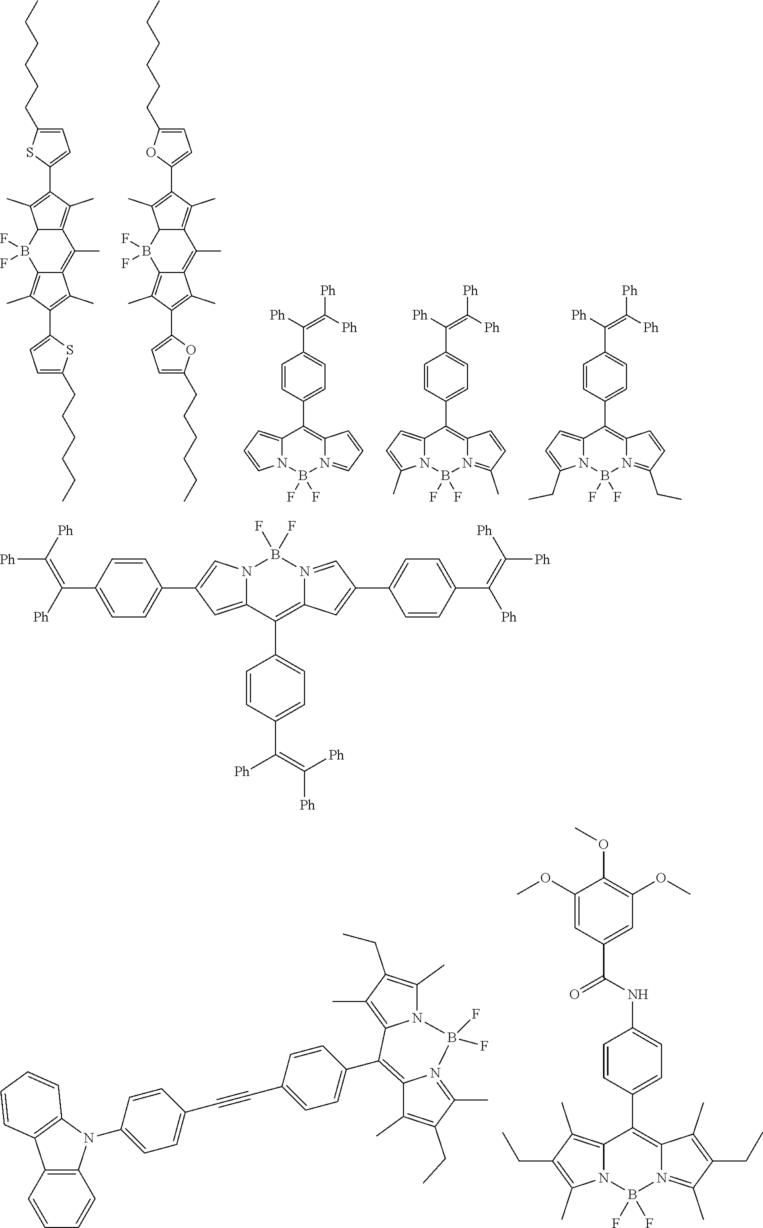

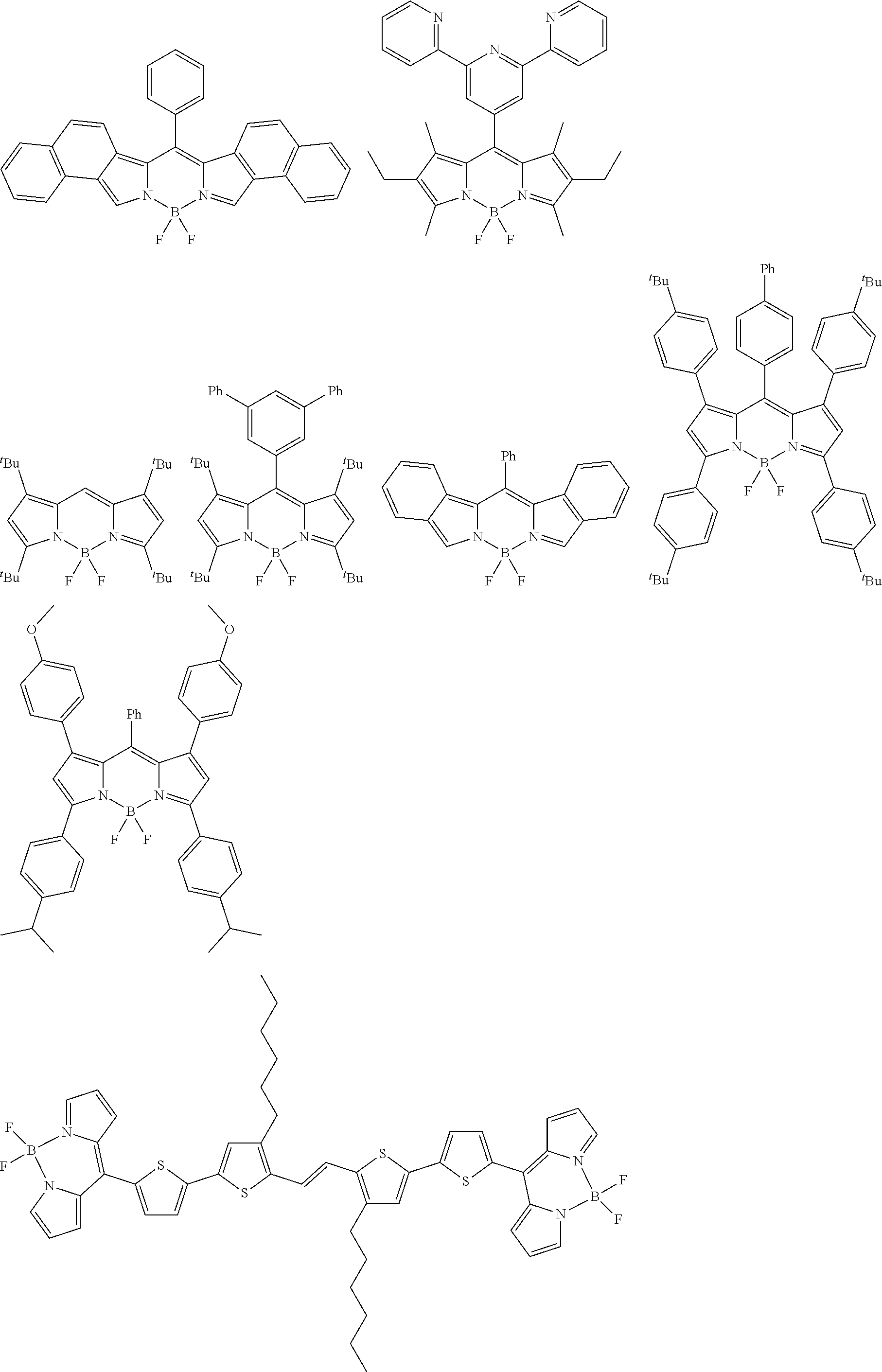

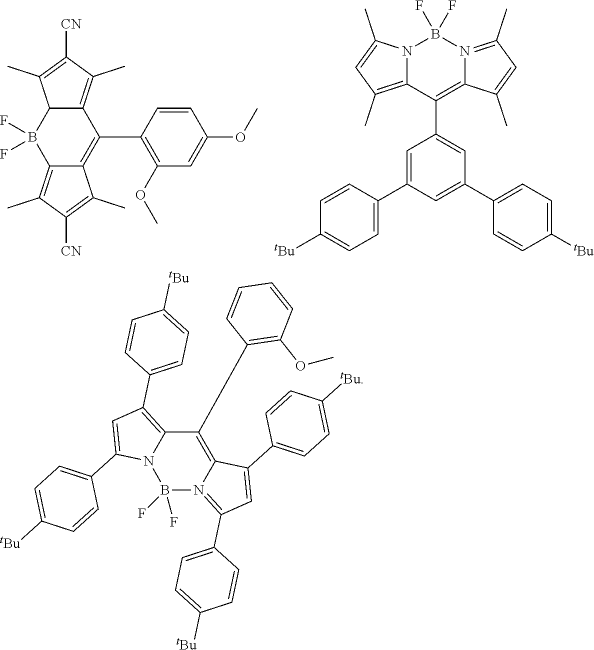

It is understood that this does not imply that BODIPY-derivatives with other structural features than those shown above are not suited as BN emitters.

For example, the BODIPY-derived structures disclosed in US2020251663 (A1), EP3671884 (A1), US20160230960 (A1), US20150303378 (A1) or derivatives thereof may be suitable BN emitters for use.

Furthermore, it is known to those skilled in the art, that one may also arrive at emitters for organic electroluminescent devices by replacing one or both of the fluorine substituents attached to the central boron atom of the BODIPY core structure by alkoxy or aryloxy groups which are attached via the oxygen atom and may optionally be substituted, preferably with electron-withdrawing substituents such as fluorine (F) or trifluoromethyl (CF₃). Such molecules are for example disclosed in US2012037890 (A1) and the person skilled in the art understands that these BODIPY-related compounds may also be suitable BN emitters. Examples of such emitter molecules are shown below, which does not imply that only the shown structures may be suitable BN emitters:

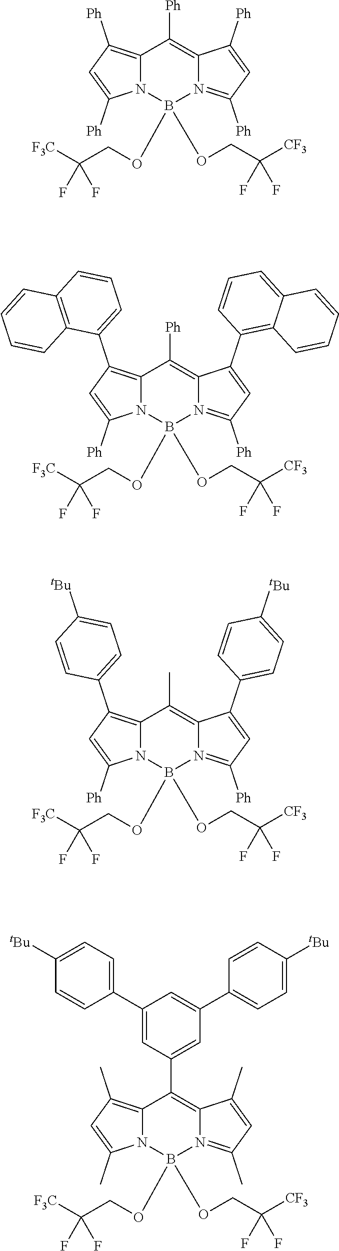

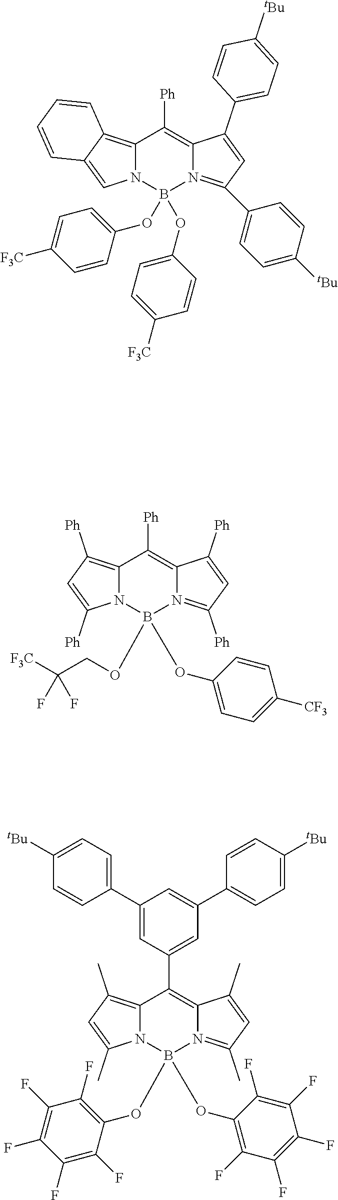

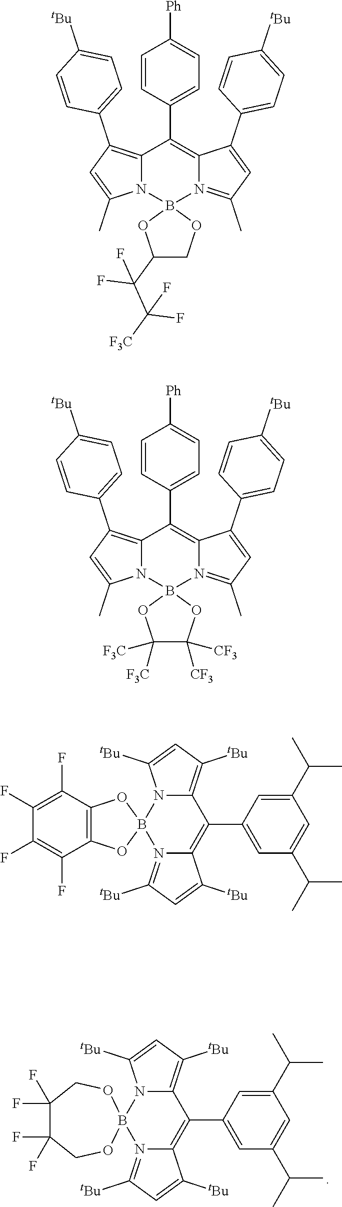

Additionally, the BODIPY-related baron-containing emitters disclosed in US20190288221 (A1) constitute a group of emitters that may provide suitable BN emitters for use according to the present invention.

In an aspect, the present invention relates to an organic molecule (that may be used as an emitter, in particular as organic molecules (e.g., usable as small FWHM emitters)) including or consisting of a structure according to the following Formula BNE-1:

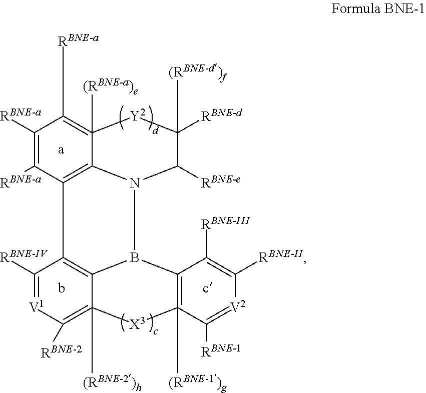

wherein:
c and d are both integers and independently of each other selected from 0 and 1;
e and f are both integers and selected from 0 and 1, wherein e and f are (always) identical (i.e., both 0 or both 1);
g and h are both integers and selected from 0 and 1, wherein g and h are (always) identical (i.e., both 0 or both 1);
if d is 0, e and f are both 1, and if d is 1, e and f are both 0;
if c is 0, g and h are both 1, and if c is 1, g and h are both 0;
V¹ is selected from nitrogen (N) and CR^{BNE-V};
V² is selected from nitrogen (N) and CR^{BNE-I};
X³ is selected from the group consisting of a direct bond, CR^{BNE-3}R^{BNE-4},
C═CR^{BNE-3}R^{BNE-4}, C═O, C═NR^{BNE-3}, NR^{BNE-3}, O, SiR^{BNE-3}R^{BNE-4}, S, S(O), and S(O)₂;
Y² is selected from the group consisting of a direct bond, CR^{BNE-3′}R^{BNE-4′},
C═CR^{BNE-3′}R^{BNE-4′}, C═O, C═NR^{BNE-3′}, NR^{BNE-3′}, O, SiR^{BNE-3′}R^{BNE-4′}, S, S(O), and S(O)₂;
R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-I}, R^{BNE-II}, R^{BNE-III}, R^{BNE-IV}, and R^{BNE-V} are each independently of each other selected from the group consisting of: a single bond linking the BN emitter moiety M^{BN} to the bridging unit L; hydrogen; deuterium; N(R^{BNE-5})₂; OR^{BNE-5}; Si(R^{BNE-5})₃; B(OR^{BNE-5})₂; B(R^{BNE-5})₂; OSO₂R^{BNE-5}; CF₃; CN; F; Cl; Br; I;
C₁-C₄₀-alkyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-alkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-thioalkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkenyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkynyl,
which is optionally substituted with one or more substituents R^{BNE-5} and
wherein one or more non-adjacent CH₂-groups are optionally substituted by R^{BNE-5}C═CR^{BNE-5}, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-5}; and
C₂-C₅₇-heteroaryl,
which is optionally substituted with one or more substituents R^{BNE-5};
R^{BNE-d}, R^{BNE-d′}, and R^{BNE-e} are independently of each other selected from the group consisting of: hydrogen; deuterium; N(R^{BNE-5})₂; OR^{BNE-5}; Si(R^{BNE-5})₃; B(OR^{BNE-5})₂; B(R^{BNE-5})₂; OSO₂R^{BNE-5}; CF₃; CN; F; Cl; Br; I;
C₁-C₄₀-alkyl,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-alkoxy,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-thioalkoxy,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkenyl,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkynyl,
which is optionally substituted with one or more substituents R^{BNE-a} and
wherein one or more non-adjacent CH₂-groups are optionally substituted by R^{BNE}—C═CR^{BNE-5}, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-a}; and
C₂-C₅₇-heteroaryl,
which is optionally substituted with one or more substituents R^{BNE-a};
R^{BNE-a} is at each occurrence independently of each other selected from the group consisting of: hydrogen; deuterium; N(R^{BNE-5})₂; OR^{BNE-5}; Si(R^{BNE-5})₃; B(OR^{BNE-5})₂; B(R^{BNE-5})₂; OSO₂R^{BNE-5}; CF₃; CN; F; Cl; Br; I;
C₁-C₄₀-alkyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-alkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-thioalkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkenyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkynyl,
which is optionally substituted with one or more substituents R^{BNE-5} and
wherein one or more non-adjacent CH₂-groups are optionally substituted by R^{BNE}—C═CR^{BNE-5}, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-5}; and
C₂-C₅₇-heteroaryl,
which is optionally substituted with one or more substituents R^{BNE-5};
R^{BNE-5} is at each occurrence independently of each other selected from the group consisting of: hydrogen; deuterium; N(R^{BNE-6})₂; OR^{BNE-6}; Si(R^{BNE-6})₃; B(OR^{BNE-6})₂; B(R^{BNE-6})₂; OSO₂R^{BNE-6}; CF₃; CN; F; Cl; Br; I;
C₁-C₄₀-alkyl,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₁-C₄₀-alkoxy,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₁-C₄₀-thioalkoxy,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₂-C₄₀-alkenyl,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₂-C₄₀-alkynyl,
which is optionally substituted with one or more substituents R^{BNE-6} and
wherein one or more non-adjacent CH₂-groups are optionally substituted by R^{BNE-6}C═CR^{BNE-6}, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₆-C₆₀-aryl,
which is optionally substituted with one or more substituents R^{BNE-6}; and
C₂-C₅₇-heteroaryl,
which is optionally substituted with one or more substituents R^{BNE-6};
R^{BNE-6} is at each occurrence independently from each other selected from the group consisting of: hydrogen; deuterium; OPh; CF₃; CN; F;
C₁-C₅-alkyl,
wherein one or more hydrogen atoms are optionally, independently of each other substituted by deuterium, CN, CF₃, Ph or F;
C₁-C₅-alkoxy,
wherein one or more hydrogen atoms are optionally, independently of each other substituted by deuterium, CN, CF₃, or F;
C₁-C₅-thioalkoxy,
wherein one or more hydrogen atoms are optionally, independently of each other substituted by deuterium, CN, CF₃, or F;
C₂-C₅-alkenyl,
wherein one or more hydrogen atoms are optionally, independently of each other substituted by deuterium, CN, CF₃, or F;
C₂-C₅-alkynyl,
wherein one or more hydrogen atoms are optionally, independently of each other substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂; and
N(C₂-C₁₇-heteroaryl)(C₆-C₁₈-aryl);
wherein R^{BNE-III} and R^{BNE-e} optionally combine to form a direct single bond; and
wherein two or more of substituents R^{BNE-a}, R^{BNE-d}, R^{BNE-d′}, R^{BNE-e}, R^{BNE-3′}, R^{BNE-4′}, and/or R^{BNE-5} optionally form a mono- or polycyclic, aliphatic or aromatic or heteroaromatic, carbo- or heterocyclic ring system with each other;
wherein two or more of the substituents R^{BNE-1}, R^{BNE-2}, R^{BNE-1′}, R^{BNE-2′}, R^{BNE-3}, R^{BNE-4}, R^{BNE-5}, R^{BNE-I}, R^{BNE-II}, R^{BNE-III}, R^{BNE-IV}, and/or R^{BNE-V} optionally form a mono- or polycyclic, aliphatic or aromatic or heteroaromatic, carbo- or heterocyclic ring system with each other;
wherein optionally two or more, preferably two, structures of Formula BNE-1 are conjugated with each other, preferably fused to each other by sharing at least one, more preferably exactly one, bond;
wherein optionally two or more, preferably two, structures of Formula BNE-1 are present in the organic molecule and share at least one, preferably exactly one, aromatic or heteroaromatic ring (i.e., this ring may be part of both structures of Formula BNE-1) which preferably is any of the rings a, b, and c′ of Formula BNE-1, but may also be any aromatic or heteroaromatic substituent selected from R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-5}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, and R^{BNE-d′}, or any aromatic or heteroaromatic ring formed by two or more substituents as stated above, wherein the shared ring may constitute the same or different moieties of the two or more structures of Formula BNE-1 that share the ring (i.e., the shared ring may for example be ring c′ of both structures of Formula BNE-1 optionally included in the organic molecule or the shared ring may for example be ring b of one and ring c′ of the other structure of Formula BNE-1 optionally included in the organic molecule); and
wherein optionally at least one of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1 and/or wherein optionally at least one hydrogen atom of any of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1.

According to the present invention, typically exactly one of the substituents of the BN emitter moiety M^{BN} represents the binding site of a single bond linking the BN emitter moiety M^{BN} to the bridging unit L.

In one embodiment of the invention, in at least one, preferably each, light-emitting layer B, at least one of the one or more organic molecules (e.g., usable as organic molecules (e.g., usable as small FWHM emitters)) includes a structure according to Formula BNE-1.

In one embodiment of the invention, in at least one, preferably each, light-emitting layer B, each organic molecule (e.g., usable as small FWHM emitter) includes a structure according to Formula BNE-1.

In one embodiment of the invention, in at least one, preferably each, light-emitting layer B, at least one of the one or more organic molecules (e.g., usable as small FWHM emitters) consists of a structure according to Formula BNE-1.

In one embodiment of the invention, in at least one, preferably each, light-emitting layer B, each organic molecule (e.g., usable as small FWHM emitter) consists of a structure according to Formula BNE-1.

In one embodiment of the invention, in which in at least one, preferably each, light-emitting layer B, at least one, preferably each, of the one or more organic molecules (e.g., usable as small FWHM emitters) includes or consists of a structure according to Formula BNE-1, V¹ is CR^{BNE-V} and V² is CR^{BNE-I}.

In one embodiment of the invention, in which in at least one, preferably each, light-emitting layer B, at least one, preferably each, of the one or more organic molecules (e.g., usable as small FWHM emitters) includes or consists of a structure according to Formula BNE-1, V¹ and V² are both nitrogen (N).

In one embodiment of the invention, in which in at least one, preferably each, light-emitting layer B, at least one, preferably each, of the one or more organic molecules (e.g., usable as small FWHM emitters) includes or consists of a structure according to Formula BNE-1, V¹ is nitrogen (N) and V² is CR^{BNE-I}.

In one embodiment of the invention, in which in at least one, preferably each, light-emitting layer B, at least one, preferably each, of the one or more organic molecules (e.g., usable as small FWHM emitters) includes or consists of a structure according to Formula BNE-1, V¹ is CR^{BNE-V} and V² is nitrogen (N).

In one embodiment of the invention, in which in at least one, preferably each, light-emitting layer B, at least one, preferably each, of the one or more organic molecules (e.g., usable as small FWHM emitters) includes or consists of a structure according to Formula BNE-1, c and d are both 0.

In one embodiment of the invention, in which in at least one, preferably each, light-emitting layer B, at least one, preferably each, of the one or more organic molecules (e.g., usable as small FWHM emitters) includes or consists of a structure according to Formula BNE-1, c is 0 and d is 1.

In one embodiment of the invention, in which in at least one, preferably each, light-emitting layer B, at least one, preferably each, of the one or more organic molecules (e.g., usable as small FWHM emitters) includes or consists of a structure according to Formula BNE-1, c is 1 and d is 0.

In a preferred embodiment of the invention, in which in at least one, preferably each, light-emitting layer B, at least one, preferably each, of the one or more organic molecules (e.g., usable as small FWHM emitters) includes or consists of a structure according to Formula BNE-1, c and d are both 1.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
X³ is selected from the group consisting of a direct bond, CR^{BNE-3}R^{BNE-4}, C═O, NR^{BNE-3}, O, S, and SiR^{BNE-3}R^{BNE-4}; and
Y² is selected from the group consisting of a direct bond, CR^{BNE-3′}R^{BNE-4′}, C═O, NR^{BNE-3′}, O, S, and SiR^{BNE-3′}R^{BNE-4′}.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
X³ is selected from the group consisting of a direct bond, CR^{BNE-3}R^{BNE-4}, NR^{BNE-3}, O, S, and SiR^{BNE-3}R^{BNE-4}; and
Y² is selected from the group consisting of a direct bond, CR^{BNE-3′}R^{BNE-4′}, NR^{BNE-3′}, O, S, and SiR^{BNE-3′}R^{BNE-4′}.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
X³ is selected from the group consisting of a direct bond, CR^{BNE-3}R^{BNE-4}, NR^{BNE-3}, O, S, and SiR^{BNE-3}R^{BNE-4}; and
Y² is a direct bond.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
X³ is a direct bond or NR^{BNE-3}; and
Y² is a direct bond.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
X³ is NR^{BNE-3}; and
Y² is a direct bond.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
R^{BNE-1}, R^{BNE-2}, R^{BNE-1′}, R^{BNE-2′}, R^{BNE-3}, R^{BNE-4}, R^{BNE-3}, R^{BNE-4′},R^{BNE-I}, R^{BNE-II}, R^{BNE-III}, R^{BNE-IV}, and R^{BNE-V} are each independently of each other selected from the group consisting of: a single bond linking the BN emitter moiety M^{BN} to the bridging unit L; hydrogen; deuterium; N(R^{BNE-5})₂; OR^{BNE-5}; Si(R^{BNE-5})₃; B(OR^{BNE-5})₂; B(R^{BNE-5})₂; OSO₂R^{BNE-5}; CF₃; CN; F; Cl; Br; I;
C₁-C₄₀-alkyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-alkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-thioalkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkenyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkynyl,
which is optionally substituted with one or more substituents R^{BNE-5} and
wherein one or more non-adjacent CH₂-groups are optionally substituted by R^{BNE-5}C═CR^{BNE-5}, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-5}; and
C₂-C₅₇-heteroaryl,
which is optionally substituted with one or more substituents R^{BNE-5};
R^{BNE-d}, R^{BNE-d′}, and R^{BNE-e} are independently of each other selected from the group consisting of: hydrogen; deuterium; CF₃; CN; F; Cl; Br; I;
C₁-C₄₀-alkyl,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-a}; and
C₂-C₅₇-heteroaryl,
which is optionally substituted with one or more substituents R^{BNE-a};
R^{BNE-a} is at each occurrence independently of each other selected from the group consisting of: hydrogen; deuterium; N(R^{BNE-5})₂; OR^{BNE-5}; Si(R^{BNE-5})₃; B(OR^{BNE-5})₂; B(R^{BNE-5})₂; OSO₂R^{BNE-5}; CF₃; CN; F; Cl; Br; I;
C₁-C₄₀-alkyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-alkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-thioalkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkenyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkynyl,
which is optionally substituted with one or more substituents R^{BNE-5} and
wherein one or more non-adjacent CH₂-groups are optionally substituted by R^{BNE}—C═CR^{BNE-5}, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-5}; and
C₂-C₅₇-heteroaryl,
which is optionally substituted with one or more substituents R^{BNE-5};
R^{BNE-5} is at each occurrence independently of each other selected from the group consisting of: hydrogen; deuterium; N(R^{BNE-6})₂; OR^{BNE-6}; Si(R^{BNE-6})₃; B(OR^{BNE-6})₂; B(R^{BNE-6})₂; OSO₂R^{BNE-6}; CF₃; CN; F; Cl; Br; I;
C₁-C₄₀-alkyl,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₁-C₄₀-alkoxy,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₁-C₄₀-thioalkoxy,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₂-C₄₀-alkenyl,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₂-C₄₀-alkynyl,
which is optionally substituted with one or more substituents R^{BNE-6} and
wherein one or more non-adjacent CH₂-groups are optionally substituted by R^{BNE-6}C═CR^{BNE-6}, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₆-C₆₀-aryl,
which is optionally substituted with one or more substituents R^{BNE-6}; and
C₂-C₅₇-heteroaryl,
which is optionally substituted with one or more substituents R^{BNE-6};
R^{BNE-6} is at each occurrence independently from each other selected from the group consisting of: hydrogen; deuterium; OPh; CF₃; CN; F;
C₁-C₅-alkyl,
wherein one or more hydrogen atoms are optionally, independently from each other substituted by deuterium, CN, CF₃, Ph or F;
C₁-C₅-alkoxy,
wherein one or more hydrogen atoms are optionally, independently from each other substituted by deuterium, CN, CF₃, or F;
C₁-C₅-thioalkoxy,
wherein one or more hydrogen atoms are optionally, independently from each other substituted by deuterium, CN, CF₃, or F;
C₂-C₅-alkenyl,
wherein one or more hydrogen atoms are optionally, independently from each other substituted by deuterium, CN, CF₃, or F;
C₂-C₅-alkynyl,
wherein one or more hydrogen atoms are optionally, independently from each other substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂; and
N(C₂-C₁₇-heteroaryl)(C₆-C₁₈-aryl);
wherein R^{BNE-III} and R^{BNE-e} optionally combine to form a direct single bond; and
wherein two or more of substituents R^{BNE-a}, R^{BNE-d}, R^{BNE-d′}, R^{BNE-e}, R^{BNE-3′} R^{BNE-4′}, and/or R^{BNE-5} optionally form a mono- or polycyclic, aliphatic or aromatic or heteroaromatic, carbo- or heterocyclic ring system with each other;
wherein two or more of the substituents R^{BNE-1}, R^{BNE-2}, R^{BNE-1′}, R^{BNE-2′}, R^{BNE-3}, R^{BNE-4}, R^{BNE-5}, R^{BNE-I}, R^{BNE-II}, R^{BNE-III}, R^{BNE-IV}, and/or R^{BNE-V} optionally form a mono- or polycyclic, aliphatic or aromatic or heteroaromatic, carbo- or heterocyclic ring system with each other;
wherein optionally two or more, preferably two, structures of Formula BNE-1 are conjugated with each other, preferably fused to each other by sharing at least one, more preferably exactly one, bond;
wherein optionally two or more, preferably two, structures of Formula BNE-1 are present in the organic molecule and share at least one, preferably exactly one, aromatic or heteroaromatic ring (i.e., this ring may be part of both structures of Formula BNE-1) which preferably is any of the rings a, b, and c′ of Formula BNE-1, but may also be any aromatic or heteroaromatic substituent selected from R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-5}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, and R^{BNE-d′}, or any aromatic or heteroaromatic ring formed by two or more substituents as stated above; wherein the shared ring may constitute the same or different moieties of the two or more structures of Formula BNE-1 that share the ring (i.e., the shared ring may for example be ring c′ of both structures of Formula BNE-1 optionally included in the organic molecule or the shared ring may for example be ring b of one and ring c′ of the other structure of Formula BNE-1 optionally included in the organic molecule); and
wherein optionally at least one of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1 and/or wherein optionally at least one hydrogen atom of any of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-I}, R^{BNE-II}, R^{BNE-III}, R^{BNE-IV}, and R^{BNE-V} are each independently of each other selected from the group consisting of: hydrogen; deuterium; N(R^{BNE-5})₂; OR^{BNE-5}; Si(R^{BNE-5})₃; B(R^{BNE-5})₂; CF₃; CN; F; Cl; Br; I;
C₁-C₁₈-alkyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₃₀-aryl,
which is optionally substituted with one or more substituents R^{BNE-5}; and
C₂-C₂₉-heteroaryl,
which is optionally substituted with one or more substituents R^{BNE-5};
R^{BNE-d}, R^{BNE-d′}, and R^{BNE-e} are independently of each other selected from the group consisting of: hydrogen; deuterium; CF₃; CN; F; Cl; Br; I;
C₁-C₁₈-alkyl,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₃₀-aryl,
which is optionally substituted with one or more substituents R^{BNE-a}; and
C₂-C₂₉-heteroaryl,
which is optionally substituted with one or more substituents R^{BNE-a};
R^{BNE-a} is at each occurrence independently of each other selected from the group consisting of: hydrogen; deuterium; N(R^{BNE-5})₂; OR^{BNE-5}; Si(R^{BNE-5})₃; B(R^{BNE-5})₂; CF₂; CN; F; Cl; Br; I;
C₁-C₁₈-alkyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₃₀-aryl,
which is optionally substituted with one or more substituents R^{BNE-5}; and
C₂-C₂₉-heteroaryl,
which is optionally substituted with one or more substituents R^{BNE-5};
R^{BNE-5} is at each occurrence independently from each other selected from the group consisting of: hydrogen; deuterium; OPh; CF₃; CN; F;
C₁-C₅-alkyl,
wherein one or more hydrogen atoms are optionally, independently from each other substituted by deuterium, CN, CF₃, or F;
C₁-C₅-alkoxy,
wherein one or more hydrogen atoms are optionally, independently from each other substituted by deuterium, CN, CF₃, or F;
C₁-C₅-thioalkoxy,
wherein one or more hydrogen atoms are optionally, independently from each other substituted by deuterium, CN, CF₃, or F;
C₂-C₅-alkenyl,
wherein one or more hydrogen atoms are optionally, independently from each other substituted by deuterium, CN, CF₃, or F;
C₂-C₅-alkynyl,
wherein one or more hydrogen atoms are optionally, independently from each other substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂; and
N(C₂-C₁₇-heteroaryl)(C₆-C₁₈-aryl);
wherein R^{BNE-III} and R^{BNE-}e optionally combine to form a direct single bond; and
wherein two or more of substituents R^{BNE-a}, R^{BNE-d}, R^{BNE-d′}, R^{BNE-e}, R^{BNE-3′}, R^{BNE-4′}, and/or R^{BNE-5} optionally form a mono- or polycyclic, aliphatic or aromatic or heteroaromatic, carbo- or heterocyclic ring system with each other;
wherein two or more of the substituents R^{BNE-1}, R^{BNE-2}, R^{BNE-1′}, R^{BNE-2′}, R^{BNE-3}, R^{BNE-4}, R^{BNE-5}, R^{BNE-I}, R^{BNE-II}, R^{BNE-III}, R^{BNE-IV}, and/or R^{BNE-V} optionally form a mono- or polycyclic, aliphatic or aromatic or heteroaromatic, carbo- or heterocyclic ring system with each other;
wherein optionally two or more, preferably two, structures of Formula BNE-1 are conjugated with each other, preferably fused to each other by sharing at least one, more preferably exactly one, bond;
wherein optionally two or more, preferably two, structures of Formula BNE-1 are present in the organic molecule and share at least one, preferably exactly one, aromatic or heteroaromatic ring (i.e., this ring may be part of both structures of Formula BNE-1) which preferably is any of the rings a, b, and c′ of Formula BNE-1, but may also be any aromatic or heteroaromatic substituent selected from R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-5}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, and R^{BNE-d′}, or any aromatic or heteroaromatic ring formed by two or more substituents as stated above; wherein the shared ring may constitute the same or different moieties of the two or more structures of Formula BNE-1 that share the ring (i.e., the shared ring may for example be ring c′ of both structures of Formula BNE-1 optionally included in the organic molecule or the shared ring may for example be ring b of one and ring c′ of the other structure of Formula BNE-1 optionally included in the organic molecule); and
wherein optionally at least one of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1 and/or wherein optionally at least one hydrogen atom of any of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
R^{BNE-1}, R^{BNE-2}, R^{BNE-1′}, R^{BNE-2′}, R^{BNE-3}, R^{BNE-4}, R^{BNE-3}, R^{BNE-4′}, R^{BNE-I}, R^{BNE-II}, R^{BNE-III}, R^{BNE-IV}, and R^{BNE-V} are each independently of each other selected from the group consisting of: hydrogen; deuterium; N(R^{BNE-5})₂; OR^{BNE-5}; Si(R^{BNE-5})₃; B(R^{BNE-5})₂; CF₃; CN; F;
C₁-C₅-alkyl,
which is optionally substituted with one or more substituents R^{BNE-5};
C₆-C₁₈-aryl,
which is optionally substituted with one or more substituents R^{BNE-5}; and
C₂-C₁₇-heteroaryl,
which is optionally substituted with one or more substituents R^{BNE-5};
R^{BNE-d}, R^{BNE-d′}, and R^{BNE-e} are independently of each other selected from the group consisting of: hydrogen; deuterium; CF₃; CN; F;
C₁-C₅-alkyl,
which is optionally substituted with one or more substituents R^{BNE-a};
C₆-C₁₈-aryl,
which is optionally substituted with one or more substituents R^{BNE-a}; and
C₂-C₁₇-heteroaryl,
which is optionally substituted with one or more substituents R^{BNE-a};
R^{BNE-a} is at each occurrence independently of each other selected from the group consisting of: hydrogen; deuterium; N(R^{BNE-5})₂; OR^{BNE-5}; Si(R^{BNE-5})₃; B(R^{BNE-5})₂; CF₃; CN; F;
C₁-C₅-alkyl,
which is optionally substituted with one or more substituents R^{BNE-5};
C₆-C₁₈-aryl,
which is optionally substituted with one or more substituents R^{BNE-5}; and
C₂-C₁₇-heteroaryl,
which is optionally substituted with one or more substituents R^{BNE-5};
R^{BNE-5} is at each occurrence independently from each other selected from the group consisting of: hydrogen; deuterium; OPh; CF₃; CN; F;
C₁-C₅-alkyl,
wherein one or more hydrogen atoms are optionally, independently from each other substituted by deuterium, CN, CF₃, or F;
C₁-C₅-alkoxy,
wherein one or more hydrogen atoms are optionally, independently from each other substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂; and
N(C₂-C₁₇-heteroaryl)(C₆-C₁₈-aryl);
wherein R^{BNE-III} and R^{BNE-e} optionally combine to form a direct single bond; and
wherein two or more of substituents R^{BNE-a}, R^{BNE-d}, R^{BNE-d′}, R^{BNE-e}, R^{BNE-3′}, R^{BNE-4′}, R^{BNE-5} optionally form a mono- or polycyclic, aliphatic or aromatic or heteroaromatic, carbo- or heterocyclic ring system with each other;
wherein two or more of the substituents R^{BNE-1}, R^{BNE-2}, R^{BNE-1′}, R^{BNE-2′}, R^{BNE-3}, R^{BNE-4}, R^{BNE-5}, R^{BNE-I}, R^{BNE-II}, R^{BNE-III}, R^{BNE-IV}, and/or R^{BNE-V} optionally form a mono- or polycyclic, aliphatic or aromatic or heteroaromatic, carbo- or heterocyclic ring system with each other;
wherein optionally two or more, preferably two, structures of Formula BNE-1 are conjugated with each other, preferably fused to each other by sharing at least one, more preferably exactly one, bond;
wherein optionally two or more, preferably two, structures of Formula BNE-1 are present in the organic molecule and share at least one, preferably exactly one, aromatic or heteroaromatic ring (i.e., this ring may be part of both structures of Formula BNE-1) which preferably is any of the rings a, b, and c′ of Formula BNE-1, but may also be any aromatic or heteroaromatic substituent selected from R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-5}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, and R^{BNE-d′}, or any aromatic or heteroaromatic ring formed by two or more substituents as stated above; wherein the shared ring may constitute the same or different moieties of the two or more structures of Formula BNE-1 that share the ring (i.e., the shared ring may for example be ring c′ of both structures of Formula BNE-1 optionally included in the organic molecule or the shared ring may for example be ring b of one and ring c′ of the other structure of Formula BNE-1 optionally included in the organic molecule); and
wherein optionally at least one of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1 and/or wherein optionally at least one hydrogen atom of any of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1.

In one embodiment of the invention, in which in at least one, preferably each, light-emitting layer B, at least one, preferably each, of the one or more organic molecules (e.g., usable as small FWHM emitters) includes or consists of a structure according to Formula BNE-1,
R^{BNE-1}, R^{BNE-2}, R^{BNE-1′}, R^{BNE-2′}, R^{BNE-3}, R^{BNE-4}, R^{BNE-3}, R^{BNE-4′}, R^{BNE-I}, R^{BNE-II}, R^{BNE-III}, R^{BNE-IV}, and R^{BNE-V} are each independently of each other selected from the group consisting of: hydrogen; deuterium; N(R^{BNE-5})₂; OR^{BNE-5}; Si(R^{BNE-5})₃; B(R^{BNE-5})₂; CF₃; CN; F;
C₁-C₅-alkyl,
which is optionally substituted with one or more substituents R^{BNE-5};
C₆-C₁₈-aryl,
which is optionally substituted with one or more substituents R^{BNE-5}; and
C₂-C₁₇-heteroaryl,
which is optionally substituted with one or more substituents R^{BNE-5};
R^{BNE-d}, R^{BNE-d′}, and R^{BNE-e} are independently of each other selected from the group consisting of: hydrogen; deuterium;
C₁-C₅-alkyl,
which is optionally substituted with one or more substituents R^{BNE-a};
C₆-C₁₈-aryl,
which is optionally substituted with one or more substituents R^{BNE-a}; and
C₂-C₁₇-heteroaryl,
which is optionally substituted with one or more substituents R^{BNE-a};
R^{BNE-a} is at each occurrence independently of each other selected from the group consisting of: hydrogen; deuterium; N(R^{BNE-5})₂; OR^{BNE-5}; Si(R^{BNE-5})₃; B(R^{BNE-5})₂; CF₃; CN; F;
C₁-C₅-alkyl,
which is optionally substituted with one or more substituents R^{BNE-5};
C₆-C₁₈-aryl,
which is optionally substituted with one or more substituents R^{BNE-5}; and
C₂-C₁₇-heteroaryl,
which is optionally substituted with one or more substituents R^{BNE-5};
R^{BNE-5} is at each occurrence independently from each other selected from the group consisting of: hydrogen; deuterium; OPh; CF₃; CN; F;
C₁-C₅-alkyl,
wherein one or more hydrogen atoms are optionally, independently from each other substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂; and
N(C₂-C₁₇-heteroaryl)(C₆-C₁₈-aryl);
wherein R^{BNE-III} and R^{BNE-e} optionally combine to form a direct single bond; and
wherein two or more of substituents R_{BNE-a}, R^{BNE-d}, R^{BNE-d′}, R^{BNE-e}, R^{BNE-3′}, R^{BNE-4′}, R^{BNE-5} optionally form a mono- or polycyclic, aliphatic or aromatic or heteroaromatic, carbo- or heterocyclic ring system with each other;
wherein two or more of the substituents R^{BNE-1}, R^{BNE-2}, R^{BNE-1′}, R^{BNE-2′}, R^{BNE-3}, R^{BNE-4}, R^{BNE-5}, R^{BNE-I}, R^{BNE-II}, R^{BNE-III}, R^{BNE-IV}, and/or R^{BNE-V} optionally form a mono- or polycyclic, aliphatic or aromatic or heteroaromatic, carbo- or heterocyclic ring system with each other;
wherein optionally two or more, preferably two, structures of Formula BNE-1 are conjugated with each other, preferably fused to each other by sharing at least one, more preferably exactly one, bond;
wherein optionally two or more, preferably two, structures of Formula BNE-1 are present in the organic molecule and share at least one, preferably exactly one, aromatic or heteroaromatic ring (i.e., this ring may be part of both structures of Formula BNE-1) which preferably is any of the rings a, b, and c′ of Formula BNE-1, but may also be any aromatic or heteroaromatic substituent selected from R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-5}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, and R^{BNE-d′}, or any aromatic or heteroaromatic ring formed by two or more substituents as stated above; wherein the shared ring may constitute the same or different moieties of the two or more structures of Formula BNE-1 that share the ring (i.e., the shared ring may for example be ring c′ of both structures of Formula BNE-1 optionally included in the organic molecule or the shared ring may for example be ring b of one and ring c′ of the other structure of Formula BNE-1 optionally included in the organic molecule); and
wherein optionally at least one of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1 and/or wherein optionally at least one hydrogen atom of any of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1.

In one embodiment of the invention, R^{BNE-III} and R^{BNE-e} combine to form a direct single bond.

In one embodiment of the invention, R^{BNE-III} and R^{BNE-e} do not combine to form a direct single bond.

In one embodiment, emitter moiety including a direct BN-bond M^{BN} in the context of the present invention may optionally also be multimers (e.g., dimers) of the aforementioned Formula BNE-1, which means that their structure includes more than one subunits, each of which has a structure according to Formula BNE-1. In this case, the skilled artisan will understand that the two or more subunits according to Formula BNE-1 may for example be conjugated, preferably fused to each other (i.e., sharing at least one bond, wherein the respective substituents attached to the atoms forming that bond may no longer be present). The two or more subunits may also share at least one, preferably exactly one, aromatic or heteroaromatic ring. This means that, for example, an emitter moiety including a direct BN-bond M^{BN} may include two or more subunits each having a structure of Formula BNE-1, wherein these two subunits share one aromatic or heteroaromatic ring (i.e., the respective ring is part of both subunits). As a result, the respective multimeric (e.g., dimeric) emitter moiety including a direct BN-bond M^{BN} may not contain two whole subunits according to Formula BNE-1 as the shared ring is only present once. Nevertheless, the skilled artisan will understand that, herein, such an emitter is still considered a multimer (for example a dimer if two subunits having a structure of Formula BNE-1 are included) of Formula BNE-1. The same holds true for multimers sharing more than one ring. It is preferred that the multimers are dimers including two subunits, each having a structure of Formula BNE-1.

In one embodiment of the invention, the emitter moiety including a direct BN-bond M^{BN} is a dimer of Formula BNE-1 as described above, which means that the emitter includes two subunits, each having a structure according to Formula BNE-1.

In one embodiment of the invention, the emitter moiety including a direct BN-bond M^{BN} includes or consists of two or more, preferably of exactly two, structures according to Formula BNE-1 (i.e., subunits), wherein these two subunits are conjugated, preferably fused to each other by sharing at least one, more preferably exactly one, bond.

In one embodiment of the invention, the emitter moiety including a direct BN-bond M^{BN} includes or consists of two or more, preferably of exactly two, structures according to Formula BNE-1 (i.e., subunits),
wherein these subunits share at least one, preferably exactly one, aromatic or heteroaromatic ring (i.e., this ring is part of both structures of Formula BNE-1) which preferably is any of the rings a, b, and c′ of Formula BNE-1, but may also be any aromatic or heteroaromatic substituent selected from R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-5}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, and R^{BNE-d′}, or any aromatic or heteroaromatic ring formed by two or more substituents as stated above; wherein the shared ring may constitute the same or different moieties of the two or more structures of Formula BNE-1 that share the ring (i.e., the shared ring may for example be ring c′ of both structures of Formula BNE-1 optionally included in the organic molecule or the shared ring may for example be ring b of one and ring c′ of the other structure of Formula BNE-1 optionally included in the organic molecule).

In one embodiment of the invention, the emitter moiety including a direct BN-bond M^{BN} includes or consists of a structure according to Formula BNE-1 (i.e., subunits),
wherein at least one of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1 and/or wherein optionally at least one hydrogen atom of any of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1.

Non-limiting examples of emitter moiety including a direct BN-bond M^{BN} including or consisting of a structure according to the Formula BNE-1 as defined herein that may be used (e.g., as small FWHM emitters) in the context of the present invention are shown below (not explicitly depicted are the typical one or more binding sites to the TADF moiety M^{TADF}, which can be at any position replacing a hydrogen atom as directly notable according to the valency of the structures by a person skilled in the art):

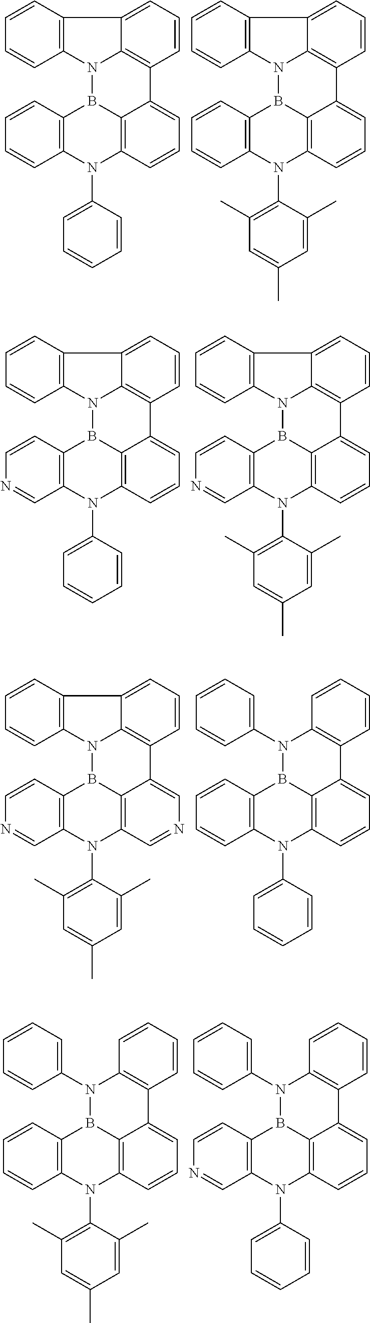

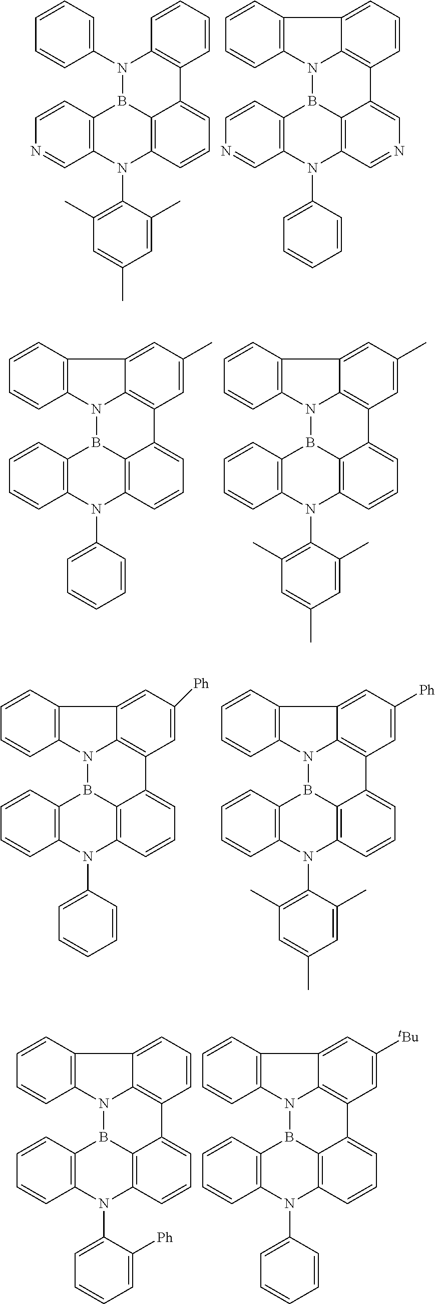

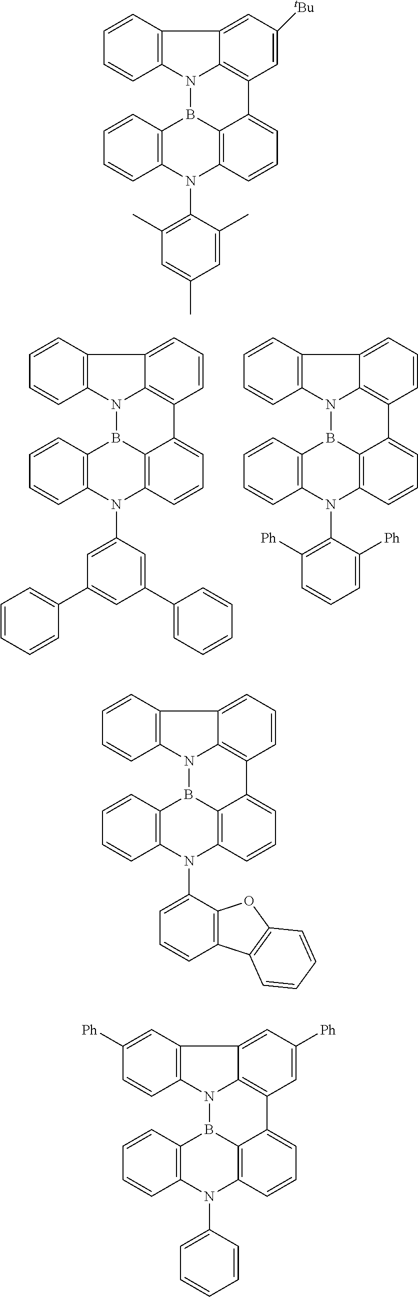

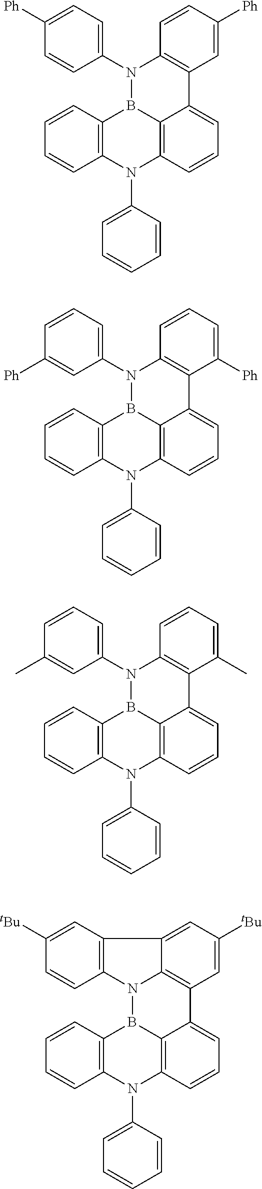

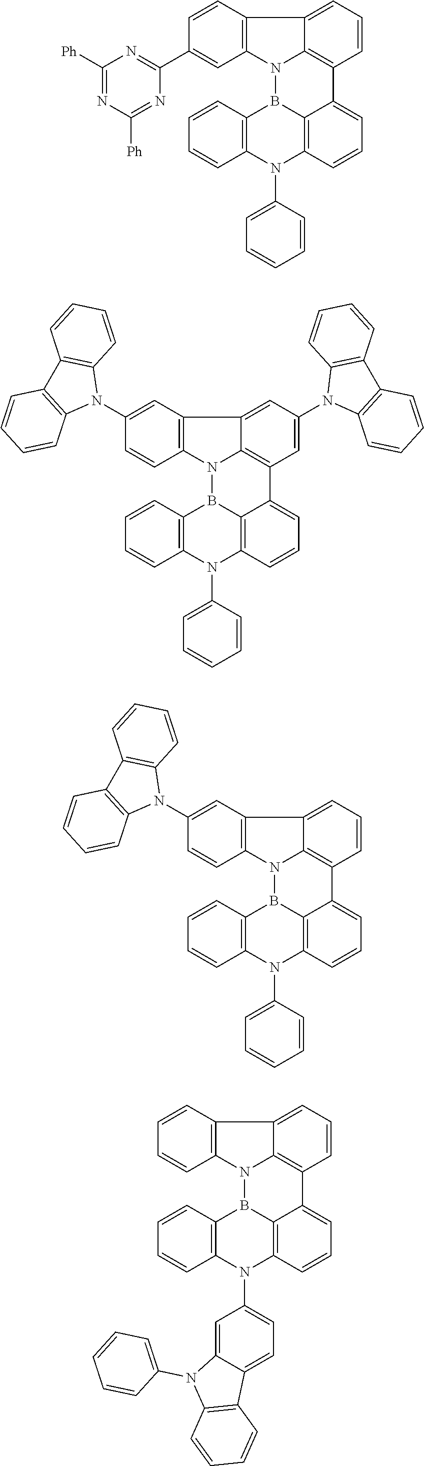 [SMILES: c1ccc(-c2nc(-c3ccccc3)nc(-c3ccc4c5cccc6c5n(c4c3)B3c4ccccc4N(c4ccccc4)c4cccc-6c43)n2)cc1 ; c1ccc(N2c3ccccc3B3c4c(cccc42)-c2cc(-n4c5ccccc5c5ccccc54)cc4c5cc(-n6c7ccccc7c7ccccc76)ccc5n3c24)cc1 ; c1ccc(N2c3ccccc3B3c4c(cccc42)-c2cccc4c5cc(-n6c7ccccc7c7ccccc76)ccc5n3c24)cc1 ; c1ccc(-n2c3ccccc3c3ccc(N4c5ccccc5B5c6c(cccc64)-c4cccc6c7ccccc7n5c46)cc32)cc1]

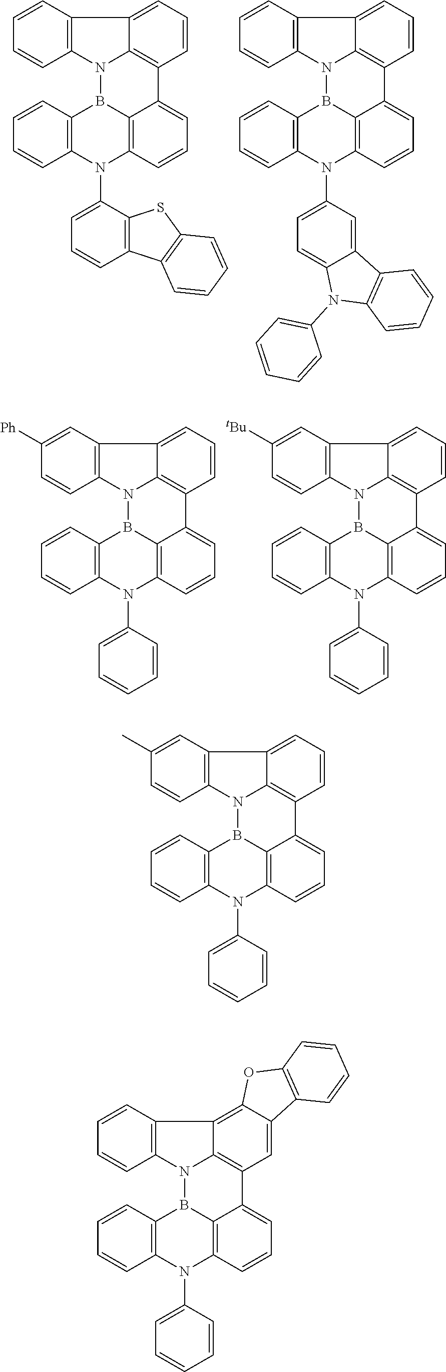

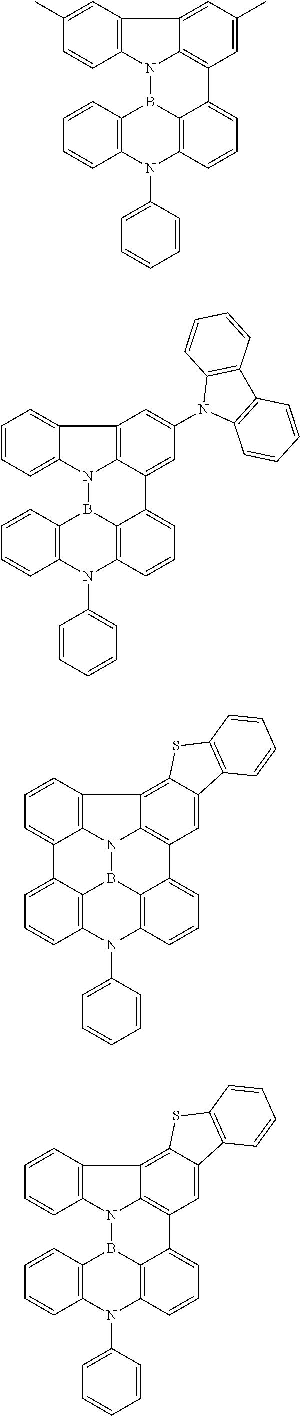

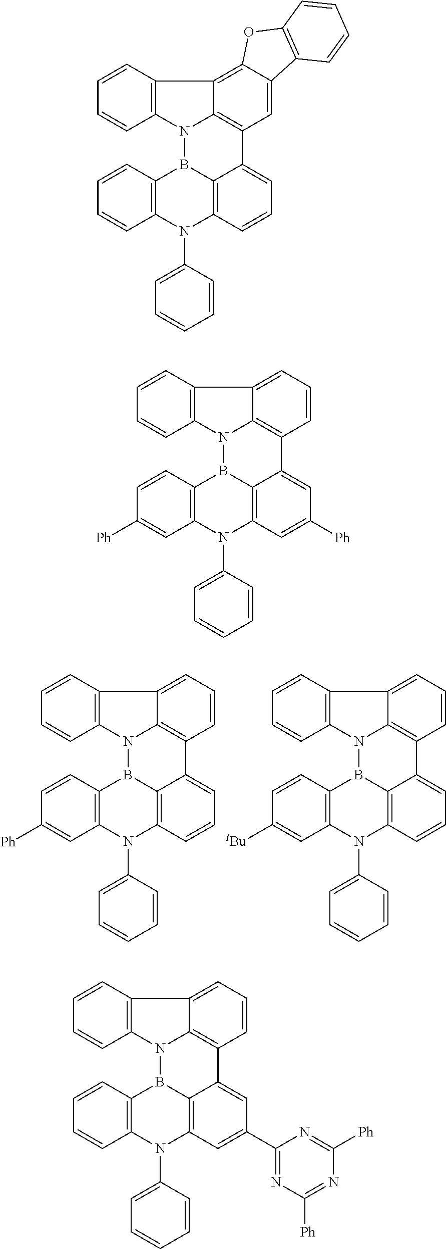

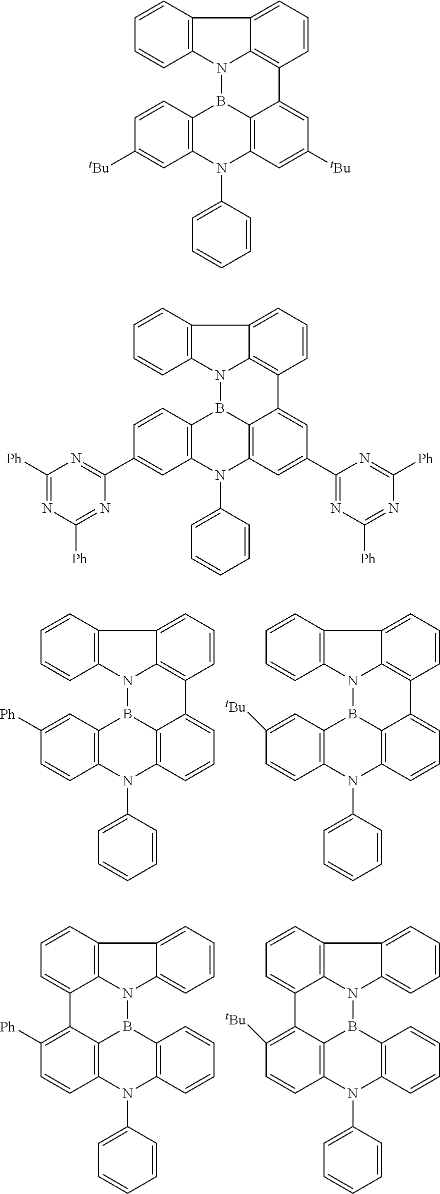

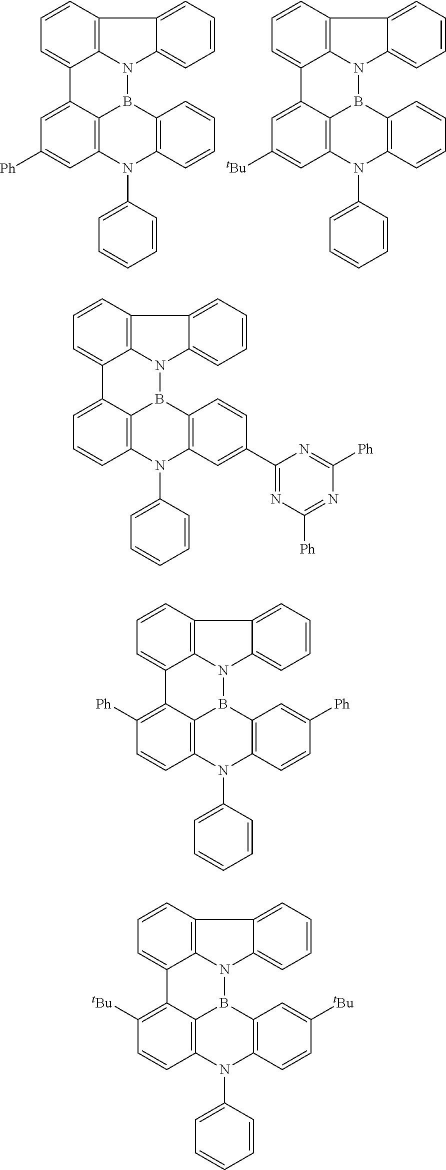

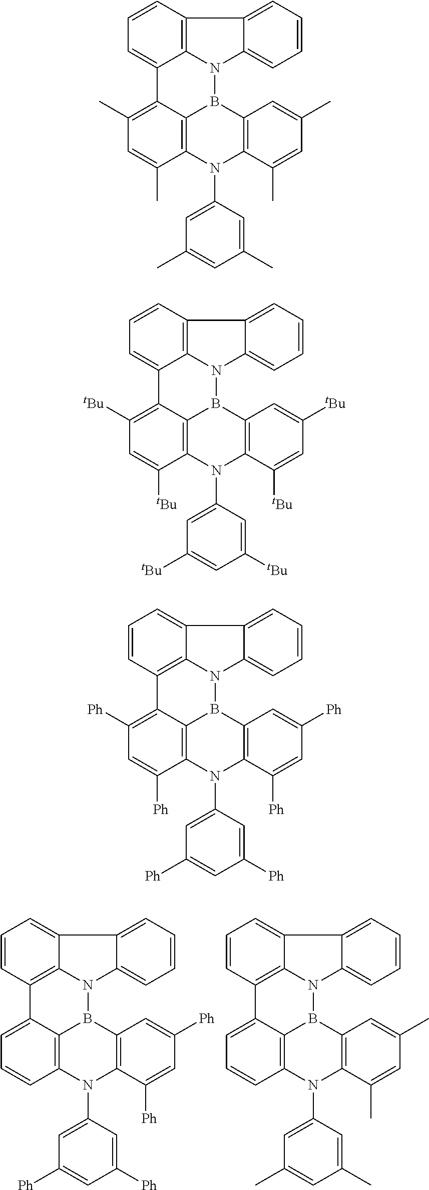

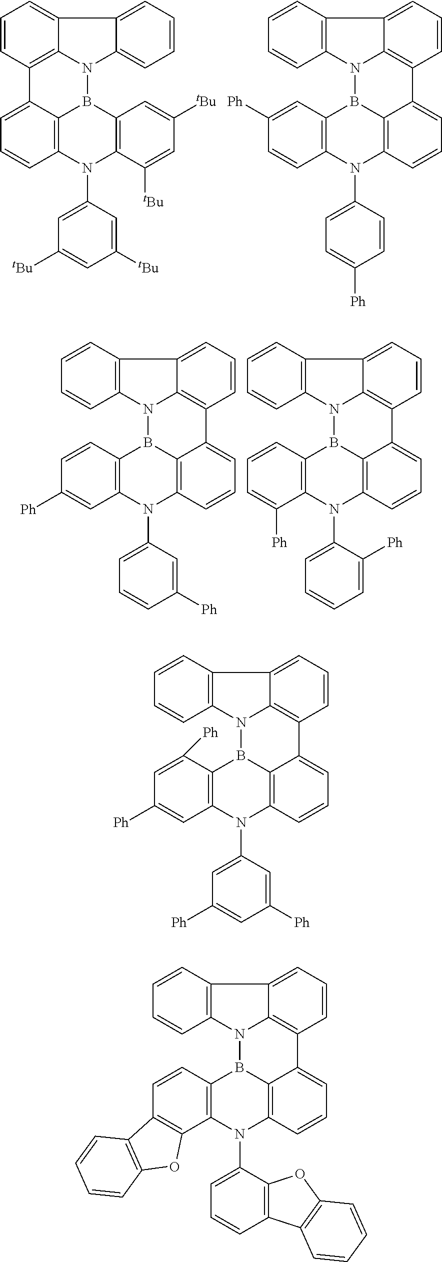

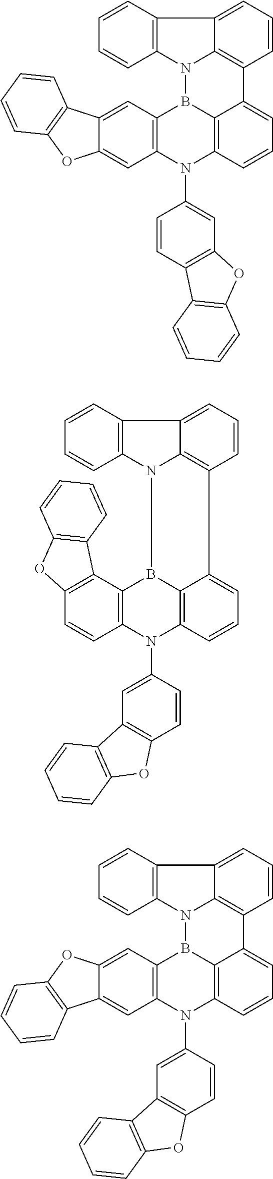

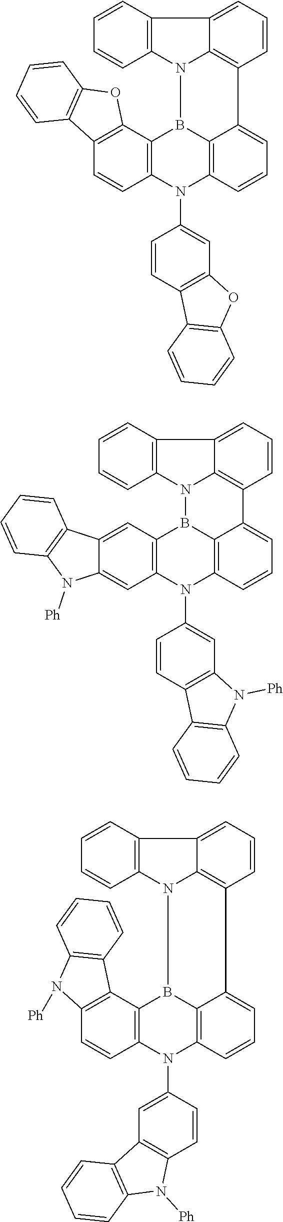

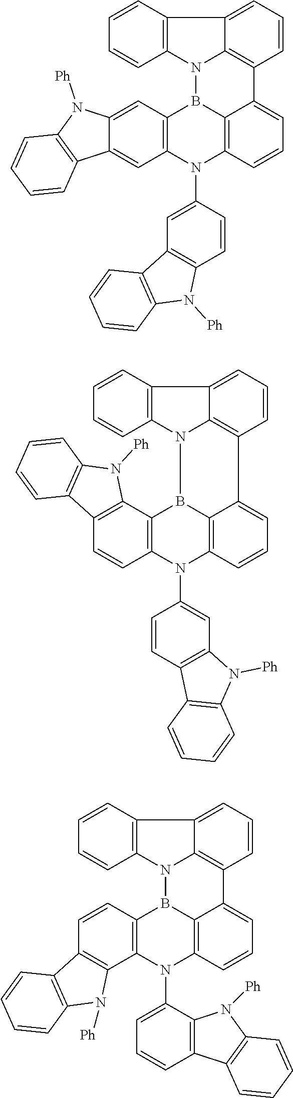

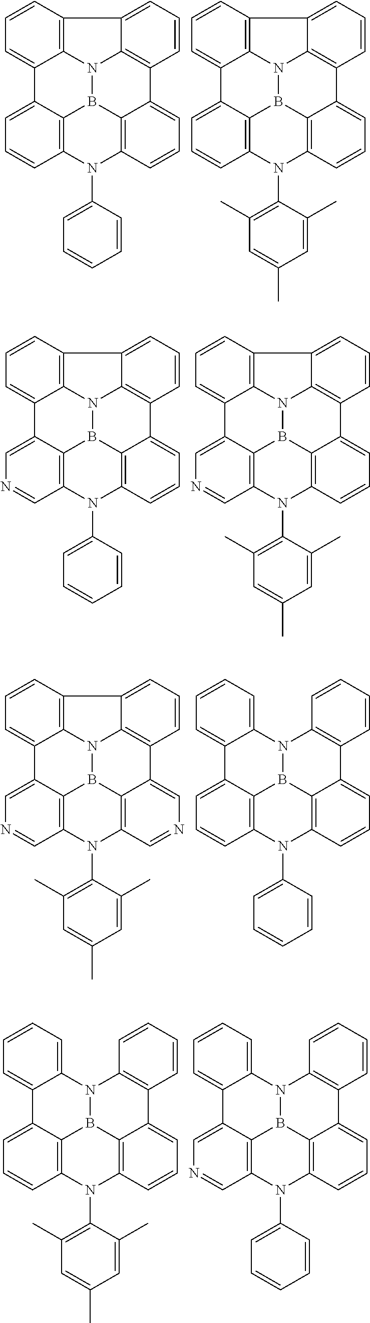

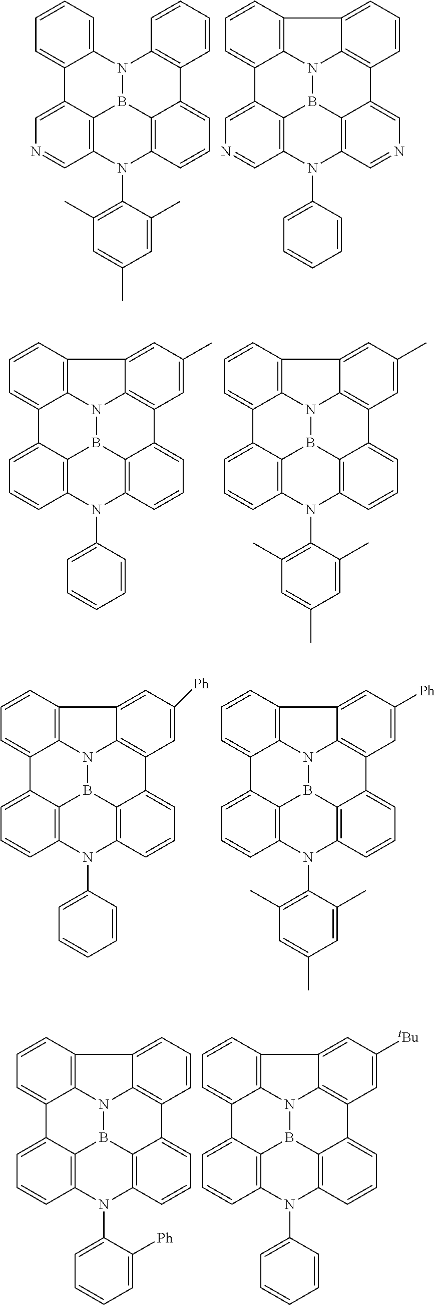

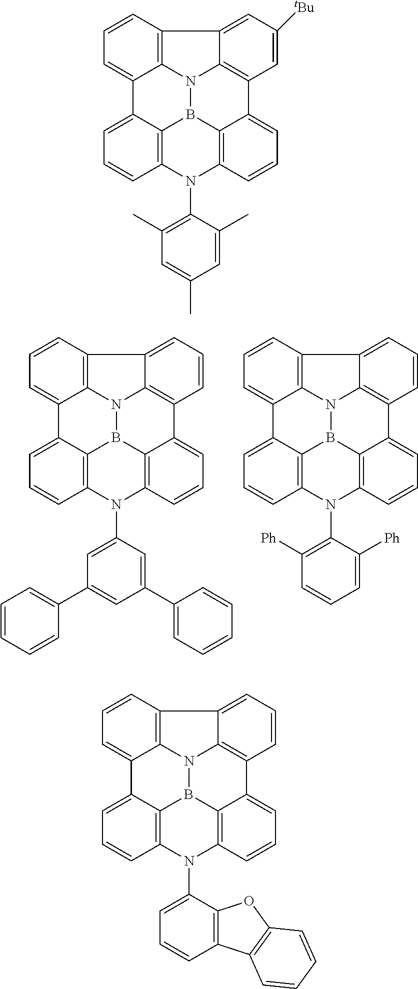

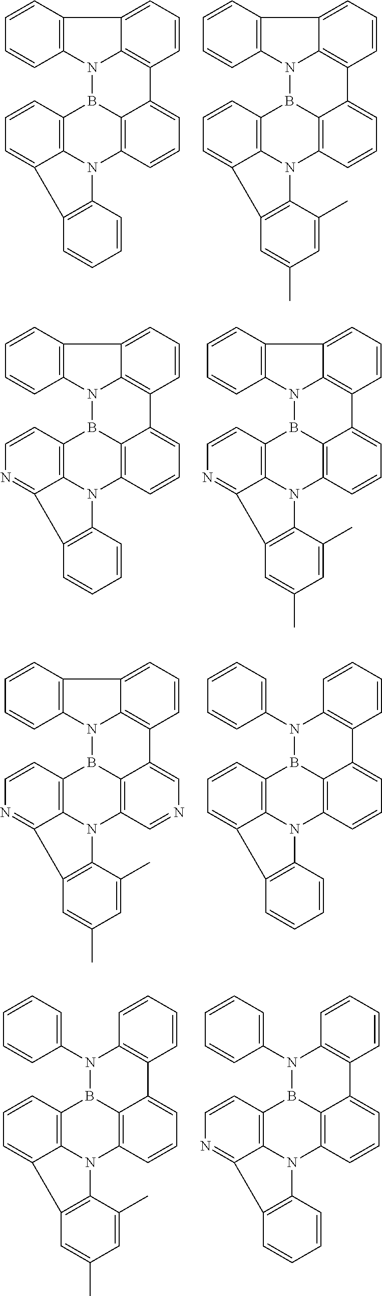

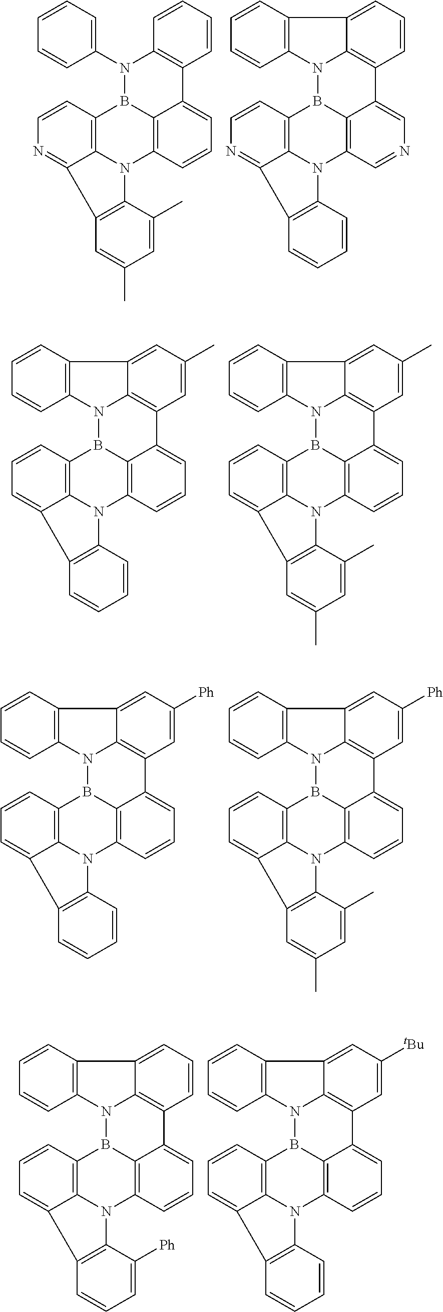

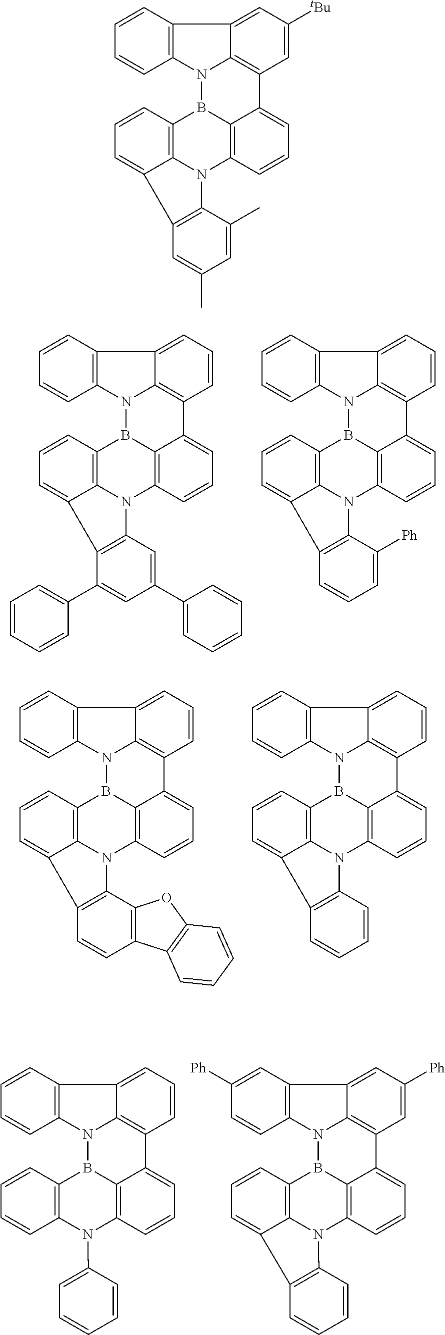

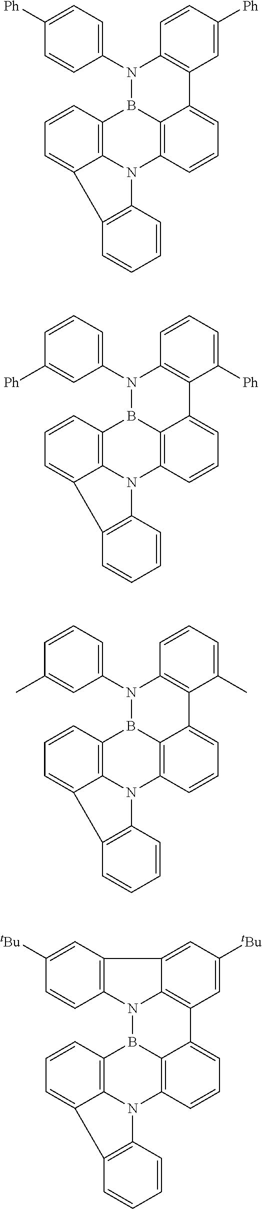

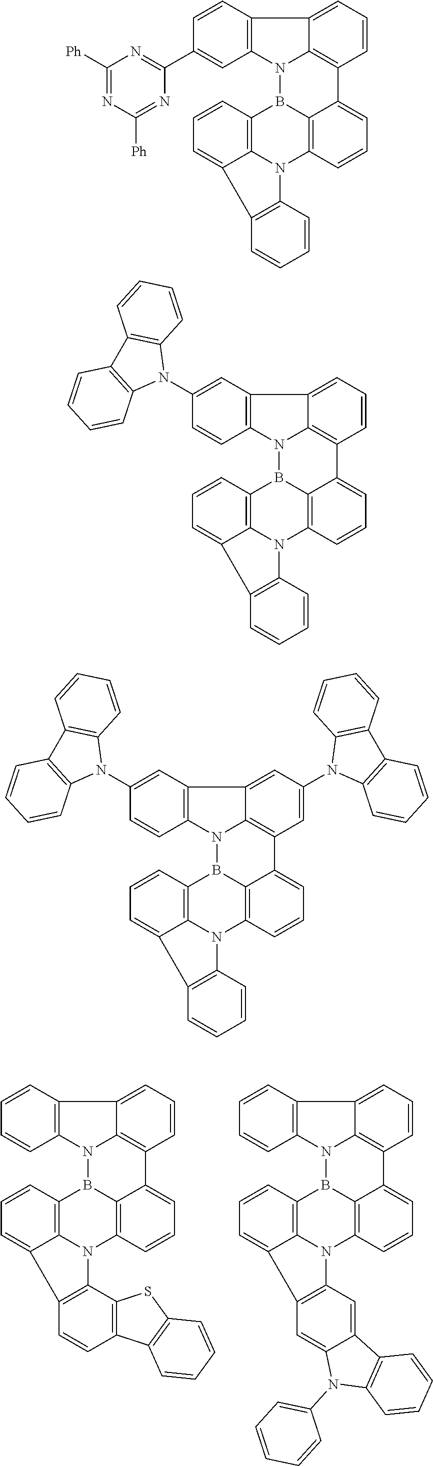 [SMILES: c1ccc(-c2nc(-c3ccccc3)nc(-c3ccc4c5cccc6c5n(c4c3)B3c4c-6cccc4-n4c5ccccc5c5cccc3c54)n2)cc1 ; c1cc2c3c(c1)-n1c4ccccc4c4cccc(c41)B3n1c3ccc(-n4c5ccccc5c5ccccc54)cc3c3cccc-2c31 ; c1cc2c3c(c1)-n1c4ccccc4c4cccc(c41)B3n1c3ccc(-n4c5ccccc5c5ccccc54)cc3c3cc(-n4c5ccccc5c5ccccc54)cc-2c31 ; c1cc2c3c(c1)-n1c4c(cccc4c4ccc5c6ccccc6sc5c41)B3n1c3ccccc3c3cccc-2c31 ; c1ccc(-n2c3ccccc3c3cc4c(cc32)c2cccc3c2n4-c2cccc4c2B3n2c3ccccc3c3cccc-4c32)cc1]

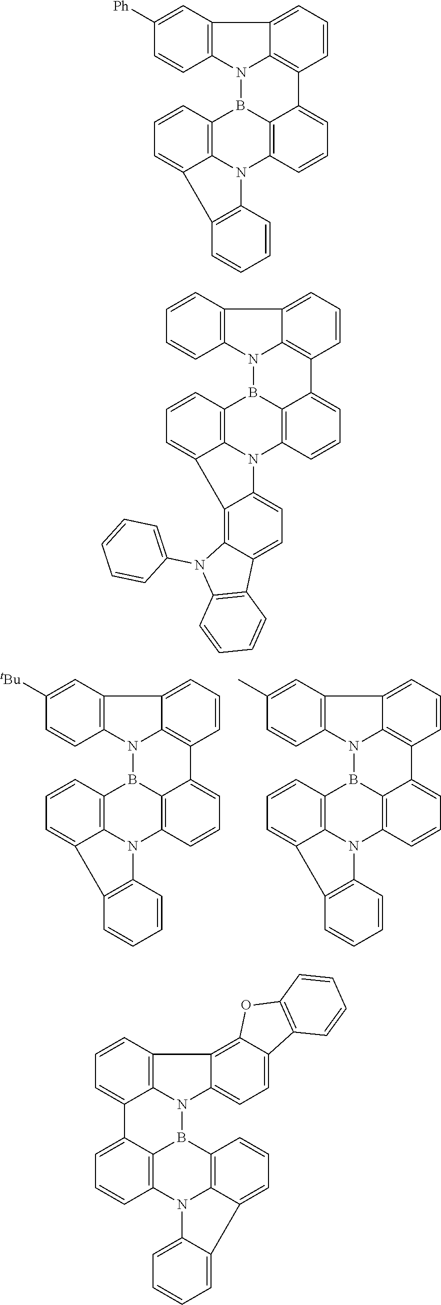

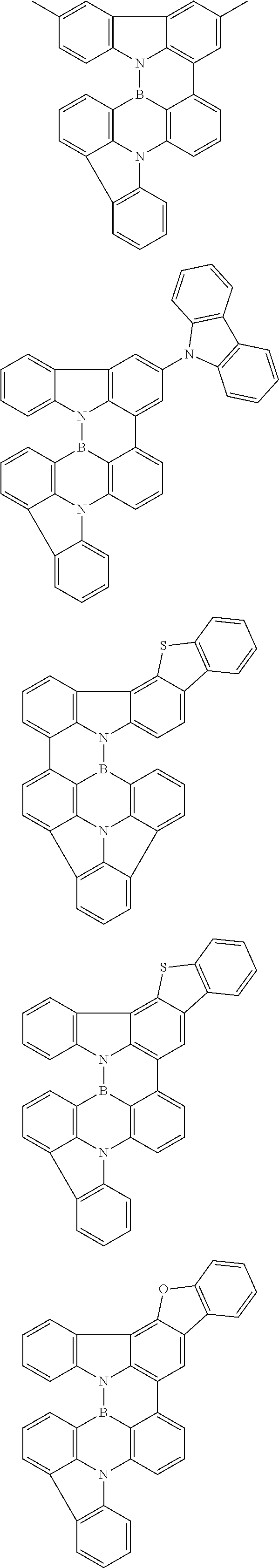

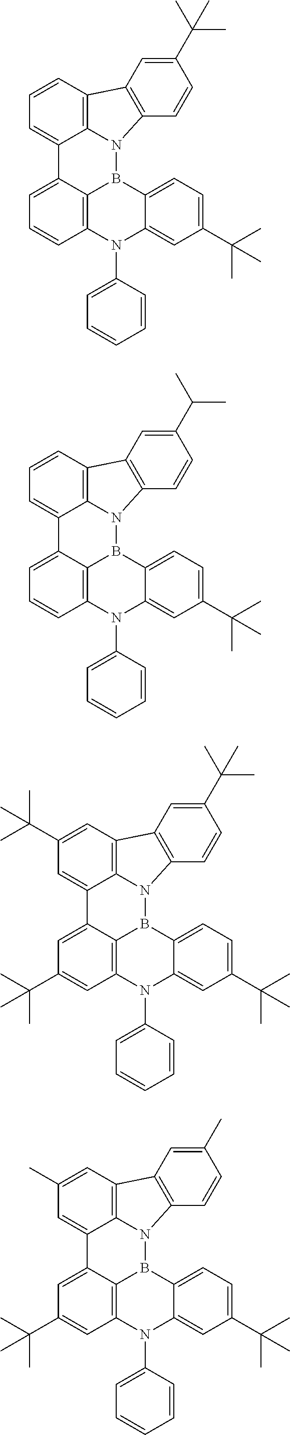

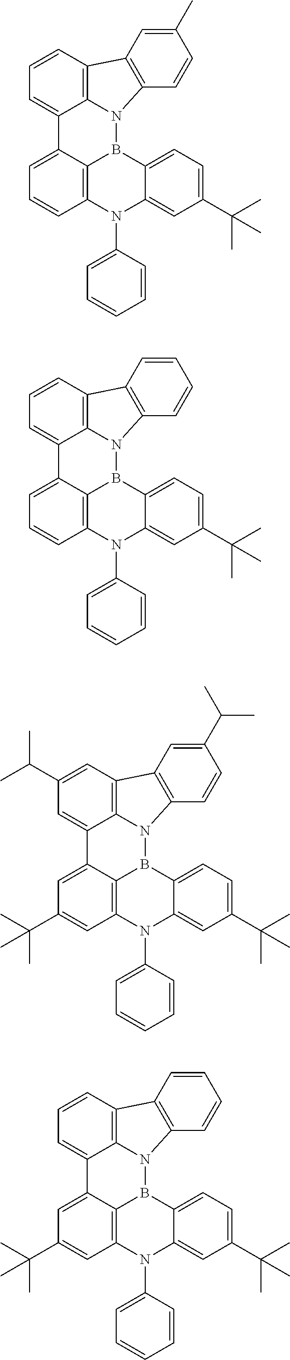

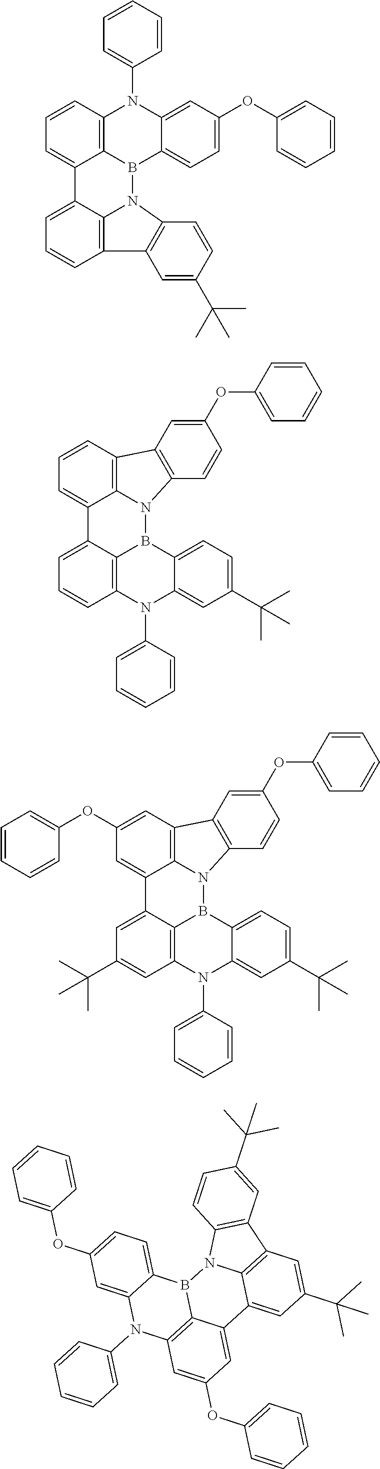

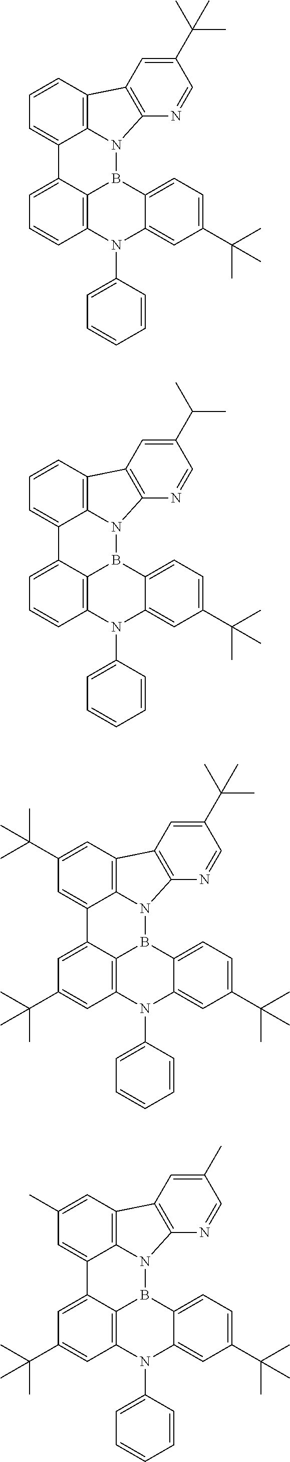

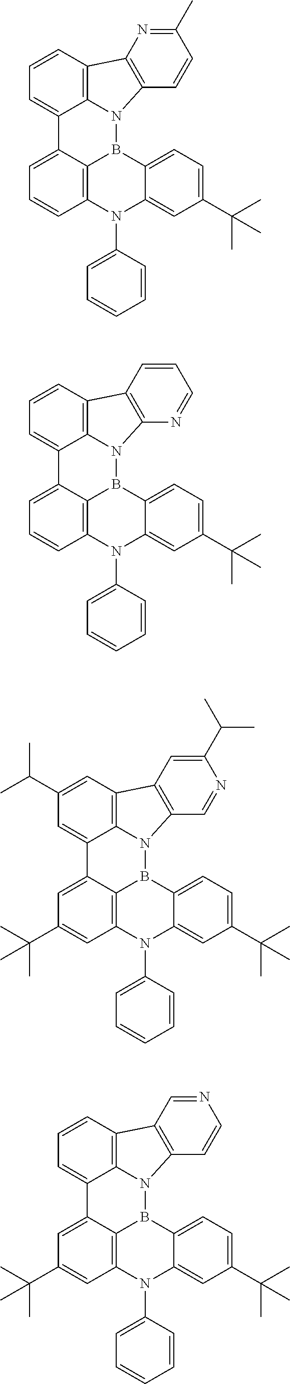

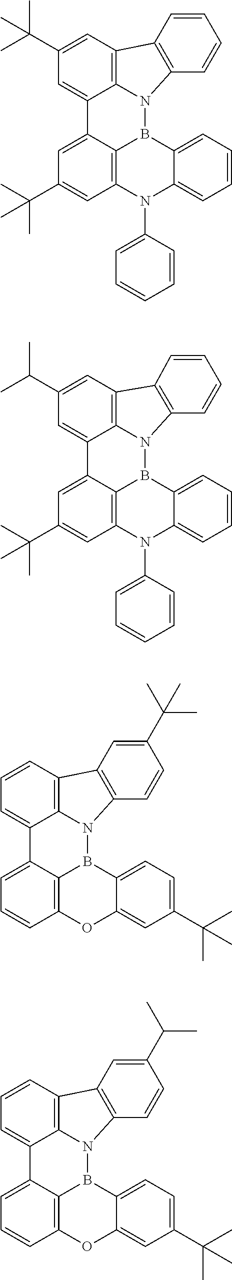

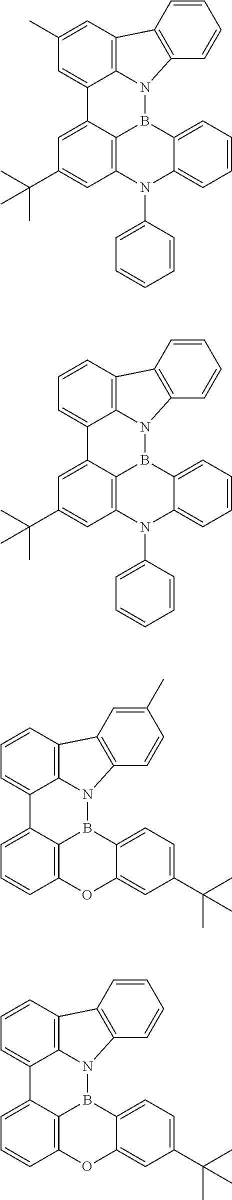 [SMILES: Cc1cc2c3c(c1)c1ccccc1n3B1c3ccccc3N(c3ccccc3)c3cc(C(C)(C)C)cc-2c31 ; CC(C)(C)c1cc2c3c(c1)N(c1ccccc1)c1ccccc1B3n1c3ccccc3c3cccc-2c31 ; Cc1ccc2c(c1)c1cccc3c1n2B1c2ccc(C(C)(C)C)cc2Oc2cccc-3c21 ; CC(C)(C)c1ccc2c(c1)Oc1cccc3c1B2n1c2ccccc2c2cccc-3c21]

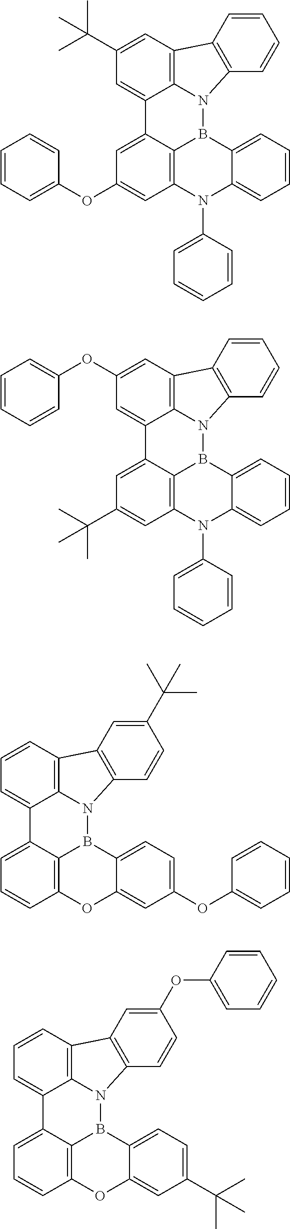

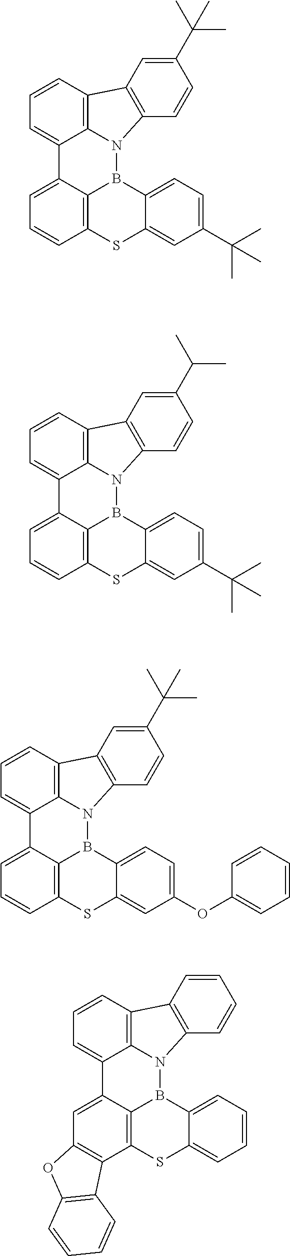 [SMILES: CC(C)(C)c1ccc2c(c1)Sc1cccc3c1B2n1c2ccc(C(C)(C)C)cc2c2cccc-3c21 ; CC(C)c1ccc2c(c1)c1cccc3c1n2B1c2ccc(C(C)(C)C)cc2Sc2cccc-3c21 ; CC(C)(C)c1ccc2c(c1)c1cccc3c1n2B1c2ccc(Oc4ccccc4)cc2Sc2cccc-3c21 ; c1ccc2c(c1)Sc1c3c(cc4oc5ccccc5c14)-c1cccc4c5ccccc5n(c14)B23]

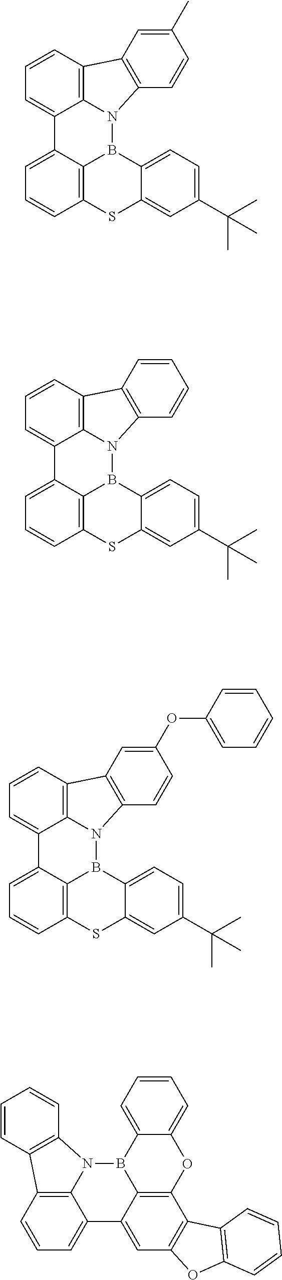 [SMILES: Cc1ccc2c(c1)c1cccc3c1n2B1c2ccc(C(C)(C)C)cc2Sc2cccc-3c21 ; CC(C)(C)c1ccc2c(c1)Sc1cccc3c1B2n1c2ccccc2c2cccc-3c21 ; CC(C)(C)c1ccc2c(c1)Sc1cccc3c1B2n1c2ccc(Oc4ccccc4)cc2c2cccc-3c21 ; c1ccc2c(c1)Oc1c3c(cc4oc5ccccc5c14)-c1cccc4c5ccccc5n(c14)B23]

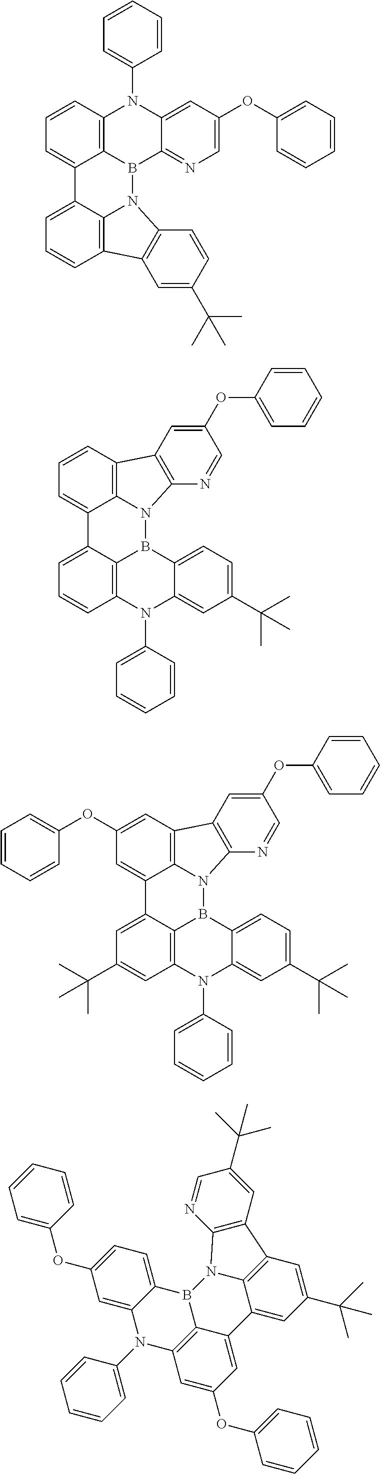

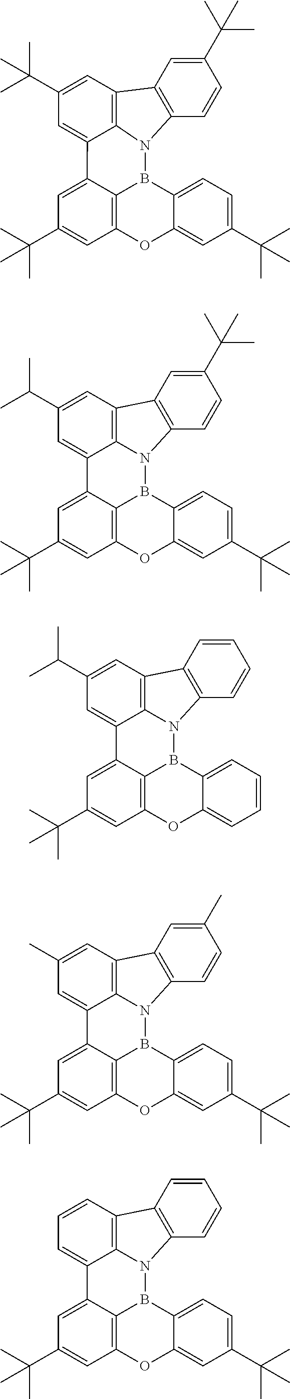

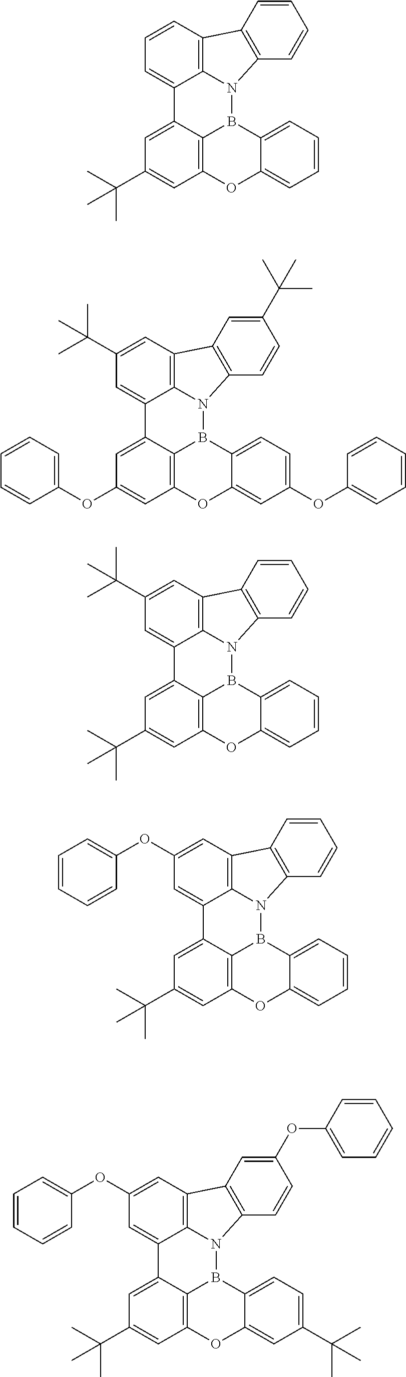 [SMILES: CC(C)(C)c1cc2c3c(c1)-c1cccc4c5ccccc5n(c14)B3c1ccccc1O2 ; CC(C)(C)c1ccc2c(c1)c1cc(C(C)(C)C)cc3c1n2B1c2ccc(Oc4ccccc4)cc2Oc2cc(Oc4ccccc4)cc-3c21 ; CC(C)(C)c1cc2c3c(c1)-c1cc(C(C)(C)C)cc4c5ccccc5n(c14)B3c1ccccc1O2 ; CC(C)(C)c1cc2c3c(c1)-c1cc(Oc4ccccc4)cc4c5ccccc5n(c14)B3c1ccccc1O2 ; CC(C)(C)c1ccc2c(c1)Oc1cc(C(C)(C)C)cc3c1B2n1c2ccc(Oc4ccccc4)cc2c2cc(Oc4ccccc4)cc-3c21]

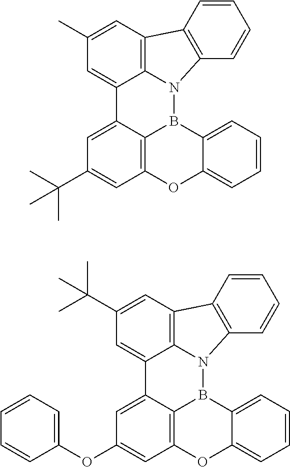 [SMILES: Cc1cc2c3c(c1)c1ccccc1n3B1c3ccccc3Oc3cc(C(C)(C)C)cc-2c31 ; CC(C)(C)c1cc2c3c(c1)c1ccccc1n3B1c3ccccc3Oc3cc(Oc4ccccc4)cc-2c31]

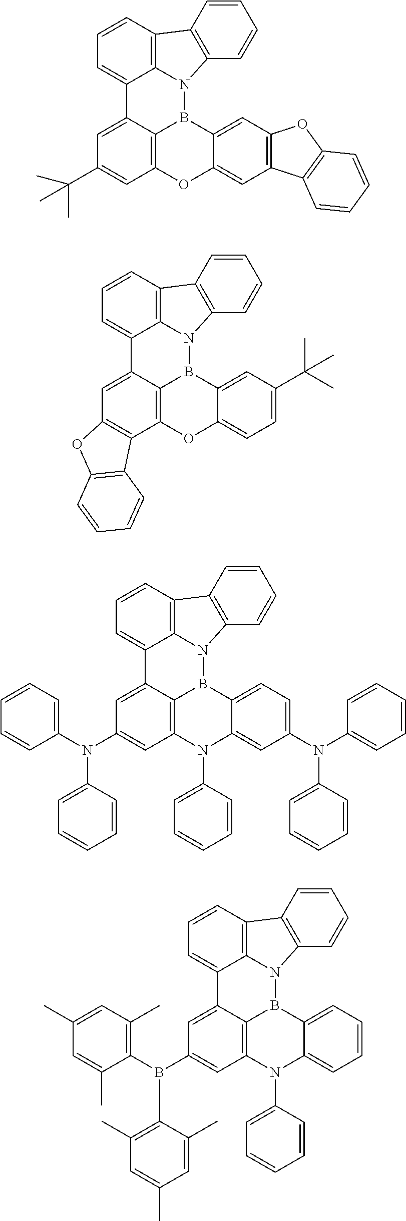

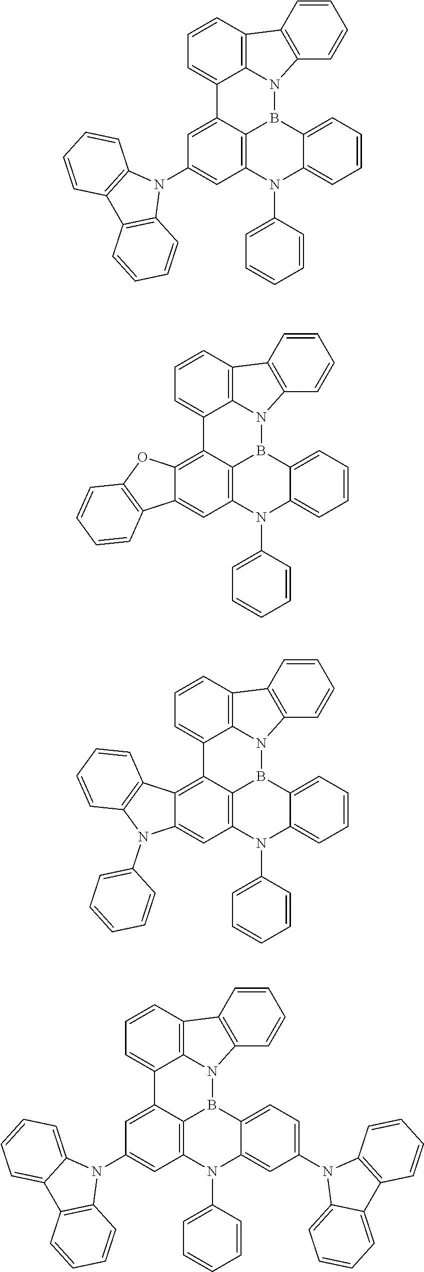

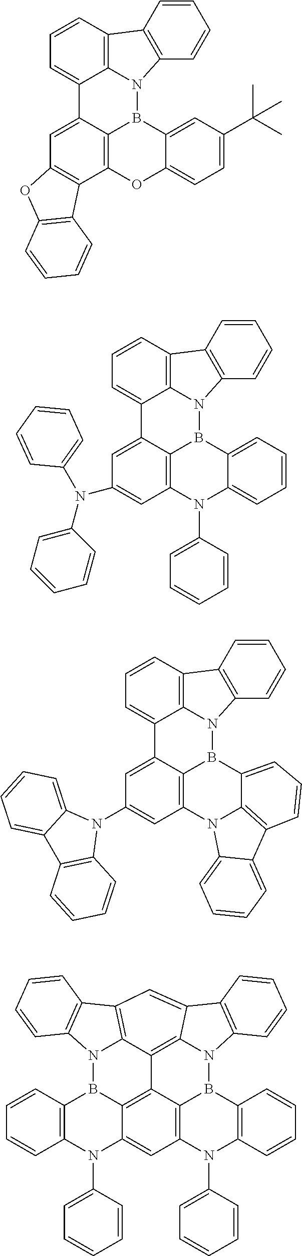 [SMILES: CC(C)(C)c1ccc2c(c1)B1c3c(cc4oc5ccccc5c4c3O2)-c2cccc3c4ccccc4n1c23 ; c1ccc(N(c2ccccc2)c2cc3c4c(c2)N(c2ccccc2)c2ccccc2B4n2c4ccccc4c4cccc-3c42)cc1 ; c1ccc2c(c1)c1cccc3c1n2B1c2c-3cc(-n3c4ccccc4c4ccccc43)cc2-n2c3ccccc3c3cccc1c32 ; c1ccc(N2c3ccccc3B3c4c2cc2c5c4-c4c6c(cc7c8ccccc8n(c47)B5c4ccccc4N2c2ccccc2)c2ccccc2n63)cc1]

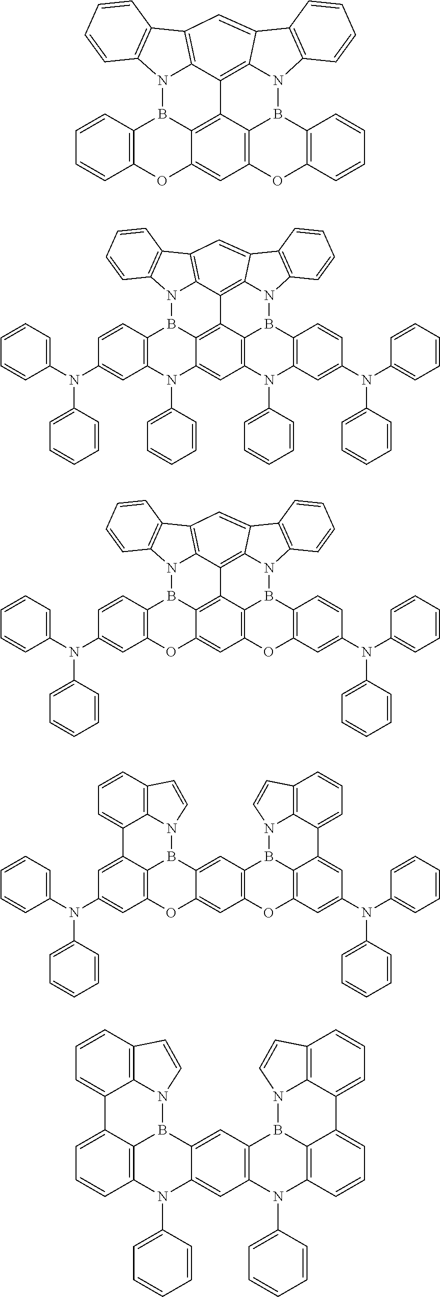

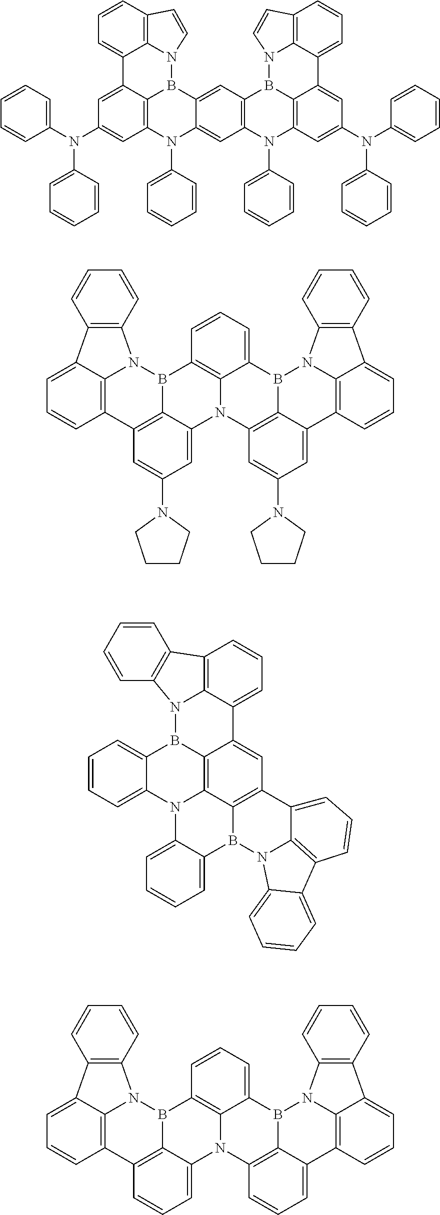

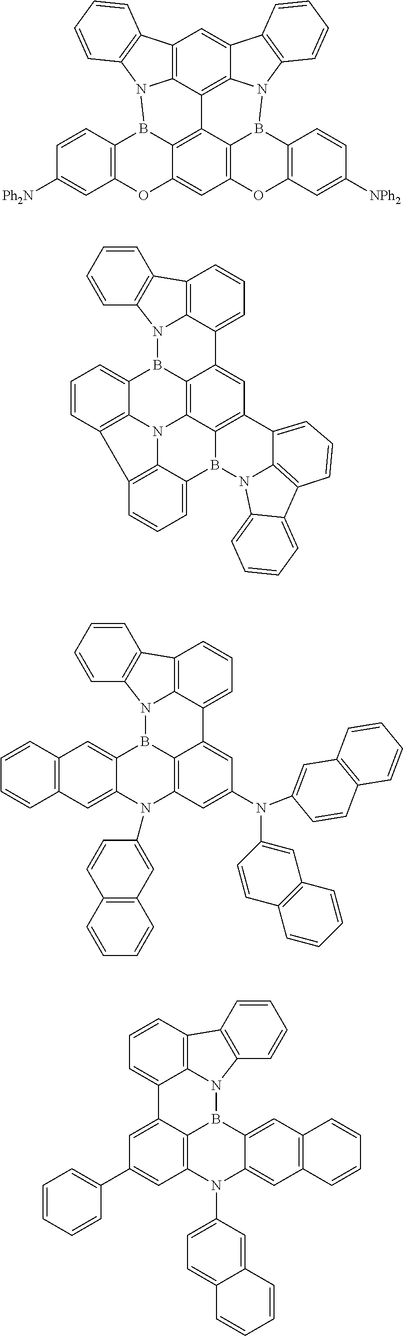

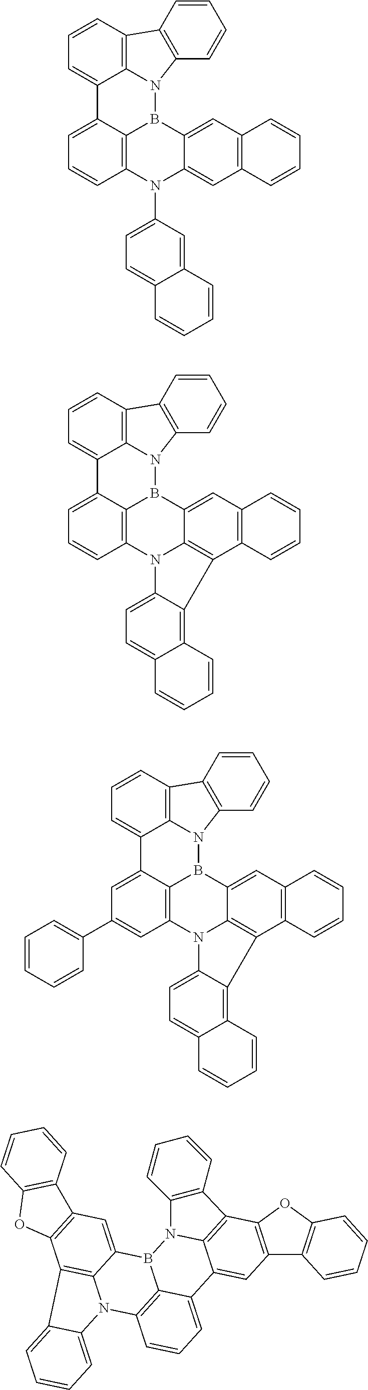

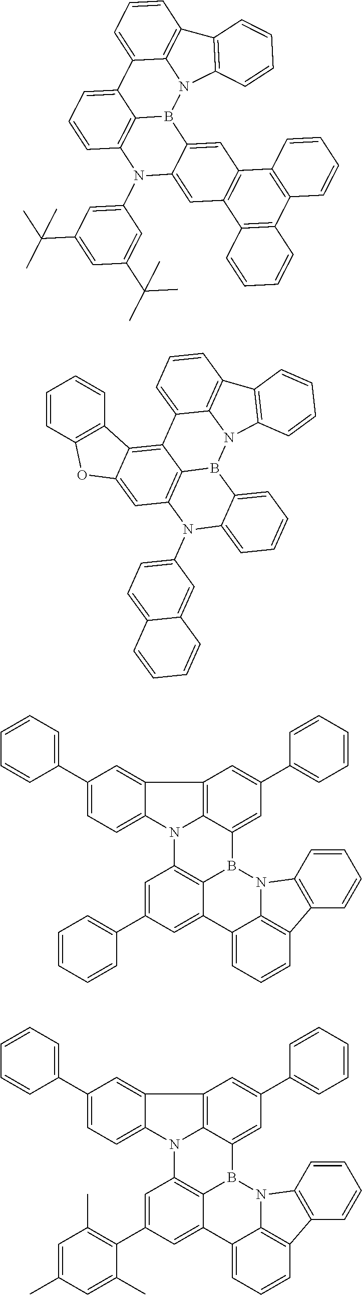 [SMILES: CC(C)(C)c1cc(N2c3cc4c5ccccc5c5ccccc5c4cc3B3c4c(cccc42)-c2cccc4c5ccccc5n3c24)cc(C(C)(C)C)c1 ; c1ccc2c(c1)B1c3c(cc4oc5ccccc5c4c3-c3cccc4c5ccccc5n1c34)N2c1ccc2ccccc2c1 ; c1ccc(-c2cc3c4c(c2)-n2c5ccc(-c6ccccc6)cc5c5cc(-c6ccccc6)cc(c52)B4n2c4ccccc4c4cccc-3c42)cc1 ; Cc1cc(C)c(-c2cc3c4c(c2)-n2c5ccc(-c6ccccc6)cc5c5cc(-c6ccccc6)cc(c52)B4n2c4ccccc4c4cccc-3c42)c(C)c1]

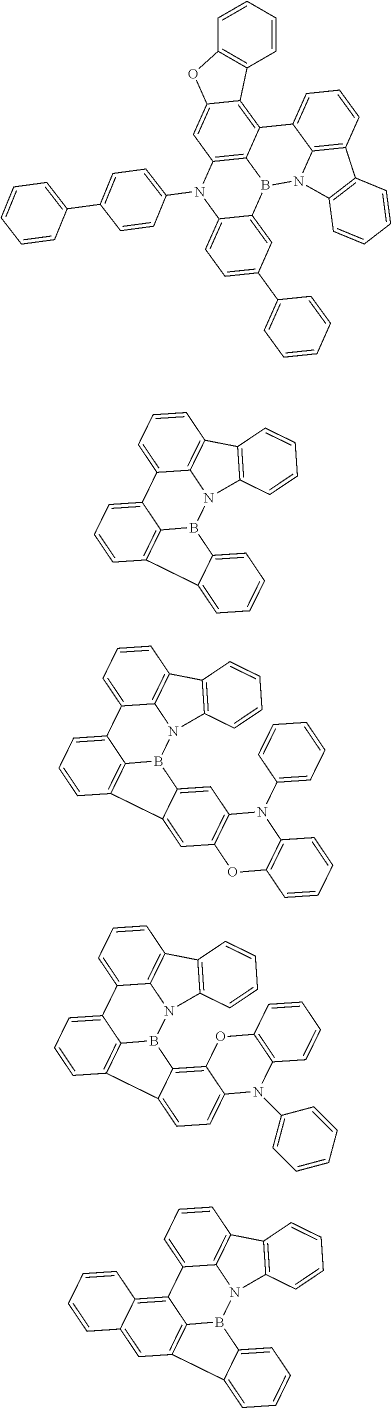 [SMILES: c1ccc(-c2ccc(N3c4ccc(-c5ccccc5)cc4B4c5c3cc3oc6ccccc6c3c5-c3cccc5c6ccccc6n4c35)cc2)cc1 ; c1ccc2c(c1)B1c3c-2cccc3-c2cccc3c4ccccc4n1c23 ; c1ccc(N2c3ccccc3Oc3cc4c(cc32)B2c3c-4cccc3-c3cccc4c5ccccc5n2c34)cc1 ; c1ccc(N2c3ccccc3Oc3c2ccc2c3B3c4c-2cccc4-c2cccc4c5ccccc5n3c24)cc1 ; c1ccc2c(c1)B1c3c-2cc2ccccc2c3-c2cccc3c4ccccc4n1c23]

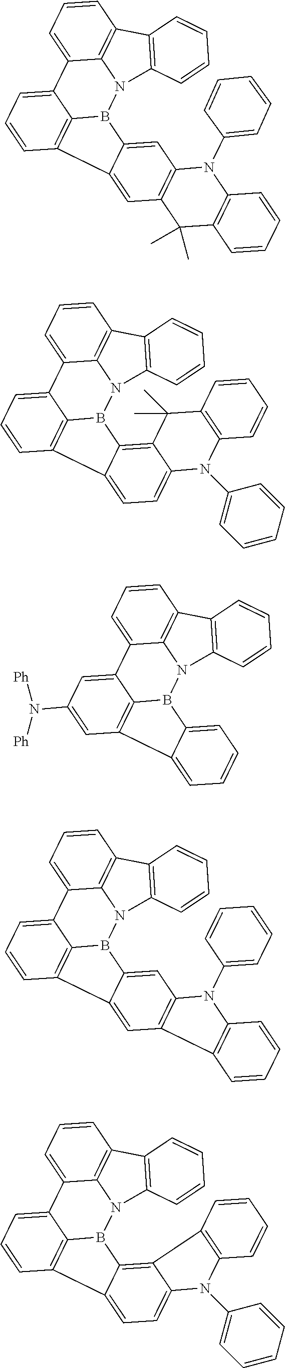 [SMILES: CC1(C)c2ccccc2N(c2ccccc2)c2cc3c(cc21)-c1cccc2c1B3n1c3ccccc3c3cccc-2c31 ; CC1(C)c2ccccc2N(c2ccccc2)c2ccc3c(c21)B1c2c-3cccc2-c2cccc3c4ccccc4n1c23 ; c1ccc(N(c2ccccc2)c2cc3c4c(c2)-c2cccc5c6ccccc6n(c25)B4c2ccccc2-3)cc1 ; c1ccc(-n2c3ccccc3c3cc4c(cc32)B2c3c-4cccc3-c3cccc4c5ccccc5n2c34)cc1 ; c1ccc(-n2c3ccccc3c3c4c(ccc32)-c2cccc3c2B4n2c4ccccc4c4cccc-3c42)cc1]

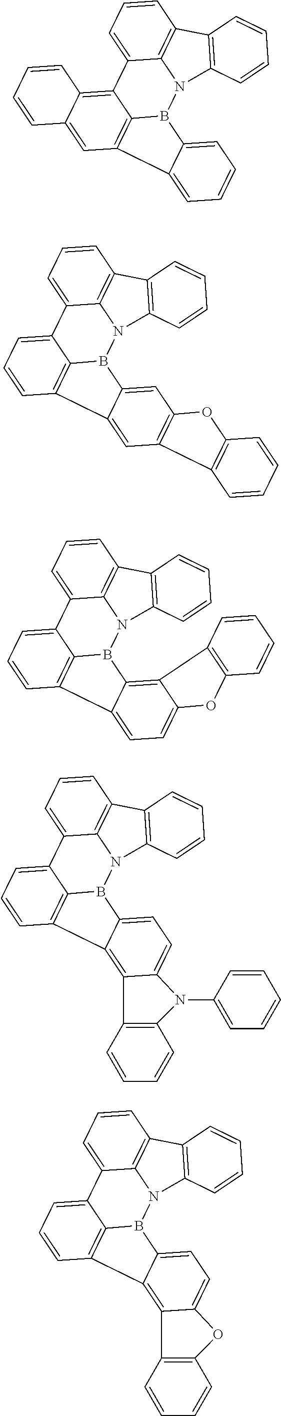

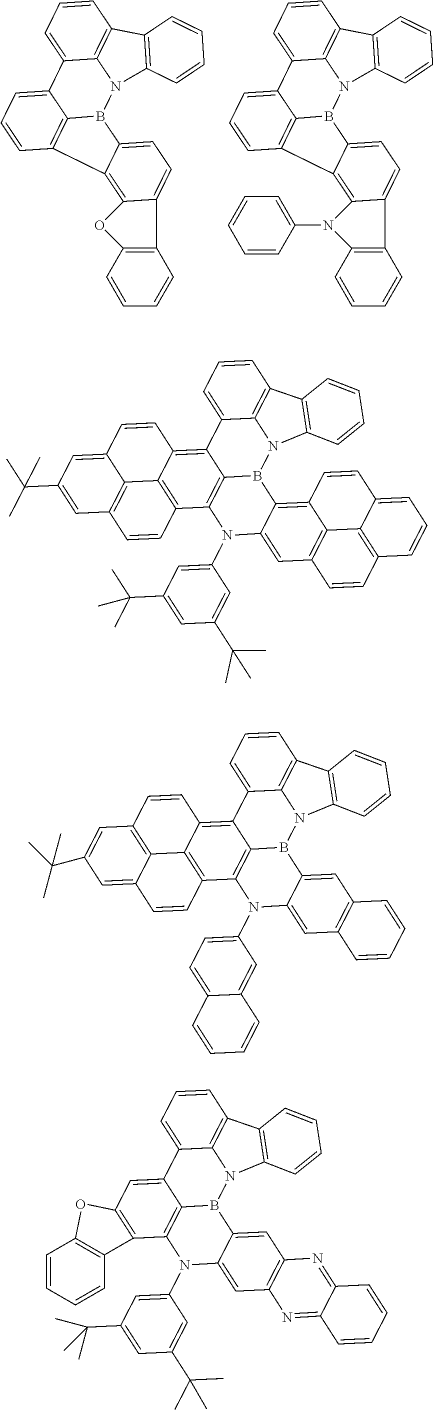

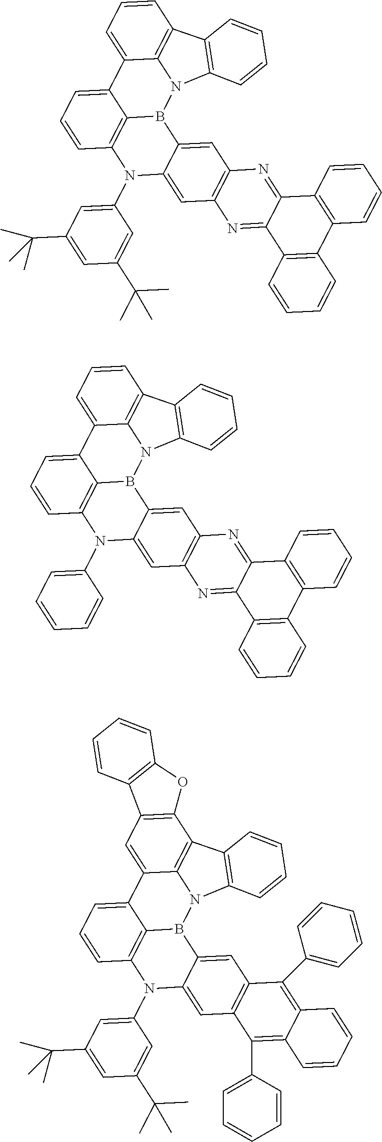

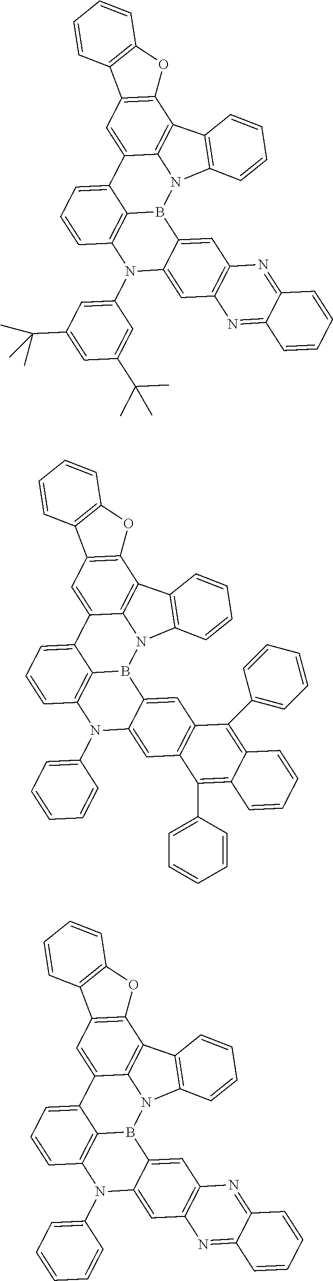 [SMILES: CC(C)(C)c1cc(N2c3cc4nc5ccccc5nc4cc3B3c4c(cccc42)-c2cc4c5ccccc5oc4c4c5ccccc5n3c24)cc(C(C)(C)C)c1 ; c1ccc(-c2c3ccccc3c(-c3ccccc3)c3cc4c(cc23)B2c3c(cccc3N4c3ccccc3)-c3cc4c5ccccc5oc4c4c5ccccc5n2c34)cc1 ; c1ccc(N2c3cc4nc5ccccc5nc4cc3B3c4c(cccc42)-c2cc4c5ccccc5oc4c4c5ccccc5n3c24)cc1]

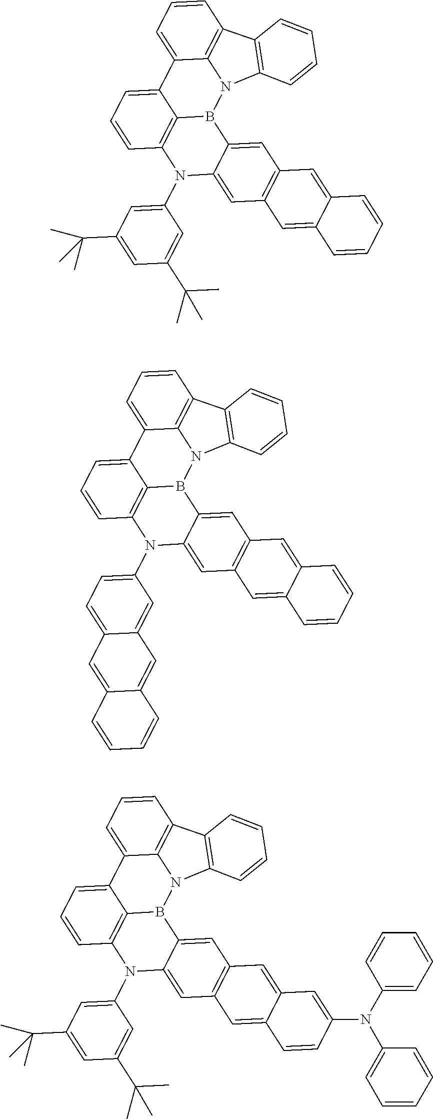 [SMILES: CC(C)(C)c1cc(N2c3cc4cc5ccccc5cc4cc3B3c4c(cccc42)-c2cccc4c5ccccc5n3c24)cc(C(C)(C)C)c1 ; c1cc2c3c(c1)N(c1ccc4cc5ccccc5cc4c1)c1cc4cc5ccccc5cc4cc1B3n1c3ccccc3c3cccc-2c31 ; CC(C)(C)c1cc(N2c3cc4cc5ccc(N(c6ccccc6)c6ccccc6)cc5cc4cc3B3c4c(cccc42)-c2cccc4c5ccccc5n3c24)cc(C(C)(C)C)c1]

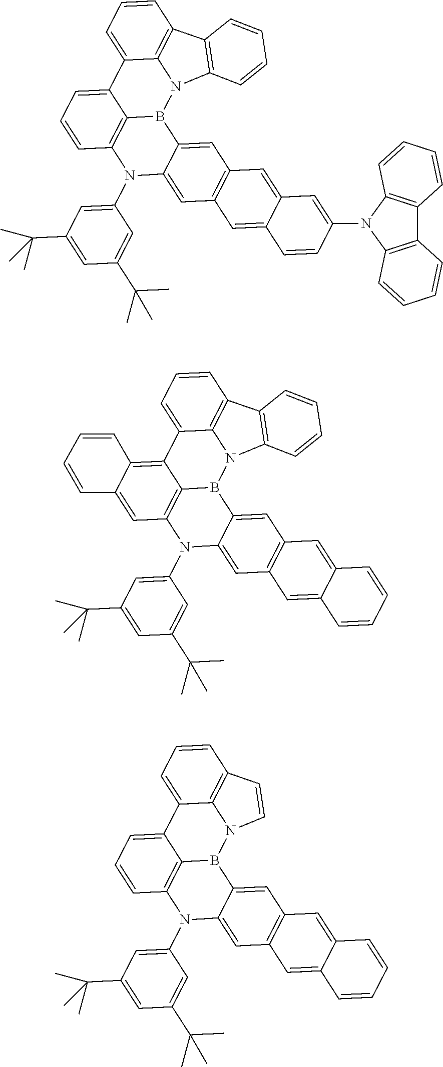 [SMILES: CC(C)(C)c1cc(N2c3cc4cc5ccc(-n6c7ccccc7c7ccccc76)cc5cc4cc3B3c4c(cccc42)-c2cccc4c5ccccc5n3c24)cc(C(C)(C)C)c1 ; CC(C)(C)c1cc(N2c3cc4cc5ccccc5cc4cc3B3c4c2cc2ccccc2c4-c2cccc4c5ccccc5n3c24)cc(C(C)(C)C)c1 ; CC(C)(C)c1cc(N2c3cc4cc5ccccc5cc4cc3B3c4c(cccc42)-c2cccc4ccn3c24)cc(C(C)(C)C)c1]

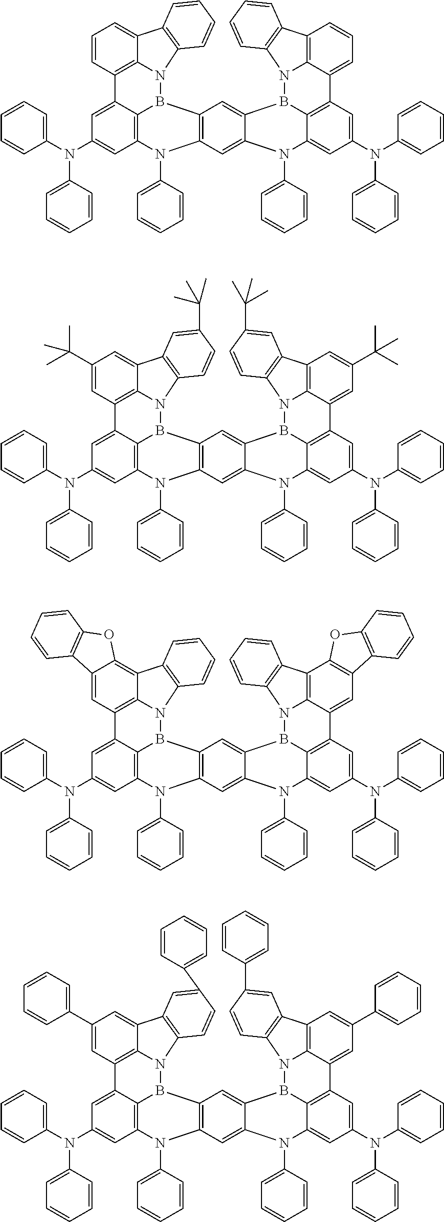

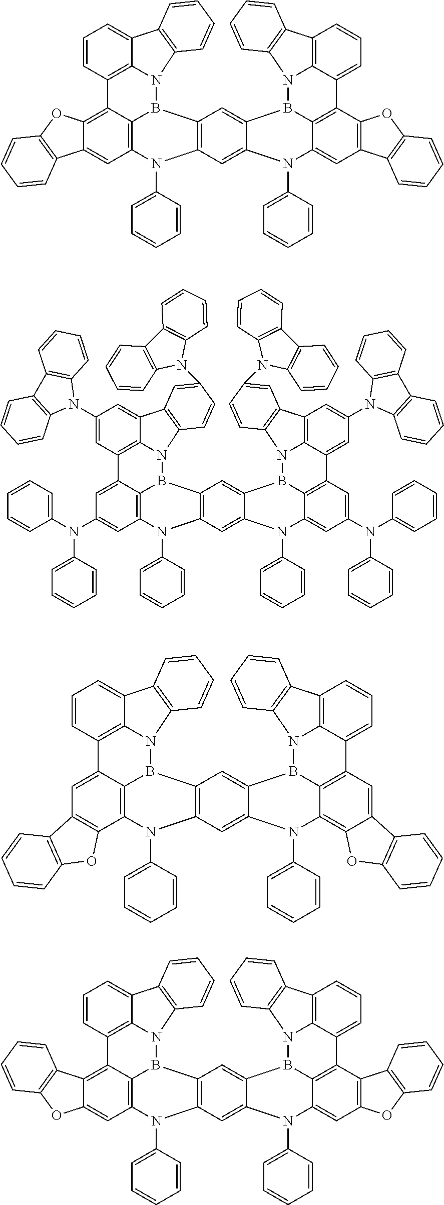

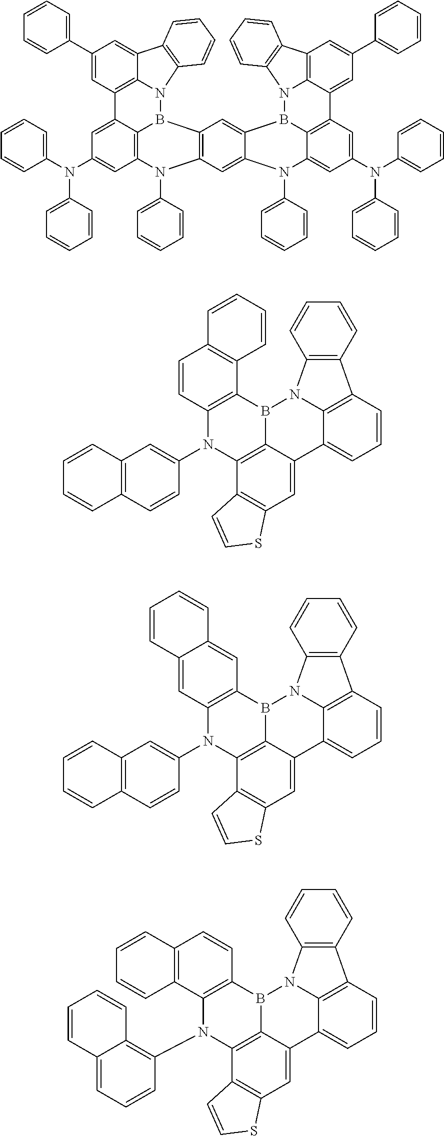 [SMILES: c1ccc(-c2cc3c4c(c2)c2ccccc2n4B2c4cc5c(cc4N(c4ccccc4)c4cc(N(c6ccccc6)c6ccccc6)cc-3c42)N(c2ccccc2)c2cc(N(c3ccccc3)c3ccccc3)cc3c2B5n2c4ccccc4c4cc(-c5ccccc5)cc-3c42)cc1 ; c1ccc2cc(N3c4ccc5ccccc5c4B4c5c(cc6sccc6c53)-c3cccc5c6ccccc6n4c35)ccc2c1 ; c1ccc2cc(N3c4cc5ccccc5cc4B4c5c(cc6sccc6c53)-c3cccc5c6ccccc6n4c35)ccc2c1 ; c1ccc2c(N3c4c(ccc5ccccc45)B4c5c(cc6sccc6c53)-c3cccc5c6ccccc6n4c35)cccc2c1]

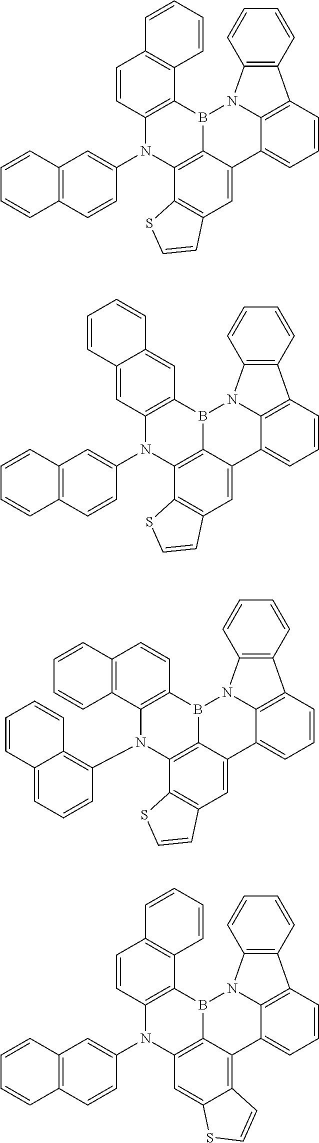

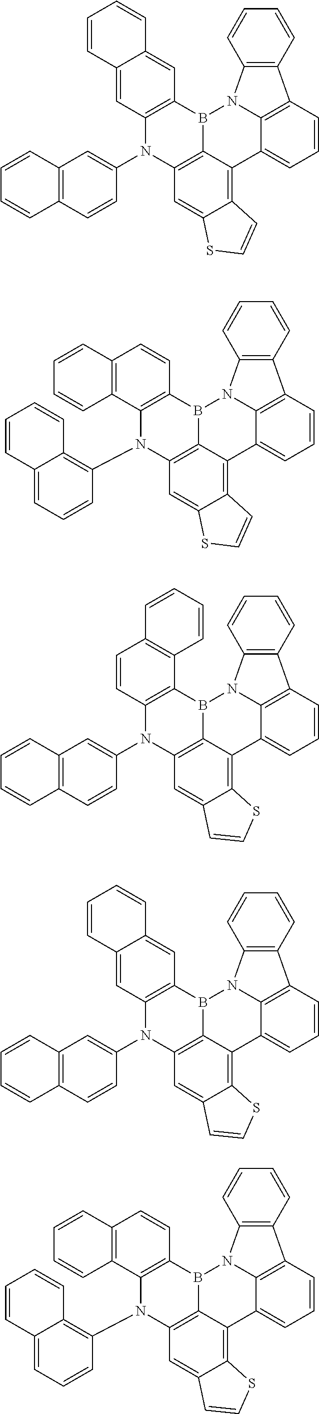

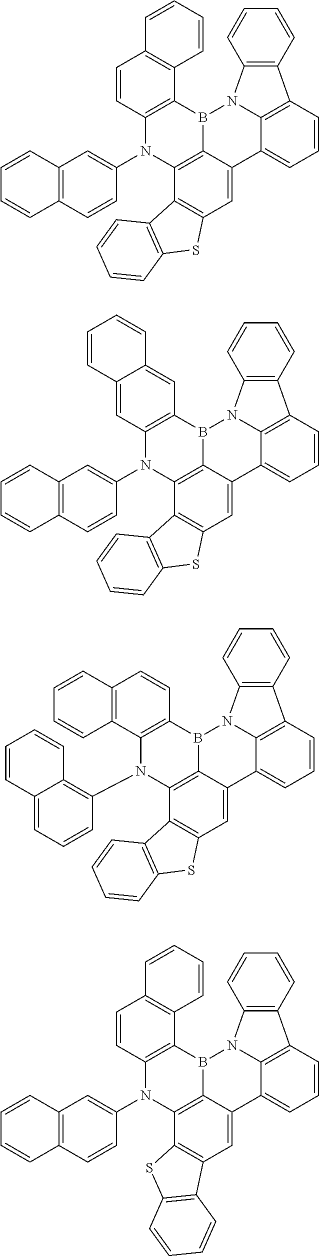

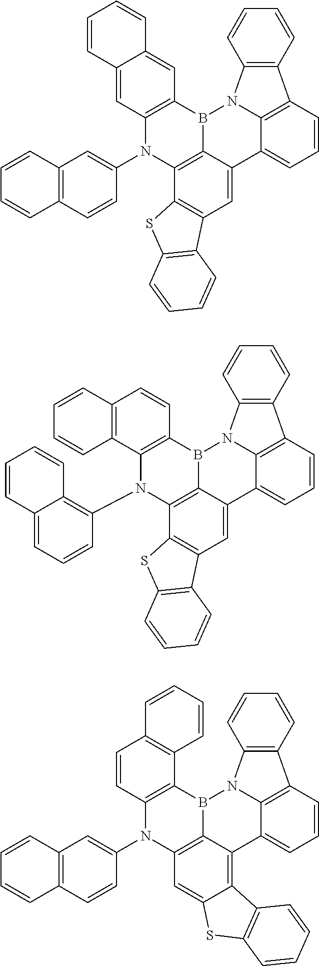

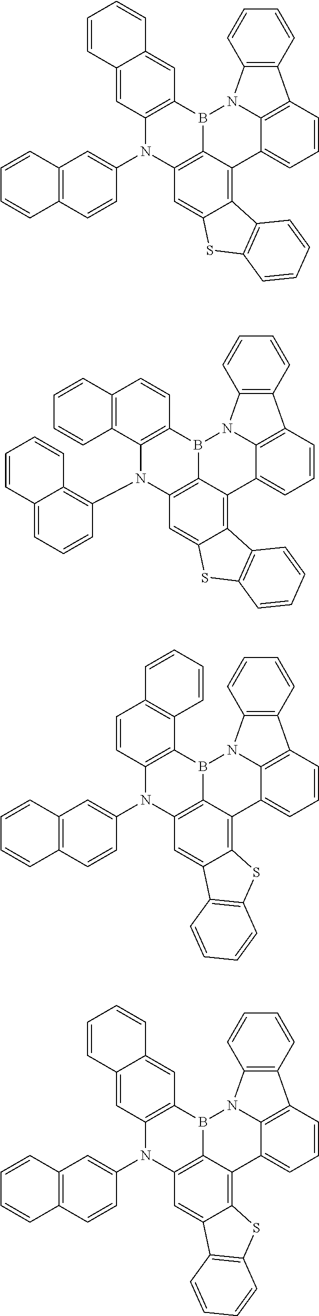 [SMILES: c1ccc2cc(N3c4cc5ccccc5cc4B4c5c3cc3sc6ccccc6c3c5-c3cccc5c6ccccc6n4c35)ccc2c1 ; c1ccc2c(N3c4cc5sc6ccccc6c5c5c4B(c4ccc6ccccc6c43)n3c4ccccc4c4cccc-5c43)cccc2c1 ; c1ccc2cc(N3c4cc5c(sc6ccccc65)c5c4B(c4c3ccc3ccccc43)n3c4ccccc4c4cccc-5c43)ccc2c1 ; c1ccc2cc(N3c4cc5ccccc5cc4B4c5c3cc3c(sc6ccccc63)c5-c3cccc5c6ccccc6n4c35)ccc2c1]

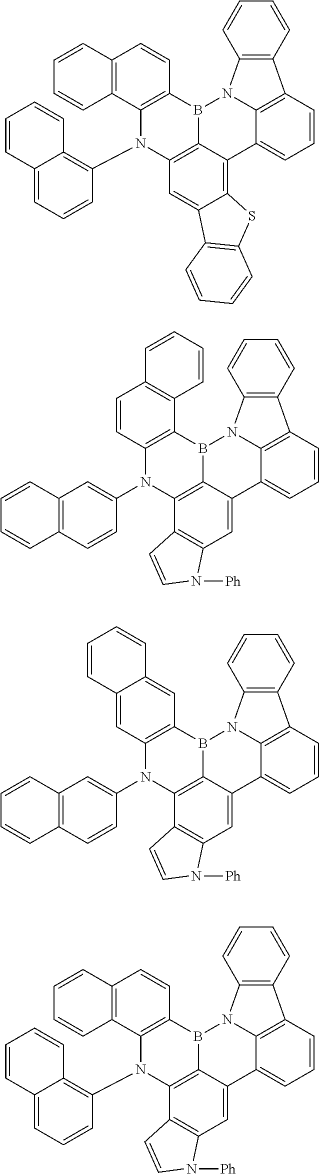

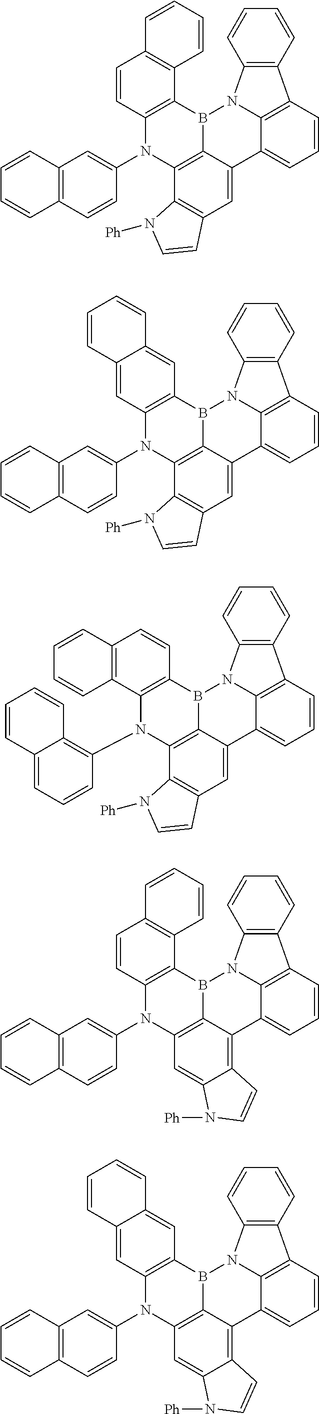

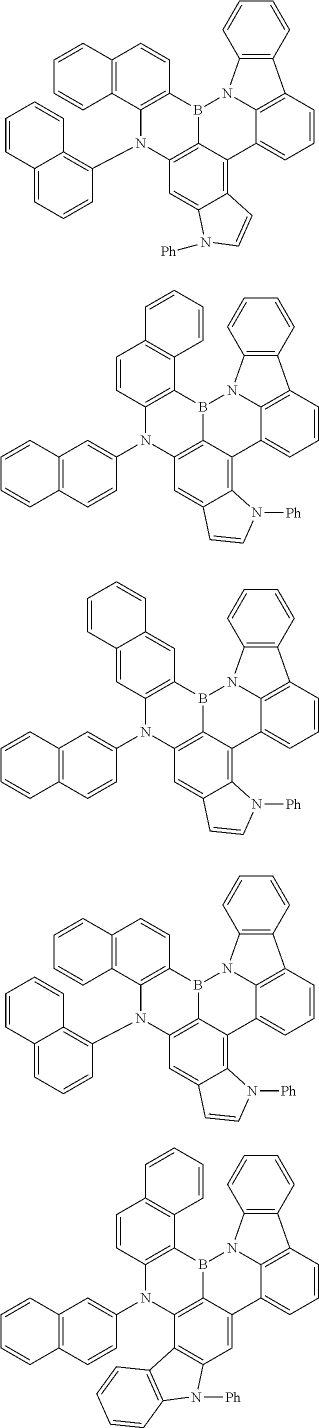

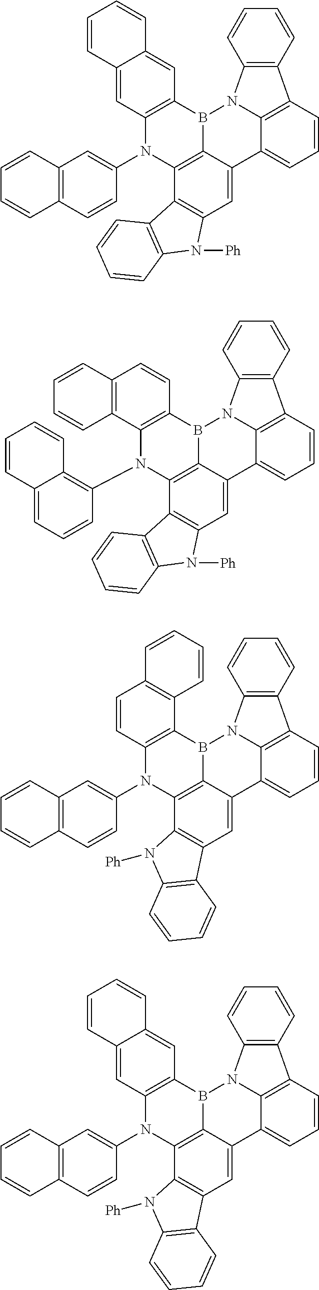 [SMILES: c1ccc(-n2c3ccccc3c3c4c5c(cc32)-c2cccc3c6ccccc6n(c23)B5c2cc3ccccc3cc2N4c2ccc3ccccc3c2)cc1 ; c1ccc(-n2c3ccccc3c3c4c5c(cc32)-c2cccc3c6ccccc6n(c23)B5c2ccc3ccccc3c2N4c2cccc3ccccc23)cc1 ; c1ccc(-n2c3ccccc3c3cc4c5c(c32)N(c2ccc3ccccc3c2)c2ccc3ccccc3c2B5n2c3ccccc3c3cccc-4c32)cc1 ; c1ccc(-n2c3ccccc3c3cc4c5c(c32)N(c2ccc3ccccc3c2)c2cc3ccccc3cc2B5n2c3ccccc3c3cccc-4c32)cc1]

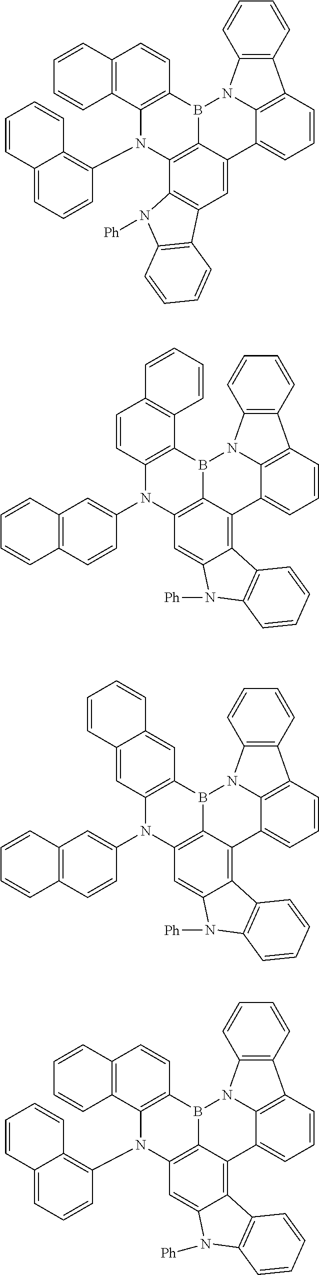

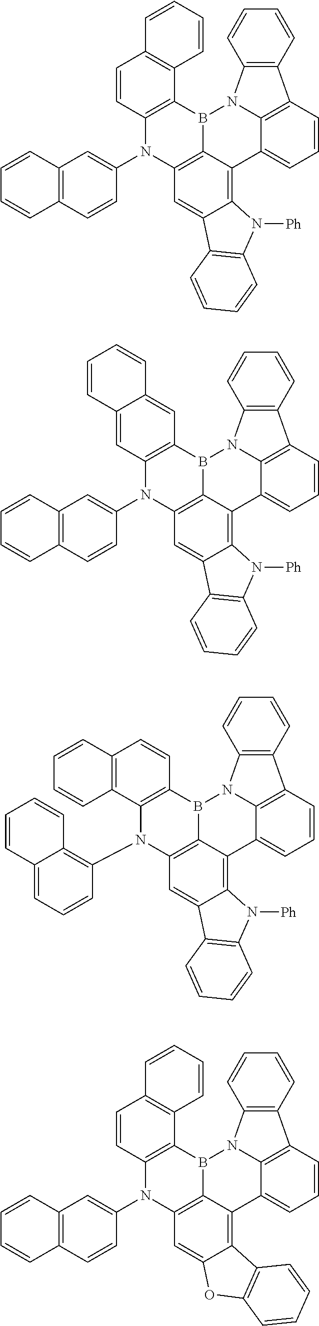

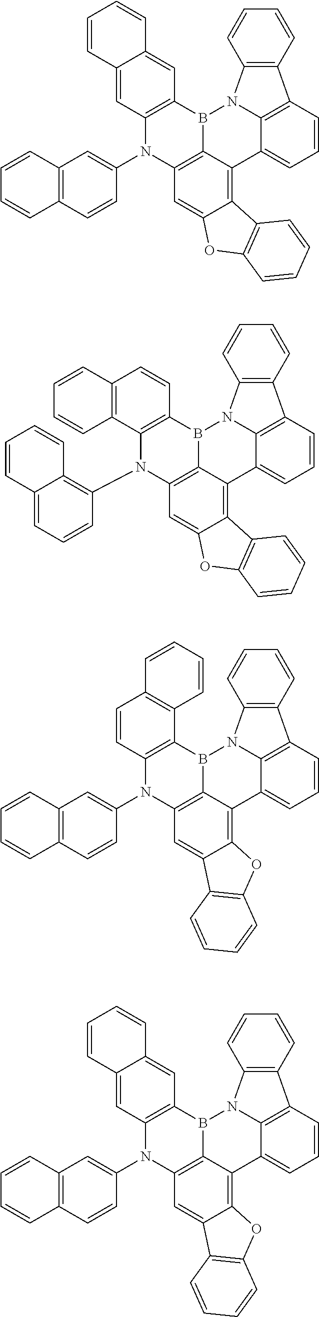

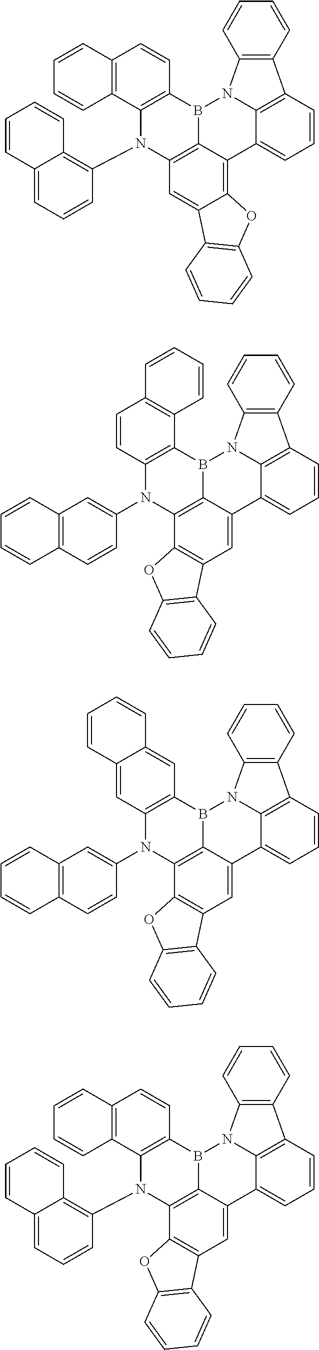 [SMILES: c1ccc2c(N3c4cc5c(oc6ccccc65)c5c4B(c4ccc6ccccc6c43)n3c4ccccc4c4cccc-5c43)cccc2c1 ; c1ccc2cc(N3c4ccc5ccccc5c4B4c5c(cc6c(oc7ccccc76)c53)-c3cccc5c6ccccc6n4c35)ccc2c1 ; c1ccc2cc(N3c4cc5ccccc5cc4B4c5c(cc6c(oc7ccccc76)c53)-c3cccc5c6ccccc6n4c35)ccc2c1 ; c1ccc2c(N3c4c(ccc5ccccc45)B4c5c(cc6c(oc7ccccc76)c53)-c3cccc5c6ccccc6n4c35)cccc2c1]

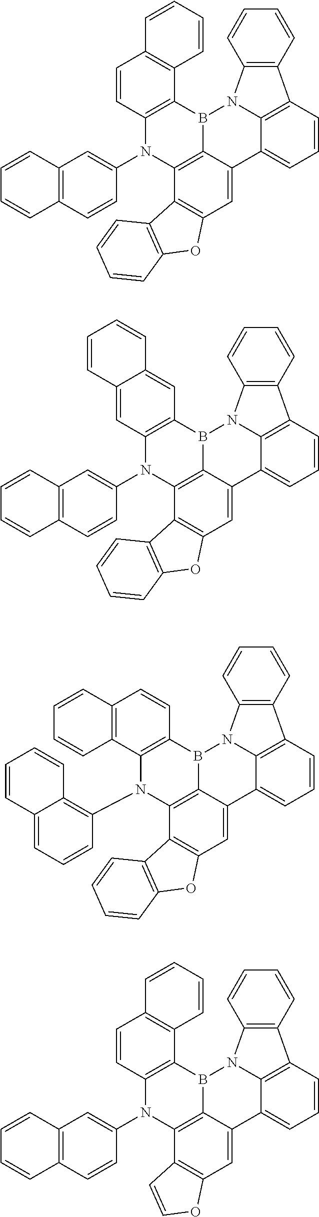

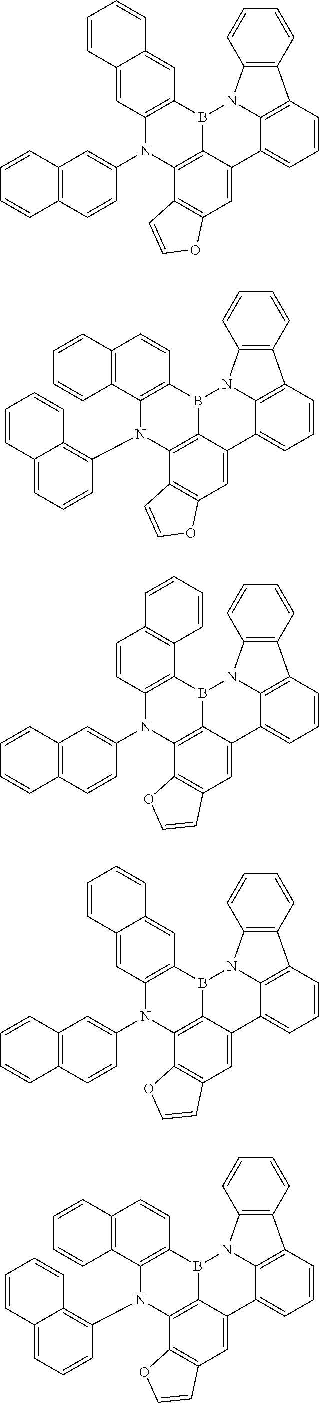

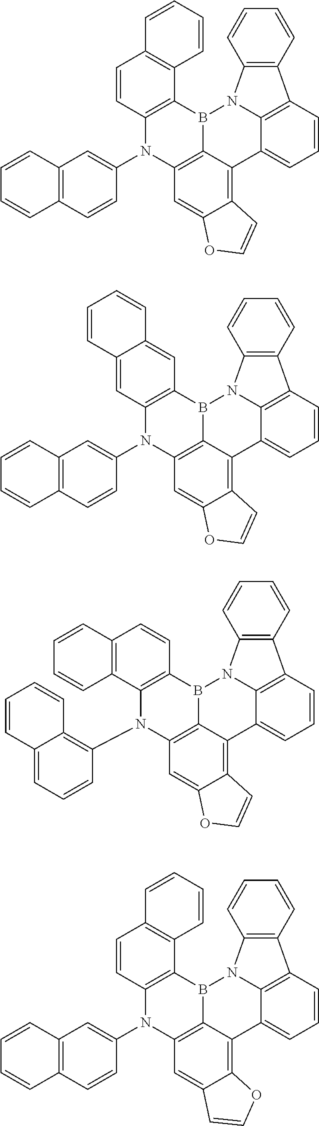

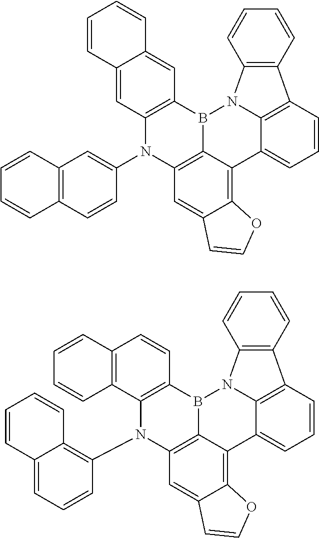

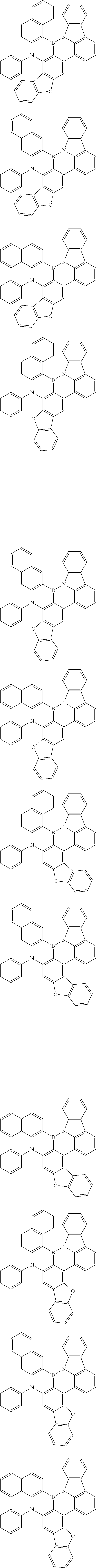

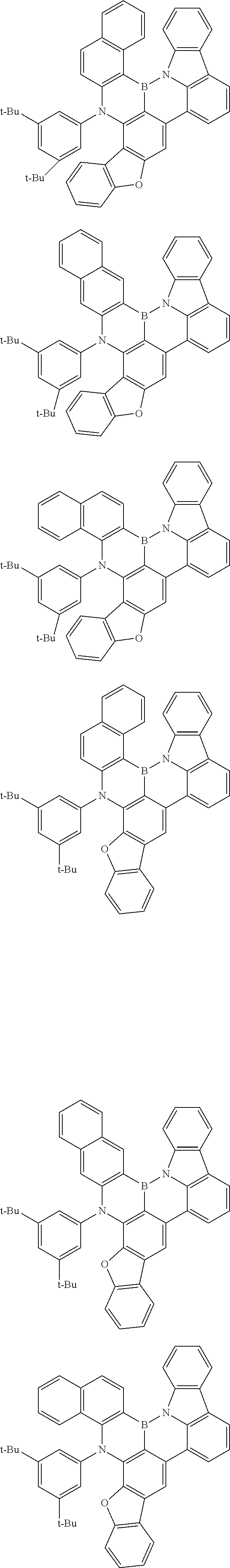

[chemical structure]

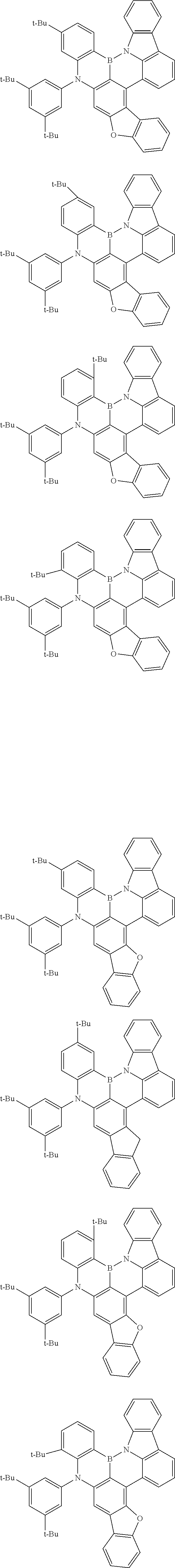

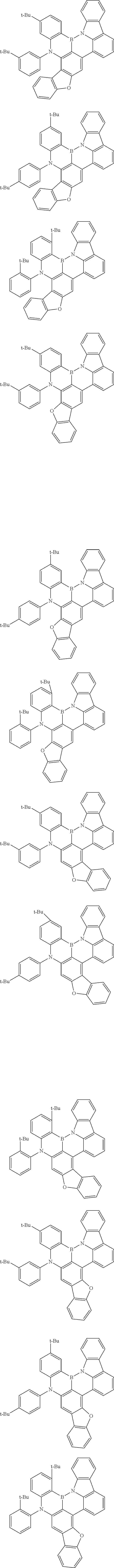

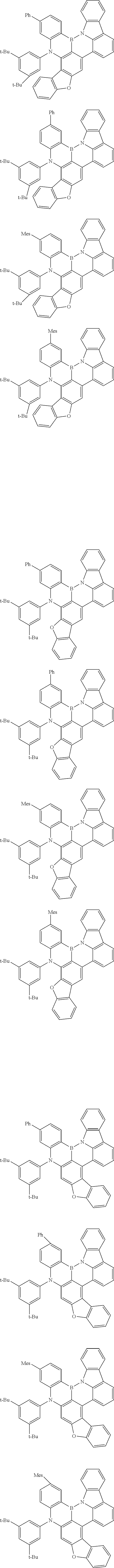

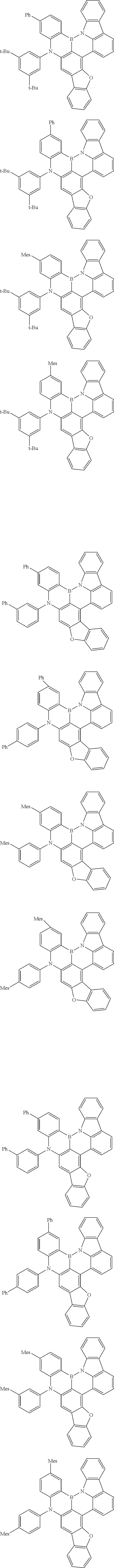

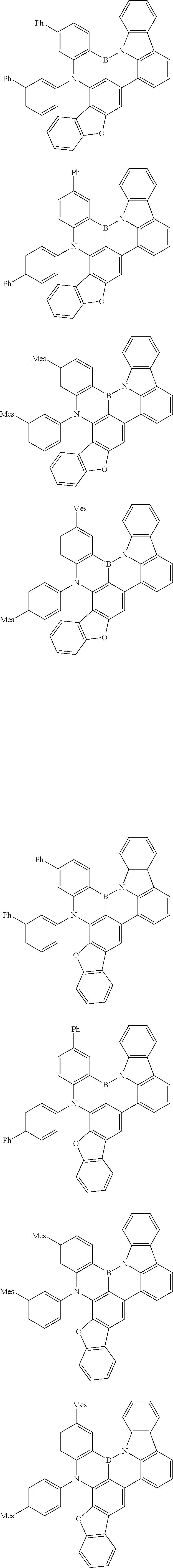

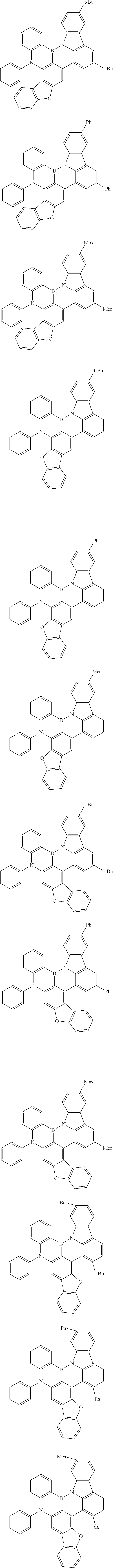

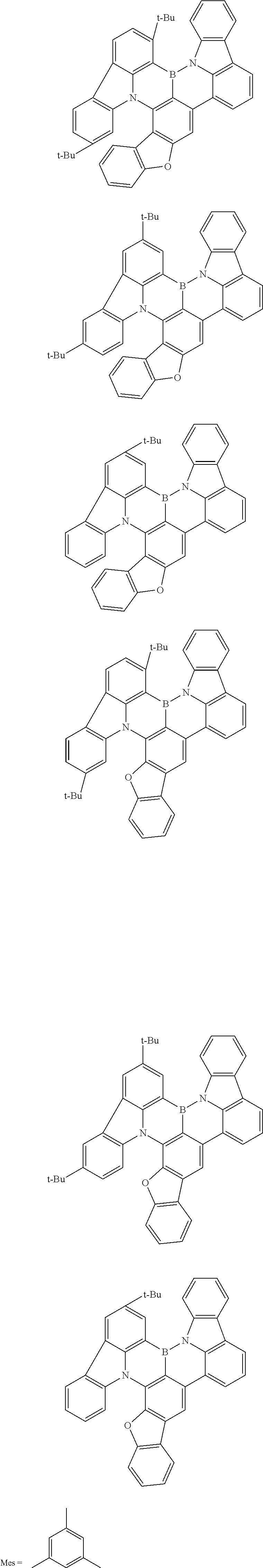

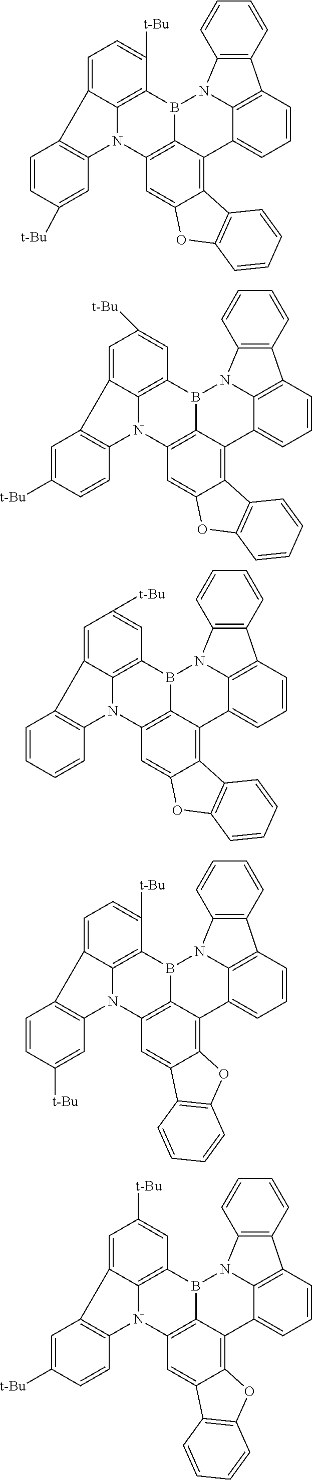

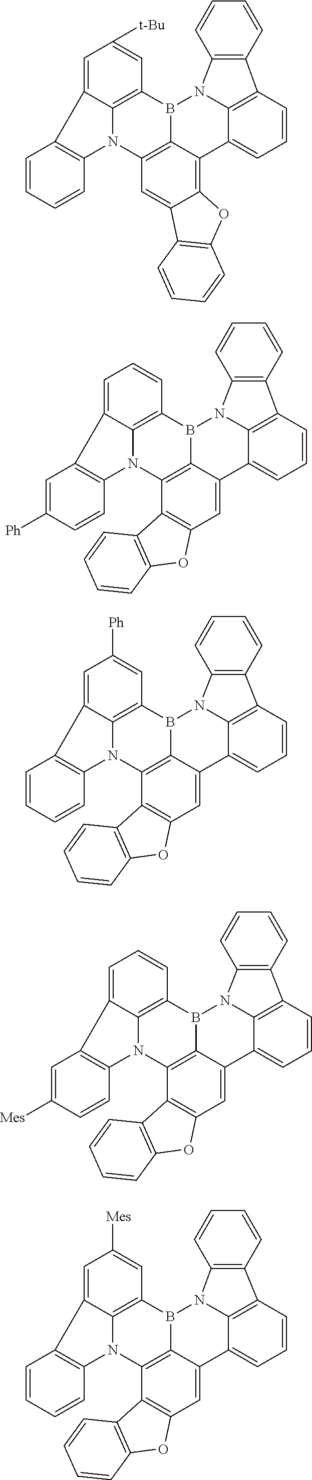

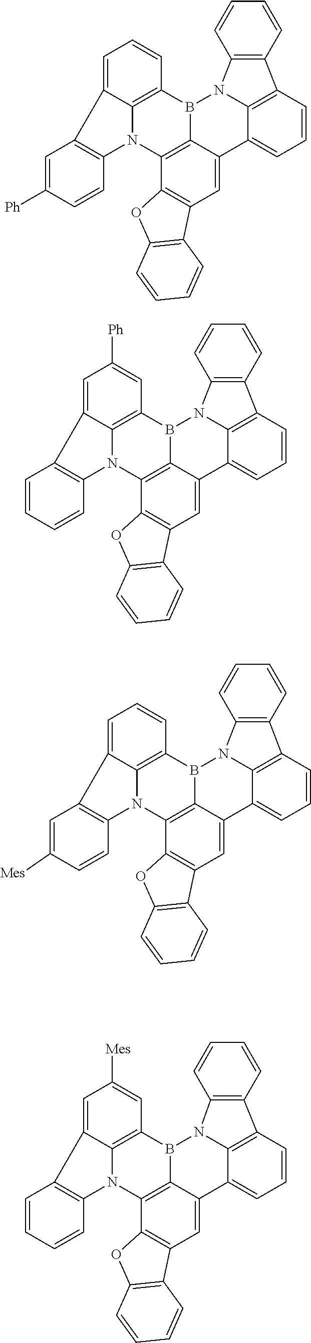

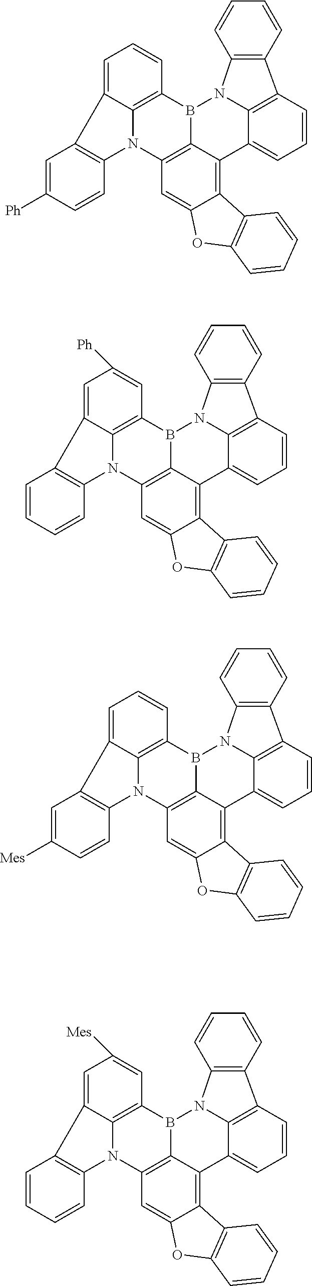

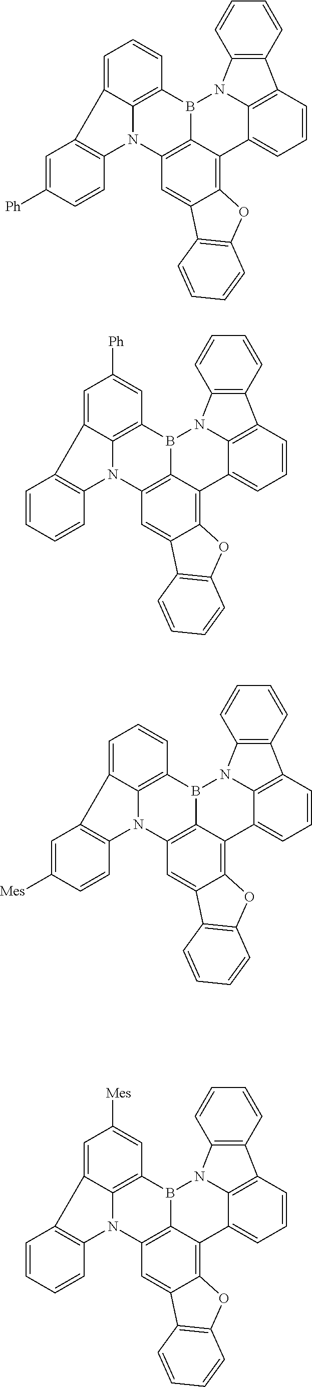

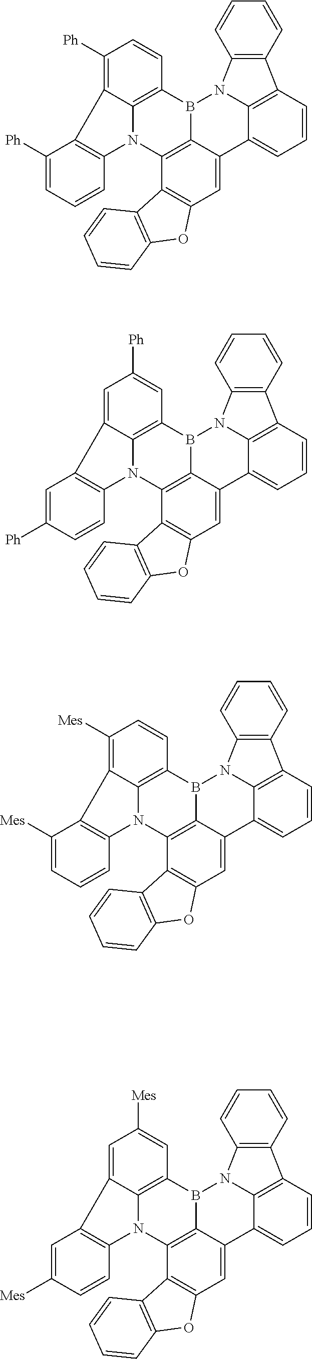

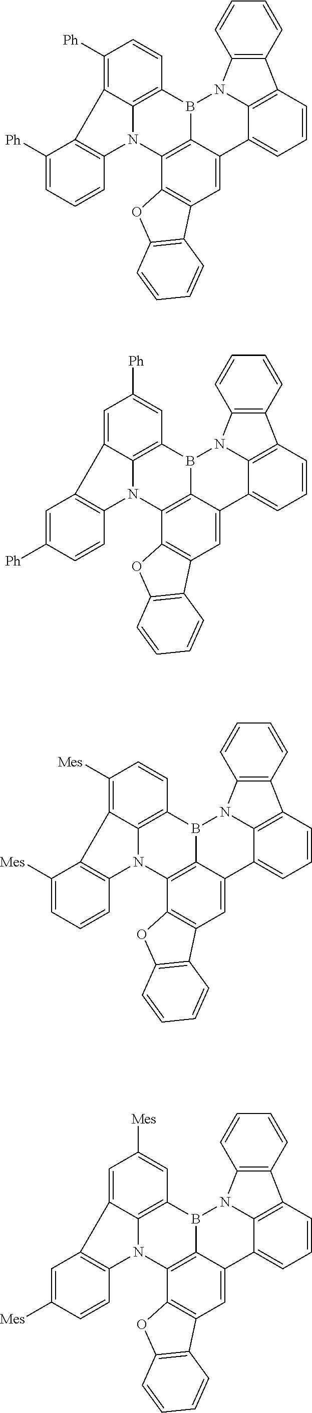

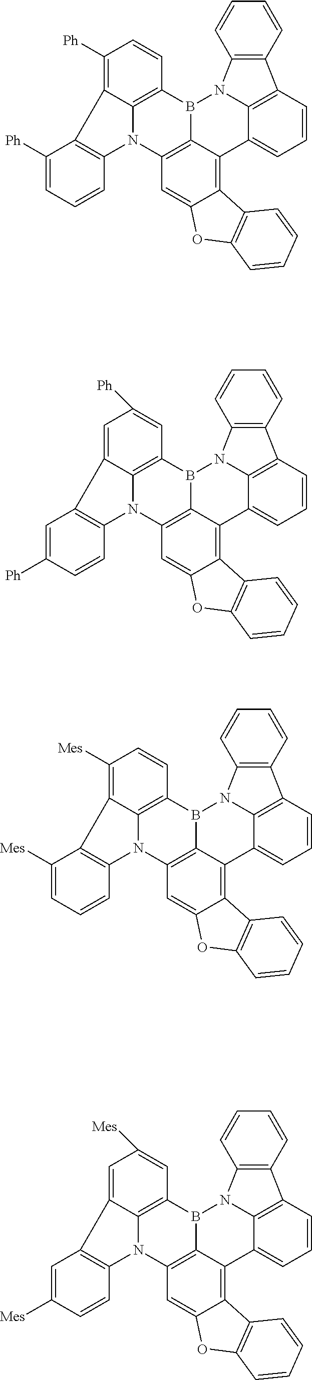

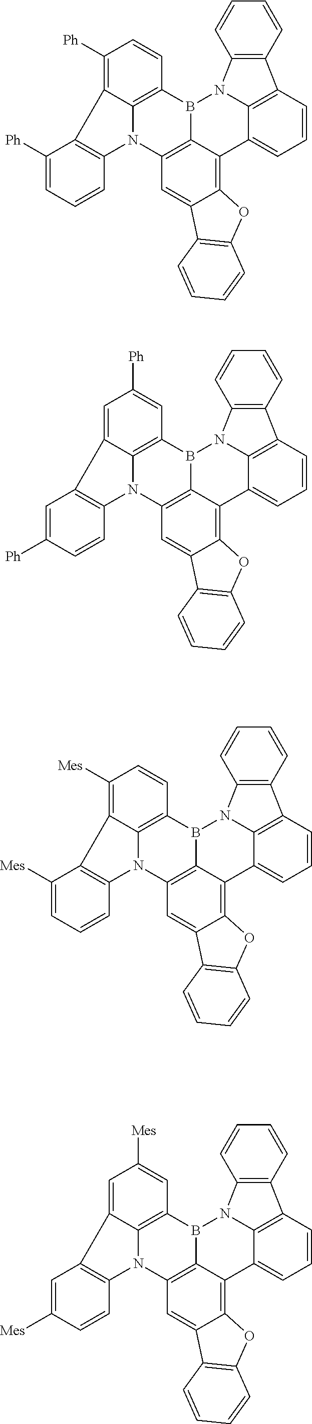

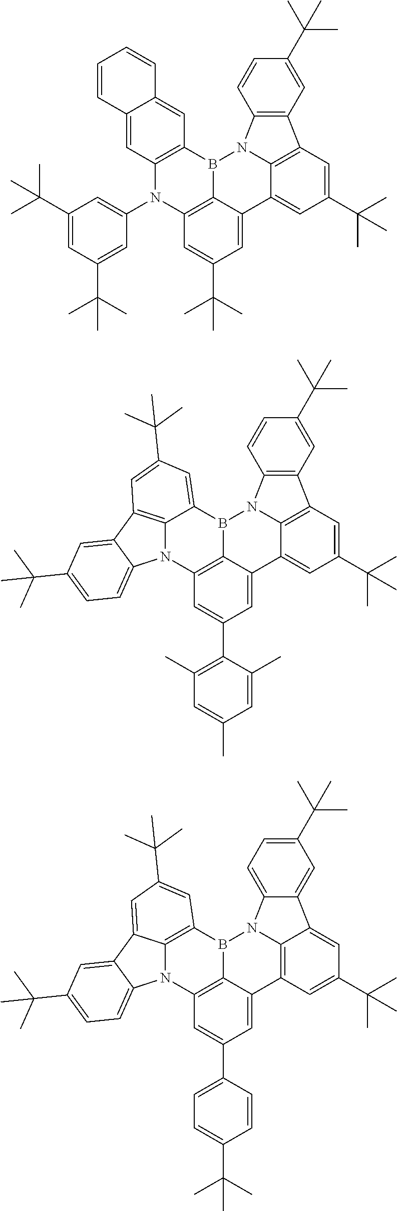

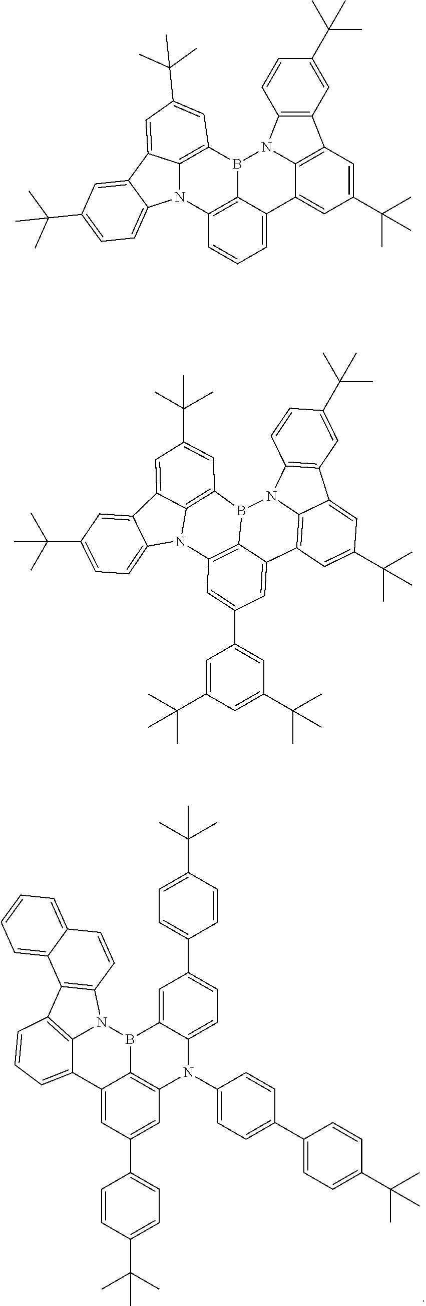

The synthesis of organic molecules (e.g., usable as small FWHM emitters) including or consisting of a structure according to Formula BNE-1 can be accomplished via standard reactions and reaction conditions known to the skilled artisan.

Typically, the synthesis includes transition-metal catalyzed cross coupling reactions and a borylation reaction, all of which are known to the skilled artisan.

For example, WO2020135953 (A1) teaches how to synthesize BN emitters including or consisting of a structure according to Formula BNE-1. Furthermore, US2018047912 (A1) teaches how to synthesize BN emitters including or consisting of a structure according to Formula BNE-1, in particular with c and d being 0.

It is understood that the emitters disclosed in US2018047912 (A1) and WO2020135953 (A1) may also be used as BN emitters in the context of the present invention.

The person skilled in the art will immediately notice which hydrogen atoms of the phenyl-rings in the core structure of the shown BN emitter (i.e., a phenyl ring binding to B as well as to at least one N) can be replaced by the binding site of the single bond linking the BN emitter moiety M^{BN} to the bridging unit L. As one example, a structure can be depicted as follows, when explicitly depicting the hydrogen atoms:

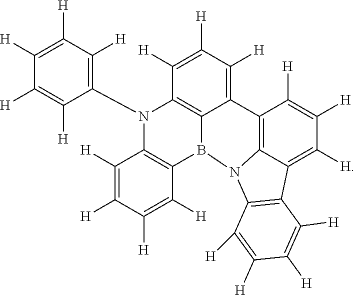

In a preferred embodiment, M^{BN} is attached to L in the para-position to the Boron atom as indicated by the following Formula M^{BN}-1:

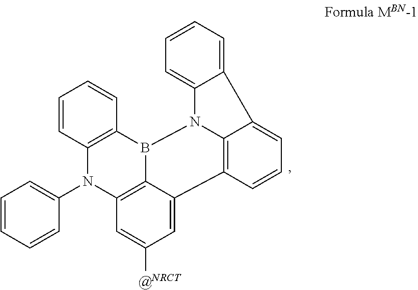

wherein @^{NRCT} represents the single bond linking the BN emitter moiety M^{BN} to the bridging unit L.

### The TADF Moiety M^{TADF}:

The thermally activated delayed fluorescence (TADF) material moiety M^{TADF} is derived from a TADF material. According to the present invention, a TADF material is characterized in that it exhibits a ΔE^{ST} value, which corresponds to the energy difference between the lowermost excited singlet state (S1) and the lowermost excited triplet state (T1), of less than 0.4 eV, preferably less than 0.3 eV, more preferably less than 0.2 eV, even more preferably less than 0.1 eV or even less than 0.05 eV.

In one embodiment of the invention, M^{TADF} consists of
a first chemical moiety consisting of a structure according to Formula I,

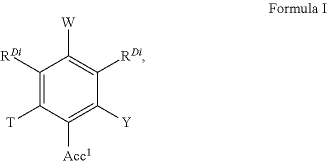

and
one second chemical moiety consisting of a structure according to Formula II,

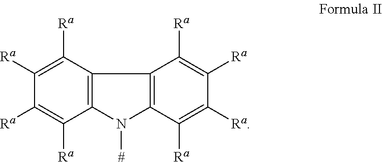

The first chemical moiety is linked to the second chemical moiety via a single bond.

T is selected from the group consisting of
the binding site of a single bond linking the first chemical moiety to the second chemical moiety, hydrogen (H), deuterium (D), and R^{TADF1}.

W is selected from the group consisting of
the binding site of a single bond linking the first chemical moiety to the second chemical moiety,
the binding site of a single bond linking the TADF moiety M^{TADF} to the bridging unit L,
H, D, and R^{TADF1}.

Y is selected from the group consisting of the binding site of a single bond linking the TADF moiety M^{TADF} to the bridging unit L, H, D, and R^{TADF1},
Acc¹ is selected from the group consisting of:
CN;
CF₃;
Ph, which is optionally substituted with one or more substituents selected from the group consisting of CN, CF₃, and F;
triazinyl, which is optionally substituted with one or more substituents R⁶;
pyridyl, which is optionally substituted with one or more substituents R⁶; and
pyrimidyl, which is optionally substituted with one or more substituents R⁶.

#represents the binding site of a single bond linking the second chemical moieties to the first chemical moiety.

R^{Di} is independently selected from the group consisting of H, D, Me, ⁱPr, ^{t}Bu, SiPh₃, CN, CF₃,
Ph, which is optionally substituted with one or more substituents independently from each other selected from the group consisting of Me, ⁱPr, ^{t}Bu, and Ph,
the binding site of the single bond linking the TADF moiety M^{TADF} to the bridging unit L, and
a third chemical moiety consisting of a structure of Formula Q:

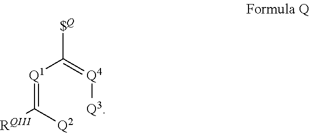

Q¹ is selected from the group consisting of N and C—R^{QI}.

Q² is selected from the group consisting of N and C—R^{QIII}.

Q³ is selected from the group consisting of N and C—R^{QIV}.

Q⁴ is selected from the group consisting of N and C—R^{QV}.

$^{Q} represents the binding site of a single bond linking the third chemical moiety to the first chemical moiety.

R^{QI} is selected from the group consisting of
H, D, CN, CF₃, SiPh₃, F, Ph, and
a fourth chemical moiety including or consisting of a structure of Formula IIQ:

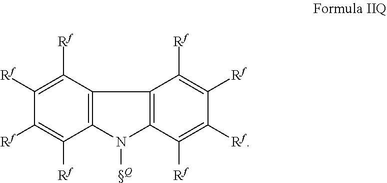

§^{Q} represents the binding site of a single bond linking the fourth chemical moiety to the third chemical moiety.

R^{QII} is selected from the group consisting of
the binding site of the single bond linking the TADF moiety M^{TADF} to the bridging unit L,
H, D, Me, ⁱPr, ^{t}Bu, SiPh₃, and
Ph, which is optionally substituted with one or more substituents independently from each other selected from the group consisting of Me, ⁱPr, ^{t}Bu, and Ph.

R^{QIII} is selected from the group consisting of:
the binding site of the single bond linking the TADF moiety M^{TADF} to the bridging unit L;
H, D, CN, CF₃, SiPh₃, F;
Ph, which is optionally substituted with one or more substituents R⁶;
triazinyl, which is optionally substituted with one or more substituents R⁶;
pyridyl, which is optionally substituted with one or more substituents R⁶; and
pyrimidyl, which is optionally substituted with one or more substituents R⁶;
R^{QIV} is selected from the group consisting of:
the binding site of the single bond linking the TADF moiety M^{TADF} to the bridging unit L;
H, D, CN, CF₃, SiPh₃, F;
Ph, which is optionally substituted with one or more substituents R⁶;
triazinyl, which is optionally substituted with one or more substituents R⁶;
pyridyl, which is optionally substituted with one or more substituents R⁶; and
pyrimidyl, which is optionally substituted with one or more substituents R⁶.

R^{QV} is selected from the group consisting of
the binding site of the single bond linking the TADF moiety M^{TADF} to the bridging unit L,
H, D, Me, ⁱPr, ^{t}Bu, SiPh₃, and
Ph, which is optionally substituted with one or more substituents independently from each other selected from the group consisting of Me, ⁱPr, ^{t}Bu, and Ph.

In one embodiment, all of Q¹, Q² and Q⁴ are each N, thereby forming a triazine moiety. In another embodiment, two of Q¹, Q² and Q⁴ are each N, thereby forming a pyrimidine moiety. In another embodiment, only one of Q¹, Q² and Q⁴ are each N, thereby forming a pyridine moiety. In another embodiment, all of Q¹, Q² Q³, and Q⁴, as far as present, are each an optionally substituted carbon atom (C—R^{QI}, C—R^{QIII}, C—R^{QIV}, C—R^{QV}), thereby forming a phenyl moiety.

According to the invention, in case one R^{Di} represents the third chemical moiety including or consisting of a structure of Formula Q,
the other R^{Di} is selected from the group consisting of H, D, Me, ⁱPr, ^{t}Bu, SiPh₃,
Ph, which is optionally substituted with one or more substituents independently from each other selected from the group consisting of Me, ⁱPr, ^{t}Bu, and Ph, and
the binding site of the single bond linking the TADF moiety M^{TADF} to the bridging unit L.

R^{TADF1} is selected from the group consisting of
Me, ⁱPr, ^{t}Bu, SiPh₃, and
Ph, which is optionally substituted with one or more substituents independently from each other selected from the group consisting of Me, ⁱPr, ^{t}Bu, and Ph.

R^{a} at each occurrence independently from each other selected from the group consisting of:
the binding site of the single bond linking the TADF moiety M^{TADF} to the bridging unit L;
hydrogen, deuterium, N(R⁵)₂, OR⁵, Si(R⁵)₃, B(OR⁵)₂, OSO₂R⁵, CF₃, CN, F, Br, I;
C₁-C₄₀-alkyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₃-C₅₇-heteroaryl,
which is optionally substituted with one or more substituents R⁵.

R⁵ is at each occurrence independently from each other selected from the group consisting of: hydrogen; deuterium; N(R⁶)₂; OR⁶; Si(R⁶)₃; B(OR⁶)₂; OSO₂R⁶; CF₃; CN; F; Br; I;
C₁-C₄₀-alkyl,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₁-C₄₀-alkoxy,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₁-C₄₀-thioalkoxy,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₂-C₄₀-alkenyl,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₂-C₄₀-alkynyl,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₆-C₆₀-aryl,
which is optionally substituted with one or more substituents R⁶; and
C₃-C₅₇-heteroaryl,
which is optionally substituted with one or more substituents R⁶.

R⁶ is at each occurrence independently from each other selected from the group consisting of: hydrogen; deuterium; OPh; CF₃; CN; F;
C₁-C₅-alkyl,
wherein optionally one or more hydrogen atoms are independently from each other substituted by deuterium, CN, CF₃, or F;
C₁-C₅-alkoxy,
wherein optionally one or more hydrogen atoms are independently from each other substituted by deuterium, CN, CF₃, or F;
C₁-C₅-thioalkoxy,
wherein optionally one or more hydrogen atoms are independently from each other substituted by deuterium, CN, CF₃, or F;
C₂-C₅-alkenyl,
wherein optionally one or more hydrogen atoms are independently from each other substituted by deuterium, CN, CF₃, or F;
C₂-C₅-alkynyl,
wherein optionally one or more hydrogen atoms are independently from each other substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)(C₅-C₁₈-aryl);
N(C₃-C₁₇-heteroaryl)(C₃-C₁₇-heteroaryl); and
N(C₃-C₁₇-heteroaryl)(C₆-C₁₈-aryl).

According to the invention, two or more of the substituents R^{a} and/or R⁵ independently from each other optionally form a mono- or polycyclic, (hetero)aliphatic, (hetero)aromatic and/or benzo-fused ring system with one or more substituents R^{a} or R⁵.

R^{f} is at each occurrence independently from each other selected from the group consisting of: hydrogen; deuterium; N(R^{5f})₂; OR^{5f}; Si(R^{5f})₃; B(OR^{5f})₂; OSO₂R^{5f}; CF₃; CN; F; Br; I;
C₁-C₄₀-alkyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₁-C₄₀-alkoxy,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₁-C₄₀-thioalkoxy,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₂-C₄₀-alkenyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₂-C₄₀-alkynyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₆-C₆₀-aryl,
which is optionally substituted with one or more substituents R^{5f}; and
C₃-C₅₇-heteroaryl,
which is optionally substituted with one or more substituents R^{5f}.
R^{5f} is at each occurrence independently from each other selected from the group consisting of: hydrogen; deuterium; N(R^{6f})₂; OR^{6f}; Si(R^{6f})₃; B(OR^{6f})₂; OSO₂R^{6f}; CF₃; CN; F; Br; I;
C₁-C₄₀-alkyl,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₁-C₄₀-alkoxy,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₁-C₄₀-thioalkoxy,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₂-C₄₀-alkenyl,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₂-C₄₀-alkynyl,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₆-C₆₀-aryl,
which is optionally substituted with one or more substituents R^{6f}; and
C₃-C₅₇-heteroaryl,
which is optionally substituted with one or more substituents R^{6f}.

R^{6f} is at each occurrence independently from each other selected from the group consisting of: hydrogen; deuterium; OPh; CF₃; CN; F;
C₁-C₅-alkyl,
wherein optionally one or more hydrogen atoms are independently from each other substituted by deuterium, CN, CF₃, or F;
C₁-C₅-alkoxy,
wherein optionally one or more hydrogen atoms are independently from each other substituted by deuterium, CN, CF₃, or F;
C₁-C₅-thioalkoxy,
wherein optionally one or more hydrogen atoms are independently from each other substituted by deuterium, CN, CF₃, or F;
C₂-C₅-alkenyl,
wherein optionally one or more hydrogen atoms are independently from each other substituted by deuterium, CN, CF₃, or F;
C₂-C₅-alkynyl,
wherein optionally one or more hydrogen atoms are independently from each other substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)(C₆-C₁₈-aryl);
N(C₃-C₁₇-heteroaryl)(C₃-C₁₇-heteroaryl); and
N(C₃-C₁₇-heteroaryl)(C₆-C₁₈-aryl).

According to the invention, two or more of the substituents R^{f} and/or R^{5f} independently from each other optionally form a mono- or polycyclic, (hetero)aliphatic, (hetero)aromatic and/or benzo-fused ring system with one or more substituents R^{f} or R^{5f}.

According to the invention, the TADF moiety M^{TADF} contains exactly one binding site of the single band linking the TADF moiety M^{TADF} to the bridging unit L.

According to the invention, one selected from the group consisting of T, W, and Y represents the binding site of a single bond linking the first chemical moiety and the second chemical moiety.

In one embodiment of the invention, Acc¹ is selected from a structure according to one of Formulas A1 to A23:

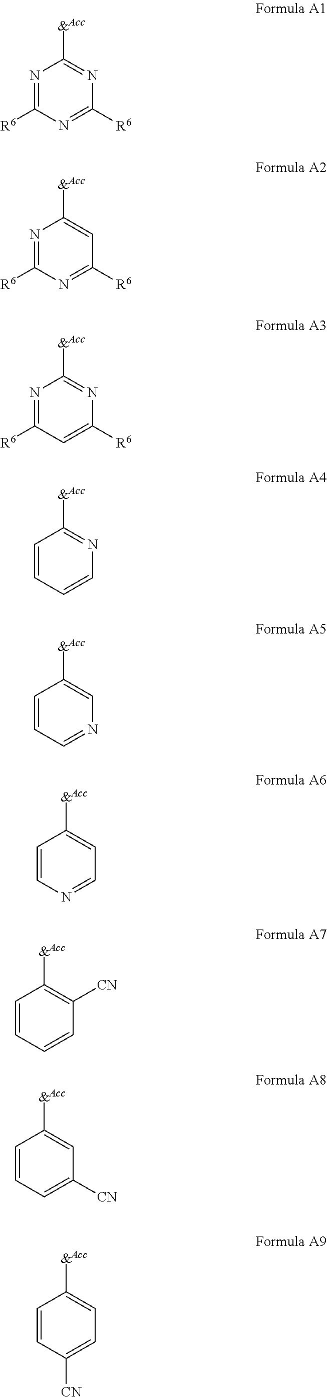

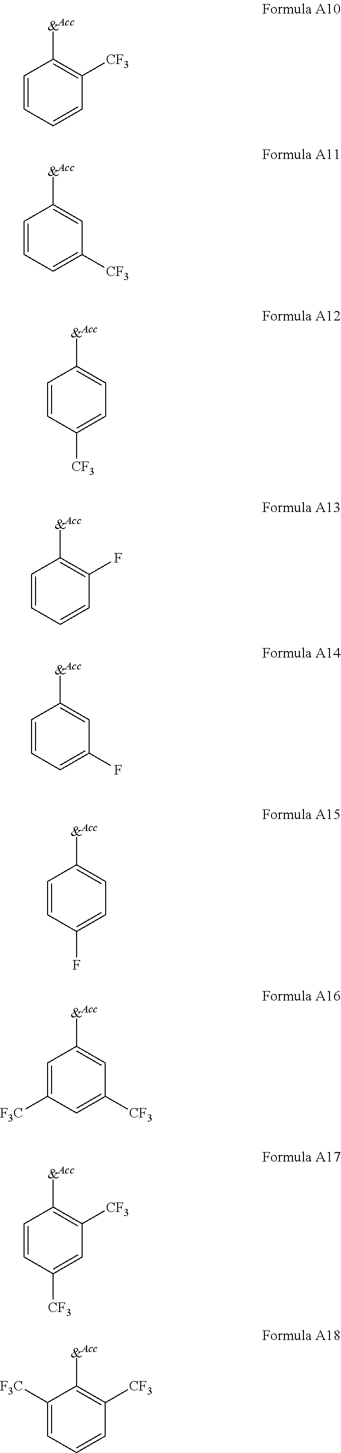

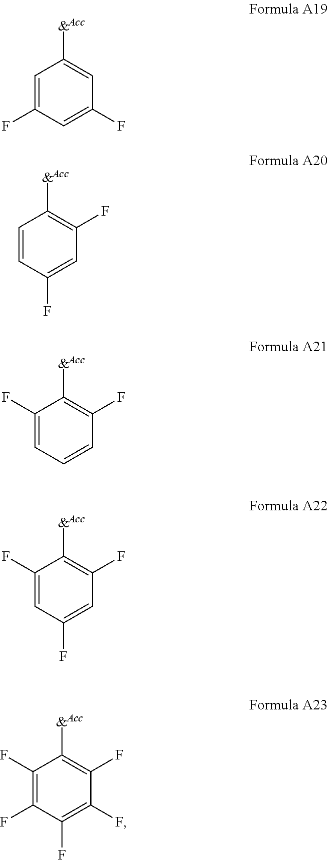

wherein &^{Acc} represents the binding site of a single bond linking Acc¹ to the first chemical moiety.

### First Chemical Moiety

In one embodiment, the first chemical moiety includes or consists of a structure of Formula Ia:

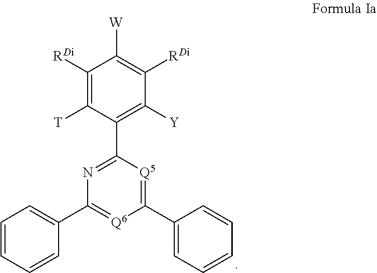

For R^{Di}, T, Wand Y, the aforementioned definitions apply.

Q⁵ is selected from the group consisting of N and C—H.

Q⁶ is selected from the group consisting of N and C—H.

According to this embodiment of the invention, at least one of Q⁵ or Q⁶ is N.

According to this embodiment of the invention, exactly one substituent selected from the group consisting of T and W represents the binding site of a single bond linking the first chemical moiety and the second chemical moiety.

In one embodiment, T represents the binding site of a single bond linking the first chemical moiety to the second chemical moiety.

In one embodiment, W represents the binding site of a single bond linking the first chemical moiety to the second chemical moiety.

### Formula LWo

In one embodiment, the first chemical moiety consists of a structure of Formula LWo:

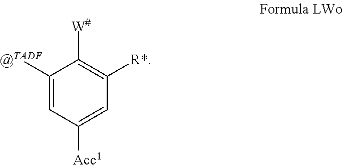

For Acc¹ the aforementioned definition applies.

R* is selected from the group consisting of H, D, Me, ⁱPr, ^{t}Bu, SiPh₃, CN, CF₃,
Ph, which is optionally substituted with one or more substituents independently from each other selected from the group consisting of Me, ⁱPr, ^{t}Bu, and Ph, and
a third chemical moiety consisting of a structure of Formula Q.

@^{TADF} represents the binding site of the single bond linking the TADF moiety M^{TADF} to the bridging unit L.

W^{#} represents the binding site of a single bond linking the first chemical moiety to the second chemical moiety.

In a further embodiment, the first chemical moiety consists of a structure of Formula LWo, and
R* represents a third chemical moiety consisting of a structure of Formula Q.

In a further embodiment, the first chemical moiety consists of a structure of Formula LWo, and
R* represents a third chemical moiety consisting of a structure according to one of Formulas B1 to B9:

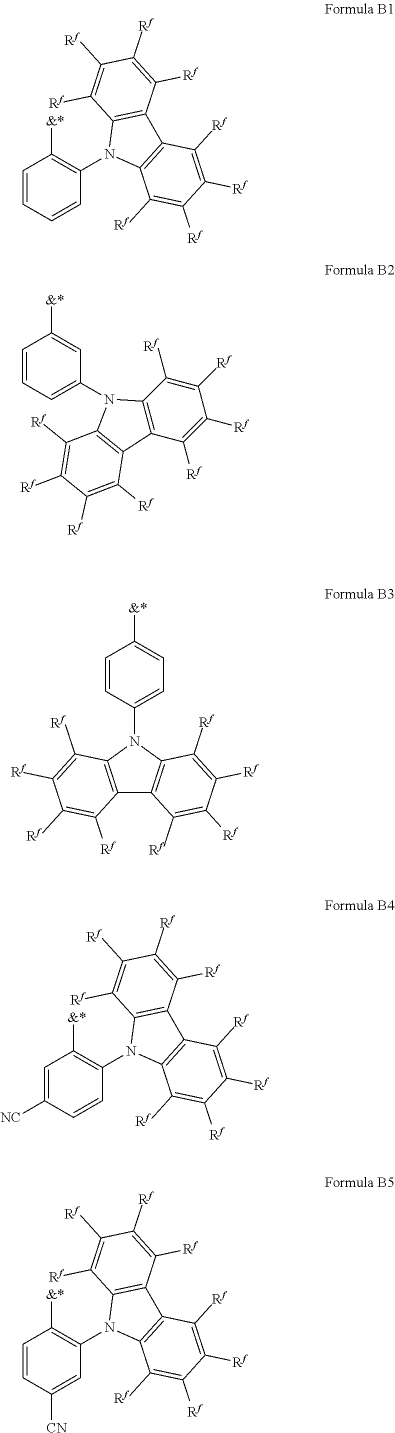

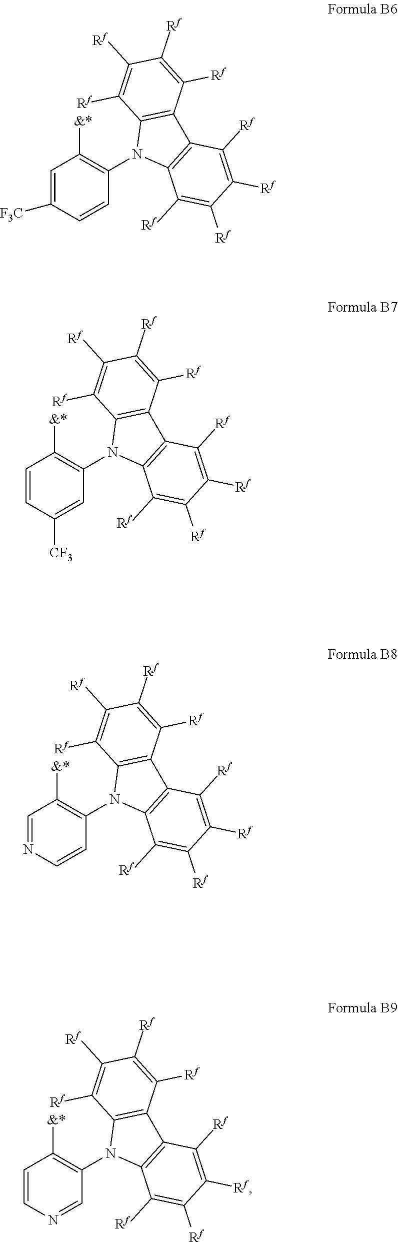

wherein &* represents the binding site of a single bond linking R* to the first chemical moiety and for R^{f} the aforementioned definition applies.

In a further embodiment, the first chemical moiety consists of a structure of Formula LWo, and
R* represents a third chemical moiety consisting of a structure according to one of Formulas A1* to A23*:

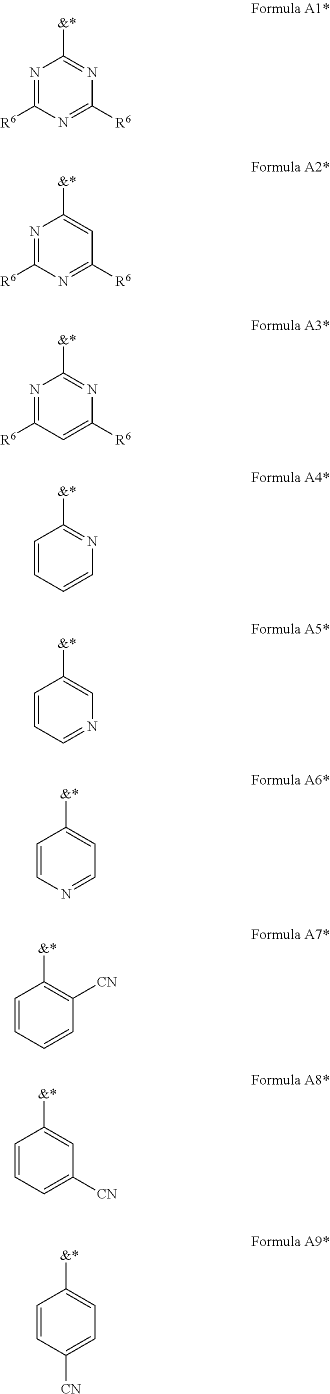

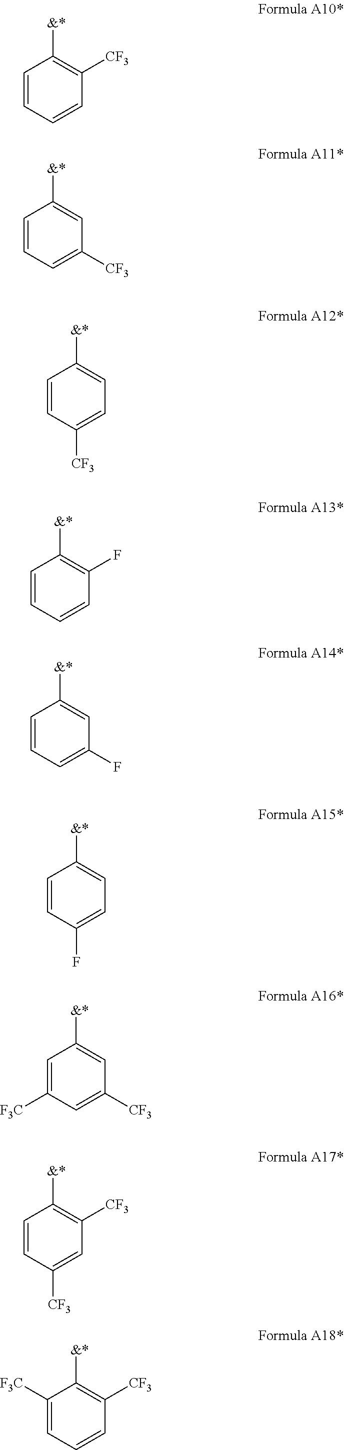

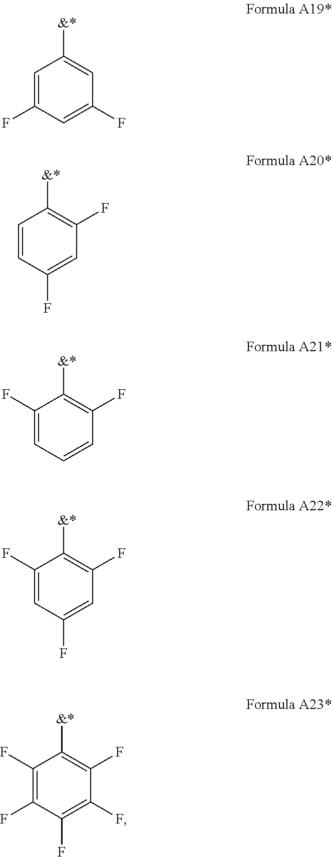

wherein &* represents the binding site of a single band linking R* to the first chemical moiety.

In one embodiment, the first chemical moiety consists of a structure of Formula LWo-I:

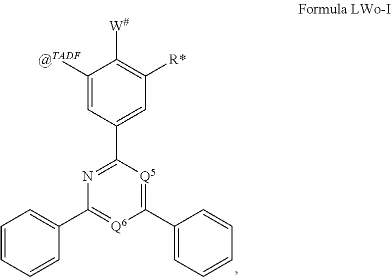

wherein for R*, @^{TADF}, W^{#}, Q⁵, and Q⁶ the aforementioned definitions apply and at least one of Q⁵ or Q⁶ is N.

In a further embodiment, the first chemical moiety consists of a structure of Formula LWo-I, and R* represents a third chemical moiety consisting of a structure according to one of Formulas B1 to B9.

In a further embodiment, the first chemical moiety consists of a structure of Formula LWo-I, and
R* represents a third chemical moiety consisting of a structure according to one of Formulas A1* to A23*:

### Formula WoL

In one embodiment, the first chemical moiety consists of a structure of Formula WoL:

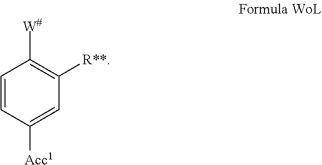

For Acc¹ the aforementioned definition applies.

R** represents a third chemical moiety consisting of a structure of Formula Q.

@^{TADF} represents the binding site of the single bond linking the TADF moiety M^{TADF} to the bridging unit L.

W^{#} represents the binding site of a single bond linking the first chemical moiety to the second chemical moiety.

In a further embodiment, the first chemical moiety consists of a structure of Formula WoL, and
R** represents a third chemical moiety consisting of a structure according to one of Formulas B1* to B9*:

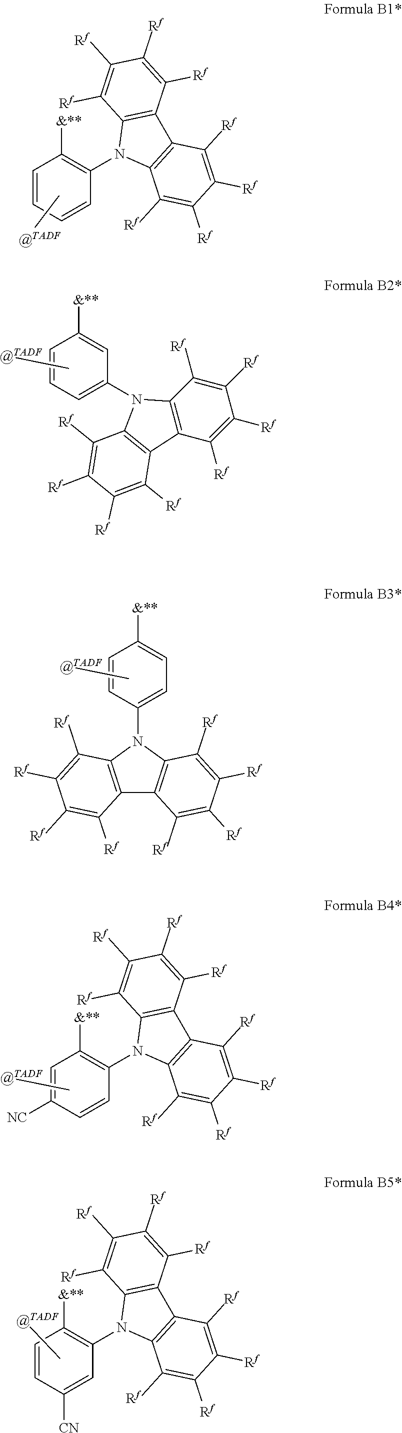

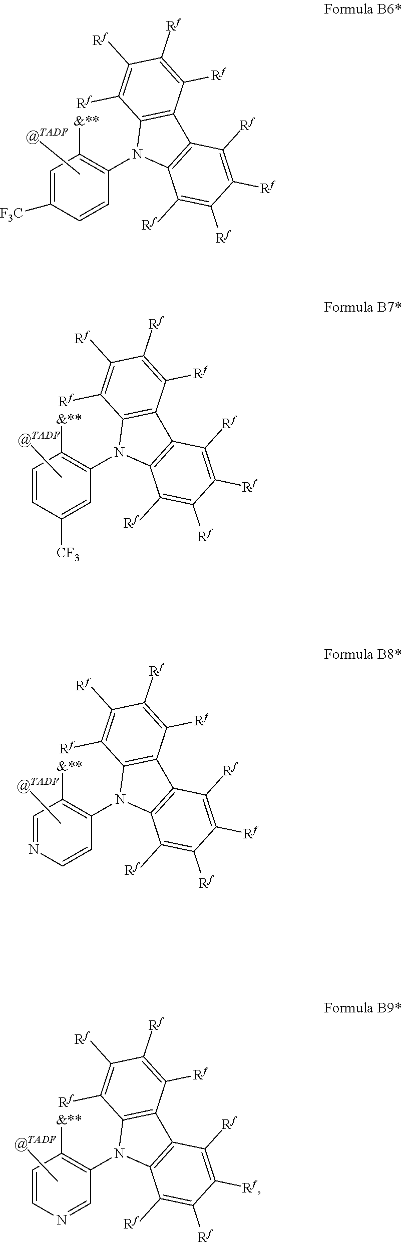

wherein &** represents the binding site of a single band linking R** to the first chemical moiety;
@^{TADF} represents the binding site of the single band linking the TADF moiety M^{TADF} to the bridging unit L; and
for R^{f} the aforementioned definition applies.

In one embodiment, the first chemical moiety consists of a structure of Formula WoL-I:

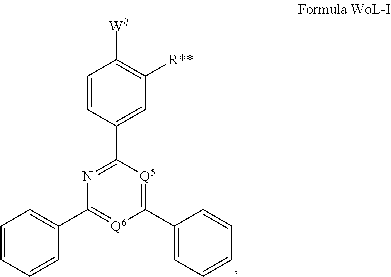

wherein for R**, @^{TADF}, W^{#}, Q⁵, and Q⁶ the aforementioned definitions apply and at least one of Q⁵ or Q⁶ is N.

In a further embodiment, the first chemical moiety consists of a structure of Formula WoL-I, and R** represents a third chemical moiety consisting of a structure according to one of Formulas B1* to B9*.

### Formula LTp

In one embodiment, the first chemical moiety consists of a structure of Formula LTp:

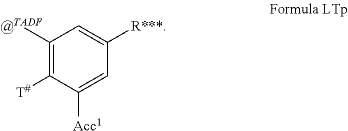

For Acc¹ the aforementioned definition applies.

R*** is selected from the group consisting of H, D, Me, ⁱPr, ^{t}Bu, SiPh₃, CN, CF₃,
Ph, which is optionally substituted with one or more substituents independently from each other selected from the group consisting of Me, ⁱPr, ^{t}Bu, and Ph, and
a third chemical moiety consisting of a structure of Formula Q.

@^{TADF} represents the binding site of the single bond linking the TADF moiety M^{TADF} to the bridging unit L.

T^{#} represents the binding site of a single bond linking the first chemical moiety to the second chemical moiety.

In a further embodiment, the first chemical moiety consists of a structure of Formula LTp, and
R*** represents a third chemical moiety consisting of a structure of Formula Q.

In a further embodiment, the first chemical moiety consists of a structure of Formula LTp, and
R*** represents a third chemical moiety consisting of a structure according to one of Formulas B1** to B9**:

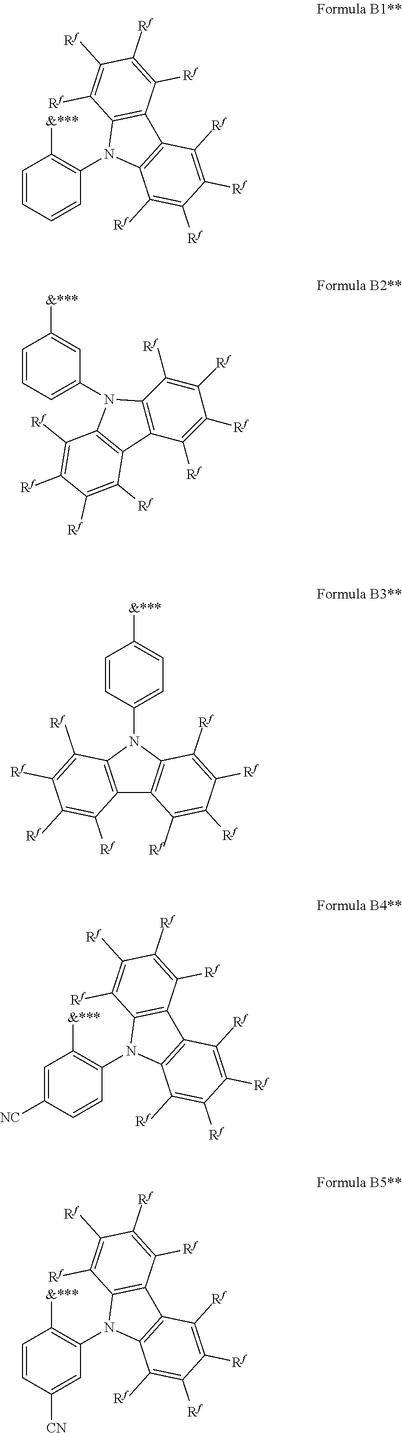

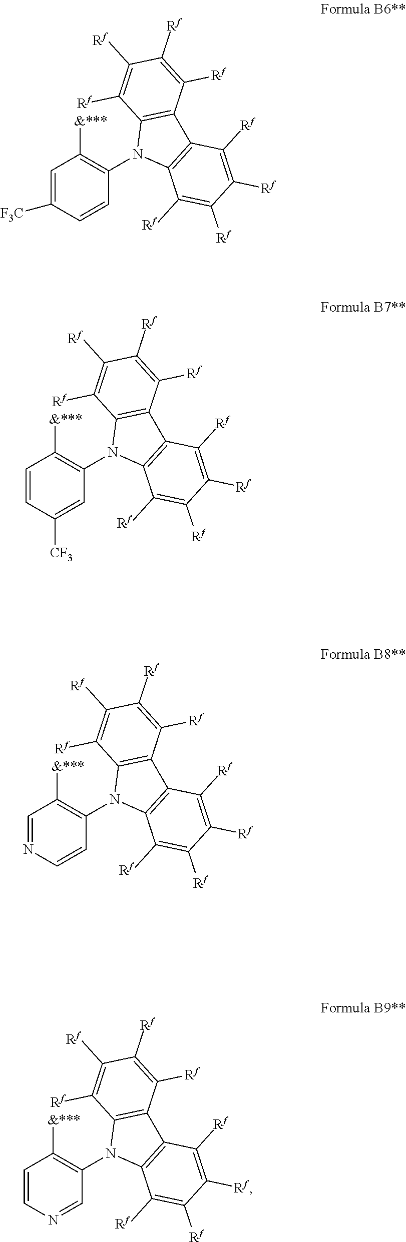

wherein &*** represents the binding site of a single bond linking R*** to the first chemical moiety and for R^{f} the aforementioned definition applies.

In a further embodiment, the first chemical moiety consists of a structure of Formula LTp, and
R*** represents a third chemical moiety consisting of a structure according to one of Formulas A1** to A23**:

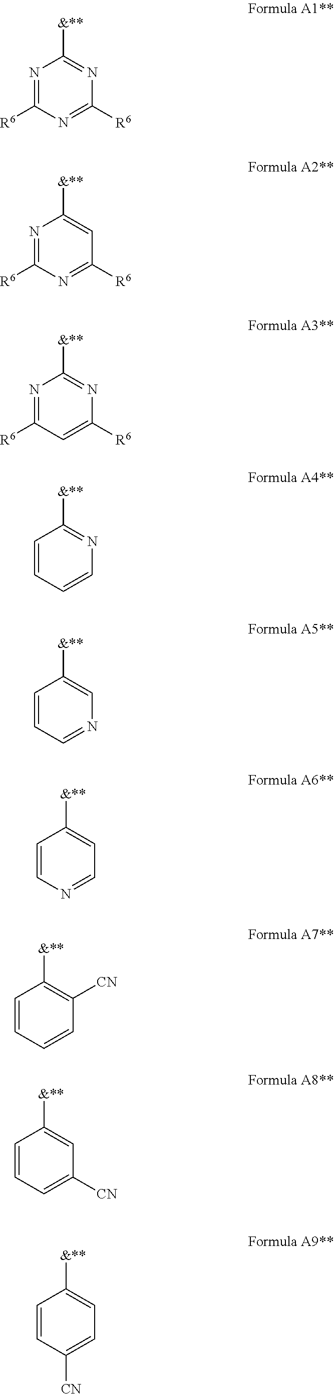

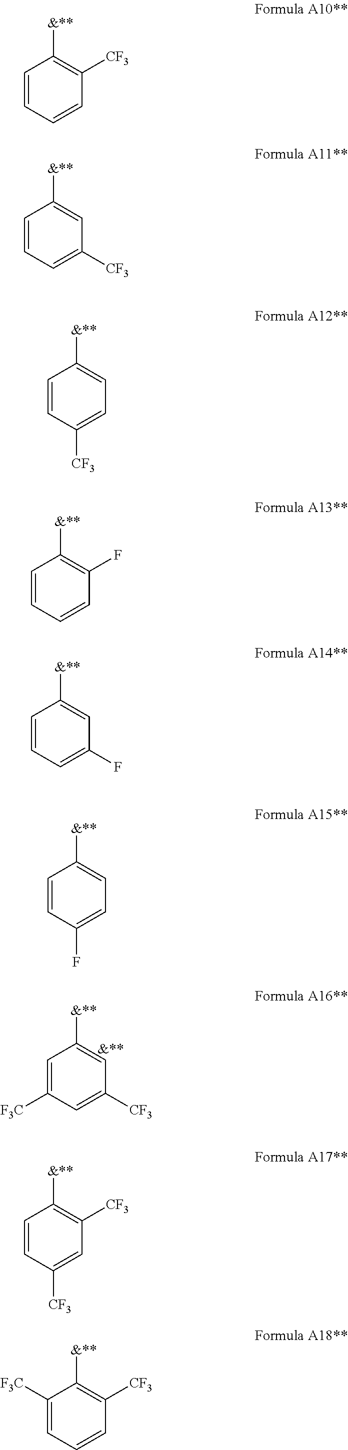

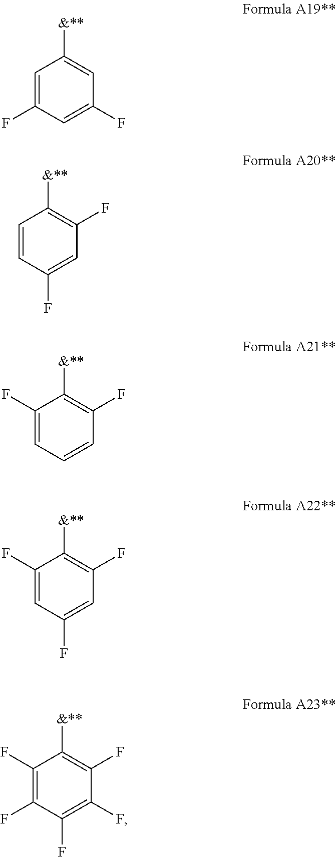

wherein &** represents the binding site of a single band linking R*** to the first chemical moiety.

In one embodiment, the first chemical moiety consists of a structure of Formula LTp-I,

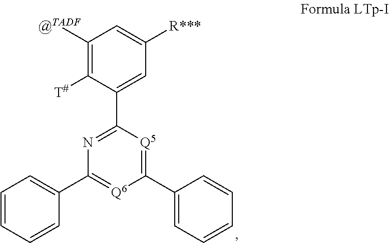

wherein for R**, @^{TADF}, T^{#}, Q⁵, and Q⁶ the aforementioned definitions apply and at least one of Q⁵ or Q⁶ is N.

In a further embodiment, the first chemical moiety consists of a structure of Formula LTp-I, and R*** represents a third chemical moiety consisting of a structure according to one of Formulas B1** to B9**:

In a further embodiment, the first chemical moiety consists of a structure of Formula LTp-I, and
R*** represents a third chemical moiety consisting of a structure according to one of Formulas A1** to A23**.

### Formula TpL

In one embodiment, the first chemical moiety consists of a structure of Formula TpL:

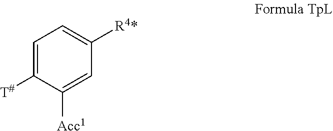

For Acc¹ the aforementioned definition applies.

R⁴* represents a third chemical moiety consisting of a structure of Formula Q.

@^{TADF} represents the binding site of the single bond linking the TADF moiety M^{TADF} to the bridging unit L.

T^{#} represents the binding site of a single bond linking the first chemical moiety to the second chemical moiety.

In a further embodiment, the first chemical moiety consists of a structure of Formula TpL, and
R⁴* represents a third chemical moiety consisting of a structure according to one of Formulas B1⁴* to B9⁴*:

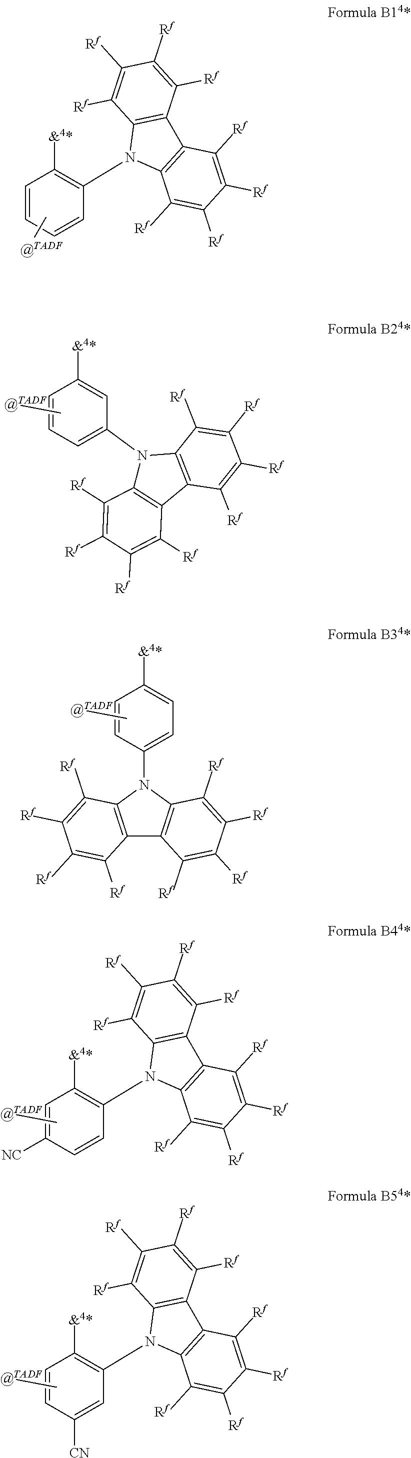

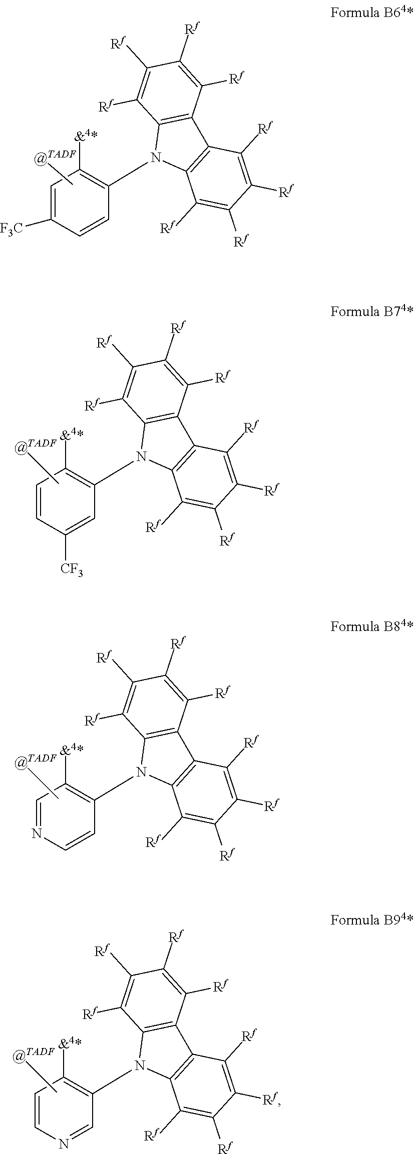

wherein &4* represents the binding site of a single bond linking R⁴* to the first chemical moiety
@TADF represents the binding site of the single bond linking the TADF moiety M^{TADF} to the bridging unit L, and
for R^{f} the aforementioned definition applies.

In one embodiment, the first chemical moiety consists of a structure of Formula TpL-I:

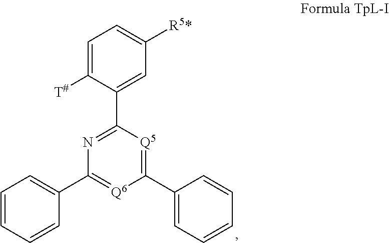

wherein for R=⁵*, @^{TADF}, T^{#}, Q⁵, and Q⁶ the aforementioned definitions apply and at least one of Q⁵ or Q⁶ is N.

In a further embodiment, the first chemical moiety consists of a structure of Formula TpL-I, and R⁵* represents a third chemical moiety consisting of a structure according to one of Formulas B1⁴* to B9⁴*.

### Formula LoT

In one embodiment, the first chemical moiety consists of a structure of Formula LoT:

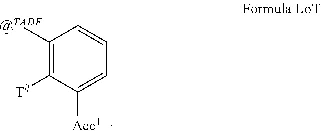

For Acc¹, @^{TADF}, and T^{#} the aforementioned definitions apply.

In one embodiment, the first chemical moiety consists of a structure of Formula LoT-I:

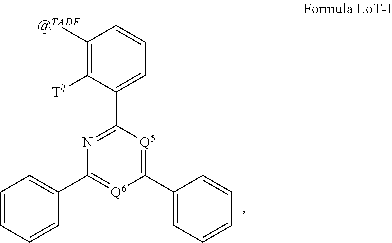

Wherein for @^{TADF}, T^{#}, Q⁵, and Q⁶ the aforementioned definitions apply and at least one of Q⁵ or Q⁶ is N.

### Formula LmT

In one embodiment, the first chemical moiety consists of a structure of Formula LmT:

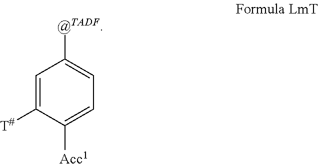

For Acc¹, @^{TADF}, and T^{#} the aforementioned definitions apply.

In one embodiment, the first chemical moiety consists of a structure of Formula LmT-I:

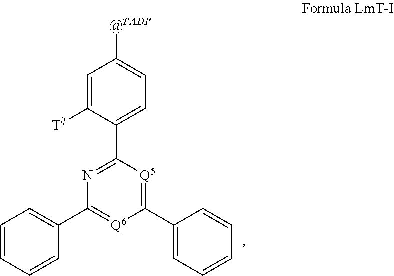

wherein for @^{TADF}, T^{#}, Q⁵, and Q⁶ the aforementioned definitions apply and at least one of Q⁵ or Q⁶ is N.

### Formula LpT

In one embodiment, the first chemical moiety consists of a structure of Formula LpT:

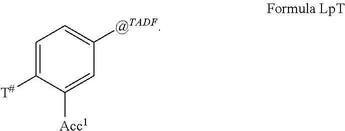

For Acc¹, @^{TADF}, and T^{#} the aforementioned definitions apply.

In one embodiment, the first chemical moiety consists of a structure of Formula LpT-I:

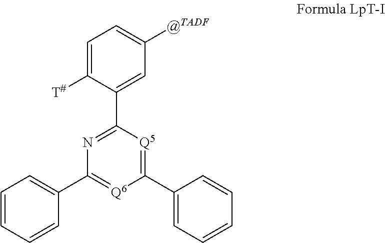

wherein for @^{TADF}, T^{#}, Q⁵, and Q⁶ the aforementioned definitions apply and at least one of Q⁵ or Q⁶ is N.

### Formula TmL

In one embodiment, the first chemical moiety consists of a structure of Formula TmL:

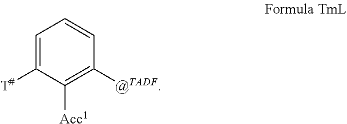

For Acc¹, @^{TADF}, and T^{#} the aforementioned definitions apply.

In one embodiment, the first chemical moiety consists of a structure of Formula TmL-I:

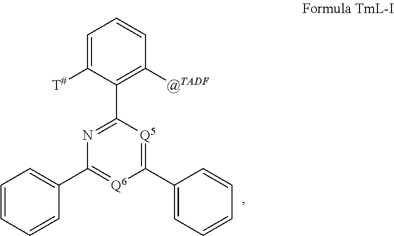

wherein for @^{TADF}, T^{#}, Q⁵, and Q⁶ the aforementioned definitions apply and at least one of Q⁵ or Q⁶ is N.

### Formula WoT

In one embodiment, the first chemical moiety consists of a structure of Formula WoT:

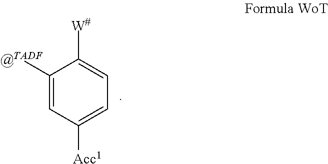

For Acc¹, @^{TADF}, and W^{#} the aforementioned definitions apply.

In one embodiment, the first chemical moiety consists of a structure of Formula WoT-I:

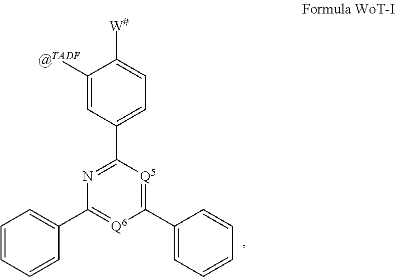

wherein for @^{TADF}, W^{#}, Q⁵, and Q⁶ the aforementioned definitions apply and at least one of Q⁵ or Q⁶ is N.

### Formula WmL

In one embodiment, the first chemical moiety consists of a structure of Formula WmL:

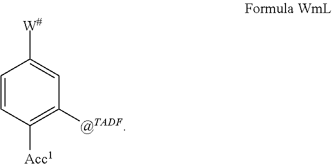

For Acc¹, @^{TADF}, and W^{#} the aforementioned definitions apply.

In one embodiment, the first chemical moiety consists of a structure of Formula VML-I:

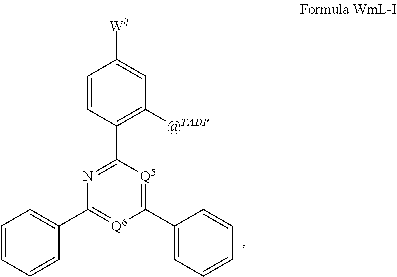

wherein for @^{TADF}, W^{#}, Q⁵, and Q⁶ the aforementioned definitions apply and at least one of Q⁵ or Q⁶ is N.

In one embodiment, the first chemical moiety consists of a structure of Formula Iaa:

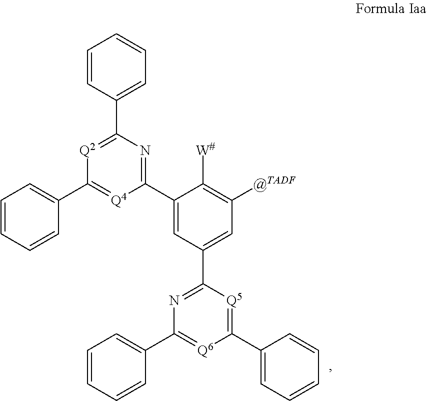

wherein for @^{TADF}, W^{#}, Q² and Q⁴, Q⁵ and Q⁶ the aforementioned definitions apply, at least one of Q² or Q⁴ is N and at least one of Q⁵ or Q⁶ is N.

In a preferred embodiment both of Q² and Q⁴ are N, thereby forming a triazine moiety. In a preferred embodiment both of Q⁵ and Q⁶ are N, thereby forming a triazine moiety. In a preferred embodiment all of Q² and Q⁴, and as far as present, Q¹, Q⁵ and/or Q⁴, are each N, thereby forming one or two or more triazine moieties.

In one embodiment, the first chemical moiety consists of a structure of Formula Iab:

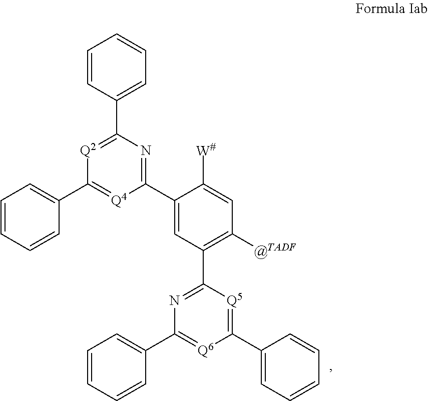

wherein for @^{TADF}, W^{#}, Q² and Q⁴, Q⁵ and Q⁶ the aforementioned definitions apply, at least one of Q² or Q⁴ is N and at least one of Q⁵ or Q⁶ is N.

### Second Chemical Moiety

In a further embodiment of the invention, the second chemical moiety includes or consists of a structure of Formula IIb:

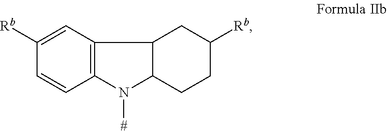

wherein
R^{b} is at each occurrence independently from each other selected from the group consisting of: a binding site of the single bond linking the TADF moiety M^{TADF} to the bridging unit L; hydrogen; deuterium; N(R⁵)₂; OR⁵; Si(R⁵)₃; B(OR⁵)₂; OSO₂R⁵; CF₃; CN; F; Br; I;
C₁-C₄₀-alkyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₃-C₅₇-heteroaryl,
which is optionally substituted with one or more substituents R⁵; and
wherein apart from the aforementioned definitions apply.

In a further embodiment of the invention the second chemical moiety includes or consists of a structure of formula IIc:

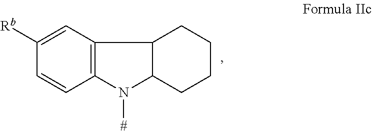

wherein
R^{b} is selected from the group consisting of: a binding site of the single bond linking the TADF moiety M^{TADF} to the bridging unit L; hydrogen; deuterium; N(R⁵)₂; OR⁵; Si(R⁵)₃; B(OR⁵)₂; OSO₂R⁵; CF₃; CN; F; Br; I;
C₁-C₄₀-alkyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₃-C₅₇-heteroaryl,
which is optionally substituted with one or more substituents R⁵; and
wherein apart from that the aforementioned definitions apply.

In one embodiment of the invention, R^{b} is at each occurrence independently from each other selected from the group consisting of:
a binding site of the single bond linking the TADF moiety M^{TADF} to the bridging unit L;
hydrogen;
deuterium;
Me, ⁱPr, ^{t}Bu, CN, CF₃;
Ph, which is optionally substituted with one or more substituents independently from each other selected from the group consisting of Me, ⁱPr, ^{t}Bu, CN, CF₃, and Ph;
pyridinyl, which is optionally substituted with one or more substituents independently from each other selected from the group consisting of Me, ⁱPr, ^{t}Bu, CN, CF₃, and Ph;
pyrimidinyl, which is optionally substituted with one or more substituents independently from each other selected from the group consisting of Me, ⁱPr, ^{t}Bu, CN, CF₃, and Ph;
carbazolyl, which is optionally substituted with one or more substituents independently from each other selected from the group consisting of Me, ⁱPr, ^{t}Bu, CN, CF₃, and Ph;
triazinyl, which is optionally substituted with one or more substituents independently from each other selected from the group consisting of Me, ⁱPr, ^{t}Bu, CN, CF₃, and Ph;

and
N(Ph)₂.

In one embodiment, the fourth chemical moiety consisting of a structure of Formula IIQ is identical to the one or two second chemical moieties including or consisting of a structure of Formula II.

In one embodiment, the fourth chemical moiety consisting of a structure of Formula IIQ is different to the one or two second chemical moieties including or consisting of a structure of Formula II.

In a further embodiment of the invention, R^{a} is at each occurrence independently from each other selected from the group consisting of
the binding site of the single bond linking the TADF moiety M^{TADF} to the bridging unit L,
hydrogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In a further embodiment of the invention, R^{a} is at each occurrence independently from each other selected from the group consisting of the binding site of the single bond linking the TADF moiety M^{TADF} to the bridging unit L, hydrogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph, and
triazinyl, which is optionally substituted with one or more substituents independently from each other selected from the group consisting of Me, ⁱPr, ^{t}Bu, CN, CF₃, and Ph.

In a further embodiment of the invention, the second chemical moiety consists of a structure of Formula IIb, a structure of Formula IIb-2, a structure of Formula IIb-3, or a structure of Formula IIb-4:

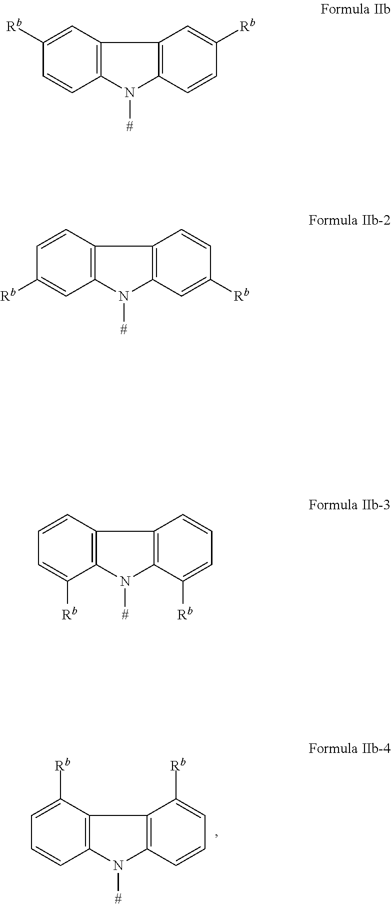

wherein
R^{b} is at each occurrence independently from each other selected from the group consisting of: a binding site of the single bond linking the TADF moiety M^{TADF} to the bridging unit L;
hydrogen; deuterium; N(R⁵)₂; OR⁵; Si(R⁵)₃; B(OR⁵)₂; OSO₂R⁵; CF₃; CN; F; Br; I;
C₁-C₄₀-alkyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₃-C₅₇-heteroaryl,
which is optionally substituted with one or more substituents R⁵.

For additional variables, the aforementioned definitions apply.

In one additional embodiment of the invention, the second chemical moiety consists of a structure of Formula IIc, a structure of Formula IIc-2, a structure of Formula IIc-3, or a structure of Formula IIc-4:

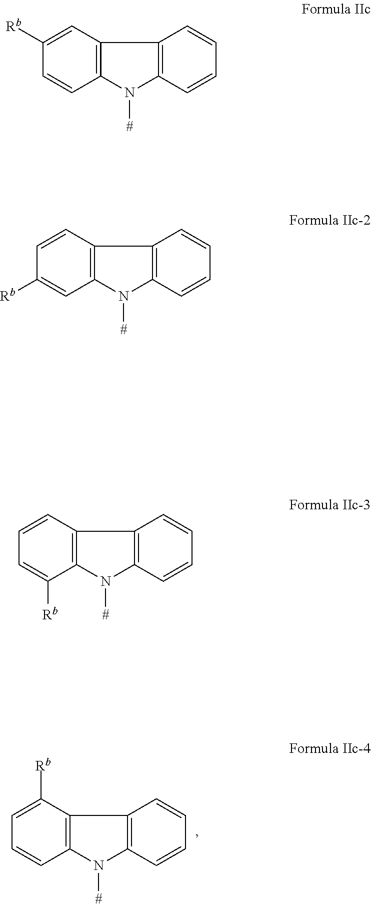

wherein the aforementioned definitions apply.

In a further embodiment of the invention, R^{b} is selected from the group consisting of
a binding site of the single bond linking the TADF moiety M^{TADF} to the bridging unit L,
Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In a further embodiment of the invention, R^{b} is at each occurrence independently from each other selected from the group consisting of
a binding site of the single bond linking the TADF moiety M^{TADF} to the bridging unit L,
Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph, and
triazinyl, which is optionally substituted with one or more substituents independently from each other selected from the group consisting of Me, ⁱPr, ^{t}Bu, CN, CF₃, and Ph.

In the following, examples of the second chemical moiety are shown:

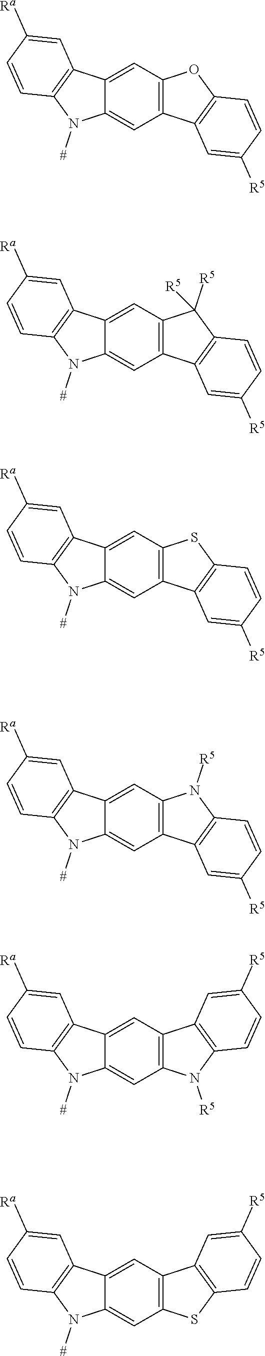

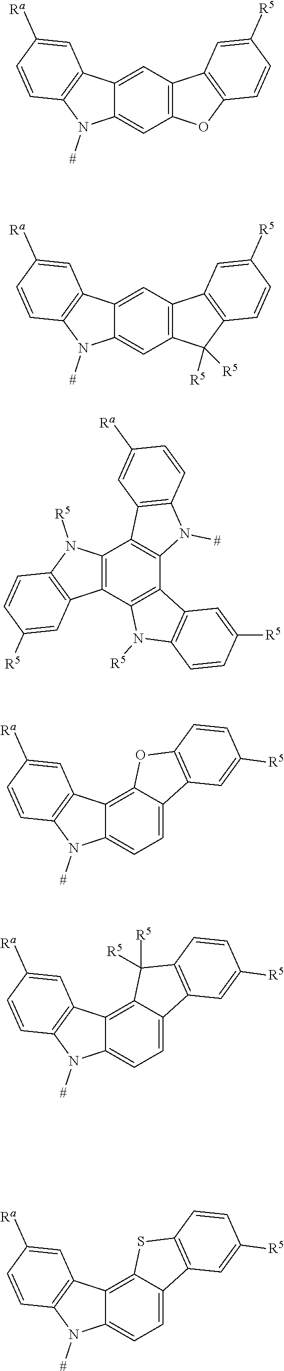

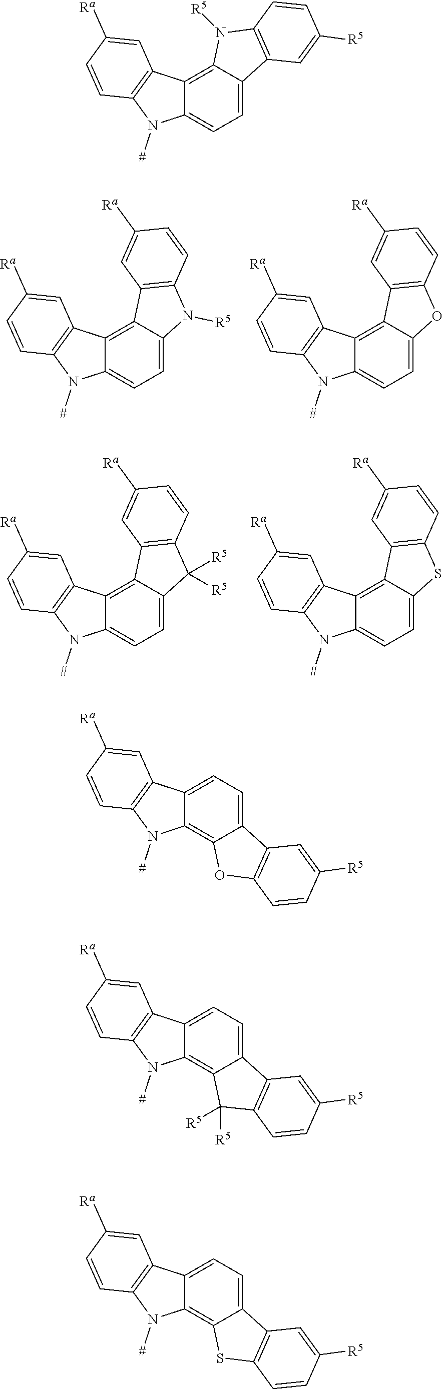

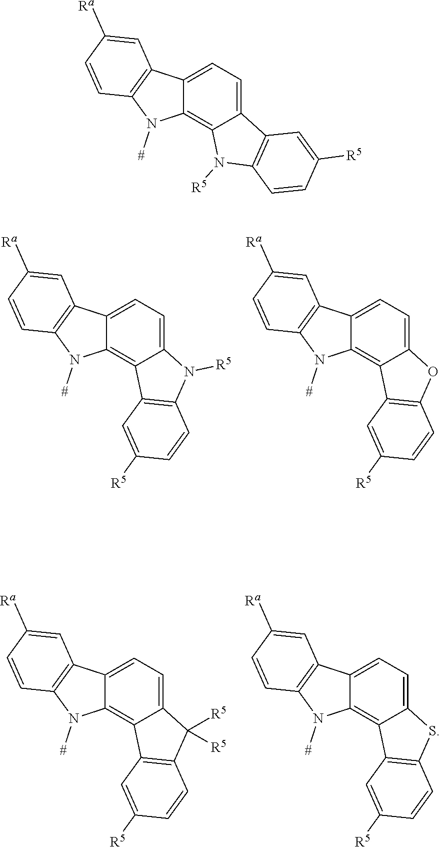

For each of the above-given second chemical moieties, the aforementioned definitions apply for #, Z, R^{a}, and R⁵.

In one embodiment, R^{a} and R⁵ are at each occurrence independently from each other selected from the group consisting of hydrogen (H), methyl (Me), i-propyl (CH(CH₃)₂) (ⁱPr), t-butyl (^{t}Bu), phenyl (Ph),
triazinyl, which is optionally substituted with one or more substituents independently from each other selected from the group consisting of Me, ⁱPr, ^{t}Bu, CN, CF₃, and Ph, and
diphenylamine (NPh₂).

### Fourth Chemical Moiety

In a further embodiment of the invention, the fourth chemical moiety includes or consists of a structure of Formula IIq:

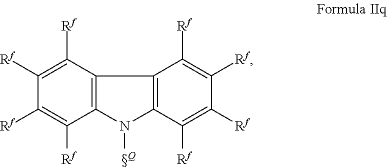

wherein §^{Q} and R^{f} are defined as above.

In a further embodiment of the invention, R^{f} is at each occurrence independently from each other selected from the group consisting of
hydrogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In a further embodiment of the invention, R^{f} is at each occurrence independently from each other selected from the group consisting of
hydrogen, Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph, and
triazinyl, which is optionally substituted with one or more substituents independently from each other selected from the group consisting of Me, ⁱPr, ^{t}Bu, CN, CF₃, and Ph.

In a further embodiment of the invention, the fourth chemical moiety consists of a structure of Formula IIbq, a structure of Formula IIbq-2, a structure of Formula IIbq-3, or a structure of Formula IIbq-4:

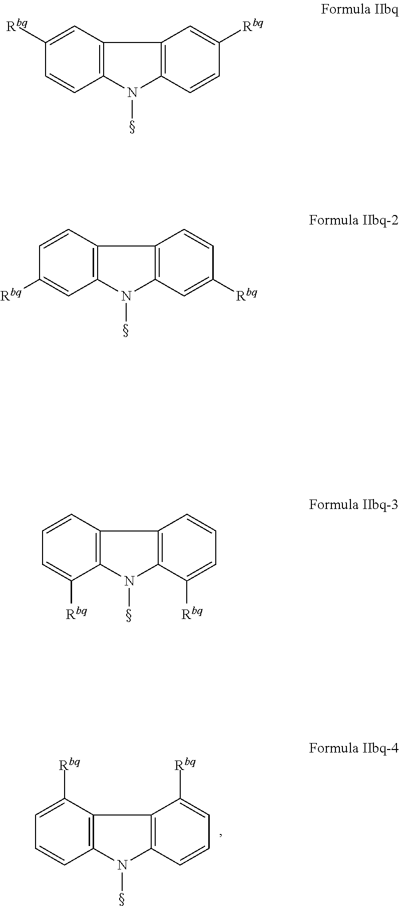

wherein
R^{bq} is at each occurrence independently from each other selected from the group consisting of:
hydrogen; deuterium; N(R^{5f})₂; OR^{5f}; Si(R^{5f})₃; B(OR^{5f})₂; OSO₂R^{5f}; CF₃; CN; F; Br; I;
C₁-C₄₀-alkyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₁-C₄₀-alkoxy,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₁-C₄₀-thioalkoxy,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₂-C₄₀-alkenyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₂-C₄₀-alkynyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₆-C₆₀-aryl,
which is optionally substituted with one or more substituents R^{5f}; and
C₃-C₅₇-heteroaryl,
which is optionally substituted with one or more substituents R^{5f}.

For additional variables, the aforementioned definitions apply.

In one additional embodiment of the invention, the fourth chemical moiety consists of a structure of Formula IIcq, a structure of Formula IIcq-2, a structure of Formula IIcq-3, or a structure of Formula IIcq-4:

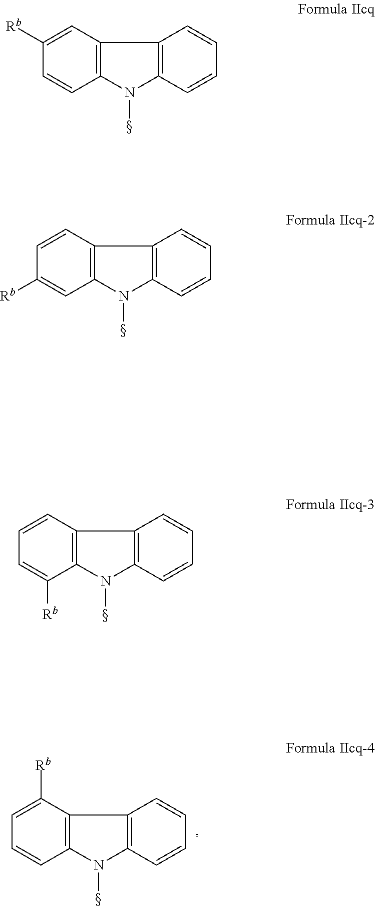

wherein the aforementioned definitions apply.

In a further embodiment of the invention, R^{bq} is at each occurrence independently from each other selected from the group consisting of Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂.

In a further embodiment of the invention, R^{bq} is at each occurrence independently from each other selected from the group consisting of
Me, ⁱPr, ^{t}Bu, CN, CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph, and
triazinyl, which is optionally substituted with one or more substituents independently from each other selected from the group consisting of Me, ⁱPr, ^{t}Bu, CN, CF₃, and Ph.

In one embodiment of the invention, R^{bq} is at each occurrence independently from each other selected from the group consisting of:
Me, ⁱPr, ^{t}Bu, Ph, which is optionally substituted with one or more substituents independently from each other selected from the group consisting of Me, ⁱPr, ^{t}Bu, CN, CFs, and Ph; and
triazinyl, which is optionally substituted with one or more substituents independently from each other selected from the group consisting of Me, ⁱPr, ^{t}Bu, CN, CFs, and Ph.

In the following, exemplary embodiments of the fourth chemical moiety are shown:

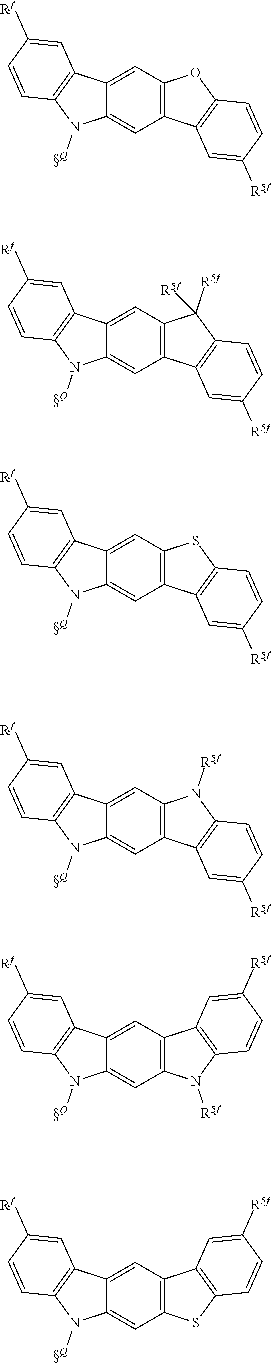

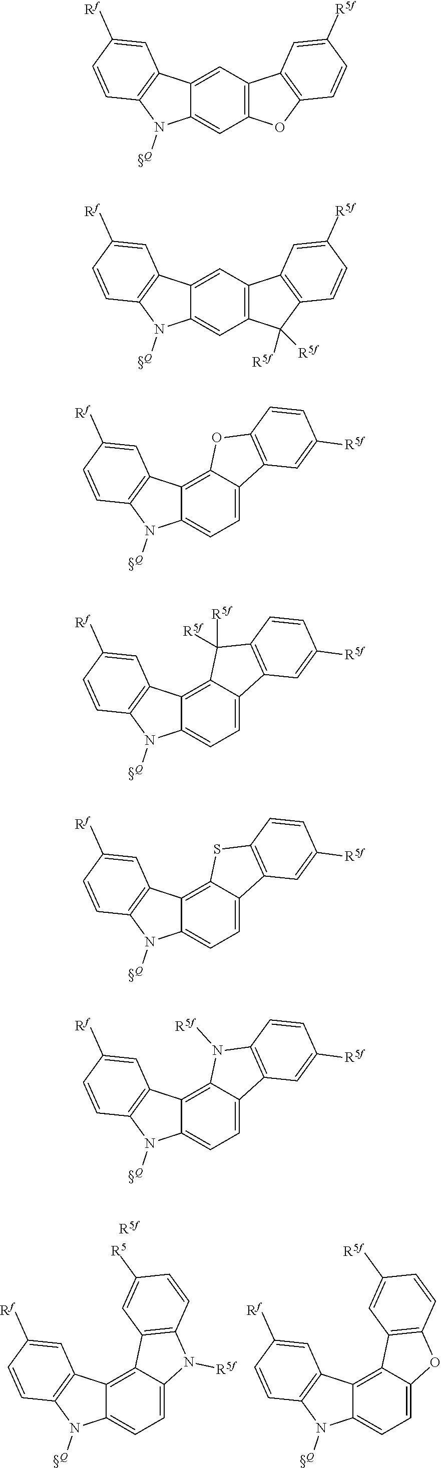

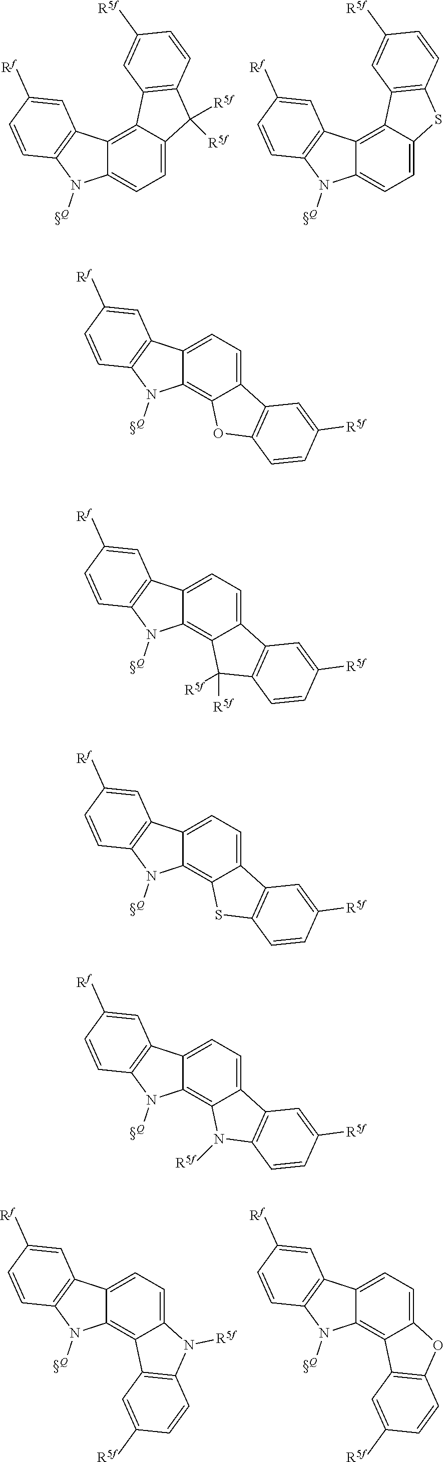

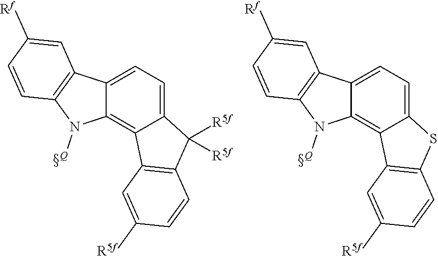

For $^{Q}, Z^{$}, R^{f}, and R^{5f} of the fourth chemical moiety shown above, the aforementioned definitions apply.

In one embodiment, R^{f} and R^{5f} is at each occurrence independently from each other selected from the group consisting of hydrogen (H), methyl (Me), i-propyl (CH(CH₃)₂) (ⁱPr), t-butyl (^{t}Bu), phenyl (Ph),
triazinyl, which is optionally substituted with one or more substituents independently from each other selected from the group consisting of Me, ⁱPr, ^{t}Bu, CN, CF₃, and Ph, and
diphenylamine (NPh₂).

### Examples of the TADF Moiety M^{TADF}

In a preferred embodiment, M^{TADF} is selected from one of the structures according to one of Formulas M^{TADF}-1 to M^{TADF}-48:

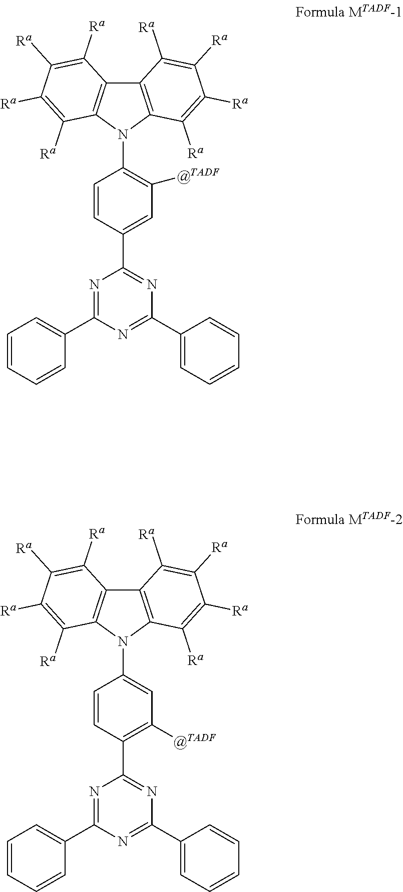

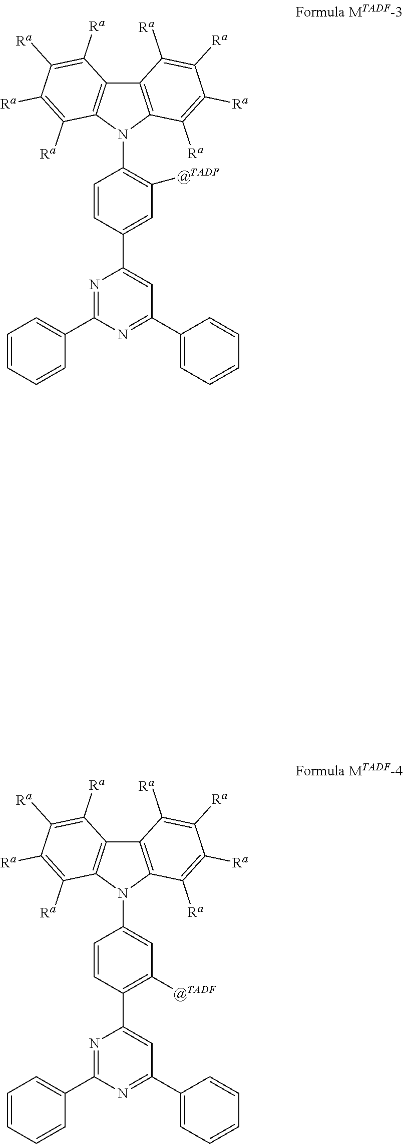

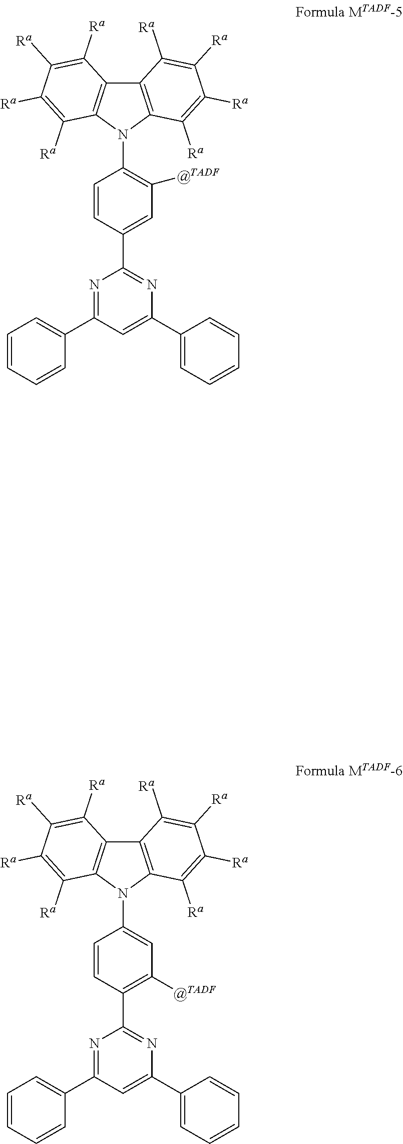

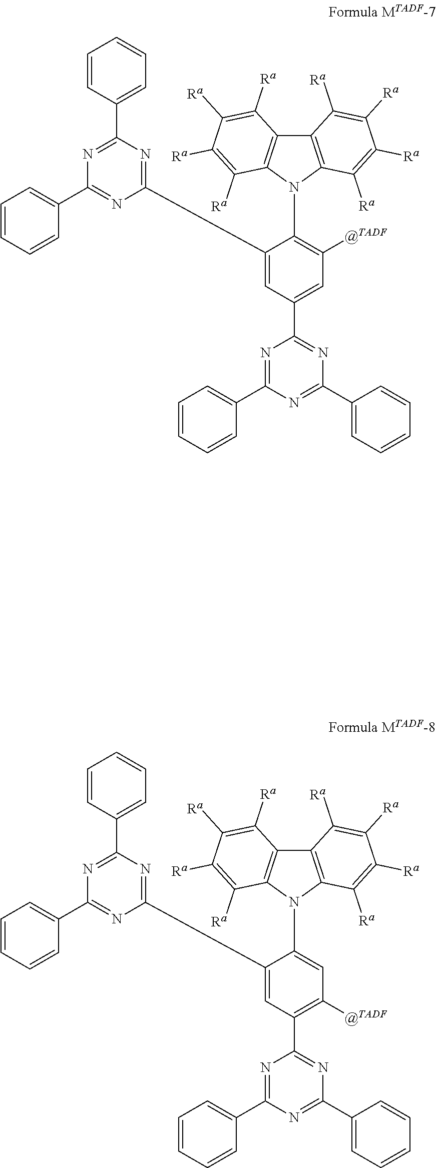

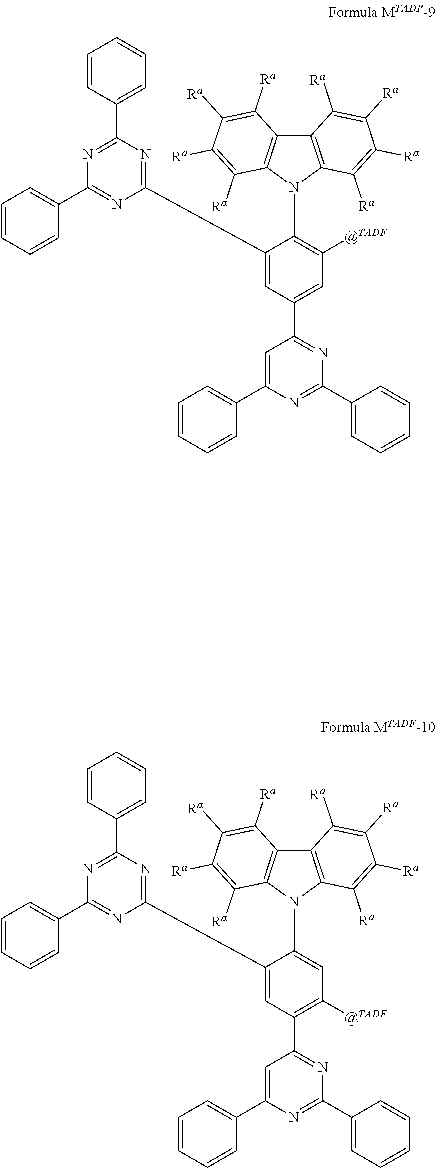

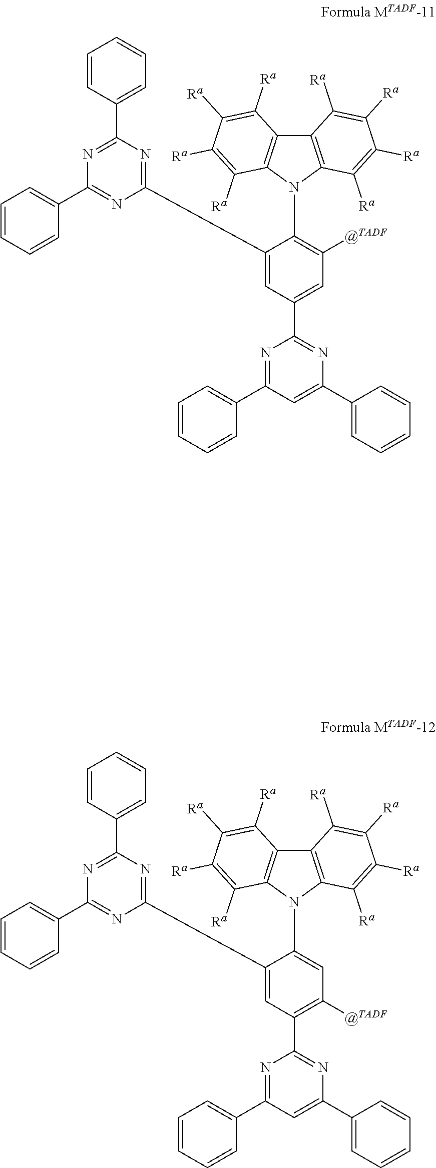

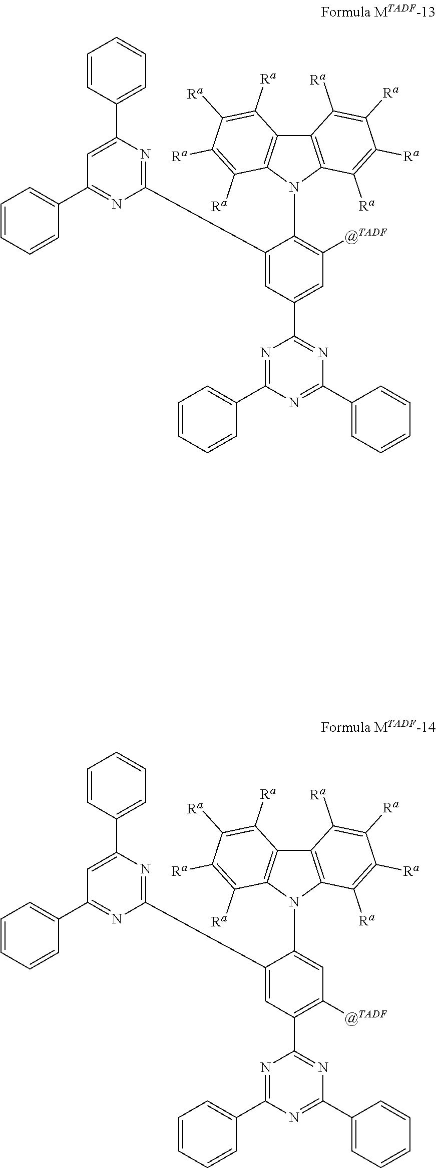

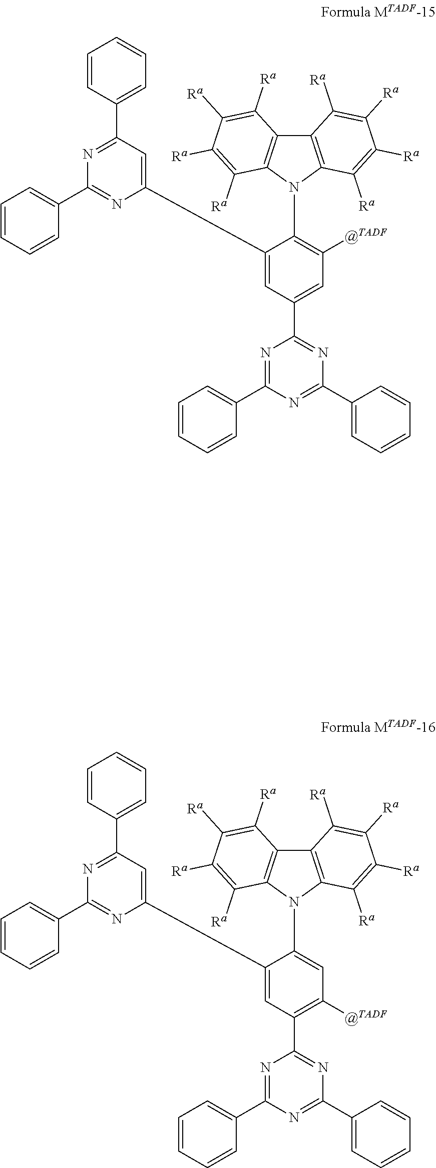

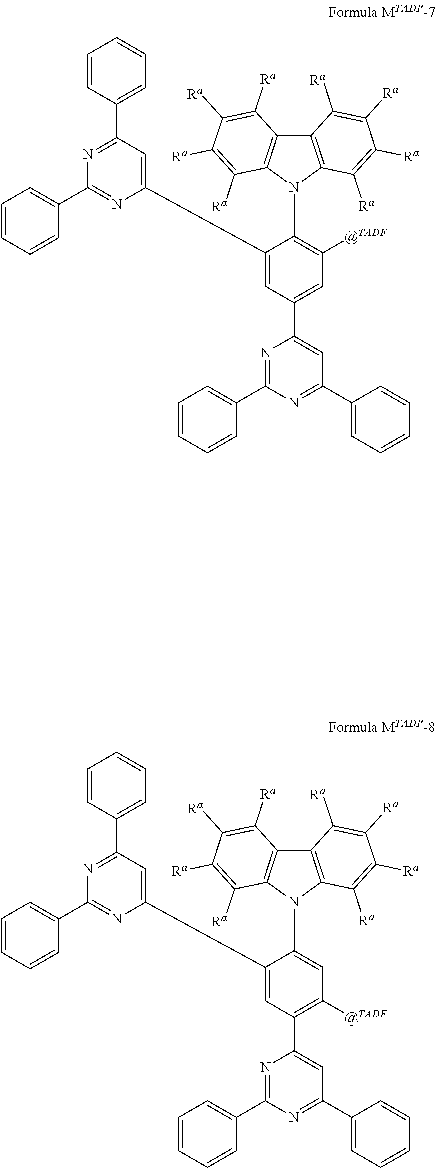

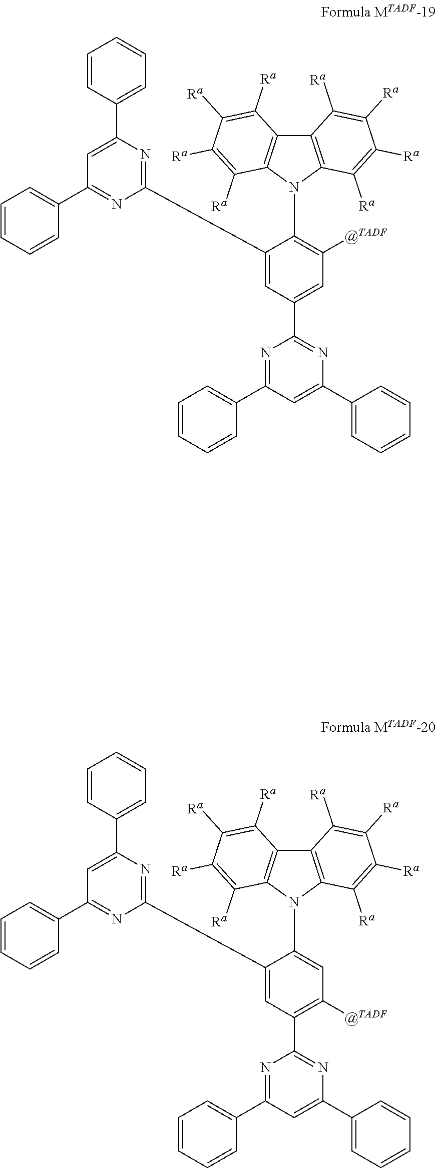

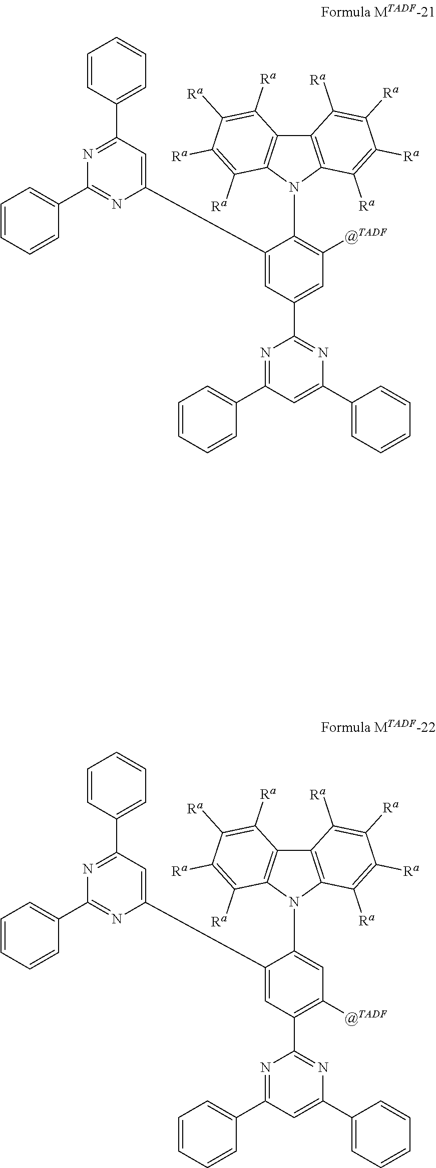

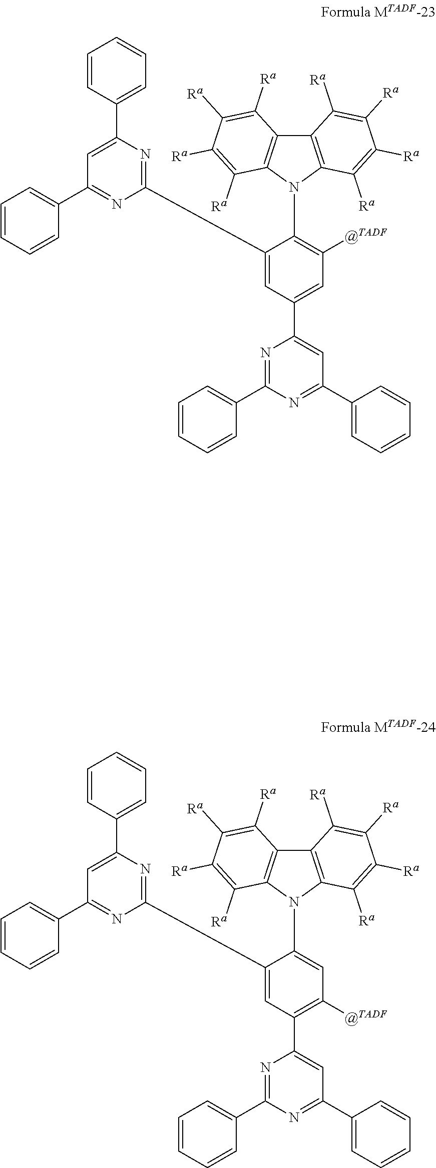

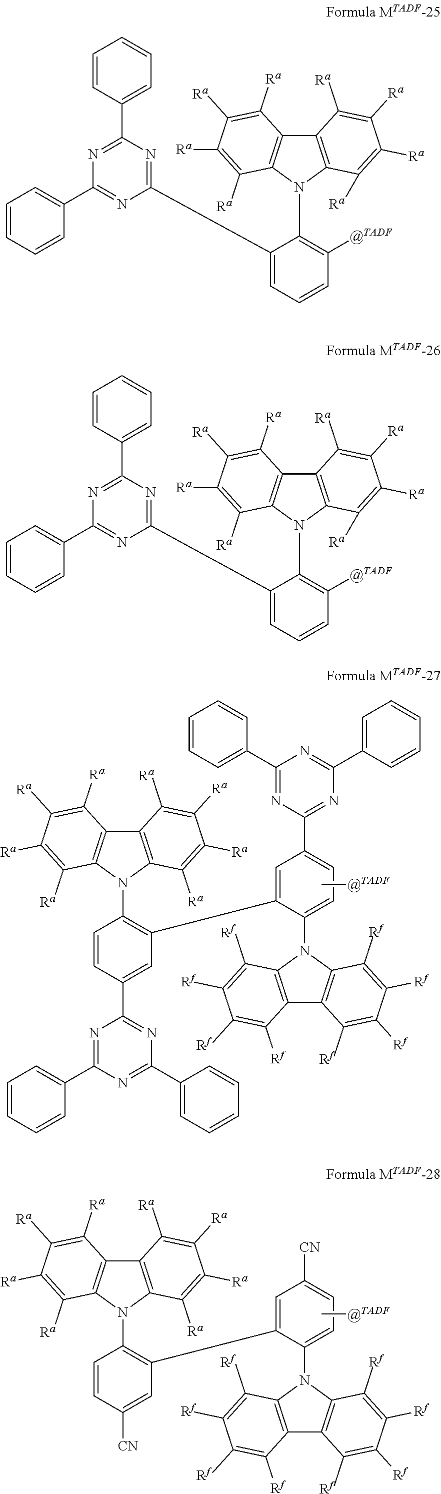

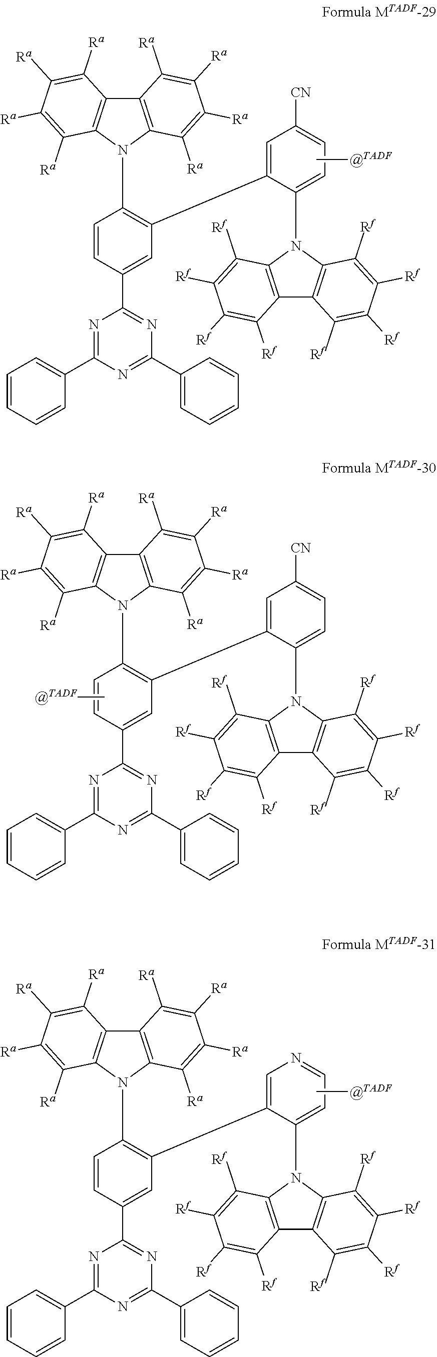

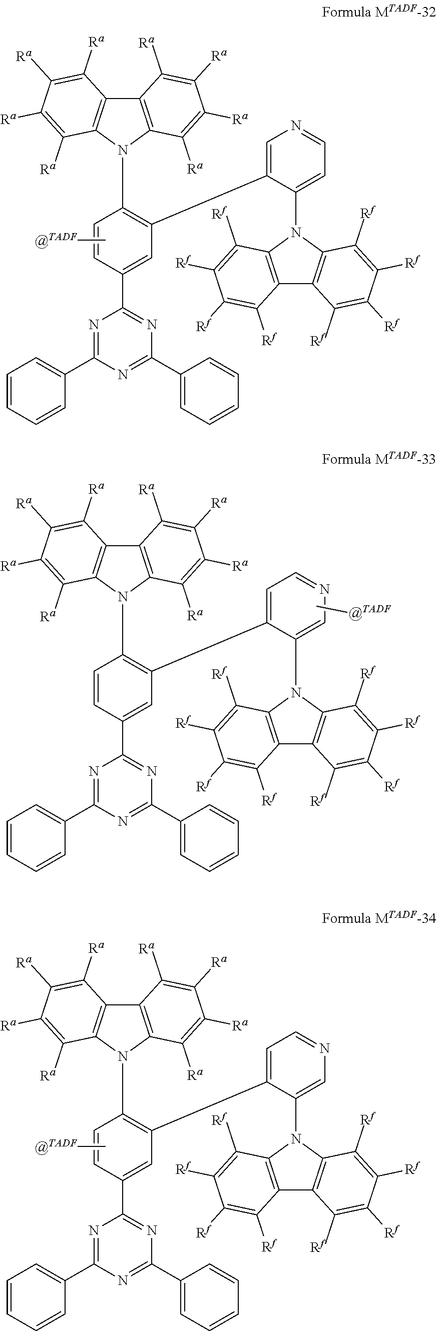

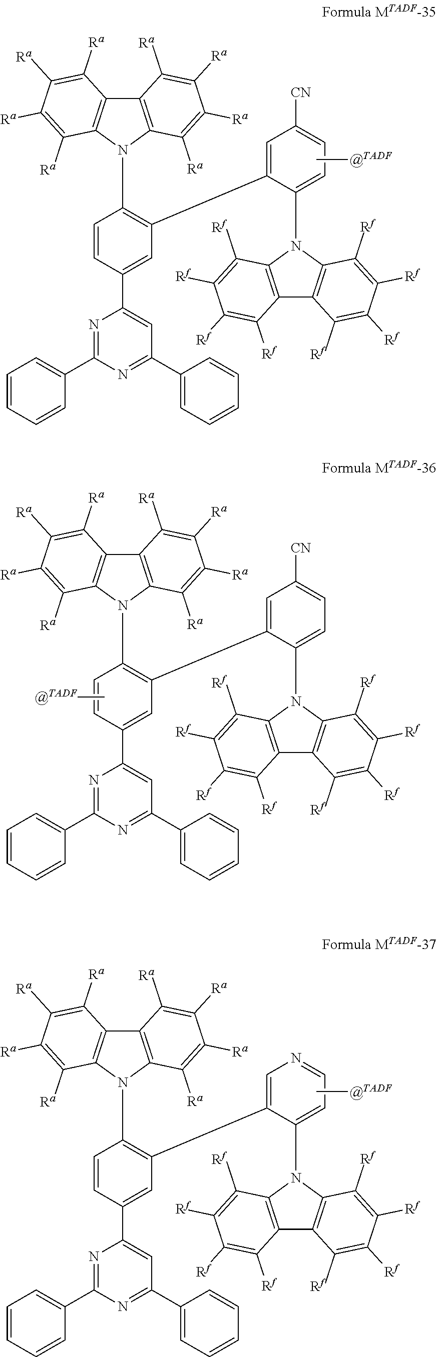

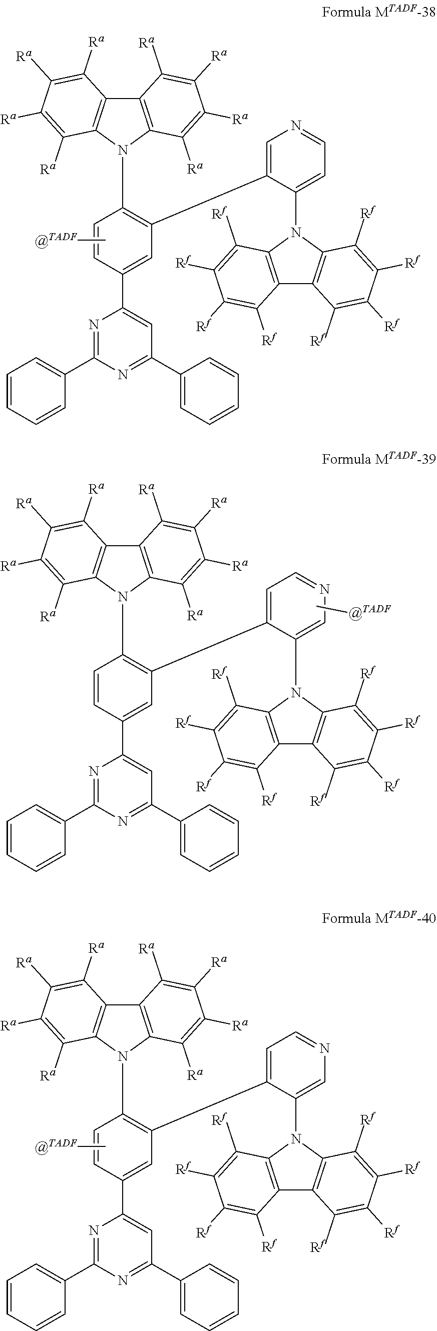

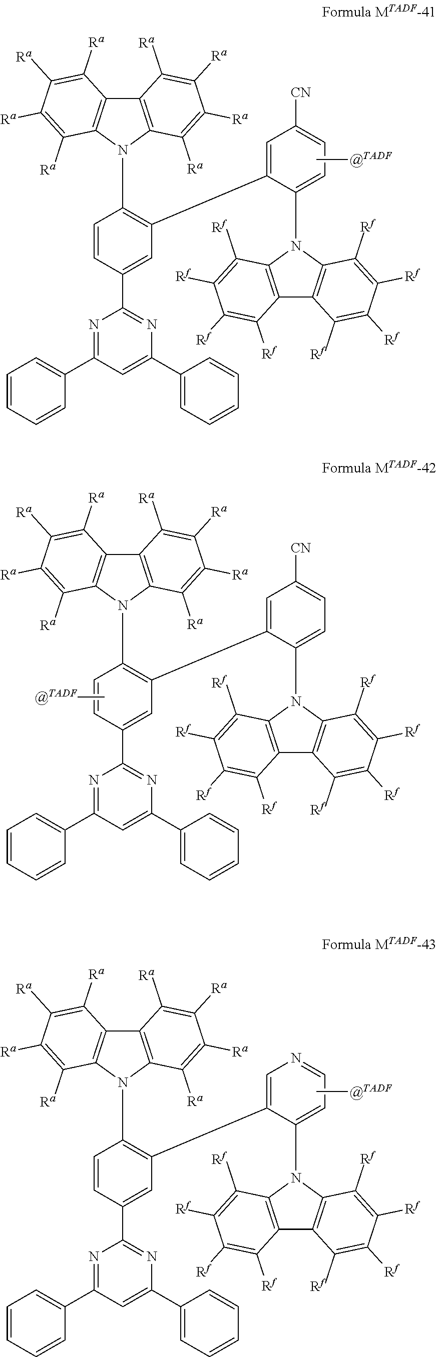

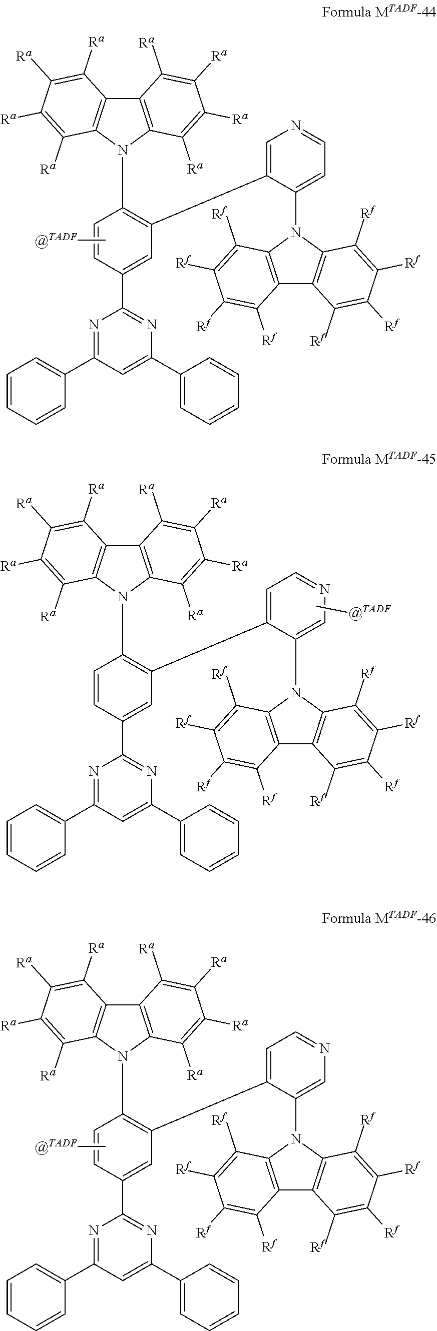

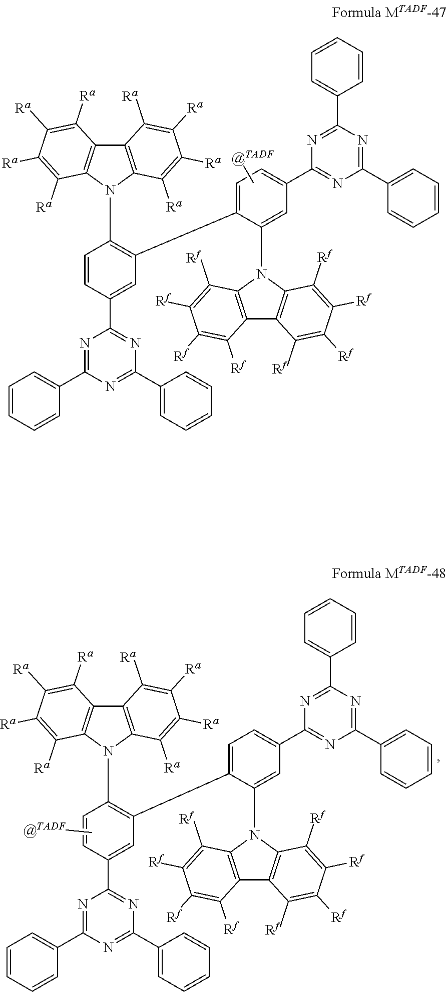

wherein for R^{a} and @^{TADF} the aforementioned definitions apply.

As used throughout the present application, the terms “aryl” and “aromatic” may be understood in the broadest sense as any mono-, bi-, or polycyclic aromatic moieties. Accordingly, an aryl group contains 6 to 60 aromatic ring atoms, and a heteroaryl group contains 5 to 60 aromatic ring atoms, of which at least one is a heteroatom. Notwithstanding, throughout the application the number of aromatic ring atoms may be given as subscripted number in the definition of certain substituents. In particular, the heteroaromatic ring includes one to three heteroatoms. Again, the terms “heteroaryl” and “heteroaromatic” may be understood in the broadest sense as any mono-, bi-, or polycyclic hetero-aromatic moieties that include at least one heteroatom. The heteroatoms may at each occurrence be the same or different and be individually selected from the group consisting of N, O, and S. Accordingly, the term “arylene” refers to a divalent substituent that bears two binding sites to other molecular structures and thereby serving as a linker structure. In case, a group in the exemplary embodiments is defined differently from the definitions given here, for example, the number of aromatic ring atoms or number of heteroatoms differs from the given definition, the definition in the exemplary embodiments is to be applied. According to the invention, a condensed (annulated) aromatic or heteroaromatic polycycle is built of two or more single aromatic or heteroaromatic cycles, which formed the polycycle via a condensation reaction.

In particular, as used throughout the present application the term aryl group or heteroaryl group includes groups which can be bound via any position of the aromatic or heteroaromatic group, derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene; pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine, and benzothiadiazole, or combinations of the abovementioned groups.

As used throughout the present application, the term cyclic group may be understood in the broadest sense as any mono-, bi-, or polycyclic moieties.

As used throughout the present application the term alkyl group may be understood in the broadest sense as any linear, branched, or cyclic alkyl substituent. In particular, the term alkyl includes the substituents methyl (Me), ethyl (Et), n-propyl (ⁿPr), i-propyl (ⁱPr), cyclopropyl, n-butyl (ⁿBu), i-butyl (ⁱBu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluorethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl, and 1-(n-decyl)-cyclohex-1-yl.

As used throughout the present application, the term alkenyl includes any linear, branched, or cyclic alkenyl substituent. The term alkenyl group exemplarily includes the substituents ethenyl, propenyl, butenyl, pentenyl, cyclopentenyl, hexenyl, cyclohexenyl, heptenyl, cycloheptenyl, octenyl, cyclooctenyl, or cyclooctadienyl.

As used throughout the present application, the term alkynyl includes any linear, branched, or cyclic alkynyl substituent. The term alkynyl group exemplarily includes ethynyl, propynyl, butynyl, pentynyl, hexynyl, heptynyl, or octynyl.

As used throughout the present application, the term alkoxy includes any linear, branched, or cyclic alkoxy substituent. The term alkoxy group exemplarily includes methoxy, ethoxy, n-propoxy, i-propoxy, n-butoxy, i-butoxy, s-butoxy, t-butoxy, and 2-methylbutoxy.

As used throughout the present application, the term thioalkoxy includes any linear, branched, or cyclic thioalkoxy substituent, in which the O of the exemplarily alkoxy groups is replaced by S.

As used throughout the present application, the terms “halogen” and “halo” may be understood in the broadest sense as being preferably fluorine, chlorine, bromine, or iodine.

Whenever hydrogen is mentioned herein, it could also be replaced by deuterium at each occurrence.

It is understood that when a molecular fragment is described as being a substituent or otherwise attached to another moiety, its name may be written as if it were a fragment (e.g., naphthyl, dibenzofuryl) or as if it were the whole molecule (e.g., naphthalene, dibenzofuran). As used herein, these different ways of designating a substituent or attached fragment are considered to be equivalent.

In one embodiment, the organic molecules according to the invention have an excited state lifetime of not more than 150 μs, of not more than 100 μs, in particular of not more than 50 μs, more preferably of not more than 10 μs or not more than 7 μs in a film of poly(methyl methacrylate) (PMMA) with 10% by weight of organic molecule at room temperature.

In one embodiment of the invention, the organic molecules according to the invention represent thermally-activated delayed fluorescence (TADF) emitters, which exhibit a ΔE_{ST} value, which corresponds to the energy difference between the first excited singlet state (S1) and the first excited triplet state (T1), of less than 5000 cm⁻¹, preferably less than 3000 cm⁻¹, more preferably less than 1500 cm⁻¹, even more preferably less than 1000 cm⁻¹ or even less than 500 cm⁻¹.

In a further embodiment of the invention, the organic molecules according to the invention have an emission peak in the visible or nearest ultraviolet range, i.e., in the range of a wavelength of from 380 to 800 nm, with a full width at half maximum of less than 0.50 eV, preferably less than 0.48 eV, more preferably less than 0.45 eV, even more preferably less than 0.43 eV or even less than 0.40 eV in a film of poly(methyl methacrylate) (PMMA) with 10% by weight of organic molecule at room temperature.

In a further embodiment of the invention, the organic molecules according to the invention have a “blue material index” (BMI), calculated by dividing the photoluminescence quantum yield (PLQY) in % by the CIEy color coordinate of the emitted light, of more than 150, in particular more than 200, preferably more than 250, more preferably of more than 300 or even more than 500.

In a further embodiment of the invention, the organic molecules according to the invention have a highest occupied molecular orbital with the energy E^{HOMO}, which is higher in energy than −6.2 eV, preferably higher in energy than −6.1 eV, and even more preferably higher in energy than −6.0 eV or even −5.9 eV.

Orbital and excited state energies can be determined either by means of experimental methods or by calculations employing quantum-chemical methods, in particular density functional theory calculations. The energy of the highest occupied molecular orbital E^{HOMO} is determined by methods known to the person skilled in the art from cyclic voltammetry measurements with an accuracy of 0.1 eV. The energy of the lowest unoccupied molecular orbital E^{LUMO} is determined as the onset of the absorption spectrum.

The onset of an absorption spectrum is determined by computing the intersection of the tangent to the absorption spectrum with the x-axis. The tangent to the absorption spectrum is set at the low-energy side of the absorption band and at the point at half maximum of the maximum intensity of the absorption spectrum.

The energy of the first excited triplet state T1 is determined from the onset of the emission spectrum at low temperature, typically at 77 K. For host compounds, where the first excited singlet state and the lowest triplet state are energetically separated by >0.4 eV, the phosphorescence is usually visible in a steady-state spectrum in 2-Me-THF. The triplet energy can thus be determined as the onset of the phosphorescence spectrum. For TADF emitter molecules, the energy of the first excited triplet state T1 is determined from the onset of the delayed emission spectrum at 77 K, if not otherwise stated measured in a film of PMMA with 10% by weight of emitter. Both for host and emitter compounds, the energy of the first excited singlet state S1 is determined from the onset of the emission spectrum, if not otherwise stated measured in a film of PMMA with 10% by weight of host or emitter compound. The onset of an emission spectrum is determined by computing the intersection of the tangent to the emission spectrum with the x-axis. The tangent to the emission spectrum is set at the high-energy side of the emission band, i.e., where the emission band rises by going from higher energy values to lower energy values, and at the point at half maximum of the maximum intensity of the emission spectrum.

A further aspect of the invention relates to the use of an organic molecule according to the invention as a luminescent emitter in an optoelectronic device.

The optoelectronic device may be understood in the broadest sense as any device based on organic materials that is suitable for emitting light in the visible or nearest ultraviolet (UV) range, i.e., in the range of a wavelength of from 380 to 800 nm. More preferably, the optoelectronic device may be able to emit light in the visible range, i.e., of from 400 to 800 nm.

In the context of such use, the optoelectronic device is more particularly selected from the group consisting of:
organic light-emitting diodes (OLEDs),
light-emitting electrochemical cells,
OLED sensors, especially in gas and vapour sensors not hermetically externally shielded,
organic diodes,
organic solar cells,
organic transistors,
organic field-effect transistors,
organic lasers, and
down-conversion elements.

In a preferred embodiment in the context of such use, the optoelectronic device is a device selected from the group consisting of an organic light emitting diode (OLED), a light emitting electrochemical cell (LEC), and a light-emitting transistor.

In the case of the use, the fraction of the organic molecule according to the invention in the emission layer in an optoelectronic device, more particularly in OLEDs, is 1% to 99% by weight, more particularly 5% to 80% by weight. In an alternative embodiment, the proportion of the organic molecule in the emission layer is 100% by weight.

In one embodiment, the light-emitting layer includes not only the organic molecules according to the invention but also a host material whose triplet (T1) and singlet (S1) energy levels are energetically higher than the triplet (T1) and singlet (S1) energy levels of the organic molecule.

### Light-Emitting Layer EML

In one embodiment, the light-emitting layer EML of an organic light-emitting diode of the invention includes (or essentially consists of) a composition including or consisting of:
(i) 1-50% by weight, preferably 5-40% by weight, in particular 10-30% by weight, of one or more organic molecules according to the invention;
(ii) 5-99% by weight, preferably 30-94.9% by weight, in particular 40-89% by weight, of at least one host compound H; and
(iii) optionally 0-94% by weight, preferably 0.1-65% by weight, in particular 1-50% by weight, of at least one further host compound D with a structure differing from the structure of the organic molecules according to the invention; and
(iv) optionally 0-94% by weight, preferably 0-65% by weight, in particular 0-50% by weight, of a solvent; and
(v) optionally 0-30% by weight, in particular 0-20% by weight, preferably 0-5% by weight, of at least one further emitter molecule F with a structure differing from the structure of the organic molecules according to the invention.

Preferably, energy can be transferred from the host compound H to the one or more organic molecules of the invention, in particular transferred from the first excited triplet state T1(H) of the host compound H to the first excited triplet state T1(E) of the one or more organic molecules according to the invention and/or from the first excited singlet state S1(H) of the host compound H to the first excited singlet state S1(E) of the one or more organic molecules according to the invention.

In one embodiment, the host compound H has a highest occupied molecular orbital HOMO(H) having an energy E^{HOMO}(H) in the range of from −5 eV to −6.5 eV, and one organic molecule according to the invention E has a highest occupied molecular orbital HOMO(E) having an energy E^{HOMO}(E), wherein E^{HOMO}(H)>E^{HOMO}(E).

In a further embodiment, the host compound H has a lowest unoccupied molecular orbital LUMO(H) having an energy E^{LUMO}(H), and the one organic molecule according to the invention E has a lowest unoccupied molecular orbital LUMO(E) having an energy E^{LUMO}(E), wherein E^{LUMO}(H)>E^{LUMO}(E).

### Light-Emitting Layer EML Including at Least One Further Host Compound D

In a further embodiment, the light-emitting layer EML of an organic light-emitting diode of the invention includes (or essentially consists of) a composition including or consisting of:
(i) 1-50% by weight, preferably 5-40% by weight, in particular 10-30% by weight, of one organic molecule according to the invention;
(ii) 5-99% by weight, preferably 30-94.9% by weight, in particular 40-89% by weight, of one host compound H; and
(iii) 0-94% by weight, preferably 0.1-65% by weight, in particular 1-50% by weight, of at least one further host compound D with a structure differing from the structure of the organic molecules according to the invention; and
(iv) optionally 0-94% by weight, preferably 0-65% by weight, in particular 0-50% by weight, of a solvent; and
(v) optionally 0-30% by weight, in particular 0-20% by weight, preferably 0-5% by weight, of at least one further emitter molecule F with a structure differing from the structure of the organic molecules according to the invention.

In one embodiment of the organic light-emitting diode of the invention, the host compound H has a highest occupied molecular orbital HOMO(H) having an energy E^{HOMO}(H) in the range of from −5 eV to −6.5 eV, and the at least one further host compound D has a highest occupied molecular orbital HOMO(D) having an energy E^{HOMO}(D), wherein E^{HOMO}(H)>E^{HOMO}(D). The relation E^{HOMO}(H)>E^{HOMO}(D) favors an efficient hole transport.

In a further embodiment, the host compound H has a lowest unoccupied molecular orbital LUMO(H) having an energy E^{LUMO}(H), and the at least one further host compound D has a lowest unoccupied molecular orbital LUMO(D) having an energy E^{LUMO}(D), wherein E^{LUMO}(H)>E^{LUMO}(D). The relation E^{LUMO}(H)>E^{LUMO}(D) favors an efficient electron transport.

In one embodiment of the organic light-emitting diode of the invention, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D),
the organic molecule E of the invention has a highest occupied molecular orbital HOMO(E) having an energy E^{HOMO}(E) and a lowest unoccupied molecular orbital LUMO(E) having an energy E^{LUMO}(E),
wherein
E^{HOMO}(H)>E^{HOMO}(D) and the difference between the energy level of the highest occupied molecular orbital HOMO(E) of organic molecule according to the invention (E^{HOMO}(E)) and the energy level of the highest occupied molecular orbital HOMO(H) of the host compound H (E^{HOMO}(H)) is between −0.5 eV and 0.5 eV, more preferably between −0.3 eV and 0.3 eV, even more preferably between −0.2 eV and 0.2 eV or even between −0.1 eV and 0.1 eV; and
E^{LUMO}(H)>E^{LUMO}(D) and the difference between the energy level of the lowest unoccupied molecular orbital LUMO(E) of organic molecule according to the invention (E^{LUMO}(E)) and the lowest unoccupied molecular orbital LUMO(D) of the at least one further host compound D (E^{LUMO}(D)) is between −0.5 eV and 0.5 eV, more preferably between −0.3 eV and 0.3 eV, even more preferably between −0.2 eV and 0.2 eV or even between −0.1 eV and 0.1 eV.

### Optoelectronic Devices

In a further aspect, the invention relates to an optoelectronic device including an organic molecule or a composition as described herein, more particularly in the form of a device selected from the group consisting of organic light-emitting diodes (OLED), light-emitting electrochemical cells, OLED sensors, more particularly gas and vapour sensors not hermetically externally shielded, organic diodes, organic solar cells, organic transistors, organic field-effect transistors, organic lasers, and down-conversion elements.

In a preferred embodiment, the optoelectronic device is a device selected from the group consisting of an organic light emitting diode (OLED), a light emitting electrochemical cell (LEC), and a light-emitting transistor.

In one embodiment of the optoelectronic device of the invention, the organic molecule according to the invention is used as emission material in a light-emitting layer EML.

In one embodiment of the optoelectronic device of the invention, the light-emitting layer EML consists of the composition according to the invention described herein.

When the optoelectronic device is an OLED, it may, for example, exhibit the following layer structure:
1. substrate
2. anode layer A
3. hole injection layer, HIL
4. hole transport layer, HTL
5. electron blocking layer, EBL
6. emitting layer, EML
7. hole blocking layer, HBL
8. electron transport layer, ETL
9. electron injection layer, EIL
10. cathode layer C,
wherein the OLED includes each layer only optionally, different layers may be merged and the OLED may include more than one layer of each layer type defined above.

Furthermore, the optoelectronic device may optionally include one or more protective layers protecting the device from damaging exposure to harmful species in the environment including, exemplarily moisture, vapor, and/or gases.

In one embodiment of the invention, the optoelectronic device is an OLED, which exhibits the following inverted layer structure:
1. substrate
2. cathode layer C
3. electron injection layer, EIL
4. electron transport layer, ETL
5. hole blocking layer, HBL
6. emitting layer, EML
7. electron blocking layer, EBL
8. hole transport layer, HTL
9. hole injection layer, HIL
10. anode layer A
wherein the OLED with an inverted layer structure includes each layer only optionally, different layers may be merged and the OLED may include more than one layer of each layer types defined above.

In one embodiment of the invention, the optoelectronic device is an OLED, which may exhibit stacked architecture. In this architecture, contrary to the typical arrangement, where the OLEDs are placed side by side, the individual units are stacked on top of each other. Blended light may be generated with OLEDs exhibiting a stacked architecture, in particular white light may be generated by stacking blue, green, and red OLEDs. Furthermore, the OLED exhibiting a stacked architecture may optionally include a charge generation layer (CGL), which is typically located between two OLED subunits and typically consists of a n-doped and p-doped layer with the n-doped layer of one CGL being typically located closer to the anode layer.

In one embodiment of the invention, the optoelectronic device is an OLED, which includes two or more emission layers between anode and cathode. In particular, this so-called tandem OLED includes three emission layers, wherein one emission layer emits red light, one emission layer emits green light, and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers. In addition, adjacent emission layers or emission layers separated by a charge generation layer may be merged.

The substrate may be formed by any material or composition of materials. Most frequently, glass slides are used as substrates. Alternatively, thin metal layers (e.g., copper, gold, silver, or aluminum films) or plastic films or slides may be used. This may allow a higher degree of flexibility. The anode layer A is mostly composed of materials allowing to obtain an (essentially) transparent film. As at least one of both electrodes should be (essentially) transparent in order to allow light emission from the OLED, either the anode layer A or the cathode layer C is transparent. Preferably, the anode layer A includes a large content or even consists of transparent conductive oxides (TCOs). Such anode layer A may exemplarily include indium tin oxide, aluminum zinc oxide, fluorine doped tin oxide, indium zinc oxide, PbO, SnO, zirconium oxide, molybdenum oxide, vanadium oxide, wolfram oxide, graphite, doped Si, doped Ge, doped GaAs, doped polyaniline, doped polypyrrole, and/or doped polythiophene.

Preferably, the anode layer A (essentially) consists of indium tin oxide (ITO). The roughness of the anode layer A caused by the transparent conductive oxides (TCOs) may be compensated by using a hole injection layer (HIL). Further, the HIL may facilitate the injection of quasi charge carriers (i.e., holes) in that the transport of the quasi charge carriers from the TCO to the hole transport layer (HTL) is facilitated. The hole injection layer (HIL) may include poly-3,4-ethylenedioxy thiophene (PEDOT), polystyrene sulfonate (PSS), MoO₂, V₂O₅, CuPC, or CuI, in particular a mixture of PEDOT and PSS. The hole injection layer (HIL) may also prevent the diffusion of metals from the anode layer A into the hole transport layer (HTL). The HIL may exemplarily include PEDOT:PSS (poly-3,4-ethylenedioxy thiophene:polystyrene sulfonate), PEDOT (poly-3,4-ethylenedioxy thiophene), mMTDATA (4,4′,4″-tris[phenyl(m-tolyl)amino]triphenylamine), Spiro-TAD (2,2′,7,7′-tetrakis(N,N-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N,N′-bis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,11-hexaazatriphenylen-hexacarbonitrile), and/or Spiro-NPD (N,N′-diphenyl-N,N′-bis-(1-naphthyl)-9,9′-spirobifluorene-2,7-diamine).

Adjacent to the anode layer A or hole injection layer (HIL) typically a hole transport layer (HTL) is located. Herein, any hole transport compound may be used. Exemplarily, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). Preferably, hole transport compounds bear comparably high energy levels of their triplet states T1. Exemplarily the hole transport layer (HTL) may include a star-shaped heterocycle such as tris(4-carbazol-9-ylphenyl)amine (TCTA), poly-TPD (poly(4-butylphenyl-diphenylamine)), alpha-NPD (N,N′-bis(naphthalen-1-yl)-N,N′-bis(phenyl)-2,2′-dimethylbenzidine), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN, and/or TrisPcz (9,9′-diphenyl-6-(9-phenyl-9H-carbazol-3-yl)-9H,9′H-3,3′-bicarbazole). In addition, the HTL may include a p-doped layer, which may be composed of an inorganic or organic dopant in an organic hole-transporting matrix. Transition metal oxides such as vanadium oxide, molybdenum oxide, or tungsten oxide may exemplarily be used as inorganic dopant. Tetrafluorotetracyanoquinodimethane (F₄-TCNQ), copper-pentafluorobenzoate (Cu(I)pFBz), or transition metal complexes may exemplarily be used as organic dopant.

The EBL may, for example, include mCP (1,3-bis(carbazol-9-yl)benzene), TCTA, 2-TNATA, mCBP (3,3-di(9H-carbazol-9-yl)biphenyl), SiMCP (3,5-Di(9H-carbazol-9-yl)phenyl]triphenylsilane), DPEPO, tris-Pcz, CzSi (9-(4-tert-Butylphenyl)-3,6-bis(triphenylsilyl)-9H-carbazole), and/or DCB (N,N′-dicarbazolyl-1,4-dimethylbenzene).

Adjacent to the hole transport layer (HTL), the light-emitting layer EML is typically located. The light-emitting layer EML includes at least one light emitting molecule. Particular, the EML includes at least one light emitting molecule according to the invention. In one embodiment, the light-emitting layer includes only the organic molecules according to the invention. Typically, the EML additionally includes one or more host material. Exemplarily, the host material is selected from CBP (4,4′-Bis-(N-carbazolyl)-biphenyl), mCP, mCBP, Sif87 (dibenzo[b,d]thiophen-2-yltriphenylsilane), CzSi, SimCP ([3,5-Di(9H-carbazol-9-yl)phenyl]triphenylsilane), Sif88 (dibenzo[b,d]thiophen-2-yl)diphenylsilane), DPEPO (bis[2-(diphenylphosphino)phenyl]ether oxide), 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine), and/or TST (2,4,6-tris(9,9′-spirobifluoren-2-yl)-1,3,5-triazine). The host material typically should be selected to exhibit first triplet (T1) and first singlet (S1) energy levels, which are energetically higher than the first triplet (T1) and first singlet (S1) energy levels of the organic molecule.

In one embodiment of the invention, the EML includes a so-called mixed-host system with at least one hole-dominant host and one electron-dominant host. In a particular embodiment, the EML includes exactly one light emitting molecule species according to the invention and a mixed-host system including T2T as electron-dominant host and at least one host selected from CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, and 9-[3,5-bis(2-dibenzothiophenyl)phenyl]-9H-carbazole as hole-dominant host. In a further embodiment the EML includes 50-80% by weight, preferably 60-75% by weight, of a host selected from CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, and 9-[3,5-bis(2-dibenzothiophenyl)phenyl]-9H-carbazole; 10-45% by weight, preferably 15-30% by weight, of T2T; and 5-40% by weight, preferably 10-30% by weight, of light emitting molecule according to the invention.

Adjacent to the light-emitting layer EML, an electron transport layer (ETL) may be located. Herein, any electron transporter may be used. Exemplarily, compounds poor of electrons such as, e.g., benzimidazoles, pyridines, triazoles, oxadiazoles (e.g., 1,3,4-oxadiazole), phosphine oxides, and sulfone, may be used. An electron transporter may also be a star-shaped heterocycle such as 1,3,5-tri(1-phenyl-1H-benzo[d]imidazol-2-yl)benzene (TPBi). The ETL may include NBphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphine oxide), BPyTP2 (2,7-di(2,2′-bipyridin-5-yl)triphenylene), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene), and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block holes or a hole blocking layer (HBL) is introduced.

The HBL may, for example, include BCP (2,9-dimethyl-4,7-diphenyl-1,10-phenanthroline=Bathocuproine), BAlq (bis(8-hydroxy-2-methylquinoline)-(4-phenylphenoxy)aluminum), NBphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphine oxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluoren-2-yl)-1,3,5-triazine), and/or TCB/TCP (1,3,5-tris(N-carbazolyl)benzene/1,3,5-tris(carbazol)-9-yl) benzene).

A cathode layer C may be located adjacent to the electron transport layer (ETL). For example, the cathode layer C may include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also consist of (essentially) non-transparent metals such as Mg, Ca, or Al. Alternatively or additionally, the cathode layer C may also include graphite and or carbon nanotubes (CNTs). Alternatively, the cathode layer C may also consist of nanoscale silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO, and/or NaF.

Optionally, also the electron transport layer (ETL) and/or a hole blocking layer (HBL) may include one or more host compounds.

In order to modify the emission spectrum and/or the absorption spectrum of the light-emitting layer EML further, the light-emitting layer EML may further include one or more further emitter molecule F. Such an emitter molecule F may be any emitter molecule known in the art. Preferably such an emitter molecule F is a molecule with a structure differing from the structure of the organic molecules according to the invention. The emitter molecule F may optionally be a TADF emitter. Alternatively, the emitter molecule F may optionally be a fluorescent and/or phosphorescent emitter molecule which is able to shift the emission spectrum and/or the absorption spectrum of the light-emitting layer EML. Exemplarily, the triplet and/or singlet excitons may be transferred from the emitter molecule according to the invention to the emitter molecule F before relaxing to the ground state S0 by emitting light typically red-shifted in comparison to the light emitted by emitter molecule E. Optionally, the emitter molecule F may also provoke two-photon effects (i.e., the absorption of two photons of half the energy of the absorption maximum).

Optionally, an optoelectronic device (e.g., an OLED) may exemplarily be an essentially white optoelectronic device. Exemplarily such white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:
violet: wavelength range of >380-420 nm;
deep blue: wavelength range of >420-480 nm;
sky blue: wavelength range of >480-500 nm;
green: wavelength range of >500-560 nm;
yellow: wavelength range of >560-580 nm;
orange: wavelength range of >580-620 nm;
red: wavelength range of >620-800 nm.

With respect to emitter molecules, such colors refer to the emission maximum. Therefore, exemplarily, a deep blue emitter has an emission maximum in the range of from >420 to 480 nm, a sky-blue emitter has an emission maximum in the range of from >480 to 500 nm, a green emitter has an emission maximum in a range of from >500 to 560 nm, a red emitter has an emission maximum in a range of from >620 to 800 nm.

A further embodiment of the present invention relates to an OLED, which emits light with CIEx and CIEy color coordinates close to the CIEx (=0.131) and CIEy (=0.046) color coordinates of the primary color blue (CIEx=0.131 and CIEy=0.046) as defined by ITU-R Recommendation BT.2020 (Rec. 2020) and thus is suited for the use in Ultra High Definition (UHD) displays, e.g., UHD-TVs. In this context, the term “close to” refers to the ranges of CIEx and CIEy coordinates provided at the end of this paragraph. In commercial applications, typically top-emitting (top-electrode is transparent) devices are used, whereas test devices as described throughout the present application represent bottom-emitting devices (bottom-electrode and substrate are transparent). The CIEy color coordinate of a blue device can be reduced by up to a factor of two, when changing from a bottom- to a top-emitting device, while the CIEx remains nearly unchanged (Okinaka et al. doi:10.1002/sdtp.10480). Accordingly, a further embodiment of the present invention relates to an OLED, whose emission exhibits a CIEx color coordinate of between 0.02 and 0.30, preferably between 0.03 and 0.25, more preferably between 0.05 and 0.20, or even more preferably between 0.08 and 0.18 or even between 0.10 and 0.15 and/or a CIEy color coordinate of between 0.00 and 0.45, preferably between 0.01 and 0.30, more preferably between 0.02 and 0.20, or even more preferably between 0.03 and 0.15 or even between 0.04 and 0.10.

A further embodiment of the present invention relates to an OLED, which emits light with CIEx and CIEy color coordinates close to the CIEx (=0.170) and CIEy (=0.797) color coordinates of the primary color green (CIEx=0.170 and CIEy=0.797) as defined by ITU-R Recommendation BT.2020 (Rec. 2020) and thus is suited for the use in Ultra High Definition (UHD) displays, e.g., UHD-TVs. In this context, the term “close to” refers to the ranges of CIEx and CIEy coordinates provided at the end of this paragraph. In commercial applications, typically top-emitting (top-electrode is transparent) devices are used, whereas test devices as used throughout the present application represent bottom-emitting devices (bottom-electrode and substrate are transparent). The CIEy color coordinate of a green device can be reduced by up to a factor of two, when changing from a bottom- to a top-emitting device, while the CIEx remains nearly unchanged (Okinaka et al. doi:10.1002/sdtp.10480). Accordingly, a further aspect of the present invention relates to an OLED, whose emission exhibits a CIEx color coordinate of between 0.06 and 0.34, preferably between 0.07 and 0.29, more preferably between 0.09 and 0.24, or even more preferably between 0.12 and 0.22 or even between 0.14 and 0.19 and/or a CIEy color coordinate of between 0.75 and 1.20, preferably between 0.76 and 1.05, more preferably between 0.77 and 0.95, or even more preferably between 0.78 and 0.90 or even between 0.79 and 0.85.

A further embodiment of the present invention relates to an OLED, which emits light with CIEx and CIEy color coordinates close to the CIEx (=0.708) and CIEy (=0.292) color coordinates of the primary color red (CIEx=0.708 and CIEy=0.292) as defined by ITU-R Recommendation BT.2020 (Rec. 2020) and thus is suited for the use in Ultra High Definition (UHD) displays, e.g., UHD-TVs. In this context, the term “close to” refers to the ranges of CIEx and CIEy coordinates provided at the end of this paragraph. In commercial applications, typically top-emitting (top-electrode is transparent) devices are used, whereas test devices as used throughout the present application represent bottom-emitting devices (bottom-electrode and substrate are transparent). The CIEy color coordinate of a red device can be reduced by up to a factor of two, when changing from a bottom- to a top-emitting device, while the CIEx remains nearly unchanged (Okinaka et al. doi:10.1002/sdtp.10480). Accordingly, a further aspect of the present invention relates to an OLED, whose emission exhibits a CIEx color coordinate of between 0.60 and 0.88, preferably between 0.61 and 0.83, more preferably between 0.63 and 0.78 or even more preferably between 0.66 and 0.76 or even between 0.68 and 0.73 and/or a CIEy color coordinate of between 0.25 and 0.70, preferably between 0.26 and 0.55, more preferably between 0.27 and 0.45 or even more preferably between 0.28 and 0.40 or even between 0.29 and 0.35.

Accordingly, a further aspect of the present invention relates to an OLED, which exhibits an external quantum efficiency at 1000 cd/m² of more than 8%, more preferably of more than 10%, more preferably of more than 13%, even more preferably of more than 15% or even more than 20% and/or exhibits an emission maximum between 420 nm and 500 nm, preferably between 430 nm and 490 nm, more preferably between 440 nm and 480 nm, even more preferably between 450 nm and 470 nm and/or exhibits a LT80 value at 500 cd/m² of more than 100 h, preferably more than 200 h, more preferably more than 400 h, even more preferably more than 750 h or even more than 1000 h.

The optoelectronic device, in particular the OLED according to the present invention can be produced by any means of vapor deposition and/or liquid processing. Accordingly, at least one layer is
prepared by means of a sublimation process,
prepared by means of an organic vapor phase deposition process,
prepared by means of a carrier gas sublimation process, or
solution processed or printed.

The methods used to produce the optoelectronic device, in particular the OLED according to the present invention are known in the art. The different layers are individually and successively deposited on a suitable substrate by means of subsequent deposition processes. The individual layers may be deposited using the same or differing deposition methods.

Vapor deposition processes exemplarily include thermal (co)evaporation, chemical vapor deposition, and/or physical vapor deposition. For active matrix OLED display, an AMOLED backplane is used as substrate. The individual layer may be processed from solutions or dispersions employing adequate solvents. Solution deposition processes exemplarily include spin coating, dip coating, and/or jet printing. Liquid processing may optionally be carried out in an inert atmosphere (e.g., in a nitrogen atmosphere) and the solvent may optionally be completely or partially removed by means known in the state of the art.

### EXAMPLES

### General Synthesis Schemes

Synthesis of M^{BN}-L-M^{TADF}:

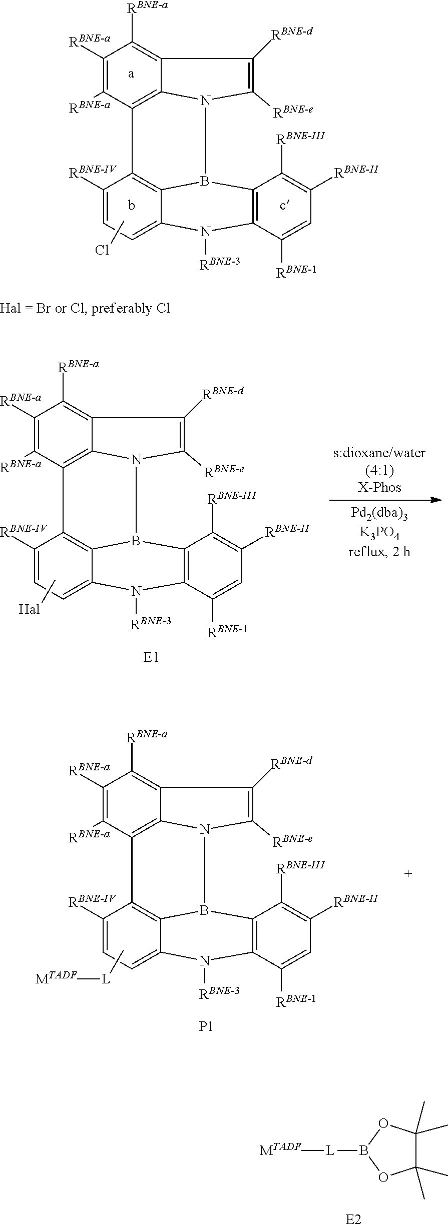

M^{BN}-Hal E1, preferably M^{BN}-CI reacts with M^{TADF}-L-boronic ester E2 (or M^{TADF}-L-boronic acid) in a Suzuki Coupling reaction to achieve the desired product P1.

For example:

E1 (1.0 equivalent), E2 (1.5 equivalent), tetrakis(triphenylphosphine)palladium(0) (CAS-No. 14221-01-3, 0.04 equivalents), and K₃PO₄ (CAS-No. 7778-53-2, 2.5 equivalents) are combined in a degassed mixture of dioxane and water (5:1 by vol.) and stirred under reflux for 16 h. After cooling down to rt, an aqueous workup is performed, followed by purification of the crude product through recrystallization or column chromatography. The desired target compound P1 is obtained as a solid.

P1 can be synthesized via a Suzuki-type coupling reaction as shown above. This means that E1 is either reacted with the boronic acid or boronic acid ester (M^{TADF}-L-B(OH)₂ or M^{TADF}-L-B(OR)₂ e.g., M^{TADF}-L-BPin; (Pin=O₂C₂(CH₃)₄) or is transferred to a boronic acid or boronic acid ester via reaction with e.g., Bis(pinacolato)diboron (B₂Pin₂, CAS: 73183-34-3) and then coupled with M^{TADF}-L-Hal (Hal is either Br or Cl, preferably Br) via a Suzuki-type coupling reaction.

Synthesis of M^{TADF}-L-Hal and M^{TADF}-L-B(OH)₂ or M^{TADF}-L-B(OR)₂

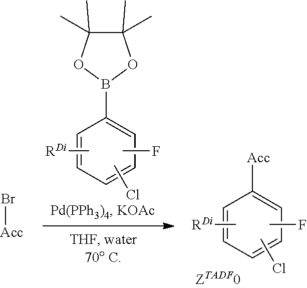

Acc-Br (1.0 equivalents) Chloro-fluoro-phenylboronic ester (1.0-1.5 equivalents), Pd(PPh₃)₄(tetrakis(triphenylphosphine)palladium(0) (CAS: 14221-01-3, 0.10 equivalents), and potassium acetate (3.0 equivalents) are stirred overnight under nitrogen atmosphere in THF/Water (4:1) at 70° C. After cooling down to room temperature (rt), the reaction mixture is extracted with ethyl acetate/brine. The organic phases are collected, the organic solvent is removed and the crude product Z^{TADF}0 is purified by MPLC or by recrystallization.

Acc-Br is preferably chosen from structures of Formulas CI1 to CI23:

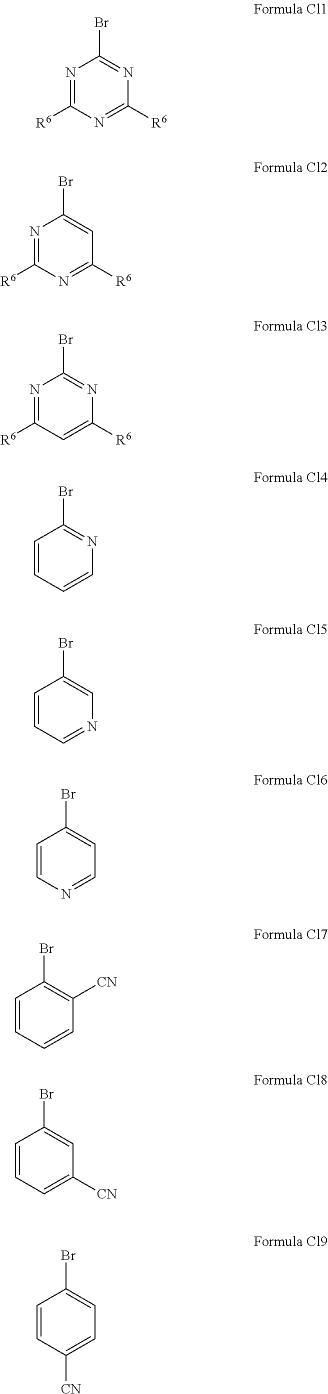

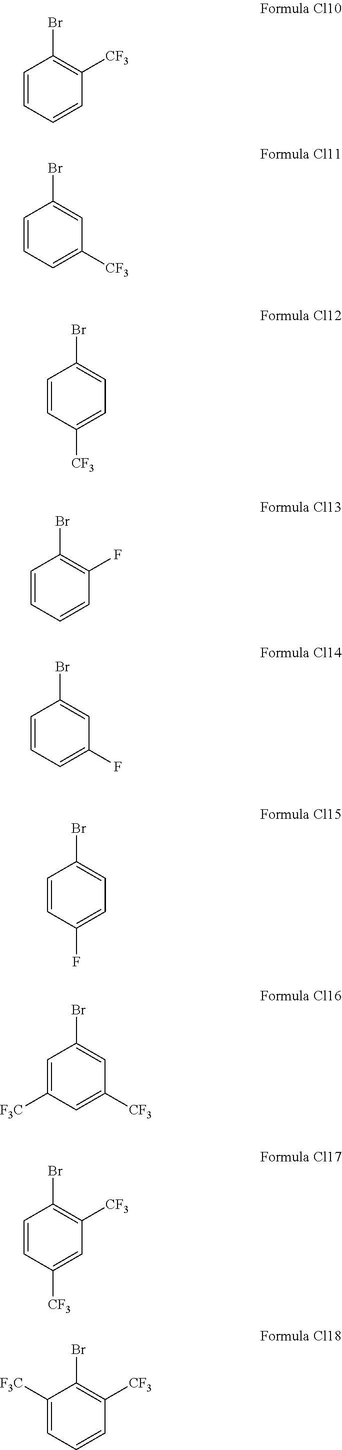

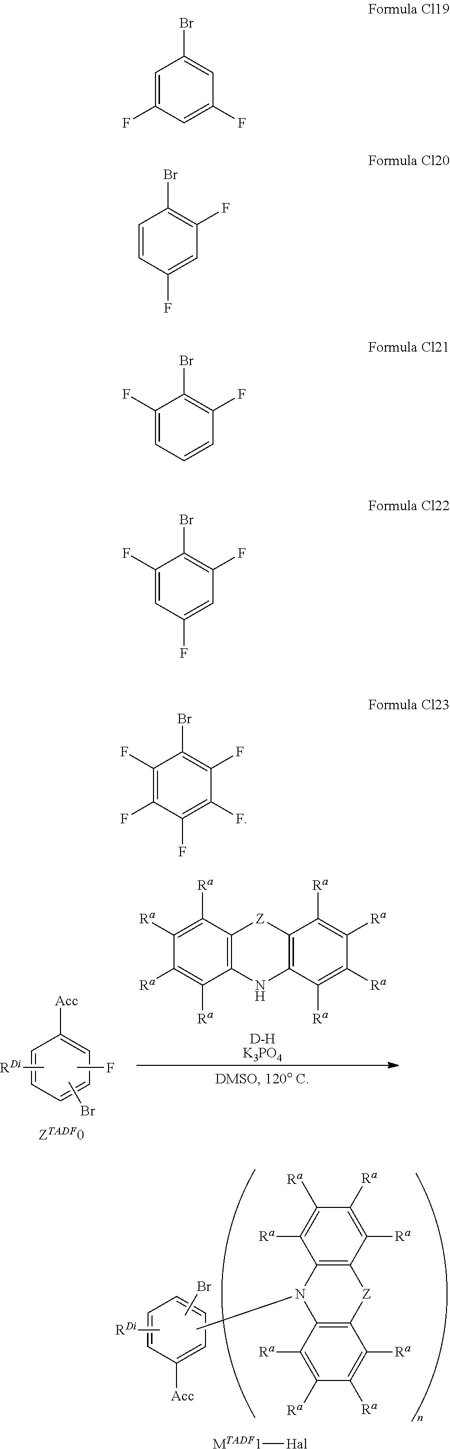

Z^{TADF}0 (1 equivalent), the corresponding donor molecule D-H (1 equivalent), and tribasic potassium phosphate (3 equivalents) are suspended under nitrogen atmosphere in DMSO and stirred at 120° C. for 12 to 16 hours. Subsequently, the reaction mixture is poured into an excess of water in order to precipitate the product. The precipitate is filtered off, washed with water and dried under vacuum. The crude product is purified by recrystallization or by flash chromatography. The product M^{TADF}1-Hal is obtained as a solid.

For the reaction of a nitrogen heterocycle in a nucleophilic aromatic substitution with an aryl halide, preferably an aryl fluoride, typical conditions include the use of a base, such as tribasic potassium phosphate or sodium hydride, for example, in an aprotic polar solvent, such as dimethyl sulfoxide (DMSO) or N,N-dimethylformamide (DMF), for example.

In particular, the donor molecule D-H is a 3,6-substituted carbazole (e.g., 3,6-dimethylcarbazole, 3,6-diphenylcarbazole, 3,6-di-tert-butylcarbazole), a 2,7-substituted carbazole (e.g., 2,7-dimethylcarbazole, 2,7-diphenylcarbazole, 2,7-di-tert-butylcarbazole), a 1,8-substituted carbazole (e.g., 1,8-dimethylcarbazole, 1,8-diphenylcarbazole, 1,8-di-tert-butylcarbazole), a 1-substituted carbazole (e.g., 1-methylcarbazole, 1-phenylcarbazole, 1-tert-butylcarbazole), a 2-substituted carbazole (e.g., 2-methylcarbazole, 2-phenylcarbazole, 2-tert-butylcarbazole), or a 3-substituted carbazole (e.g., 3-methylcarbazole, 3-phenylcarbazole, 3-tert-butylcarbazole).

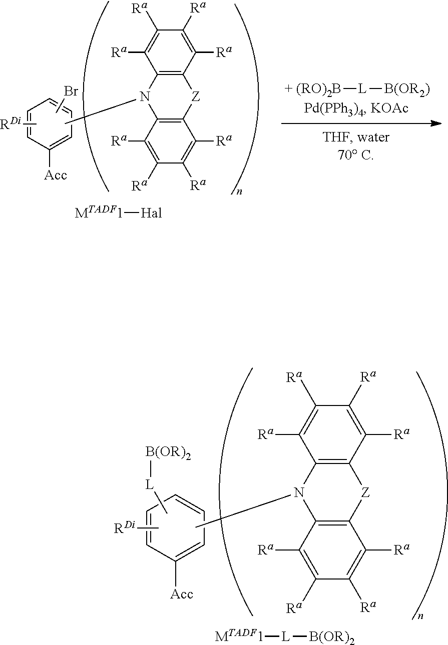

M^{TADF}1-Hal (1.0 equivalents), the diboronic ester of the bridging unit, (RO)₂B-L-B(OR)₂ (e.g., 1,3-phenyldiboronic acid, bis(pinacol) ester) (1.0-1.5 equivalents), Pd(PPh₃)₄(tetrakis(triphenylphosphine)palladium(0) (CAS: 14221-01-3, 0.10 equivalents), and potassium acetate (3 equivalents) are stirred overnight under nitrogen atmosphere in THF/Water (4:1) at 70° C. After cooling down to room temperature (RT), the reaction mixture is extracted with ethyl acetate/brine. The organic phases are collected, the organic solvent is removed and the crude product M^{TADF}1-L-B(OR)₂ is purified by flash chromatography or by recrystallization.

For example:

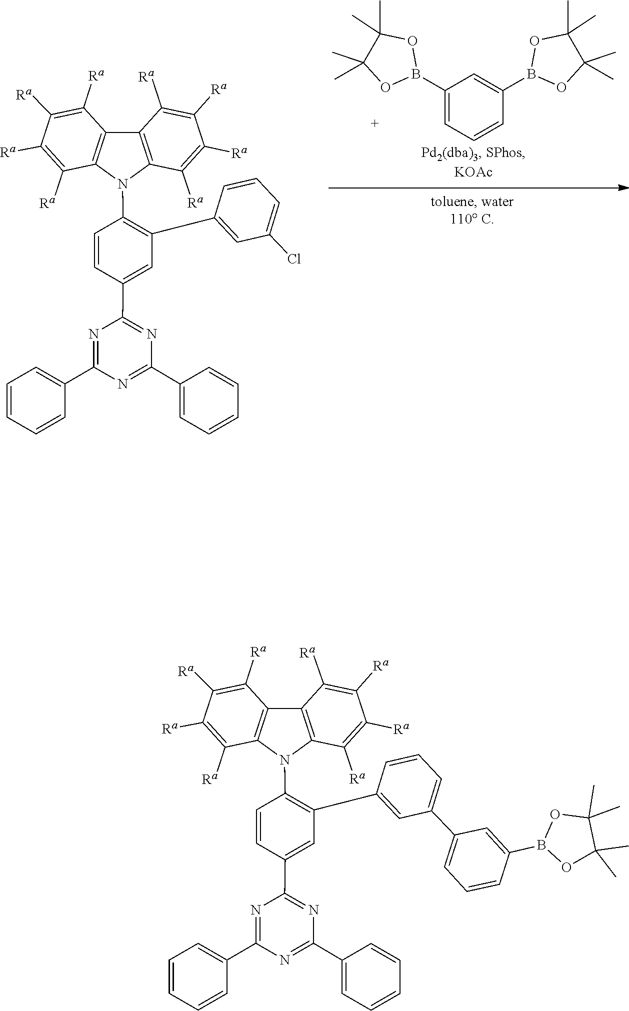

### Alternative Route:

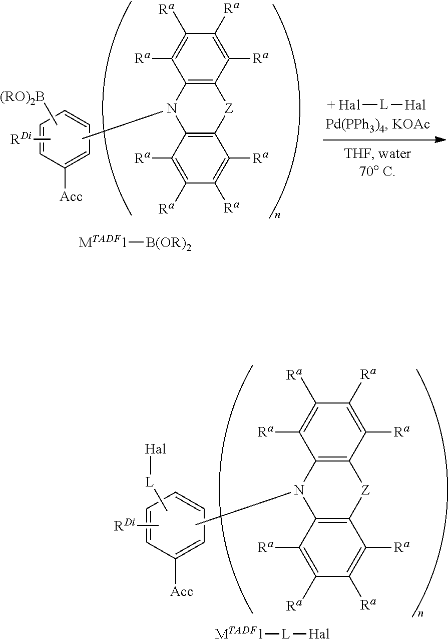

M^{TADF}-B(OR)₂ (1.0 equivalents), the dihalide of the bridging unit, Hal-L-Hal (e.g., 1,3-dibromophenyl) (1.0-1.5 equivalents), Pd(PPh₃)₄ (tetrakis(triphenylphosphine)palladium(0) (CAS: 14221-01-3, 0.10 equivalents), and potassium acetate (3 equivalents) are stirred overnight under nitrogen atmosphere in THF/Water (4:1) at 70° C. After cooling down to room temperature (RT), the reaction mixture is extracted with ethyl acetate/brine. The organic phases are collected, the organic solvent is removed and the crude product M^{TADF}1-L-Hal is purified by flash chromatography or by recrystallization.

### For Example

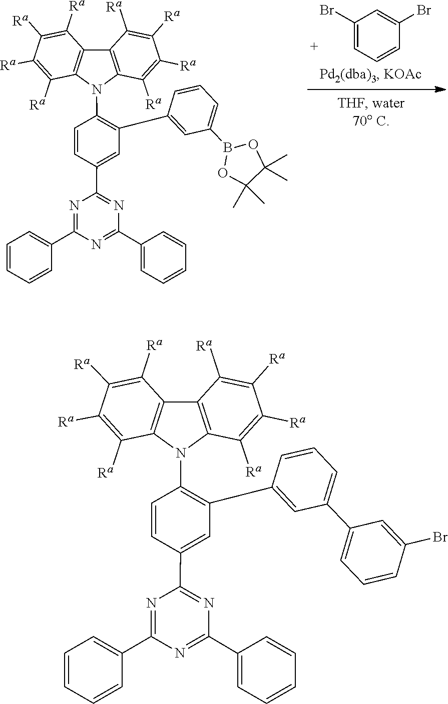

To obtain M^{TADF}1-B(OR)₂, e.g., M^{TADF}1-BPin, M^{TADF}1-Hal may be reacted with a boron acid ester, e.g., Bis(pinacolato)diboron (B₂Pin₂, CAS: 73183-34-3), employing known conditions.

By choosing the right reaction conditions M^{TADF}1-L-Hal can also be obtained from the reaction of M^{TADF}1-Hal with (RO)₂B-L-Hal, e.g., M^{TADF}1-Br with (RO)₂B-L-Cl, and M^{TADF}1-L-B(OR)₂ can also be obtained from the reaction of M^{TADF}1-B(OR)₂ with Hal-L-Hal followed by borylation as described above.

In case a third chemical moiety consisting of a structure of Formula Q is present in the molecule and M^{TADF}1 is bound via the structure of Formula Q to the bridging unit L, the structure has to be introduced as the dihalide of the structure of Formula Q in reaction with M^{TADF}1-B(OR)₂ or as diboronic ester of the structure of Formula Q in reaction with M^{TADF}1-Hal. Here the previously described conditions apply.

### For Example

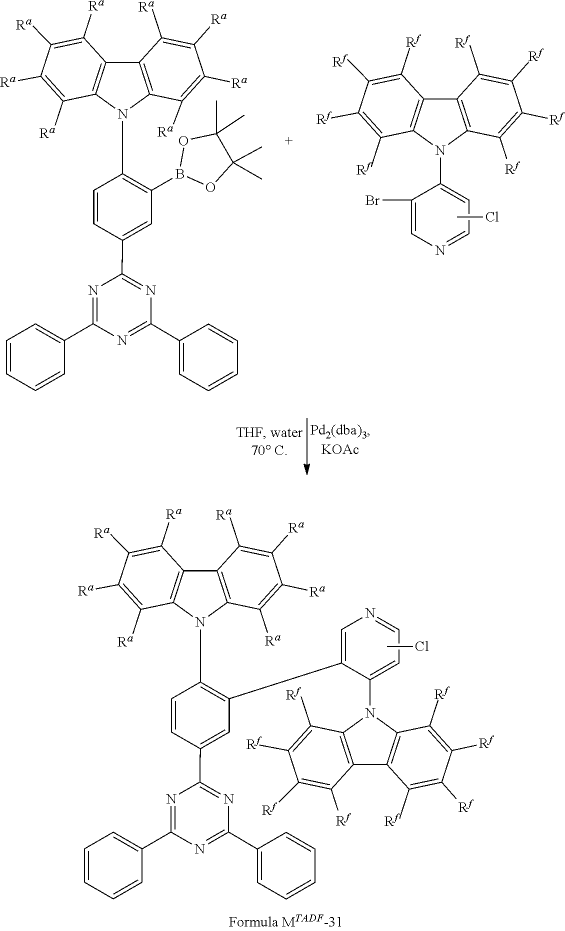

Pd(PPh₃)₄ (tetrakis(triphenylphosphine)palladium(0) (CAS: 14221-01-3) is used as a Pd catalyst during the Suzuki coupling reactions. Other catalyst alternatives are known in the art ((tris(dibenzylideneacetone)dipalladium(0)) or [1,1′-bis(diphenylphosphino)ferrocene]-palladium (II) dichloride). For example, the ligand may be selected from the group consisting of S-Phos ([2-dicyclohexylphoshino-2′,6′-dimethoxy-1,1′-biphenyl]; or SPhos), X-Phos (2-(dicyclohexylphosphino)-2″,4″,6″-triisopropylbiphenyl; or XPhos), and P(Cy)₃ (tricyclohexylphosphine). The salt is, for example, selected from tribasic potassium phosphate and potassium acetate and the solvent can be a pure solvent, such as THF/water, toluene or dioxane, or a mixture, such as toluene/dioxane/water or dioxane/toluene. A person of skill in the art can determine which Pd catalyst, ligand, salt, and solvent combination will result in high reaction yields.

### HPLC-MS:

HPLC-MS analysis is performed on an HPLC by Agilent (1100 series) with MS-detector (Thermo LTQ XL).

Exemplary a typical HPLC method is as follows: a reverse phase column 4.6 mm×150 mm, particle size 3.5 μm from Agilent (ZORBAX Eclipse Plus 95 Å C18, 4.6×150 mm, 3.5 μm HPLC column) is used in the HPLC. The HPLC-MS measurements are performed at room temperature (rt) following gradients:

| Flow rate [ml/min] | time [min] | A[%] | B[%] | C[%] |
|---|---|---|---|---|
| 2.5 | 0 | 40 | 50 | 10 |
| 2.5 | 5 | 40 | 50 | 10 |
| 2.5 | 25 | 10 | 20 | 70 |
| 2.5 | 35 | 10 | 20 | 70 |
| 2.5 | 35.01 | 40 | 50 | 10 |
| 2.5 | 40.01 | 40 | 50 | 10 |
| 2.5 | 41.01 | 40 | 50 | 10 |

using the following solvent mixtures:

| | | |
|---|---|---|
| solvent A: | H₂O (90%) | MeCN (10%) |
| solvent B: | H₂O (10%) | MeCN (90%) |
| solvent C: | THF (50%) | MeCN (50%) |

An injection volume of 5 μL from a solution with a concentration of 0.5 mg/mL of the analyte is taken for the measurements.

Ionization of the probe is performed using an APCI (atmospheric pressure chemical ionization) source either in positive (APCI+) or negative (APCI−) ionization mode.

### Cyclic Voltammetry

Cyclic voltammograms are measured from solutions having concentration of 10⁻³ mol/l of the organic molecules in dichloromethane or a suitable solvent and a suitable supporting electrolyte (e.g., 0.1 mol/l of tetrabutylammonium hexafluorophosphate). The measurements are conducted at room temperature under nitrogen atmosphere with a three-electrode assembly (Working and counter electrodes: Pt wire, reference electrode: Pt wire) and calibrated using FeCp₂/FeCp₂_{⁺} as internal standard. The HOMO data is corrected using ferrocene (FeCp₂) as internal standard against SCE.

### Density Functional Theory Calculation

Molecular structures are optimized employing the BP86 functional and the resolution of identity approach (RI). Excitation energies are calculated using the (BP86) optimized structures employing Time-Dependent DFT (TD-DFT) methods. Orbital and excited state energies are calculated with the B3LYP functional. Def2-SVP basis sets and a m4-grid for numerical integration are used. The Turbomole program package is used for all calculations.

### Photophysical Measurements

Sample pretreatment: Spin-coating

Apparatus: Spin150, SPS euro.

The sample concentration is 10 mg/ml, dissolved in a suitable solvent.

Program: 1) 3 s at 400 U/min; 2) 20 s at 1000 U/min at 1000 Upm/s; 3) 10 s at 4000 U/min at 1000 Upm/s. After coating, the films are dried at 70° C. for 1 min.

### Photoluminescence Spectroscopy and TCSPC (Time-Correlated Single-Photon Counting)

Steady-state emission spectroscopy is measured by a Horiba Scientific, Modell FluoroMax-4 equipped with a 150 W Xenon-Arc lamp, excitation- and emission monochromators and a Hamamatsu R928 photomultiplier and a time-correlated single-photon counting option. Emission and excitation spectra are corrected using standard correction fits.

Excited state lifetimes are determined employing the same system using the TCSPC method with FM-2013 equipment and a Horiba Yvon TCSPC hub.

### Excitation Sources:

NanoLED 370 (wavelength: 371 nm, pulse duration: 1.1 ns)
NanoLED 290 (wavelength: 294 nm, pulse duration: <1 ns)
SpectraLED 310 (wavelength: 314 nm)
SpectraLED 355 (wavelength: 355 nm).

Data analysis (exponential fit) is done using the software suite DataStation and DAS6 analysis software. The fit is specified using the chi-squared-test.

### Photoluminescence Quantum Yield Measurements

For photoluminescence quantum yield (PLQY) measurements, an Absolute PL Quantum Yield Measurement C9920-03G system (Hamamatsu Photonics) is used. Photoluminescence quantum yields and CIE coordinates are determined using the software U6039-05 version 3.6.0.

Emission maxima are given in nm, photoluminescence quantum yields Φ_{PL} in % and CIE coordinates as x,y values.

PLQY is determined using the following protocol:
Quality assurance: Anthracene in ethanol (known concentration) is used as reference
Excitation wavelength: the absorption maximum of the organic molecule is determined and the organic molecule is excited using this wavelength

### Measurement

Photoluminescence quantum yields are measured for sample of solutions or films under nitrogen atmosphere. The photoluminescence quantum yield is calculated using the equation:

$${Φ}_{PL} = \frac{{n}_{photon} , emited}{{n}_{photon} , absorbed} = \frac{\int \frac{λ}{hc} [ {Int}_{emitted}^{sample} ( λ ) - {Int}_{absorbed}^{sample} ( λ ) ] d λ}{\int \frac{λ}{hc} [ {Int}_{emitted}^{reference} ( λ ) - {Int}_{absorbed}^{reference} ( λ ) ] d λ} ,$$

wherein nₚₕₒₜₒₙ denotes the photon count and Int. denotes the intensity.

### Production and Characterization of Optoelectronic Devices

OLED devices including organic molecules according to the invention can be produced via vacuum-deposition methods. If a layer contains more than one compound, the weight-percentage of one or more compounds is given in %. The total weight-percentage values amount to 100%, thus if a value is not given, the fraction of this compound equals to the difference between the given values and 100%.

The not fully optimized OLEDs are characterized using standard methods and measuring electroluminescence spectra, the external quantum efficiency (in %) in dependency on the intensity, calculated using the light detected by the photodiode, and the current. The OLED device lifetime is extracted from the change of the luminance during operation at constant current density. The LT50 value corresponds to the time point, where the measured luminance decreased to 50% of the initial luminance, analogously LT80 value corresponds to the time point, at which the measured luminance decreased to 80% of the initial luminance, LT 95 value corresponds to the time point, at which the measured luminance decreased to 95% of the initial luminance etc.

Accelerated lifetime measurements are performed (e.g., applying increased current densities). Exemplarily LT80 values at 500 cd/m² are determined using the following equation:

$$LT 80 ( 500 \frac{{cd}^{2}}{{m}^{2}} ) = LT 80 ( {L}_{0} ) {( \frac{{L}_{0}}{500 \frac{{cd}^{2}}{{m}^{2}}} )}^{1.6} ,$$

wherein L₀ denotes the initial luminance at the applied current density.

The values correspond to the average of several pixels (typically two to eight), the standard deviation between these pixels is given.

### Example of Organic Molecules of the Invention

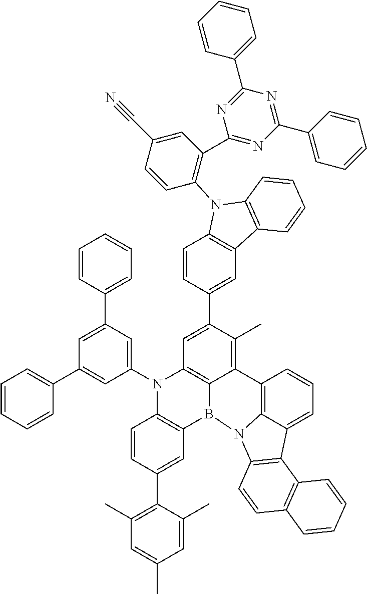 [SMILES: Cc1cc(C)c(-c2ccc3c(c2)B2c4c(cc(-c5ccc6c(c5)c5ccccc5n6-c5ccc(C#N)cc5-c5nc(-c6ccccc6)nc(-c6ccccc6)n5)c(C)c4-c4cccc5c6c7ccccc7ccc6n2c45)N3c2cc(-c3ccccc3)cc(-c3ccccc3)c2)c(C)c1]

### Example 1

MS (LC-MS, APPI ion source): 897 m/z at rt: 9.20 min.

The emission maximum of Example 1 (0.001 mg/mL in toluene) is at 449 nm with a full-width at half maximum (FWHM) of 41 nm, the CIEx coordinate is 0.16 and the CIEy coordinate is 0.13. The photoluminescence quantum yield (PLQY) is 53%.

The absorption maximum of Example 1 (0.01 mg/mL in toluene) is at 438 nm and has an absorption coefficient at the absorption maximum of 88000 M⁻¹ cm⁻¹.

1-19. (canceled)

20. An organic molecule, comprising a structure of Formula A: 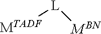
Formula A,
wherein:
M^{TADF} represents a thermally activated delayed fluorescence (TADF) moiety;
L represents a direct bond or a divalent bridging unit that links M^{TADF} and M^{BN} and that is linked to M^{TADF} and to M^{BN} via a single bond each; and
M^{BN} represents an emitter moiety comprising a direct BN-bond.

21. The organic molecule according to claim 20, wherein M^{BN} represents an emitter moiety comprising a structure according to Formula BNE-1: 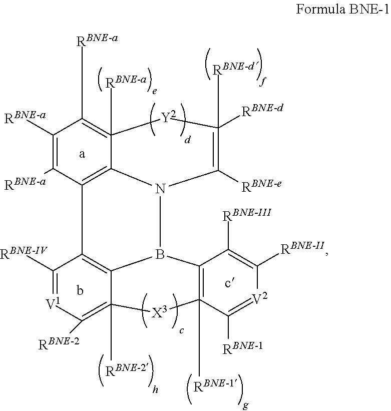
wherein:
c and d are both integers and independently of each other selected from among 0 and 1;
e and f are both integers and selected from among 0 and 1, wherein e and f are identical;
g and h are both integers and selected from among 0 and 1, wherein g and h are identical;
when d is 0, then e and f are both 1, and when d is 1, then e and f are both 0;
when c is 0, then g and h are both 1, and when c is 1, then g and h are both 0;
V¹ is selected from among nitrogen (N) and CR^{BNE-V};
V² is selected from among nitrogen (N) and CR^{BNE-I};
X³ is selected from the group consisting of a direct bond, CR^{BNE-3}R^{BNE-4}, C═CR^{BNE-3}R^{BNE-4}, C═O, C═NR^{BNE-3}, NR^{BNE-3}, O, SiR^{BNE-3}R^{BNE-4}, S, S(O), and S(O)₂;
Y² is selected from the group consisting of a direct bond, CR^{BNE-3′}R^{BNE-4′}, C═CR^{BNE-3′}R^{BNE-4′}, C═O, C═NR^{BNE-3′}, NR^{BNE-3′}, O, SiR^{BNE-3′}R^{BNE-4′}, S, S(O), and S(O)₂;
R^{BNE-1}, R^{BNE-2}, R^{BNE-1′}, R^{BNE-2′}, R^{BNE-3}, R^{BNE-4}, R^{BNE-3′}, R^{BNE-4′},R^{BNE-I}, R^{BNE-II}, R^{BNE-III}, R^{BNE-IV}, and R^{BNE-V} are each independently of each other selected from the group consisting of: a single bond linking the emitter moiety M^{BN} to the bridging unit L; hydrogen; deuterium; N(R^{BNE-5})₂; OR^{BNE-5}; Si(R^{BNE-5})₃; B(OR^{BNE-5})₂; B(R^{BNE-5})₂; OSO₂R^{BNE-5}; CF₃; CN; F; Cl; Br; I;
C₁-C₄₀-alkyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-alkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-thioalkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkenyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkynyl,
which is optionally substituted with one or more substituents R^{BNE-5} and
wherein one or more non-adjacent CH₂-groups are optionally substituted by R^{BNE-5}C═CR^{BNE-5}, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-5}; and
C₂-C₅₇-heteroaryl,
which is optionally substituted with one or more substituents R^{BNE-5};
R^{BNE-d}, R^{BNE-d′}, and R^{BNE-e} are independently of each other selected from the group consisting of: hydrogen; deuterium; N(R^{BNE-5})₂; OR^{BNE-5}; Si(R^{BNE-5})₃; B(OR^{BNE-5})₂; B(R^{BNE-5})₂; OSO₂R^{BNE-5}; CF₃; CN; F; Cl; Br; I;
C₁-C₄₀-alkyl,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-alkoxy,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-thioalkoxy,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkenyl,
which is optionally substituted with one or more substituents R^{BNE-a} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkynyl,
which is optionally substituted with one or more substituents R^{BNE-a} and
wherein one or more non-adjacent CH₂-groups are optionally substituted by R^{BNE}—C═CR^{BNE-5}, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-a}; and
C₂-C₅₇-heteroaryl,
which is optionally substituted with one or more substituents R^{BNE-a};
R^{BNE-a} is at each occurrence independently of each other selected from the group consisting of: hydrogen; deuterium; N(R^{BNE-5})₂; OR^{BNE-5}; Si(R^{BNE-5})₃; B(OR^{BNE-5})₂; B(R^{BNE-5})₂; OSO₂R^{BNE-5}; CF₃; CN; F; Cl; Br; I;
C₁-C₄₀-alkyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-alkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₁-C₄₀-thioalkoxy,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkenyl,
which is optionally substituted with one or more substituents R^{BNE-5} and
wherein one or more non-adjacent CH₂-groups are optionally substituted by R^{BNE-5}C═CR^{BNE-5}, C≡C, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₂-C₄₀-alkynyl,
which is optionally substituted with one or more substituents R^{BNE-5} and
wherein one or more non-adjacent CH₂-groups are optionally substituted by R^{BNE-5}C═CR^{BNE-5}, Si(R^{BNE-5})₂, Ge(R^{BNE-5})₂, Sn(R^{BNE-5})₂, C═O, C═S, C═Se, C═NR^{BNE-5}, P(═O)(R^{BNE-5}), SO, SO₂, NR^{BNE-5}, O, S, or CONR^{BNE-5};
C₆-C₆₀-aryl,
which is optionally substituted with one or more substituents R^{BNE-5}; and
C₂-C₅₇-heteroaryl,
which is optionally substituted with one or more substituents R^{BNE-5};
R^{BNE-5} is at each occurrence independently of each other selected from the group consisting of: hydrogen; deuterium; N(R^{BNE-6})₂; OR^{BNE-6}; Si(R^{BNE-6})₃; B(OR^{BNE-6})₂; B(R^{BNE-6})₂; OSO₂R^{BNE-6}; CF₃; CN; F; Cl; Br; I;
C₁-C₄₀-alkyl,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₁-C₄₀-alkoxy,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₁-C₄₀-thioalkoxy,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₂-C₄₀-alkenyl,
which is optionally substituted with one or more substituents R^{BNE-6} and
wherein one or more non-adjacent CH₂-groups are optionally substituted by R^{BNE-6}C═CR^{BNE-6}, C≡C, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₂-C₄₀-alkynyl,
which is optionally substituted with one or more substituents R^{BNE-6} and
wherein one or more non-adjacent CH₂-groups are optionally substituted by R^{BNE-6}C═CR^{BNE-6}, Si(R^{BNE-6})₂, Ge(R^{BNE-6})₂, Sn(R^{BNE-6})₂, C═O, C═S, C═Se, C═NR^{BNE-6}, P(═O)(R^{BNE-6}), SO, SO₂, NR^{BNE-6}, O, S, or CONR^{BNE-6};
C₆-C₆₀-aryl,
which is optionally substituted with one or more substituents R^{BNE-6}; and
C₂-C₅₇-heteroaryl,
which is optionally substituted with one or more substituents R^{BNE-6};
R^{BNE-6} is at each occurrence independently from each other selected from the group consisting of: hydrogen; deuterium; OPh; CF₃; CN; F;
C₁-C₅-alkyl,
wherein one or more hydrogen atoms are optionally, independently of each other substituted by deuterium, CN, CF₃, Ph, or F;
C₁-C₅-alkoxy,
wherein one or more hydrogen atoms are optionally, independently of each other substituted by deuterium, CN, CF₃, or F;
C₁-C₅-thioalkoxy,
wherein one or more hydrogen atoms are optionally, independently of each other substituted by deuterium, CN, CF₃, or F;
C₂-C₅-alkenyl,
wherein one or more hydrogen atoms are optionally, independently of each other substituted by deuterium, CN, CF₃, or F;
C₂-C₅-alkynyl,
wherein one or more hydrogen atoms are optionally, independently of each other substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂; and
N(C₂-C₁₇-heteroaryl)(C₆-C₁₈-aryl);
wherein R^{BNE-III} and R^{BNE-e} optionally combine to form a direct single bond; and
wherein two or more substituents selected from among R^{BNE-a}, R^{BNE-d}, R^{BNE-d′}, R^{BNE-e}, R^{BNE-3′}, R^{BNE-4′}, and R^{BNE-5} optionally form a mono- or polycyclic, aliphatic or aromatic or heteroaromatic, carbo- or heterocyclic ring system with each other;
wherein two or more substituents selected from among R^{BNE-1}, R^{BNE-2}, R^{BNE-1′}, R^{BNE-2′}, R^{BNE-3}, R^{BNE-4}, R^{BNE-5}, R^{BNE-I}, R^{BNE-II}, R^{BNE-III}, R^{BNE-IV}, and R^{BNE-V} optionally form a mono- or polycyclic, aliphatic or aromatic or heteroaromatic, carbo- or heterocyclic ring system with each other;
wherein optionally two or more structures of Formula BNE-1 are conjugated with each other, or fused to each other by sharing at least one bond;
wherein optionally two or more structures of Formula BNE-1 are present in the organic molecule and share at least one aromatic or heteroaromatic ring which is any of the rings a, b, and c′ of Formula BNE-1, or any aromatic or heteroaromatic substituent selected from among R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-5}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, and R^{BNE-d′}, or any aromatic or heteroaromatic ring formed by two or more substituents selected therefrom, wherein the shared ring constitute the same or different moieties of the two or more structures of Formula BNE-1 that share the ring; and
wherein optionally at least one of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1 and/or wherein optionally at least one hydrogen atom of any of R^{BNE-1}, R^{BNE-2}, R^{BNE-1′}, R^{BNE-2′}, R^{BNE-3}, R^{BNE-4}, R^{BNE-5}, R^{BNE-3′}, R^{BNE-4′}, R^{BNE-6}, R^{BNE-I}, R^{BNE-II}, R^{BNE-III}, R^{BNE-IV}, R^{BNE-V}, R^{BNE-a}, R^{BNE-e}, R^{BNE-d}, or R^{BNE-d′} is replaced by a bond to a further chemical entity of Formula BNE-1; and
wherein exactly one of the substituents of the emitter moiety M^{BN} represents a binding site of a single bond linking the emitter moiety M^{BN} to the bridging unit L.

22. The organic molecule according to claim 21, wherein V¹ is CR^{BNE-V}, and V² is CR^{BNE-I}.

23. The organic molecule according to claim 21, wherein:
each of c and d is 1;
each of e, f, g, and h is 0;
Y² is a direct bond; and
X³ is NR^{BNE-3}.

24. The organic molecule according to claim 21, wherein each of R^{BNE-1}, R^{BNE-2}, R^{BNE-1′}, R^{BNE-2′}, R^{BNE-3}, R^{BNE-4}, R^{BNE-3′}, R^{BNE-4′}, R^{BNE-I}, R^{BNE-II}, R^{BNE-III}, R^{BNE-IV}, R^{BNE-V}, R^{BNE-d}, R^{BNE-d′}, R^{BNE-e}, R^{BNE-a}, is at each occurrence independently from each other selected from the group consisting of:
a binding site of the single bond linking the emitter moiety M^{BN} to the bridging unit L,
hydrogen,
deuterium,
halogen,
Me,
ⁱPr,
^{t}Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph, and
N(Ph)₂; and
wherein exactly one of the substituents selected from the group consisting of R^{BNE-1}, R^{BNE-2}, R^{BNE-3}, R^{BNE-4}, R^{BNE-I}, R^{BNE-II}, R^{BNE-III}, R^{BNE-IV}, and R^{BNE-V} represents the binding site of the single bond linking the emitter moiety M^{BN} to the bridging unit L.

25. The organic molecule according to claim 21, wherein R^{BNE-IV}, R^{BNE-2} or R^{BNE-V} represents the binding site of the single bond linking the emitter moiety M^{BN} to the bridging unit L.

26. The organic molecule according to claim 20, wherein L comprises one or more consecutively linked divalent moieties independently selected from the group consisting of:
a direct bond;
C₆-C₆₀-arylene, which is optionally substituted with one or more substituents R^{L};
C₃-C₅₇-heteroarylene, which is optionally substituted with one or more substituents R^{L};
R^{L}Si(R^{L}₂);
Si(R^{L}₂)R^{L};
Si(R^{L2}); and
R^{L}Si(R^{L}₂)R^{L}; and
wherein R^{L} is at each occurrence independently from each other selected from the group consisting of:
Ph, which is optionally substituted with one or more substituents independently from each other selected from the group consisting of C₁-C₄ alkyl, C₁-C₄ haloalkyl, CN, CF₃, and Ph;
pyridinyl and pyridinylene, each of which is optionally substituted with one or more substituents independently from each other selected from the group consisting of C₁-C₄ alkyl, C₁-C₄ haloalkyl, CN, CF₃, or Ph;
pyrimidinyl and pyrimidinylene, each of which is optionally substituted with one or more substituents independently from each other selected from the group consisting of C₁-C₄ alkyl, C₁-C₄ haloalkyl, CN, CF₃, and Ph;
carbazolyl and carbazolylene, each of which is optionally substituted with one or more substituents independently from each other selected from the group consisting of C₁-C₄ alkyl, C₁-C₄ haloalkyl, CN, CF₃, and Ph;
triazinyl and triazinylene, each of which is optionally substituted with one or more substituents independently from each other selected from the group consisting of Me, C₁-C₄ alkyl, C₁-C₄ haloalkyl, CN, CF₃, and Ph;
and
N(Ph)₂.

27. The organic molecule according to claim 20, wherein L is selected from the group consisting of:
a direct bond;
C₆-C₆₀-arylene, which is optionally substituted with one or more substituents R^{L};
C₃-C₅₇-heteroarylene, which is optionally substituted with one or more substituents R^{L};
C₆-C₆₀-arylene-C₃-C₅₇-heteroarylene, which is optionally substituted with one or more substituents R^{L};
C₃-C₅₇-heteroarylene-C₆-C₆₀-arylene, which is optionally substituted with one or more substituents R^{L};
C₆-C₆₀-arylene-C₆-C₆₀-arylene, which is optionally substituted with one or more substituents R^{L};
C₃-C₅₇-heteroarylene-C₃-C₅₇-heteroarylene, which is optionally substituted with one or more substituents R^{L};
C₆-C₆₀-arylene-C₃-C₅₇-heteroarylene-C₆-C₆₀-arylene, which is optionally substituted with one or more substituents R^{L};
C₃-C₅₇-heteroarylene-C₆-C₆₀-arylene-C₃-C₅₇-heteroarylene, which is optionally substituted with one or more substituents R^{L};
C₆-C₆₀-arylene-C₆-C₆₀-arylene-C₆-C₆₀-arylene, which is optionally substituted with one or more substituents R^{L};
C₃-C₅₇-heteroarylene-C₃-C₅₇-heteroarylene-C₃-C₅₇-heteroarylene, which is optionally substituted with one or more substituents R^{L};
R^{L}Si(R^{L}₂);
Si(R^{L}₂)R^{L};
Si(R^{L}₂); and
R^{L}Si(R^{L}₂)R^{L}; and
wherein R^{L} is at each occurrence independently from each other selected from the group consisting of:
Ph, which is optionally substituted with one or more substituents independently from each other selected from the group consisting of Me, ⁱPr, ^{t}Bu, CN, CF₃, and Ph;
Me, ⁱPr, ^{t}Bu, CN, CF₃;
pyridinyl and pyridinylene, each of which is optionally substituted with one or more substituents independently from each other selected from the group consisting of Me, ⁱPr, ^{t}Bu, CN, CF₃, and Ph;
pyrimidinyl and pyrimidinylene, each of which is optionally substituted with one or more substituents independently from each other selected from the group consisting of Me, ⁱPr, ^{t}Bu, CN, CF₃, and Ph;
carbazolyl and carbazolylene, each of which is optionally substituted with one or more substituents independently from each other selected from the group consisting of Me, ⁱPr, ^{t}Bu, CN, CF₃, and Ph;
triazinyl and triazinylene, each of which is optionally substituted with one or more substituents independently from each other selected from the group consisting of Me, ⁱPr, ^{t}Bu, CN, CF₃, and Ph;
and
N(Ph)₂.

28. The organic molecule according to claim 20, wherein L is selected from the group consisting of structures of Formula L1 to L43: 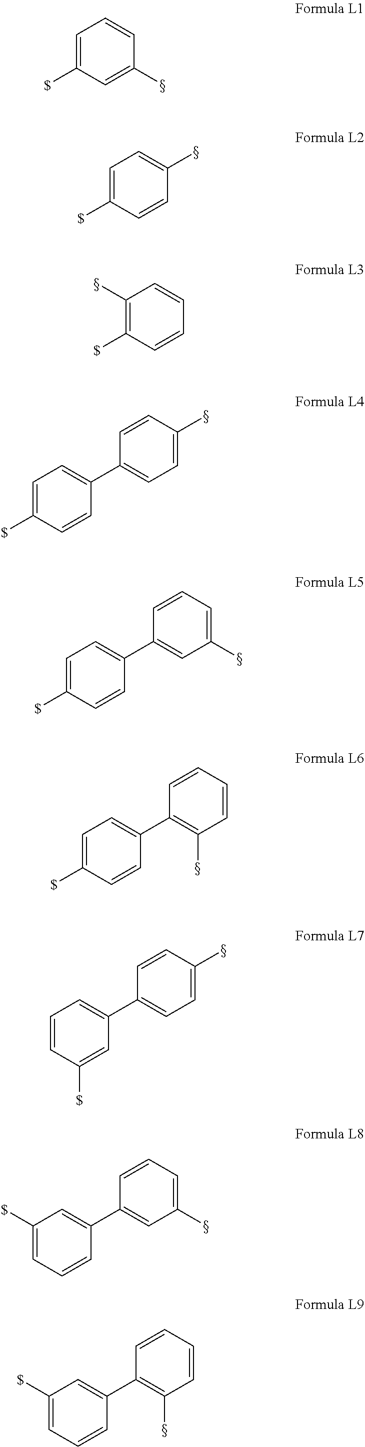 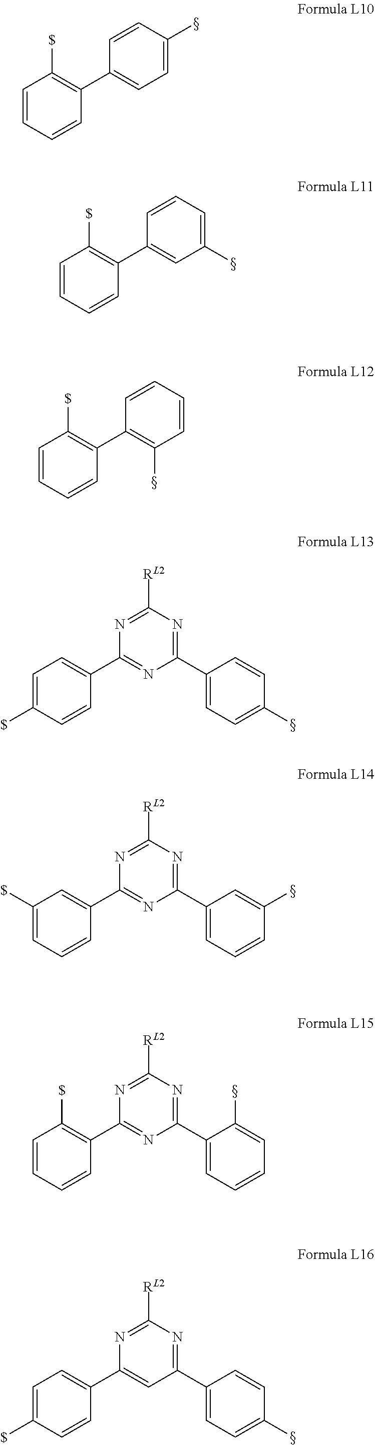 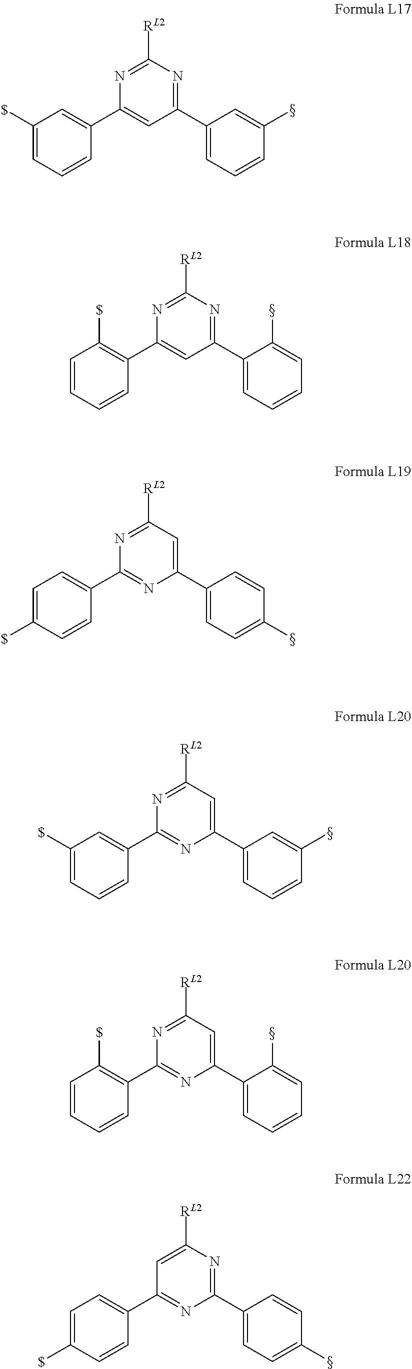 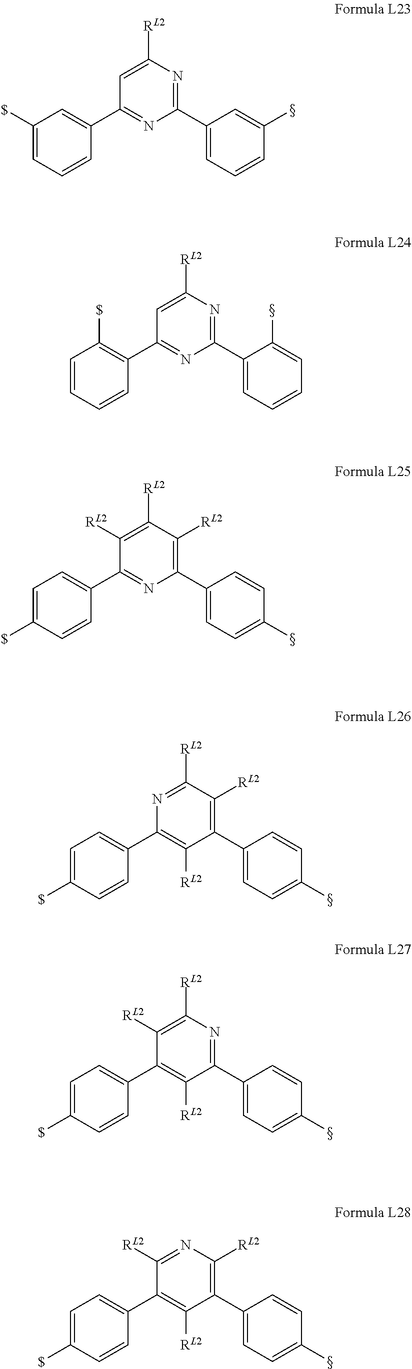 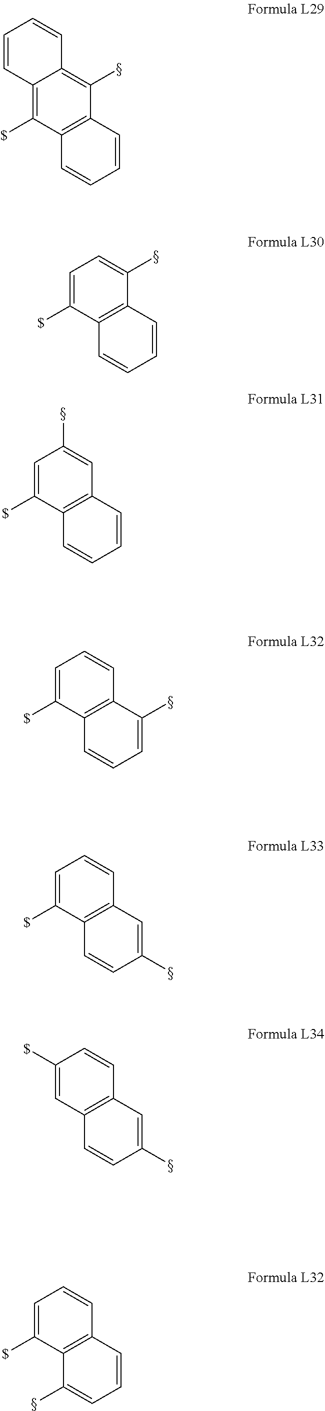 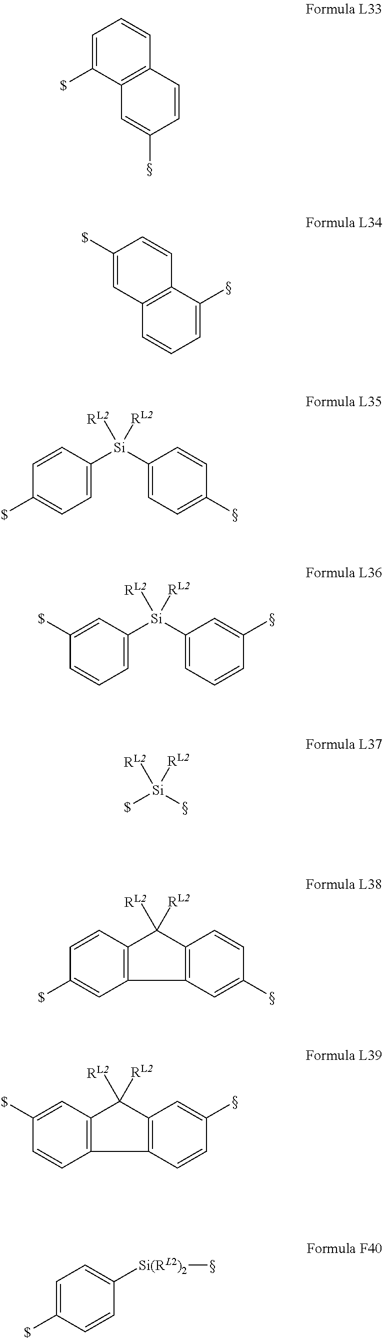 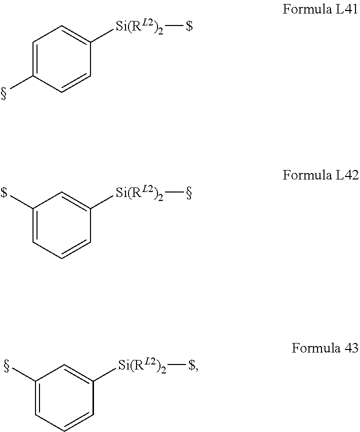
$ representing a binding site of a single bond linking L and M^{TADF},
§ representing a binding site of a single bond linking L and M^{BN}, and
R^{L2} being at each occurrence independently selected from the group consisting of H, deuterium, Me, ⁱPr, ^{t}Bu, Ph, and pyridyl.

29. The organic molecule according to claim 20, wherein M^{TADF} comprises
a first chemical moiety comprising a structure according to Formula I: 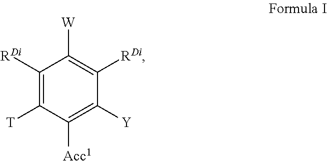
and
a second chemical moiety comprising a structure according to Formula II: 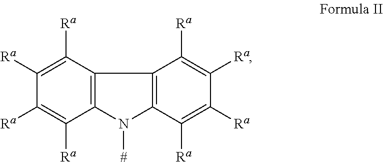
wherein:
the first chemical moiety is linked to the second chemical moiety via a single bond;
T is selected from the group consisting of
hydrogen (H), deuterium (D), R^{TADF1}, and a binding site of a single bond linking the first chemical moiety to the second chemical moiety,
W is selected from the group consisting of
a binding site of a single bond linking the first chemical moiety to the second chemical moiety,
a binding site of a single bond linking the TADF moiety M^{TADF} to the bridging unit L,
H, D, and R^{TADF1};
Y is selected from the group consisting of H, D, R^{TADF1}, and a binding site of a single bond linking the TADF moiety M^{TADF} to the bridging unit L;
Acc¹ is selected from the group consisting of:
triazinyl, which is optionally substituted with one or more substituents R⁶;
CN;
CF₃;
Ph, which is optionally substituted with one or more substituents selected from the group consisting of CN, CF₃, and F;
pyridyl, which is optionally substituted with one or more substituents R⁶; and
pyrimidyl, which is optionally substituted with one or more substituents R⁶;
#represents a binding site of a single bond linking the second chemical moieties to the first chemical moiety;
R^{Di} is independently selected from the group consisting of a binding site of a single bond linking the TADF moiety M^{TADF} to the bridging unit L, H, D, Me, ⁱPr, ^{t}Bu, SiPh₃, CN, CF₃,
Ph, which is optionally substituted with one or more substituents independently from each other selected from the group consisting of Me, ⁱPr, ^{t}Bu, and Ph, and
a third chemical moiety comprising a structure of Formula Q: 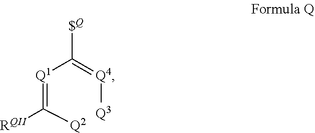
wherein
Q¹ is selected from the group consisting of N and C—R^{QI};
Q² is selected from the group consisting of N and C—R^{QIII};
Q₃ is selected from the group consisting of N and C—R^{QIV};
Q⁴ is selected from the group consisting of N and C—R^{QV}; and
$^{Q} represents a binding site of a single bond linking the third chemical moiety to the first chemical moiety;
R^{QI} is selected from the group consisting of
H,
D,
CN,
CF₃,
SiPh₃,
F,
Ph, and
a fourth chemical moiety comprising a structure of Formula IIQ: 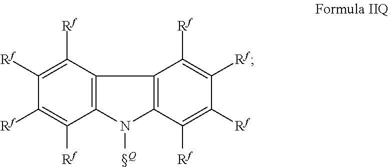
§^{Q} represents a binding site of a single bond linking the fourth chemical moiety to the third chemical moiety;
R^{QII} is selected from the group consisting of
a binding site of a single bond linking the TADF moiety M^{TADF} to the bridging unit L,
H, D, Me, ⁱPr, ^{t}Bu, SiPh₃, and
Ph, which is optionally substituted with one or more substituents independently from each other selected from the group consisting of Me, ⁱPr, ^{t}Bu, and Ph;
R^{QIII} is selected from the group consisting of
a binding site of a single bond linking the TADF moiety M^{TADF} to the bridging unit L,
H,
D,
CN,
CF₃,
SiPh₃,
F,
Ph, which is optionally substituted with one or more substituents R⁶,
triazinyl, which is optionally substituted with one or more substituents R⁶,
pyridyl, which is optionally substituted with one or more substituents R⁶, and
pyrimidyl, which is optionally substituted with one or more substituents R⁶;
R^{QIV} is selected from the group consisting of
a binding site of a single bond linking the TADF moiety M^{TADF} to the bridging unit L,
H,
D,
CN,
CF₃,
SiPh₃,
F,
Ph, which is optionally substituted with one or more substituents R⁶,
triazinyl, which is optionally substituted with one or more substituents R⁶,
pyridyl, which is optionally substituted with one or more substituents R⁶, and
pyrimidyl, which is optionally substituted with one or more substituents R⁶;
R^{QV} is selected from the group consisting of
a binding site of a single bond linking the TADF moiety M^{TADF} to the bridging unit L,
H, D, Me, ⁱPr, ^{t}Bu, SiPh₃, and
Ph, which is optionally substituted with one or more substituents independently from each other selected from the group consisting of Me, ⁱPr, ^{t}Bu, and Ph;
wherein in case one R^{Di} represents the third chemical moiety comprising a structure of Formula Q,
the other R^{Di} is selected from the group consisting of H, D, Me, ⁱPr, ^{t}Bu, SiPh₃,
Ph, which is optionally substituted with one or more substituents independently from each other selected from the group consisting of Me, ⁱPr, ^{t}Bu, and Ph, and
a binding site of a single bond linking the TADF moiety M^{TADF} to the bridging unit L;
R^{TADF1} is selected from the group consisting of
Me, ⁱPr, ^{t}Bu, SiPh₃, and
Ph, which is optionally substituted with one or more substituents independently from each other selected from the group consisting of Me, ⁱPr, ^{t}Bu, and Ph;
R^{a} at each occurrence independently from each other selected from the group consisting of:
a binding site of a single bond linking the TADF moiety M^{TADF} to the bridging unit L;
H;
D;
N(R⁵)₂;
OR⁵;
Si(R⁵)₃;
B(OR⁵)₂;
OSO₂R⁵;
CF₃;
CN;
F;
Br;
I;
C₁-C₄₀-alkyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₃-C₅₇-heteroaryl,
which is optionally substituted with one or more substituents R⁵;
R⁵ is at each occurrence independently from each other selected from the group consisting of:
H;
D;
N(R⁶)₂;
OR⁶;
Si(R⁶)₃;
B(OR⁶)₂;
OSO₂R⁶;
CF₃;
CN;
F;
Br;
I;
C₁-C₄₀-alkyl,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₁-C₄₀-alkoxy,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₁-C₄₀-thioalkoxy,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₂-C₄₀-alkenyl,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₂-C₄₀-alkynyl,
which is optionally substituted with one or more substituents R⁶ and
wherein one CH₂-group or more than one non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S, or CONR⁶;
C₆-C₆₀-aryl,
which is optionally substituted with one or more substituents R⁶; and
C₃-C₅₇-heteroaryl,
which is optionally substituted with one or more substituents R⁶;
R⁶ is at each occurrence independently from each other selected from the group consisting of:
C₆-C₁₈-aryl, which is optionally substituted with one or more C₁-C₅-alkyl substituents;
hydrogen;
deuterium;
OPh;
CF₃;
CN;
F;
C₁-C₅-alkyl, wherein optionally one or more hydrogen atoms are independently from each other substituted by deuterium, CN, CF₃, or F;
C₁-C₅-alkoxy, wherein optionally one or more hydrogen atoms are independently from each other substituted by deuterium, CN, CF₃, or F;
C₁-C₅-thioalkoxy, wherein optionally one or more hydrogen atoms are independently from each other substituted by deuterium, CN, CF₃, or F;
C₂-C₅-alkenyl, wherein optionally one or more hydrogen atoms are independently from each other substituted by deuterium, CN, CF₃, or F;
C₂-C₅-alkynyl, wherein optionally one or more hydrogen atoms are independently from each other substituted by deuterium, CN, CF₃, or F;
C₃-C₁₇-heteroaryl, which is optionally substituted with one or more C₁-C₅-alkyl substituents;
N(C₆-C₁₈-aryl)(C₆-C₁₈-aryl);
N(C₃-C₁₇-heteroaryl)(C₃-C₁₇-heteroaryl); and
N(C₃-C₁₇-heteroaryl)(C₆-C₁₈-aryl);
wherein two or more of the substituents R^{a} and/or R⁵ independently from each other optionally form a mono- or polycyclic, (hetero)aliphatic, (hetero)aromatic and/or benzo-fused ring system with one or more substituents R^{a} or R⁵;
R^{f} is at each occurrence independently from each other selected from the group consisting of:
H;
D;
N(R^{5f})₂;
OR^{5f};
Si(R^{5f})₃;
B(OR^{5f})₂;
OSO₂R^{5f};
CF₃;
CN;
F;
Br;
I;
C₁-C₄₀-alkyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₁-C₄₀-alkoxy,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₁-C₄₀-thioalkoxy,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₂-C₄₀-alkenyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₂-C₄₀-alkynyl,
which is optionally substituted with one or more substituents R^{5f} and
wherein one CH₂-group or more than one non-adjacent CH₂-groups are optionally substituted by R^{5f}C═CR^{5f}, C≡C, Si(R^{5f})₂, Ge(R^{5f})₂, Sn(R^{5f})₂, C═O, C═S, C═Se, C═NR^{5f}, P(═O)(R^{5f}), SO, SO₂, NR^{5f}, O, S, or CONR^{5f};
C₆-C₆₀-aryl,
which is optionally substituted with one or more substituents R^{5f}; and
C₃-C₅₇-heteroaryl,
which is optionally substituted with one or more substituents R^{5f};
R^{5f} is at each occurrence independently from each other selected from the group consisting of:
H;
D;
N(R^{6f})₂;
OR^{6f};
Si(R^{6f})₃;
B(OR^{6f})₂;
OSO₂R^{6f};
CF₃;
CN;
F;
Br;
I;
C₁-C₄₀-alkyl,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₁-C₄₀-alkoxy,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₁-C₄₀-thioalkoxy,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₂-C₄₀-alkenyl,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₂-C₄₀-alkynyl,
which is optionally substituted with one or more substituents R^{6f} and
wherein one CH₂-group or more than one non-adjacent CH₂-groups are optionally substituted by R^{6f}C═CR^{6f}, C≡C, Si(R^{6f})₂, Ge(R^{6f})₂, Sn(R^{6f})₂, C═O, C═S, C═Se, C═NR^{6f}, P(═O)(R^{6f}), SO, SO₂, NR^{6f}, O, S, or CONR^{6f};
C₆-C₆₀-aryl,
which is optionally substituted with one or more substituents R^{6f}; and
C₃-C₅₇-heteroaryl,
which is optionally substituted with one or more substituents R^{6f};
R^{6f} is at each occurrence independently from each other selected from the group consisting of:
H;
D;
OPh;
CF₃;
CN;
F;
C₁-C₅-alkyl,
wherein optionally one or more hydrogen atoms are independently from each other substituted by deuterium, CN, CF₃, or F;
C₁-C₅-alkoxy,
wherein optionally one or more hydrogen atoms are independently from each other substituted by deuterium, CN, CF₃, or F;
C₁-C₅-thioalkoxy,
wherein optionally one or more hydrogen atoms are independently from each other substituted by deuterium, CN, CF₃, or F;
C₂-C₅-alkenyl,
wherein optionally one or more hydrogen atoms are independently from each other substituted by deuterium, CN, CF₃, or F;
C₂-C₅-alkynyl,
wherein optionally one or more hydrogen atoms are independently from each other substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₁₈-aryl)(C₆-C₁₈-aryl);
N(C₃-C₁₇-heteroaryl)(C₃-C₁₇-heteroaryl); and
N(C₃-C₁₇-heteroaryl)(C₆-C₁₈-aryl);
wherein two or more of the substituents R^{f} and/or R^{5f} independently from each other optionally form a mono- or polycyclic, (hetero)aliphatic, (hetero)aromatic and/or benzo-fused ring system with one or more substituents R^{f} or R^{5f};
wherein M^{TADF} contains exactly one binding site of the single bond linking the TADF moiety M^{TADF} to the bridging unit L; and
wherein one selected from the group consisting of T, W, and Y represents a binding site of a single bond linking the first chemical moiety and the second chemical moiety.

30. The organic molecule according to claim 29, wherein the first chemical moiety comprises a structure of Formula Ia: 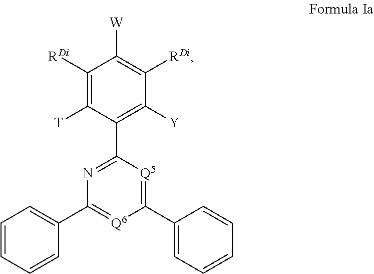
wherein:
R^{Di}, T, Wand Y are each the same defined as in Formula I;
Q⁵ is selected from the group consisting of N and C—H;
Q⁶ is selected from the group consisting of N and C—H;
wherein at least one of Q⁵ or Q⁶ is N; and
wherein exactly one substituent selected from the group consisting of T and W represents a binding site of a single bond linking the first chemical moiety and the second chemical moiety.

31. The organic molecule according to claim 29, wherein the second chemical moiety comprises a structure of Formula IIb: 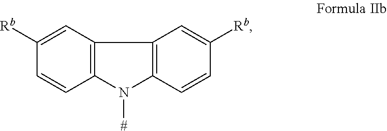
wherein
R^{b} is at each occurrence independently from each other selected from the group consisting of a binding site of a single bond linking the TADF moiety M^{TADF} to the bridging unit L;
hydrogen, deuterium, N(R⁵)₂, OR⁵, Si(R⁵)₃, B(OR⁵)₂, OSO₂R⁵, CF₃, CN, F, Br, I;
C₁-C₄₀-alkyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₃-C₅₇-heteroaryl,
which is optionally substituted with one or more substituents R⁵; and
wherein apart from that the definitions in Formula I apply.

32. The organic molecule according claim 29, wherein the second chemical moiety comprises a structure of Formula IIc: 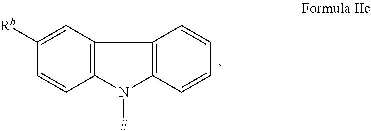
wherein
R^{b} is selected from the group consisting of: a binding site of a single bond linking the TADF moiety M^{TADF} to the bridging unit L; hydrogen; deuterium; N(R⁵)₂; OR⁵; Si(R⁵)₃; B(OR⁵)₂; OSO₂R⁵; CF₃; CN; F; Br; I;
C₁-C₄₀-alkyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-alkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₁-C₄₀-thioalkoxy,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkenyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₂-C₄₀-alkynyl,
which is optionally substituted with one or more substituents R⁵ and
wherein one CH₂-group or more than one non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S, or CONR⁵;
C₆-C₆₀-aryl,
which is optionally substituted with one or more substituents R⁵; and
C₃-C₅₇-heteroaryl,
which is optionally substituted with one or more substituents R⁵; and
wherein apart from that the definitions in Formula I apply.

33. The organic molecule according to claim 31, wherein R^{b} is at each occurrence independently from each other selected from the group consisting of:
a binding site of a single bond linking the TADF moiety M^{TADF} to the bridging unit L:
hydrogen;
deuterium;
Me, ⁱPr, ^{t}Bu, CN, CF₃;
Ph, which is optionally substituted with one or more substituents independently from each other selected from the group consisting of Me, ⁱPr, ^{t}Bu, CN, CF₃, and Ph;
pyridinyl, which is optionally substituted with one or more substituents independently from each other selected from the group consisting of Me, ⁱPr, ^{t}Bu, CN, CF₃, and Ph;
pyrimidinyl, which is optionally substituted with one or more substituents independently from each other selected from the group consisting of Me, ⁱPr, ^{t}Bu, CN, CF₃, and Ph;
carbazolyl, which is optionally substituted with one or more substituents independently from each other selected from the group consisting of Me, ⁱPr, ^{t}Bu, CN, CF₃, and Ph;
triazinyl, which is optionally substituted with one or more substituents independently from each other selected from the group consisting of Me, ⁱPr, ^{t}Bu, CN, CF₃, and Ph;
and
N(Ph)₂.

34. An optoelectronic device, comprising the organic molecule according to claim 20 as a luminescent emitter.

35. The optoelectronic device according to claim 34, wherein the optoelectronic device is at least one selected from the group consisting of:
organic light-emitting diodes (OLEDS);
light-emitting electrochemical cells;
OLED-sensors;
organic diodes;
organic solar cells;
organic transistors;
organic field-effect transistors;
organic lasers;
down-conversion elements; and
combinations thereof.

36. A composition, comprising:
one or more organic molecules according to claim 20 as a luminescent emitter; and
one or more emitter and/or host materials, which differ from the organic molecules; and
optionally, one or more dyes and/or one or more solvents.

37. An optoelectronic device, comprising the composition according to claim 36 or a layer formed from the composition, wherein the optoelectronic device is at least one selected from the group consisting of organic light-emitting diodes (OLED), light-emitting electrochemical cell, OLED-sensors, organic diodes, organic solar cells, organic transistors, organic field-effect transistors, organic lasers, down-conversion elements, and combinations thereof.

38. The optoelectronic device according to claim 37, comprising
a substrate,
an anode and a cathode, wherein the anode or the cathode is disposed on the substrate, and
a light-emitting layer between the anode and the cathode and comprising the composition or the layer formed from the composition.

39. The optoelectronic device according to claim 34, comprising
a substrate,
an anode and a cathode, the anode or the cathode being on the substrate, and
a light-emitting layer between the anode and the cathode and comprising the organic molecule.
